(19) United States
(12) Patent Application Publication
(10) Pub. No.: US 2024/0147749 A1
(43) Pub. Date: May 2, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Cuifang Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/374,159

(22) Filed: Sep. 28, 2023

(30) Foreign Application Priority Data
Sep. 29, 2022 (CN) 202211195315.7

(51) Int. Cl. H10K 50/12; C07F 15/00; C09K 11/06; H10K 85/30; H10K 85/60

(52) U.S. Cl. CPC H10K 50/12; C07F 15/0033; C09K 11/06; H10K 85/342; H10K 85/631; H10K 85/654; C09K 2211/185

(57) ABSTRACT

Provided are an organic electroluminescent material and a device thereof. The organic electroluminescent material is a metal complex having a ligand of a structure of Formula 1 and can be used as an emissive material in an emissive layer of an organic electroluminescent device. The metal complexes having these new ligands can achieve a significant red shift of the maximum emission wavelength of the device, effectively control the emitted color of the device, achieve deeper red luminescence, significantly improve the efficiency of the device, and reduce the voltage of the device. These new metal complexes can provide better device performance. Further provided are an electroluminescent device including the metal complex and a compound composition including the metal complex.

### CROSS-REFERENCE TO RELATED APPLICATION(S)

This application claims priority to Chinese Patent Application No. CN 202211195315.7 filed on Sep. 29, 2022, the disclosure of which is incorporated herein by reference in its entirety.

### TECHNICAL FIELD

The present disclosure relates to compounds for organic electronic devices such as organic light-emitting devices. More particularly, the present disclosure relates to a metal complex having a ligand of a structure of Formula 1 and an organic electroluminescent device and compound composition including the metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, rang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modem organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Phosphorescent metal complexes can be used as phosphorescent doped materials for the emissive layer and are applied to the field of organic electroluminescence lighting or display. To meet the needs in different cases, the adjustment of the color or saturation of a material on a certain basis can be achieved by adjusting the structure of the ligand in the material so that phosphorescent metal complexes with different emission wavelengths or saturations are obtained.

CN111892631A discloses a metal complex having the following general structure:

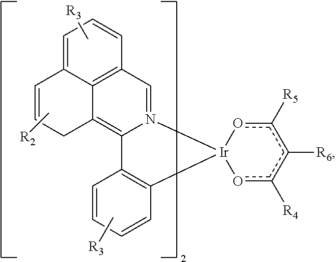

and further discloses the following specific structure:

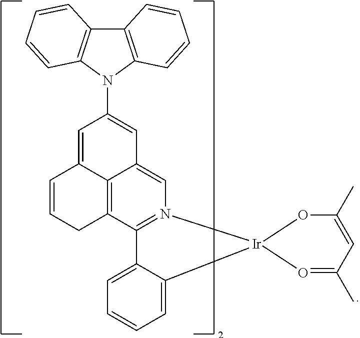

The metal complex disclosed therein must have a ligand of a skeleton structure of

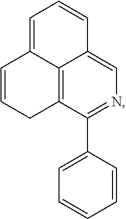 [SMILES: C1=Cc2cccc3cnc(-c4ccccc4)c(c23)C1]

and does not disclose or teach a metal complex where the carbazole or similar structures thereof is substituted onto a different ligand skeleton structure.

To meet the increasing requirements of the industry for the performance of electroluminescent devices in various aspects, such as emitted color, color saturation, drive voltage, and luminescence efficiency, research on phosphorescent devices is still urgently needed. In the research on phosphorescent devices, the structure of ligands in phosphorescent materials is crucial to the performance of phosphorescent materials.

### SUMMARY

The present disclosure aims to provide a series of metal complexes having a ligand of a structure of Formula 1 to solve at least part of the above-mentioned problems. The metal complex may be used as the emissive material in organic electroluminescent devices. The metal complexes having these new ligands can achieve a significant red-shift of the maximum emission wavelength of the device, effectively control the emitted color of the device, achieve deeper red luminescence, significantly improve the efficiency of the device, and reduce the voltage of the device. These new metal complexes can provide better device performance.

According to an embodiment of the present disclosure, a metal complex is disclosed. The metal complex includes a metal M and a ligand Lₐ coordinated to the metal M, wherein the metal M is selected from a metal with a relative atomic mass greater than 40, and Lₐ has a structure represented by Formula 1:

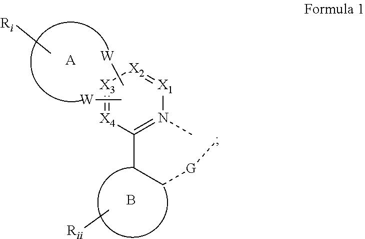

wherein the ring A and the ring B are, at each occurrence identically or differently, selected from a five-membered unsaturated carbocyclic ring, an aromatic ring having 6 to 30 carbon atoms or a heteroaromatic ring having 3 to 30 carbon atoms;
W is, at each occurrence identically or differently, selected from C, CRᵢᵢᵢ, CRᵢᵢᵢRᵢᵢᵢ, SiRᵢᵢᵢRᵢᵢᵢ, GeRᵢᵢᵢRᵢᵢᵢ, PRᵢᵢᵢ, O, S, N or NRᵢᵢᵢ; when two Rᵢᵢᵢ are present at the same time, the two Rᵢᵢᵢ are identical or different;
X₁ to X₄ are, at each occurrence identically or differently, selected from C, CRₓ or N, and any adjacent two of X₁ to X₄ are selected from C and are each joined to W in the ring A to form a fused ring;
V is, at each occurrence identically or differently, selected from C or N;
G is, at each occurrence identically or differently, selected from a single bond, O, S, Se, Nk_{g} or PR_{g};
Rᵢ and Rᵢᵢ represent, at each occurrence identically or differently, mono-substitution, multiple substitutions or non-substitution;
at least one of Rᵢ, Rᵢᵢᵢ, and Rₓ is present and has a structure represented by Formula 2:

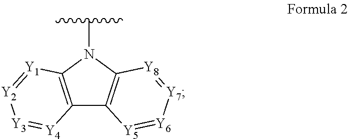

wherein “ [symbol] ” represents an attachment position of Formula 2, and Y₁ to Y₈ are, at each occurrence identically or differently, selected from CRₓ or N;
Rᵢ, Rᵢᵢ, Rᵢᵢᵢ, Rₓ, R_{g} and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵢ, Rᵢᵢ, Rᵢᵢᵢ, Rₓ, and R_{y} can be optionally joined to form a ring, and when X₄ is selected from CRₓ, the Rₓ is not joined to Rᵢ to form a ring.

According to another embodiment of the present disclosure, an electroluminescent device is further disclosed. The electroluminescent device includes an anode, a cathode, and an organic layer disposed between the anode and the cathode, wherein the organic layer includes a metal complex whose specific structure is shown in the preceding embodiment.

According to another embodiment of the present disclosure, a compound composition is further disclosed. The compound composition includes a metal complex whose specific structure is shown in the preceding embodiments.

The metal complex including a ligand of a structure of Formula 1, as disclosed by the present disclosure, may be used as the emissive material in the electroluminescent devices. The metal complexes having these new ligands can achieve a significant red-shift of the maximum emission wavelength of the device, effectively control the emitted color of the device, achieve deeper red luminescence, significantly improve the efficiency of the device, and reduce the voltage of the device. These new metal complexes can provide better device performance.

### BRIEF DESCRIPTION OF DRAWINGS

FIG. 1 is a schematic diagram of an organic light-emitting apparatus that may include a metal complex and a compound composition disclosed herein.

FIG. 2 is a schematic diagram of another organic light-emitting apparatus that may include a metal complex and a compound composition disclosed herein.

### DETAILED DESCRIPTION

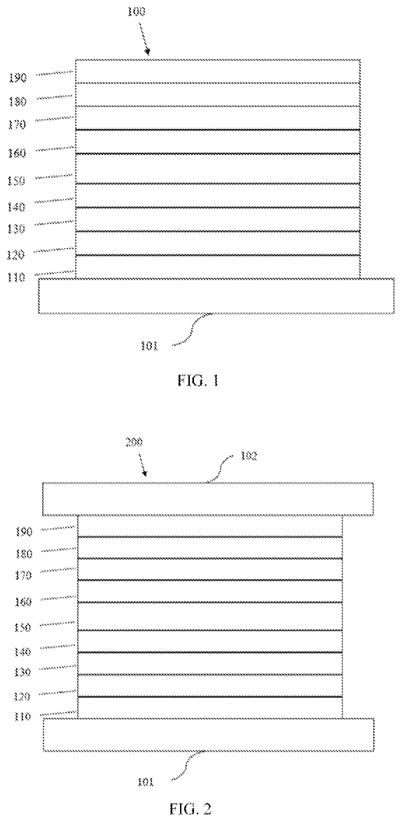

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols, 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trinethylgermanylmethyl, trimethylgermanylethyl, trimethylgermanylisopropyl, dimethylethylgermanylmethyl, dimethylisopropylgennanylmethyl, tert-butyldimethylgermanylmethyl, triethylgermanylmethyl, triethylgermanylethyl, triisopropylgermanylnmethyl, triisopropylgermanylethyl, trimethylsilylnmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms.

Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, n-hydroxybenzyl, o-hydroxybenzyl, p-aminobenzyl, n-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgennanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgennanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

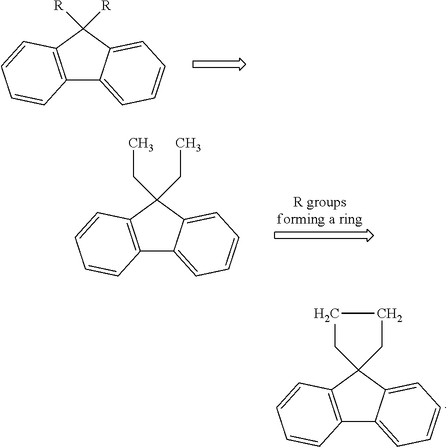

The expression that adjacent substituents can be optionally joined to form a ring is also intended to mean that two substituents bonded to carbon atoms which are directly bonded to each other are joined to each other via a chemical bond to form a ring, which can be exemplified by the following formula:

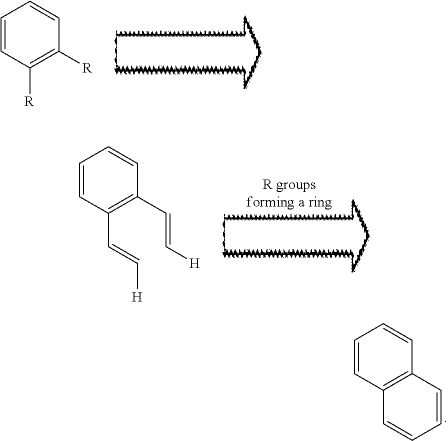

The expression that adjacent substituents can be optionally joined to form a ring is also intended to mean that two substituents bonded to further distant carbon atoms are joined to each other via a chemical bond to form a ring, which can be exemplified by the following formula:

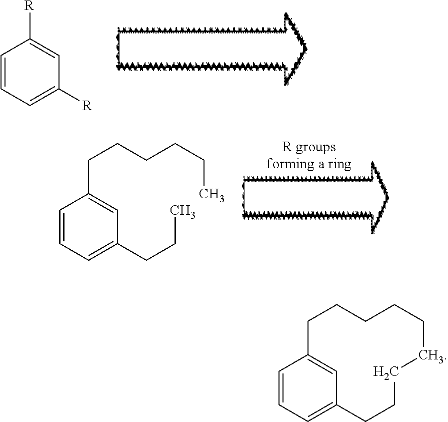

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

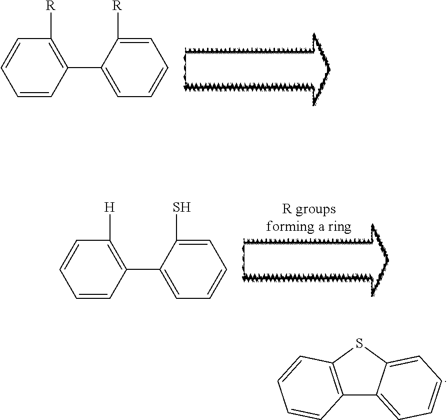

According to an embodiment of the present disclosure, a metal complex is disclosed. The metal complex includes a metal M and a ligand Lₐ coordinated to the metal M, wherein the metal M is selected from a metal with a relative atomic mass greater than 40, and Lₐ has a structure represented by Formula 1:

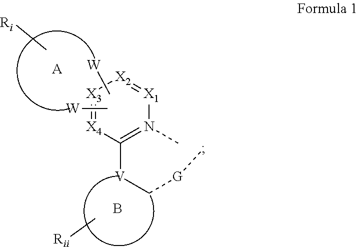

wherein the ring A and the ring B are, at each occurrence identically or differently, selected from a five-membered unsaturated carbocyclic ring, an aromatic ring having 6 to 30 carbon atoms or a heteroaromatic ring having 3 to 30 carbon atoms;
W is, at each occurrence identically or differently, selected from C, CRᵢᵢᵢ, CRᵢᵢᵢRᵢᵢᵢ, SiRᵢᵢᵢRᵢᵢᵢ, GeRᵢᵢᵢRᵢᵢᵢ, PRᵢᵢᵢ, O, S, N or NRᵢᵢᵢ; when two Rᵢᵢᵢ are present at the same time, the two Rᵢᵢᵢ are identical or different;
X₁ to X₄ are, at each occurrence identically or differently, selected from C, CRₓ or N, and any adjacent two of X₁ to X₄ are selected from C and are each joined to W in the ring A to form a fused ring;
V is, at each occurrence identically or differently, selected from C or N;
G is, at each occurrence identically or differently, selected from a single bond, O, S, Se, NR_{g} or PR_{g};
Rᵢ and Rᵢᵢ represent, at each occurrence identically or differently, mono-substitution, multiple substitutions or non-substitution;
at least one of Rᵢ, Rᵢᵢᵢ, and Rₓ is present and has a structure represented by Formula 2:

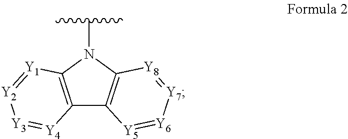

wherein “ [symbol] ” represents an attachment position of Formula 2, and Y₁ to Y₈ are, at each occurrence identically or differently, selected from CR_{y} or N;
Rᵢ, Rᵢᵢ, Rᵢᵢᵢ, Rₓ, R_{y}, and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents Rᵢ, Rᵢᵢ, Rᵢᵢᵢ, Rₓ, and R_{y} can be optionally joined to form a ring, and when X₄ is selected from CRₓ, the Rₓ is not joined to Rᵢ to form a ring.

Herein, the expression that any adjacent two of X₁ to X₄ are selected from C and are each joined to W in the ring A to form a fused ring includes the following cases: X₁ and X₂ are C and are each joined to W in the ring A to form a fused ring, X₂ and X₃ are C and are each joined to W in the ring A to form a fused ring, and X₃ and X₄ are C and are each joined to W in the ring A to form a fused ring. For example, when X₃ and X₄ are C and are each joined to W in the ring A to form a fused ring, the ligand Lₐ has the following structure:

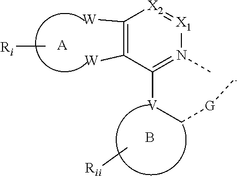

Herein, the ring A is selected from a five-membered unsaturated carbocyclic ring, an aromatic ring having 6 to 30 carbon atoms or a heteroaromatic ring having 3 to 30 carbon atoms, wherein the two carbon atoms joined to W in X₁ to X₄ are counted when counting the number of carbon atoms included in the five-membered unsaturated carbocyclic ring, the aromatic ring or the heteroaromatic ring.

Herein, the expression that adjacent substituents Rᵢ, Rᵢᵢ, Rᵢᵢᵢ, Rₓ, and R_{y} can be optionally joined to form a ring is intended to mean that any one or more of groups of adjacent substituents, such as adjacent substituents Rᵢ, adjacent substituents Rᵢᵢ, adjacent substituents Rᵢᵢᵢ, adjacent substituents Rₓ, adjacent substituents R_{y}, adjacent substituents Rᵢ and Rᵢᵢ, adjacent substituents Rᵢ and Rᵢᵢᵢ, adjacent substituents Rᵢ and Rₓ, adjacent substituents R₁ and R_{y}, adjacent substituents Rᵢ, and Rᵢᵢᵢ, adjacent substituents Rᵢ and Rₓ, adjacent substituents Rᵢᵢ and R_{y}, adjacent substituents Rᵢᵢ and Rᵢᵢᵢ, adjacent substituents Rᵢᵢᵢ and R_{y}, adjacent substituents Rₓ and R_{y}, can be joined to form a ring. Apparently, for the persons skilled in the art, it is also possible that none of these groups are joined to form a ring.

According to an embodiment of the present disclosure, the ring A is selected from a five-membered unsaturated carbocyclic ring, an aromatic ring having 6 to 18 carbon atoms or a heteroaromatic ring having 3 to 18 carbon atoms.

According to an embodiment of the present disclosure, the ring A is a benzene ring, a naphthalene ring, a pyridine ring, a pyrrole ring, a furan ring, a thiophene ring, an imidazole ring, a benzofuran ring or a benzothiophene ring.

According to an embodiment of the present disclosure, the ring A is a benzene ring, a naphthalene ring, a furan ring, a thiophene ring, a benzofuran ring or a benzothiophene ring.

According to an embodiment of the present disclosure, X₁ and X₂ are C and are each joined to W in the ring A to form a fused ring, the ring A forms a fused ring structure via X₁ and X₂, and X₁ and X₄ are selected from C, CRₓ or N:
wherein Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, X₃ and X₄ are C and are each joined to W in the ring A to form a fused ring structure, the ring A forms a fused ring structure via X₃ and X₄, and X₁ and X₂ are selected from C, CRₓ or N:
wherein Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, V is selected from C, and the ring B is selected from an aromatic ring having 6 to 20 carbon atoms or a heteroaromatic ring having 3 to 20 carbon atoms.

According to an embodiment of the present disclosure, the ring B has a structure represented by Formula 3 or Formula 4:

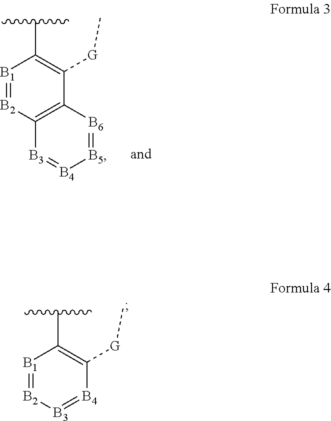

wherein “ [symbol] ” represents a position where Formula 3 or Formula 4 is joined to a six-membered ring including X₁ to X₄ in Formula 1, and B₁ to B₆ are, at each occurrence identically or differently, selected from CRᵢᵢ or N;
G is, at each occurrence identically or differently, selected from a single bond, O, S, Se, NR_{g} or PR_{g};
Rᵢᵢ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents Rᵢᵢ and R_{g} can be optionally joined to form a ring.

Herein, the expression that adjacent substituents Rᵢᵢ and R_{g} can be optionally joined to form a ring is intended to mean that any one or more of groups of adjacent substituents, such as adjacent substituents Rᵢᵢ, adjacent substituents R_{g}, and adjacent substituents Rᵢᵢ and R_{g}, can be joined to form a ring. Apparently, for the persons skilled in the art, it is also possible that none of these groups are joined to form a ring.

According to an embodiment of the present disclosure, at least one of W is selected from N.

According to an embodiment of the present disclosure, W is, at each occurrence identically or differently, selected from C, CRᵢᵢᵢ or CRᵢᵢᵢRᵢᵢᵢ; when two Rᵢᵢᵢ are present at the same time, the two Rᵢᵢᵢ are identical or different;
Rᵢᵢᵢ is, at each occurrence identically or differently, selected from the group consisting of hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, V is C, and G is selected from a single bond.

According to an embodiment of the present disclosure, Lₐ is selected from a structure represented by any one of Formula 5 to Formula 17:

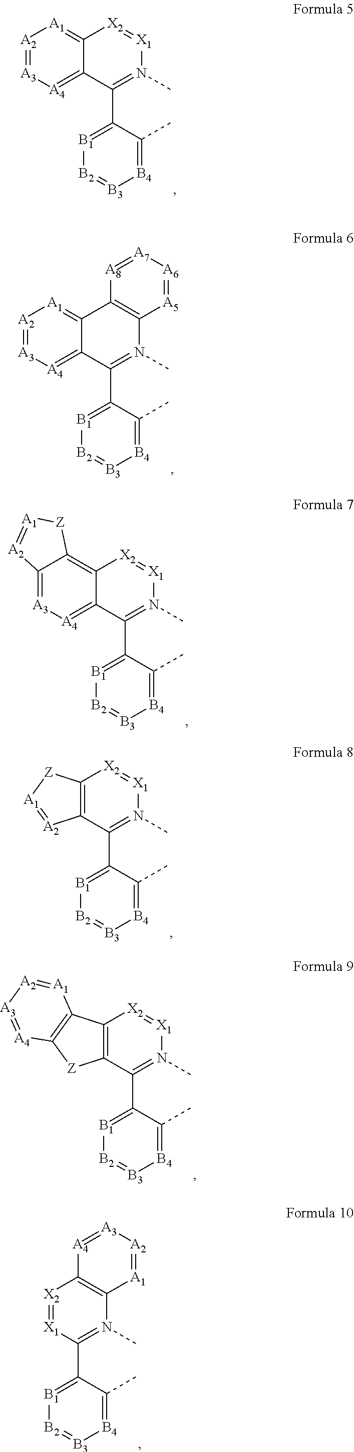

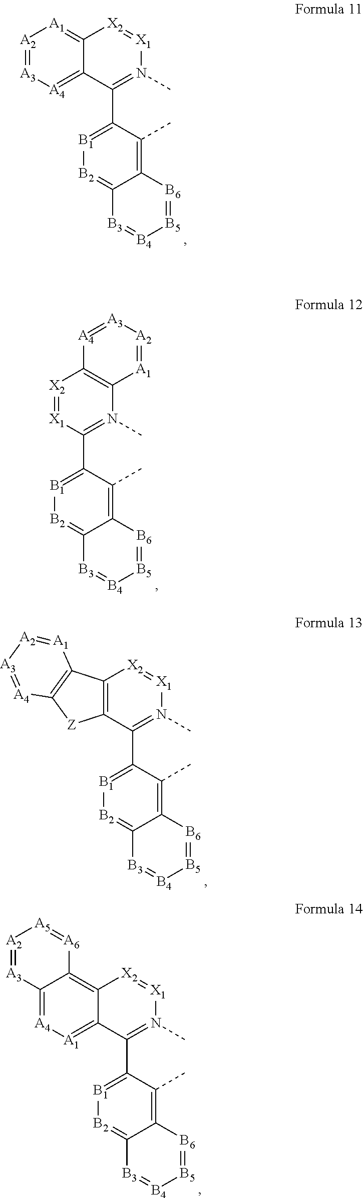

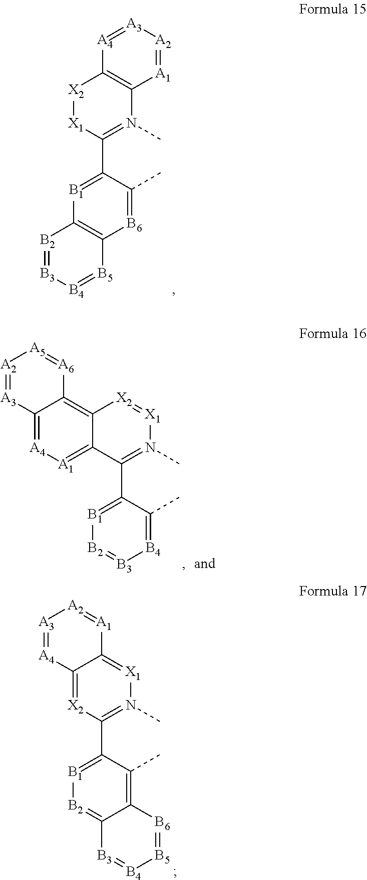

wherein
in Formula 5 to Formula 17, X₁ to X₂ are, at each occurrence identically or differently, selected from CRₓ or N, A₁ to A₈ are, at each occurrence identically or differently, selected from CRᵢ or N, and B₁ to B₆ are, at each occurrence identically or differently, selected from CRᵢᵢ or N; at least one of Rᵢ, Rᵢᵢᵢ, and Rₓ is present and has the structure represented by Formula 2:

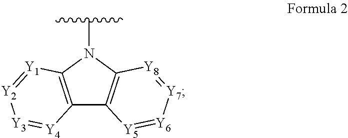

wherein “ [symbol] ” represents an attachment position of Formula 2, and Y₁ to Y₈ are, at each occurrence identically or differently, selected from CR_{y} or N;
Z is, at each occurrence identically or differently, selected from CRᵢᵢᵢRᵢᵢᵢ, SiRᵢᵢᵢRᵢᵢᵢ, GeRᵢᵢᵢRᵢᵢᵢ, PRᵢᵢᵢ, O, S or NRᵢᵢᵢ; when two Rᵢᵢᵢ are present at the same time, the two Rᵢᵢᵢ are identical or different;
Rₓ, R_{y}, Rᵢ, Rᵢᵢ, and Rᵢᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y}, Rᵢ, Rᵢᵢ, and Rᵢᵢᵢ can be optionally joined to form a ring, and in Formula 17, when X₂ is selected from CRₓ, the Rₓ is not joined to Rᵢ to form a ring.

According to an embodiment of the present disclosure, Z is, at each occurrence identically or differently, selected from O, S or NRᵢᵢᵢ.

According to an embodiment of the present disclosure, Lₐ is selected from a structure represented by Formula 5 or Formula 12.

According to an embodiment of the present disclosure, in Formula 5 to Formula 17, at least one of X₁ to Xₙ and/or A₁ to Aₘ and/or B₁ to B_{q} is selected from N, wherein the Xₙ corresponds to one with the largest serial number of X₁ to X₂ in any one of Formula 5 to Formula 17, the Aₘ corresponds to one with the largest serial number of A₁ to A₈ in any one of Formula 5 to Formula 17, and the B_{c} corresponds to one with the largest serial number of B₁ to B₆ in any one of Formula 5 to Formula 17.

According to an embodiment of the present disclosure, in Formula 5 to Formula 17, at least one of X₁ to X₂ is selected from N.

According to an embodiment of the present disclosure, in Formula 5 to Formula 17, X₂ is N.

According to an embodiment of the present disclosure, in Formula 5 to Formula 17, X₁ to X₂ are each independently selected from CRₓ, A₁ to A₈ are each independently selected from CRᵢ, B₁ to Bₕ are each independently selected from CRᵢᵢ, and at least one of Rᵢ and Rₓ is present and has the structure represented by Formula 2;
adjacent substituents Rₓ, Rᵢ, Rᵢᵢ, and R_{y} can be optionally joined to form a ring, and in Formula 17, when X₇ is selected from CRₓ, the Rₓ is not joined to Rᵢ to form a ring.

Herein, the expression that adjacent substituents Rₓ, Rᵢ, Rᵢᵢ, and R_{y} can be optionally joined to form a ring is intended to mean that any one or more of groups of adjacent substituents, such as adjacent substituents Rₓ, adjacent substituents Rᵢ, adjacent substituents Rᵢ, adjacent substituents R_{y}, adjacent substituents Rₓ and Rᵢ, adjacent substituents Rₓ and Rᵢᵢ, adjacent substituents Rₓ and R_{y}, adjacent substituents Rᵢ and Rᵢᵢ, adjacent substituents Rᵢ and R_{y}, and adjacent substituents Rᵢᵢ and R_{y}, can be joined to form a ring. Apparently, for the persons skilled in the art, it is also possible that none of these groups are joined to form a ring.

According to an embodiment of the present disclosure, in Formula 2, Y₁ to Y₈ are, at each occurrence identically or differently, selected from CRₓ;
R_{y} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 2, at least one of Y₁ to Y₈ is selected from N.

According to an embodiment of the present disclosure, Rₓ, R_{y}, Rᵢ, and Rᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, at least two or three of Rₓ, Rᵢ, and Rᵢᵢ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

According to an embodiment of the present disclosure, in Formula 5 to Formula 17, X₁ to X₂ are, at each occurrence identically or differently, selected from CR₁, A₁ to A₈ are, at each occurrence identically or differently, selected from CRᵢ, and at least one of Rᵢ and Rₓ is present and has the structure represented by Formula 2.

According to an embodiment of the present disclosure, in Formula 5 to Formula 9. Formula 11, Formula 13, Formula 14, Formula 16, and Formula 17, A₁ to A₄ are, at each occurrence identically or differently, selected from CRᵢ, and at least one of Rᵢ has the structure represented by Formula 2; in Formula 10, Formula 12, and Formula 15, X₁ to X₂ are, at each occurrence identically or differently, selected from CRₓ, and at least one of Rᵢ has the structure represented by Formula 2.

According to an embodiment of the present disclosure, in Formula 5, Formula 6, Formula 11, Formula 14, Formula 16, and Formula 17, A₂ to A₁ are, at each occurrence identically or differently, selected from CRᵢ, and at least one of Rᵢ has the structure represented by Formula 2; in Formula 9 and Formula 13, A₂ to A₃ are, at each occurrence identically or differently, selected from CRₓ, and at least one of Rᵢ has the structure represented by Formula 2; in Formula 7 and Formula 8, A₁ to A₂ are, at each occurrence identically or differently, selected from CRᵢ, and at least one of Rᵢ has the structure represented by Formula 2; in Formula 10, Formula 12, and Formula 15, X₂ is, at each occurrence identically or differently, selected from CRₓ, and at least one of Rₓ has the structure represented by Formula 2.

According to an embodiment of the present disclosure, in Formula 5 to Formula 17, Rᵢᵢ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms or combinations thereof.

According to an embodiment of the present disclosure, in Formula 5 to Formula 17, Rᵢᵢ is, at each occurrence identically or differently, selected from hydrogen, deuterium, fluorine, methyl, ethyl, isopropyl, isobutyl, t-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl or combinations thereof.

According to an embodiment of the present disclosure, in Formula 5 to Formula 17, B₂ is CRᵢᵢ, and the Rᵢᵢ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted alkenyl having 2 to 20 carbon atoms, and combinations thereof.

According to an embodiment of the present disclosure, in Formula 5 to Formula 17, B₂ is CRᵢᵢ, and the Rᵢᵢ is, at each occurrence identically or differently, selected from deuterium, halogen, substituted or unsubstituted alkyl having 1 to 20 carbon atoms, substituted or unsubstituted cycloalkyl having 4 to 10 carbon atoms, substituted or unsubstituted alkylsilyl having 3 to 10 carbon atoms or combinations thereof.

According to an embodiment of the present disclosure, in Formula 5 to Formula 17, B₂ is CRᵢᵢ, and the Rᵢᵢ is, at each occurrence identically or differently, selected from deuterium, fluorine, methyl, ethyl, isopropyl, isobutyl, i-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl or combinations thereof.

According to an embodiment of the present disclosure, Lₐ is, at each occurrence identically or differently, selected from the group consisting of Lₐ₁ to Lₐ₇₄₂, wherein the specific structures of Lₐ₁ to Lₐ₇₄₂ are referred to claim 12.

According to an embodiment of the present disclosure, the metal complex has a structure of M(Lₐ)ₘ(L_{b})ₙ(L_{c})_{q};
wherein the metal M is selected from a metal with a relative atomic mass greater than 40; Lₐ, L_{b}, and L_{c} are a first ligand, a second ligand and a third ligand of the complex, respectively; m is 1, 2 or 3, n is 0, 1 or 2, q is 0, 1 or 2, and m+n+q equals an oxidation state of the metal M; when m is greater than 1, a plurality of L_{g} are identical or different; when n is 2, two L_{b} are identical or different; when q is 2, two L_{c} are identical or different;
L_{b} and L_{c} are, at each occurrence identically or differently, selected from the group consisting of the following structures:

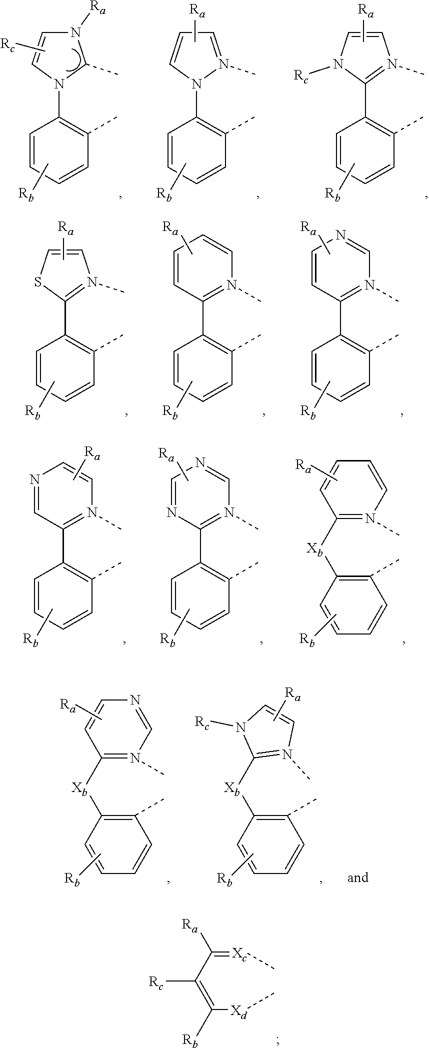

wherein Rₐ, R_{b}, and R_{c} represent, at each occurrence identically or differently, mono-substitution, multiple substitutions or non-substitution;
X_{b} is, at each occurrence identically or differently, selected from the group consisting of, O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; adjacent substituents Rₐ, R_{b}, R_{c}, R_{N1}, R_{N2}, R_{C1}, and R_{C2} can be optionally joined to form a ring.

Herein, the expression that adjacent substituents Rₐ, R_{b}, R_{c}, R_{N1}, R_{N2}, R_{C1}, and R_{C2} can be optionally joined to form a ring is intended to mean that any one or more of groups of adjacent substituents, such as adjacent substituents Rₐ, adjacent substituents R_{b}, adjacent substituents R_{c}, adjacent substituents R_{N1}, adjacent substituents R_{N2}, adjacent substituents R_{C1}, adjacent substituents R_{C2}, adjacent substituents Rₐ and R_{b}, adjacent substituents Rₐ and R_{c}, adjacent substituents Rₐ and R_{C2}, adjacent substituents R_{c} and R_{C2}, adjacent substituents Rₐ and R_{C1}, adjacent substituents Rₐ and R_{C2}, adjacent substituents R_{b} and R_{C1}, adjacent substituents R_{b} and R_{N1}, adjacent substituents R_{b} and R_{N2}, adjacent substituents R_{b} and R_{C1}, adjacent substituents R_{b} and R_{C2}, adjacent substituents R_{c} and R_{N1}, adjacent substituents R_{c} and R_{N1}, adjacent substituents R_{c} and R_{C1}, adjacent substituents R_{c} and R_{C2}, adjacent substituents R_{N1} and R_{C1}, adjacent substituents R_{N1} and R_{C2}, adjacent substituents R_{N2} and R_{C1}, adjacent substituents R_{N2} and R_{C2}, and adjacent substituents R_{C1} and R_{C2}, can be joined to form a ring. Apparently, for the persons skilled in the art, it is also possible that none of these groups are joined to form a ring.

According to an embodiment of the present disclosure, the metal M is selected from Ir, Rh, Re, Os, Pt, Au or Cu.

According to an embodiment of the present disclosure, the metal M is selected from Ir, Pt or Os.

According to an embodiment of the present disclosure, the metal M is Ir.

According to an embodiment of the present disclosure. L_{b} is, at each occurrence identically or differently, selected from the following structure:

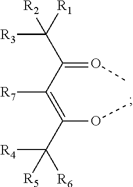

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof.

According to an embodiment of the present disclosure, at least one or two of R₁ to R₃ is(are) selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R₄ to R& is substituted or unsubstituted alkyl having 1 to 20 carbon atoms, substituted or unsubstituted cycloalkyl having 3 to 20 ring carbon atoms, substituted or unsubstituted heteroalkyl having 1 to carbon atoms or combinations thereof.

According to an embodiment of the present disclosure, at least two of R₁ to R₃ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R& are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

According to an embodiment of the present disclosure, L is, at each occurrence identically or differently, selected from the group consisting of L_{b1} to L_{b322}, and L_{c} is, at each occurrence identically or differently, selected from the group consisting of L_{c1} to L_{c231}, wherein the specific structures of L_{b1} to Lₕ₃₂₂ and the specific structures of L_{c1} to L₂₁ are referred to claim 16.

According to an embodiment of the present disclosure, the metal complex has a structure of Ir(L₂)₂(L_{b}), a structure of Ir(Lₐ)₂(L_{c}) or a structure of Ir(Lₐ)(L_{c})₂; wherein when the metal complex has the structure of Ir(L)₂(L_{b}), Lₐ is, at each occurrence identically or differently, selected from any one or any two of the group consisting of L_{c1} to Lₐ₇₄₂, and L_{b} is selected from any one of the group consisting of L_{b1} to Lₐ₃₂₂;
when the metal complex has the structure of Ir(Lₐ)₂(L_{c}), Lₐ is, at each occurrence identically or differently, selected from any one or any two of the group consisting of Lₐ₁ to Lₐ₇₄₂, and L_{c} is selected from any one of the group consisting of L_{c1} to L_{c233};
when the metal complex has the structure of Ir(Lₐ)(L_{c})₂, Lₐ is selected from any one of the group consisting of Lₐ₁ to Lₐ₇₄₂ and L_{c} is, at each occurrence identically or differently, selected from any one or any two of the group consisting of L_{c} to L_{c231}.

According to an embodiment of the present disclosure, the metal complex is selected from the group consisting of Compound 1 to Compound 160, wherein the specific structures of Compound 1 to Compound 160 are referred to claim 17.

According to an embodiment of the present disclosure, an electroluminescent device is further disclosed. The electroluminescent device includes:
an anode,
a cathode, and
an organic layer disposed between the anode and the cathode, wherein the organic layer includes the metal complex in any one of the preceding embodiments.

According to an embodiment of the present disclosure, the device emits red light or white light.

According to an embodiment of the present disclosure, the organic layer is an emissive layer, and the metal complex is an emissive material.

According to an embodiment of the present disclosure, the emissive layer further includes at least one host material.

According to an embodiment of the present disclosure, the at least one host material includes at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, a compound composition is further disclosed. The compound composition includes the metal complex in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, materials disclosed herein may be used in combination with a wide variety of dopants, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this present disclosure.

Material Synthesis Example

The method for preparing the compound of the present disclosure is not limited herein. Typically, the following compounds are used as examples without limitation, and the synthesis routes and preparation methods thereof are described below.

### Synthesis Example 1: Synthesis of Compound 1

Step 1: Synthesis of Intermediate 3

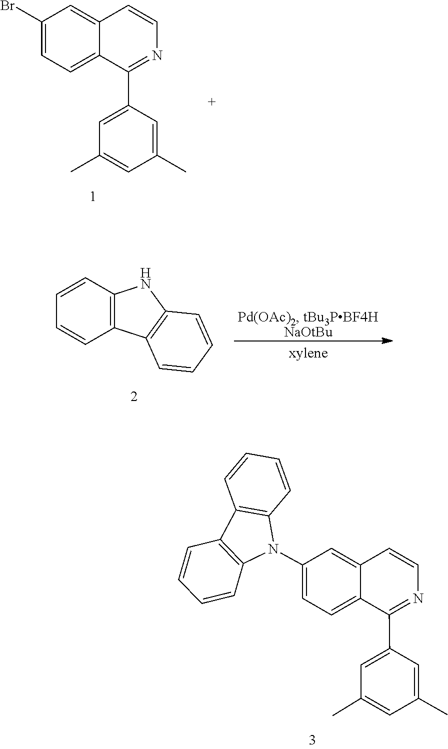 [SMILES: Cc1cc(C)cc(-c2nccc3cc(Br)ccc23)c1 ; c1ccc2c(c1)[nH]c1ccccc12 ; "Pd(OAc)2, tBu3P·BF4HNaOtBu" ; Cc1cc(C)cc(-c2nccc3cc(-n4c5ccccc5c5ccccc54)ccc23)c1]

Intermediate 1 (1.00 g, 5.05 mmol), Intermediate 2 (1.57 g, 5.05 mmol), palladium acetate (0.29 g, 0.25 mmol), tri-tert-butylphosphine tetrafluoroborate (1.07 g, 10.10 mmol), sodium tert-butoxide (1.07 g, 10.10 mmol), and xylene (50 mL) were added in a 100 mL round-bottom flask. Then, the reaction was heated to 140° C. under nitrogen protection and stirred overnight. After TLC showed that the reaction was completed, the system was cooled to room temperature. Ethyl acetate was then added to the reaction, and liquids were separated. The aqueous phase was extracted with ethyl acetate. The organic phases were combined, dried, and subjected to rotary evaporation to dryness to give a crude product. The crude product was isolated by silica gel column chromatography (using an eluent of ethyl acetate:petroleum ether=1:20, v/v) to give Intermediate 3 as a white solid (1.60 g, 92.3%).

### Step 2: Synthesis of Iridium Dimer

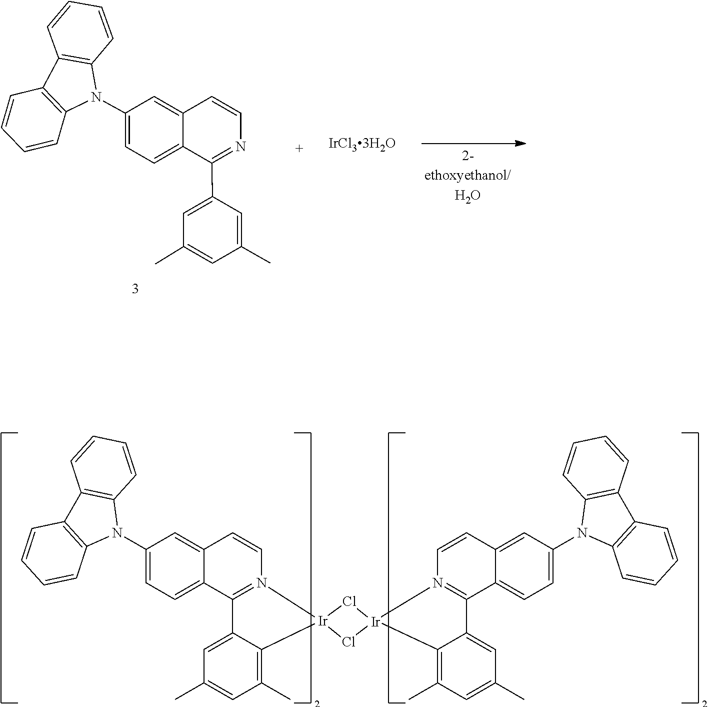

Intermediate 3 (1.05 g, 2.20 mmol), iridium trichloride trihydrate (0.31 g, 0.88 mmol), 2-ethoxyethanol (20 mL), and water (7 mL) were added in a 100 mL round-bottom flask and heated to 130° C. under a nitrogen atmosphere with continuous stirring for 24 h. The reaction system was cooled to room temperature and filtered to give an iridium dimer as a red solid which was directly used in the next step without further purification.

### Step 3: Synthesis of Compound 1

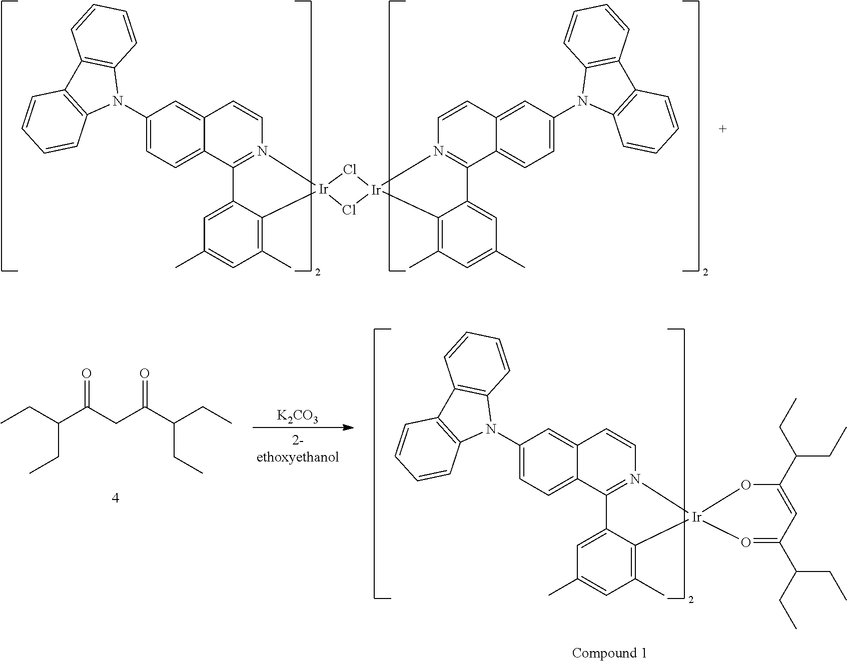

The iridium dimer given in step 2, Intermediate 4 (0.35 g, 1.32 mmol), potassium carbonate (0.48 g, 3.52 mmol), and 20 mL of 2-ethoxyethanol were added in a 100 mL round-bottom flask and reacted at 50° C. for 24 h under nitrogen protection. The reaction system was filtered, and the filter cake was washed with ethanol. Dichloromethane was added to the resulting solid, and the filtrate was collected. Ethanol was added, and the resulting solution was concentrated. A red solid was collected by filtration, and the product was further purified by column chromatography and recrystallized with DCM/MeOH to give 0.22 g of Compound 1, with a yield of 47%. The structure of the compound was confirmed as the target product by LC-MS, with a molecular weight of 1198.5.

### Synthesis Example 2: Synthesis of Compound 51

### Step 1: Synthesis of Intermediate 7

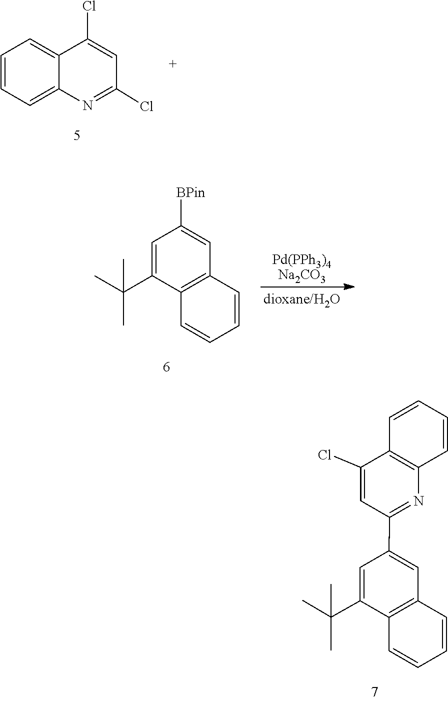

Intermediate 5 (1.00 g, 5.05 mmol), Intermediate 6 (1.57 g, 5.05 mmol), Pd(PPh₃)₄ (0.29 g, 0.25 mmol), sodium carbonate (1.07 g, 10.10 mmol), 1,4-dioxane (20 mL), and water (5 mL) were added in a 100 mL round-bottom flask. Then, the reaction was heated to 80° C. under nitrogen protection and stirred overnight. After TLC showed that the reaction was completed, the system was cooled to room temperature. Ethyl acetate was then added to the reaction, and liquids were separated. The aqueous phase was extracted with ethyl acetate. The organic phases were combined, dried, and subjected to rotary evaporation to dryness to give a crude product. The crude product was isolated by silica gel column chromatography (using an eluent of ethyl acetate:petroleum ether=1:20, v/v) to give Intermediate 7 as a white solid (1.60 g, 92.3%).

### Step 2: Synthesis of Intermediate 8

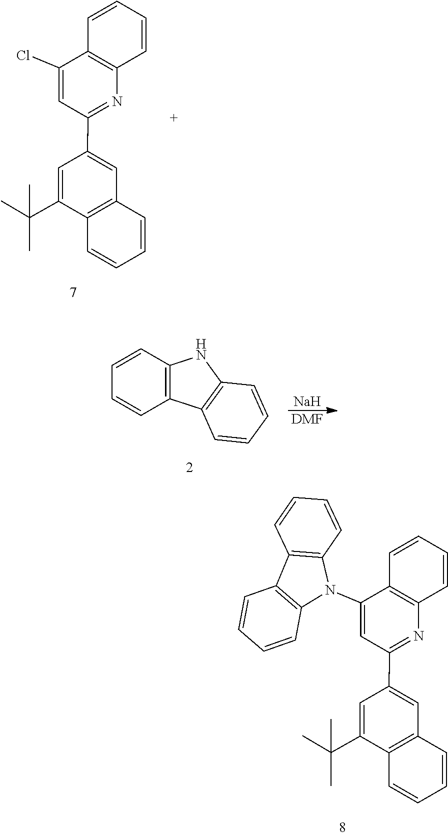

Intermediate 7 (1.50 g, 4.34 mmol), Intermediate 2 (0.87 g, 5.20 mmol), sodium hydride (0.22 g, 5.64 mmol), and DMF (20 mL) were heated to 130° C. under nitrogen protection and reacted for 24 h. After TLC showed that the reaction was completed, the reaction system was cooled to room temperature. 200 mL of water were added to the reaction system until solids were precipitated from the solution. The solution was filtered, and the solids were washed with water several times and suction-filtered to dryness to give the target product. The silica gel was washed with an eluent (where ethyl acetate:petroleum ether=1:30, v/v), and the solvent was removed in vacuo to give Intermediate 8 (1.20 g, 58%).

### Step 3: Synthesis of Iridium Dimer

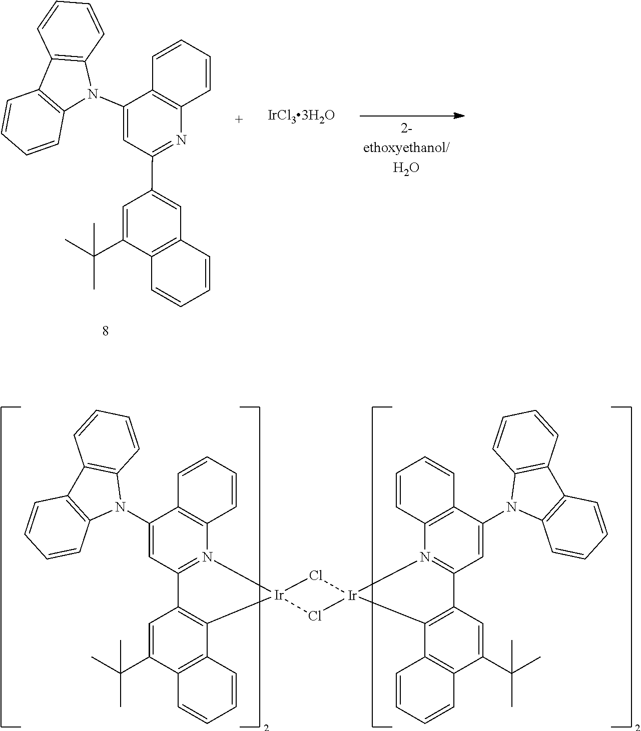

Intermediate 8 (1.05 g, 2.20 mmol), iridium trichloride trihydrate (0.31 g, 0.88 mmol), 2-ethoxyethanol (20 mL), and water (7 mL) were added in a 100 mL round-bottom flask and heated to 130° C. under a nitrogen atmosphere with continuous stirring for 24 h. The reaction system was cooled to room temperature and filtered to give an iridium dimer as a red solid which was directly used in the next step without further purification.

### Step 4: Synthesis of Compound S1

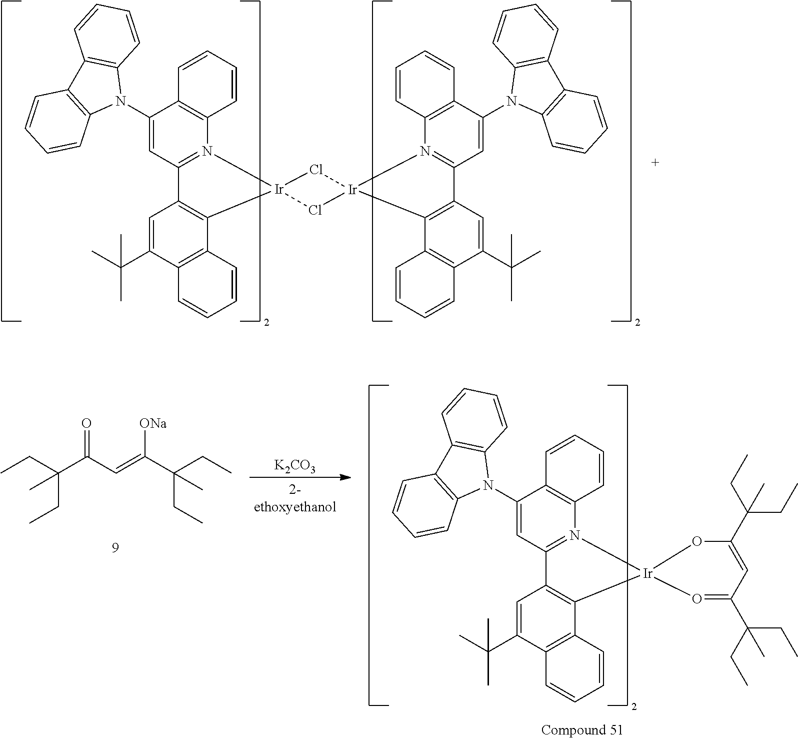

The iridium dimer given in step 3, Intermediate 9 (0.35 g, 1.32 mmol), potassium carbonate (0.48 g, 3.52 mmol), and 20 mL of 2-ethoxyethanol were added in a 100 mL round-bottom flask and reacted at 50° C. for 24 h under nitrogen protection. The reaction system was filtered, and the filter cake was washed with ethanol. Dichloromethane was added to the resulting solid, and the filtrate was collected. Ethanol was added, and the resulting solution was concentrated. A red solid was collected by filtration, and the product was further purified by column chromatography and recrystallized with DCM/MeOH to give 0.22 g of Compound 51, with a yield of 47%. The structure of the compound was confirmed as the target product by LC-MS, with a molecular weight of 1382.6.

The persons skilled in the art will appreciate that the above preparation methods are merely exemplary. The persons skilled in the art can obtain other compound structures of the present disclosure via modifications of the preparation methods.

### Device Example 1

First, a glass substrate having an indium tin oxide (ITO) anode with a thickness of 120 nm was cleaned and then treated with oxygen plasma and UV ozone. After the treatment, the substrate was dried in a glovebox to remove moisture. Then, the substrate was mounted on a substrate holder and placed in a vacuum chamber. Organic layers specified below were sequentially deposited through vacuum thermal evaporation on the ITO anode at a rate of 0.2 to 2 Angstroms per second at a vacuum degree of about 10-3 torr. Compound HI and Compound HT were co-deposited as a hole injection layer (HIL, at a mass ratio of 3:97, 100 Å). Compound HT was deposited as a hole transport layer (HTL, 400 Å). Compound EB was deposited as an electron blocking layer (EBL, 50 Å). Compound 1 of the present disclosure was doped in a host compound RH to be deposited as an emissive layer (EML, at a mass ratio of 2:98, 400 Å). Compound HB was deposited as a hole blocking layer (HBL, 50 Å). On the HBL, a mixture of Compound ET and 8-hydroxyquinolinolato-lithium (Liq) was deposited as an electron transport layer (ETL, 350 Å). Liq with a thickness of 1 nm was deposited as an electron injection layer, and Al with a thickness of 120 nm was deposited as a cathode. Finally, the device was transferred back to the glovebox and encapsulated with a glass lid and a moisture absorbent to complete the device.

### Device Example 2

The preparation method in Device Example 2 was the same as the preparation method in Device Example 1, except that Compound 1 of the present disclosure was replaced with Compound 51 of the present disclosure in the emissive layer (EML).

### Device Comparative Example 1

The preparation method in Device Comparative Example 1 was the same as the preparation method in Device Example 1, except that Compound 1 of the present disclosure was replaced with Compound RD1 in the emissive layer (EML).

### Device Comparative Example 2

The preparation method in Device Comparative Example 2 was the same as the preparation method in Device Example 1, except that Compound 1 of the present disclosure was replaced with Compound RD2 in the emissive layer (EML).

### Device Comparative Example 3

The preparation method in Device Comparative Example 3 was the same as the preparation method in Device Example 1, except that Compound 1 of the present disclosure was replaced with Compound RD3 in the emissive layer (EML).

Detailed structures and thicknesses of layers of the devices are shown in the following table. The layers using more than one material were obtained by doping different compounds at their mass ratios as recorded.

TABLE 1
Device structures in device examples and device comparative examples

| Device No. | HIL | HTL | EBL | EML | HBL | ETL |
|---|---|---|---|---|---|---|
| Comparative | Compound | Compound | Compound | Compound | Compound | Compound |
| Example 1 | HT:HI | HT | EB | RH:RD1 (98:2) | HB | ET:Liq |
| | (97:3) | (400 Å) | (50 Å) | (400 Å) | (50 Å) | (40:60) |
| | (100 Å) | | | | | (350 Å) |
| Comparative | Compound | Compound | Compound | Compound | Compound | Compound |
| Example 2 | HT:HI | HT | EB | RH:RD2 (98:2) | HB | ET:Liq |
| | (97:3) | (400 Å) | (50 Å) | (400 Å) | (50 Å) | (40:60) |
| | (100 Å) | | | | | (350 Å) |
| Comparative | Compound | Compound | Compound | Compound | Compound | Compound |
| Example 3 | HT:HI | HT | EB | RH:RD3 (98:2) | HB | ET:Liq |
| | (97:3) | (400 Å) | (50 Å) | (400 Å) | (50 Å) | (40:60) |
| | (100 Å) | | | | | (350 Å) |
| Example 1 | Compound | Compound | Compound | Compound | Compound | Compound |
| | HT:HI | HT | EB | RH:Compound | HB | ET:Liq |
| | (97:3) | (400 Å) | (50 Å) | 1(98:2) | (50 Å) | (40:60) |
| | (100 Å) | | | (400 Å) | | (350 Å) |
| Example 2 | Compound | Compound | Compound | Compound | Compound | Compound |
| | HT:HI | HT | EB | R.H:Compound | HB | ET:Liq |
| | (97:3) | (400 Å) | (50 Å) | 51(98:2) | (50 Å) | (40:60) |
| | (100 Å) | | | (400 Å) | | (350 Å) |

The structures of the materials used in the devices are as follows:

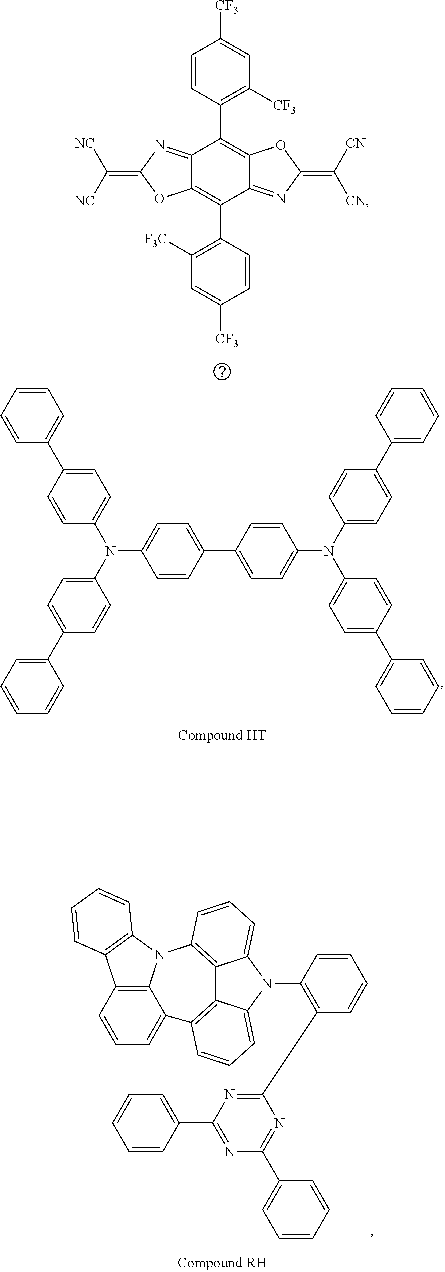 [SMILES: N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2nc(-c3ccccc3)nc(-c3ccccc3-n3c4cccc5c6cccc7c8ccccc8n(c8cccc3c8c54)c67)n2)cc1]

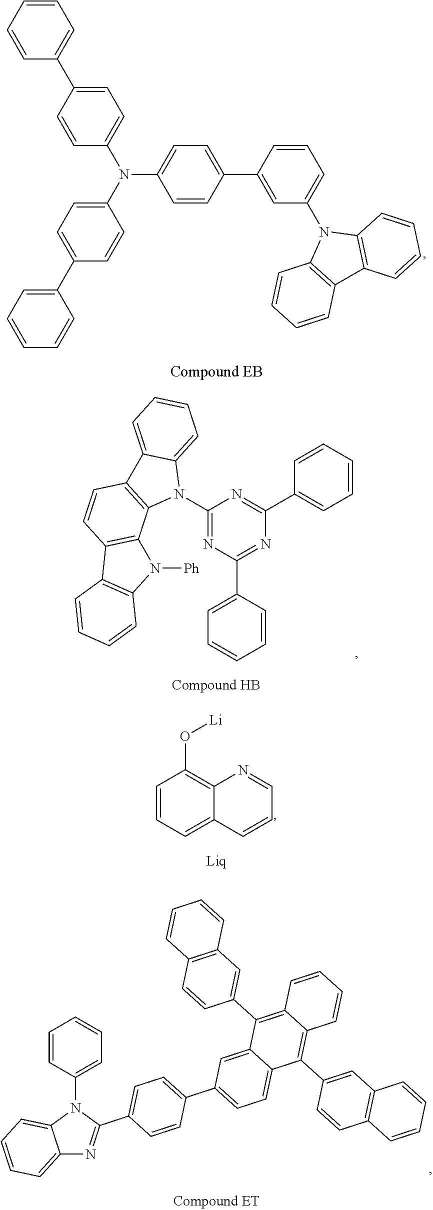

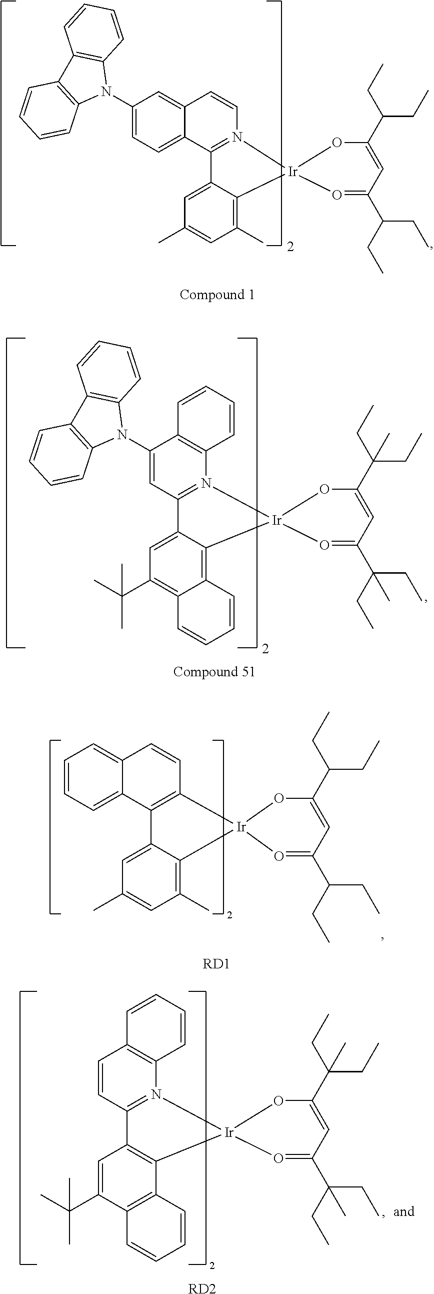

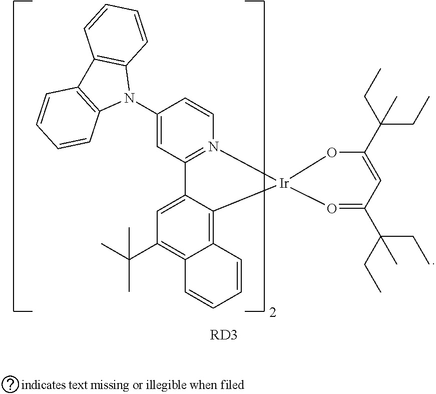

The IVL characteristics of the devices were measured. Table 2 shows the data such as the maximum emission wavelength (λₘₐₓ) voltage (V) and external quantum efficiency (EQE) measured at a current density of 15 mA/cm².

TABLE 2
Device data

| Device No. | λₘₐₓ (nm) | Voltage (V) | EQE (%) |
|---|---|---|---|
| Comparative | 633 | 3.54 | 21.0 |
| Example 1 | | | |
| Comparative | 642 | 3.66 | 17.0 |
| Example 2 | | | |
| Comparative | 593 | 3.54 | 17.7 |
| Example 3 | | | |
| Example 1 | 646 | 3.48 | 24.0 |
| Example 2 | 667 | 3.45 | 19.5 |

### Discussion

As can be seen from Table 2, compared with Comparative Example 1, in Example 1, the spectrum was significantly red-shifted by 13 nm, the external quantum efficiency was increased from 21% in Comparative Example 1 to 24%, with a significant increase of 14.3%, and the voltage was also reduced, indicating that by introducing carbazole or a group with a similar structure on the ligand, a significant red-shift of the maximum emission wavelength of the device using an emissive material including the ligand can be achieved, thereby achieving deeper red luminescence and substantially improving the device performance.

Compared with Comparative Example 2 where Compound RD2 was used in the emissive layer, in Device Example 2 where Compound 51 of the present disclosure was used in the emissive layer, the spectrum was significantly red-shifted by 25 nm, the external quantum efficiency was increased from 17% in Comparative Example 2 to 19.5%, with a significant increase of 14.7%, and the voltage was also significantly reduced, with the reduction from original 3.66 V to 3.45 V, indicating again that by introducing carbazole or a group with a similar structure on the ligand, a significant red-shift of the maximum emission wavelength of the device using an emissive material including the ligand can be achieved, thereby achieving deeper red luminescence and substantially improving the device performance.

Compared with Comparative Example 3 where Compound RD3 was used in the emissive layer, in Device Example 2 where Compound 51 of the present disclosure was used in the emissive layer, the spectrum was significantly red-shifted by 74 nm, the external quantum efficiency was increased from 17.7% in Comparative Example 3 to 19.5%, with a significant increase of 10.2%, and the voltage was also reduced, indicating again that by introducing carbazole or a group with a similar structure on the ligand, a significant red-shift of the maximum emission wavelength of the device can be achieved, thereby achieving deeper red luminescence and substantially improving the device performance.

In conclusion, the metal complexes having the new ligand of a structure of Formula 1 disclosed by the present disclosure can achieve a significant red-shift of the maximum emission wavelength of the device, effectively control the emitted color of the device, achieve deeper red luminescence, significantly improve the efficiency of the device, and reduce the voltage of the device, proving that the metal complex of the present disclosure has excellent performance and broad application prospects.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A metal complex, comprising a metal M and a ligand Lₐ coordinated to the metal M, wherein the metal M is selected from a metal with a relative atomic mass greater than 40, and Lₐ has a structure represented by Formula 1: 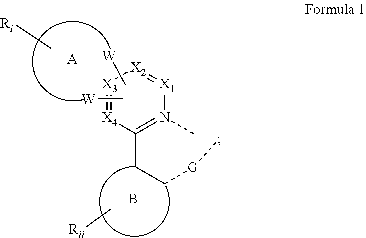
wherein the ring A and the ring B are, at each occurrence identically or differently, selected from a five-membered unsaturated carbocyclic ring, an aromatic ring having 6 to 30 carbon atoms or a heteroaromatic ring having 3 to 30 carbon atoms;
W is, at each occurrence identically or differently, selected from C, CRᵢᵢᵢ, CRᵢᵢᵢRᵢᵢᵢ, SiRᵢᵢᵢRᵢᵢᵢ, GeRᵢᵢᵢRᵢᵢᵢ, PRᵢᵢᵢ, O, S, N or NRᵢᵢᵢ; when two Rᵢᵢᵢ are present at the same time, the two Rᵢᵢᵢ are identical or different;
X₁ to X₄ are, at each occurrence identically or differently, selected from C, CRₓ or N, and any adjacent two of X₁ to X₄ are selected from C and are each joined to W in the ring A to form a fused ring;
V is, at each occurrence identically or differently, selected from C or N;
G is, at each occurrence identically or differently, selected from a single bond, O, S, Se, NR_{g} or PR_{g};
Rᵢ and Rᵢᵢ represent, at each occurrence identically or differently, mono-substitution, multiple substitutions or non-substitution;
at least one of Rᵢ, Rᵢᵢᵢ, and Rₓ is present and has a structure represented by Formula 2: 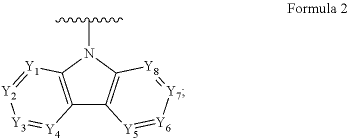
wherein Y₁ to Y₈ are, at each occurrence identically or differently, selected from CR_{y} or N;
Rᵢ, Rᵢᵢ, Rᵢᵢᵢ, Rₓ, R_{y}, and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵢ, Rᵢᵢ, Rᵢᵢᵢ, Rₓ, and R_{y} can be optionally joined to form a ring, and when X₄ is selected from CRₓ, the Rₓ is not joined to Rᵢ to form a ring.

2. The metal complex according to claim 1, wherein the ring A is selected from a five-membered unsaturated carbocyclic ring, an aromatic ring having 6 to 18 carbon atoms or a heteroaromatic ring having 3 to 18 carbon atoms; preferably, the ring A is selected from a benzene ring, a naphthalene ring, a pyridine ring, a pyrrole ring, a furan ring, a thiophene ring, an imidazole ring, a benzofuran ring or a benzothiophene ring; more preferably, the ring A is selected from a benzene ring, a naphthalene ring, a furan ring, a thiophene ring, a benzofuran ring or a benzothiophene ring.

3. The metal complex according to claim 1, wherein X₁ and X₂ are C and are each joined to W in the ring A to form a fused ring structure; or X₃ and X₄ are C and are each joined to W in the ring A to form a fused ring structure.

4. The metal complex according to claim 1, wherein V is selected from C, and the ring B is selected from an aromatic ring having 6 to 20 carbon atoms or a heteroaromatic ring having 3 to 20 carbon atoms; preferably, the ring B has a structure represented by Formula 3 or Formula 4: 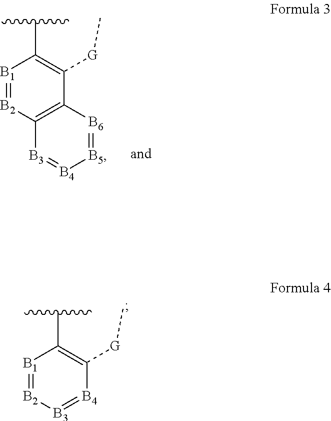
wherein B₁ to B₆ are, at each occurrence identically or differently, selected from CRᵢᵢ or N;
G is, at each occurrence identically or differently, selected from a single bond, O, S, Se, NR_{g} or PR_{g};
Rᵢᵢ and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rᵢᵢ and R_{g} can be optionally joined to form a ring.

5. The metal complex according to claim 1, wherein V is C, and G is selected from a single bond;
preferably, Lₐ has a structure represented by any one of Formula 5 to Formula 17: 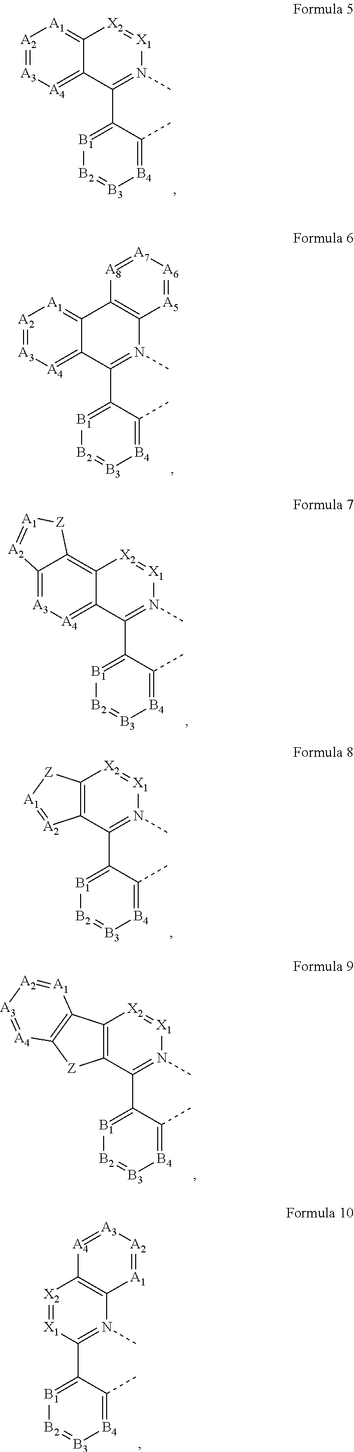 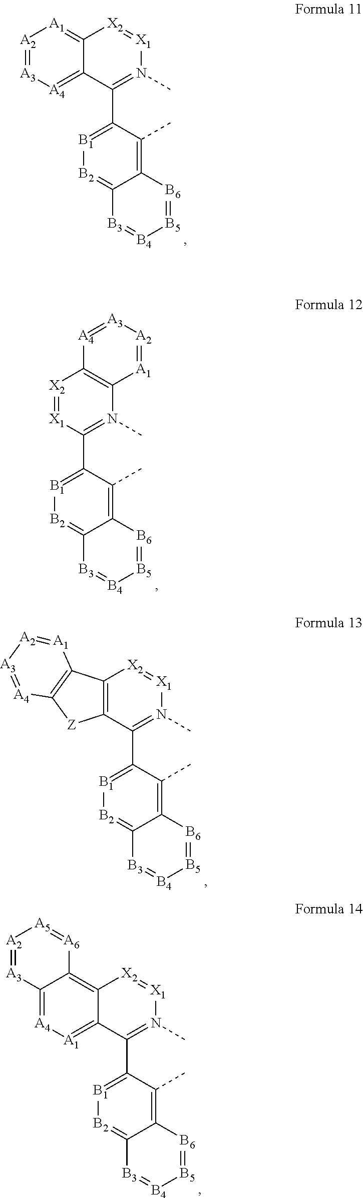 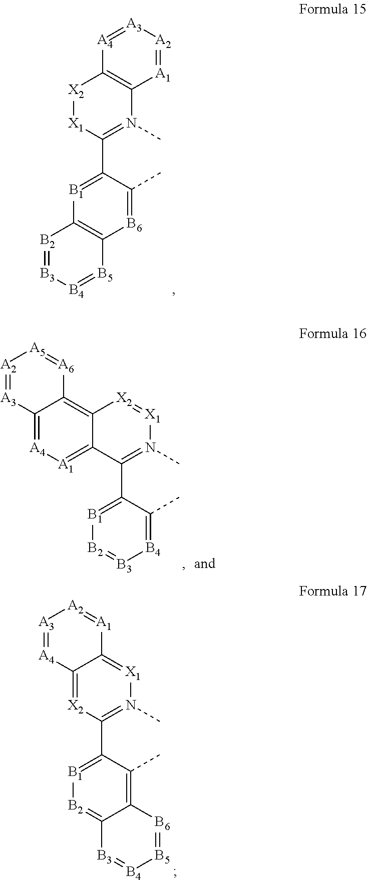
wherein
in Formula 5 to Formula 17, X₁ to X₂ are, at each occurrence identically or differently, selected from CRₓ or N, A₁ to A₈ are, at each occurrence identically or differently, selected from CRᵢ or N, and B₁ to B₆ are, at each occurrence identically or differently, selected from CRᵢᵢ or N;
at least one of Rᵢ, Rᵢᵢᵢ, and Rₓ is present and has the structure represented by Formula 2: 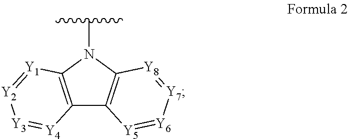
wherein Y₁ to Y₈ are, at each occurrence identically or differently, selected from CR_{y} or N;
Z is, at each occurrence identically or differently, selected from CRᵢᵢᵢRᵢᵢᵢ, SiRᵢᵢᵢRᵢᵢᵢ, GeRᵢᵢᵢRᵢᵢᵢ, PRᵢᵢᵢ, O, S or NRᵢᵢᵢ; when two Rᵢᵢᵢ are present at the same time, the two Rᵢᵢᵢ are identical or different;
Rₓ, R_{y}, Rᵢ, Rᵢᵢ, and Rᵢᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₓ, R_{y}, Rᵢ, Rᵢᵢ, and Rᵢᵢᵢ can be optionally joined to form a ring, and in Formula 17, when X₂ is selected from CRₓ, the Rₓ is not joined to Rᵢ to form a ring; more preferably, Lₐ has a structure represented by Formula 5 or Formula 12.

6. The metal complex according to claim 5, wherein in Formula 5 to Formula 17, at least one of X₁ to Xₙ and/or A₁ to Aₘ and/or B₁ to B_{q} is selected from N, wherein the Xₙ corresponds to one with the largest serial number of X₁ to X₂ in any one of Formula 5 to Formula 17, the Aₘ corresponds to one with the largest serial number of A₁ to A₈ in any one of Formula 5 to Formula 17, and the B_{q} corresponds to one with the largest serial number of B₁ to B₆ in any one of Formula 5 to Formula 17;
preferably, in Formula 5 to Formula 17, at least one of X₁ to X₂ is selected from N;
more preferably, X₂ is N.

7. The metal complex according to claim 5, wherein in Formula 5 to Formula 17, X₁ to X₂ are each independently selected from CRₓ, A₁ to A₈ are each independently selected from CRᵢ, B₁ to B₆ are each independently selected from CRᵢᵢ, and at least one of Rᵢ and Rₓ is present and has the structure represented by Formula 2;
adjacent substituents Rₓ, Rᵢ, Rᵢᵢ, and R_{y} can be optionally joined to form a ring, and in Formula 17, when X₂ is selected from CRₓ, the Rₓ is not joined to Rᵢ to form a ring;
preferably, Rₓ, R_{y}, Rᵢ, and Rᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof;
more preferably, at least one of Rₓ, Rᵢ, and Rᵢᵢ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a cyano group, and combinations thereof.

8. The metal complex according to claim 5, wherein in Formula 5 to Formula 17, X₁ to X₂ are, at each occurrence identically or differently, selected from CRₓ, A₁ to A₄ are, at each occurrence identically or differently, selected from CRᵢ, and at least one of Rᵢ and Rₓ is present and has the structure represented by Formula 2.

9. The metal complex according to claim 5, wherein in Formula 5 to Formula 9, Formula 11, Formula 13, Formula 14, Formula 16, and Formula 17, A₁ to A₄ are, at each occurrence identically or differently, selected from CRᵢ, and at least one of Rᵢ has the structure represented by Formula 2; in Formula 10, Formula 12, and Formula 15, X₁ to X₂ are, at each occurrence identically or differently, selected from CRₓ, and at least one of Rₓ has the structure represented by Formula 2;
preferably, in Formula 5, Formula 6, Formula 11, Formula 14, Formula 16, and Formula 17, A₂ to A₃ are, at each occurrence identically or differently, selected from CRᵢ, and at least one of Rᵢ has the structure represented by Formula 2; in Formula 9 and Formula 13, A₂ to A₄ are, at each occurrence identically or differently, selected from CRₓ, and at least one of Rᵢ has the structure represented by Formula 2; in Formula 7 and Formula 8, A₁ to A₂ are, at each occurrence identically or differently, selected from CRᵢ, and at least one of Rᵢ has the structure represented by Formula 2; in Formula 10, Formula 12, and Formula IS, X₂ is, at each occurrence identically or differently, selected from CRₓ, and at least one of Rₓ has the structure represented by Formula 2.

10. The metal complex according to claim 5, wherein in Formula 5 to Formula 17, Rᵢᵢ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms or combinations thereof:
preferably, Rᵢᵢ is, at each occurrence identically or differently, selected from hydrogen, deuterium, fluorine, methyl, ethyl, isopropyl, isobutyl, t-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl or combinations thereof.

11. The metal complex according to claim 5, wherein in Formula 5 to Formula 17, B₂ is CRᵢᵢ, and the Rᵢᵢ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted alkylsilyl having 3 to 20 carbon atoms, substituted or unsubstituted alkenyl having 2 to 20 carbon atoms, and combinations thereof;
preferably, Rᵢᵢ is, at each occurrence identically or differently, selected from deuterium, halogen, substituted or unsubstituted alkyl having 1 to 20 carbon atoms, substituted or unsubstituted cycloalkyl having 4 to 10 carbon atoms, substituted or unsubstituted alkylsilyl having 3 to 10 carbon atoms or combinations thereof;
preferably, Rᵢᵢ is, at each occurrence identically or differently, selected from deuterium, fluorine, methyl, ethyl, isopropyl, isobutyl, t-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl or combinations thereof.

12. The metal complex according to claim 1, wherein Lₐ is, at each occurrence identically or differently, selected from the group consisting of the following structures:

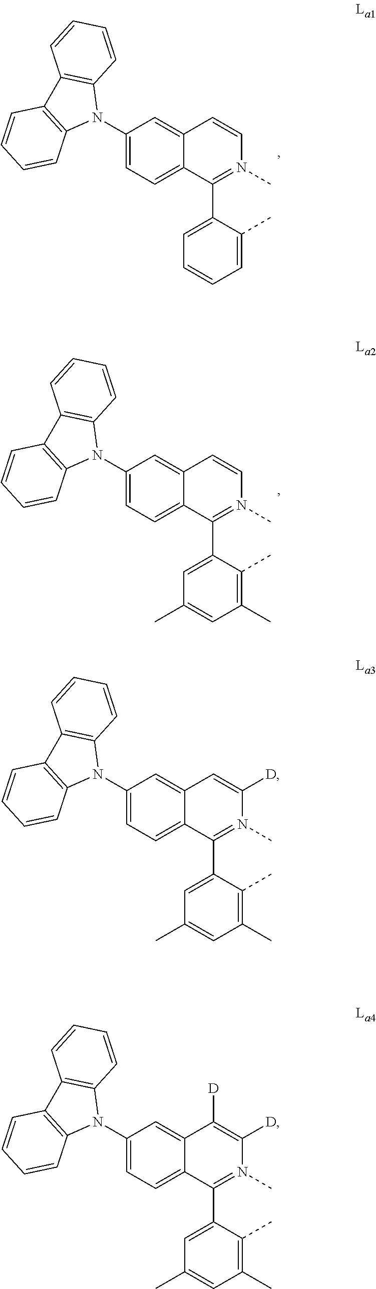

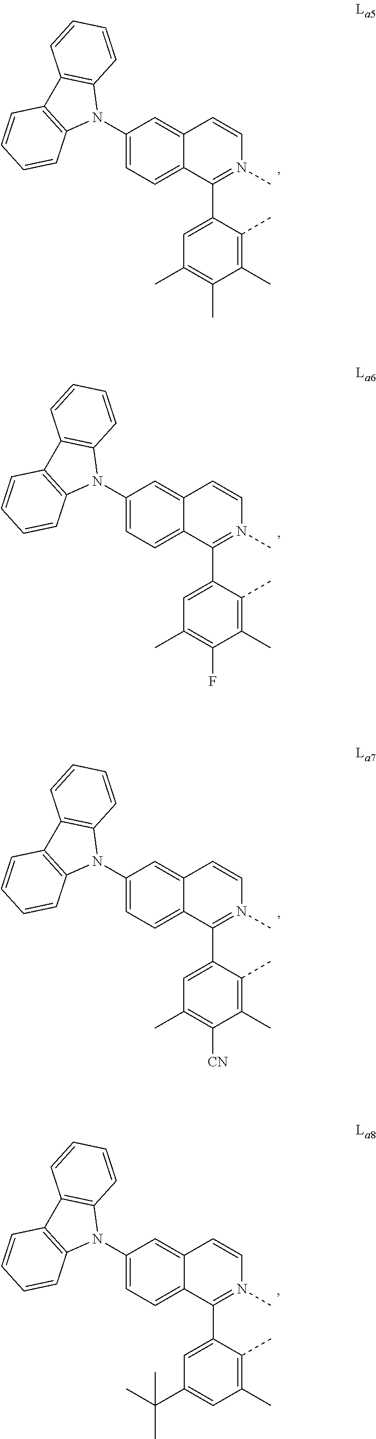

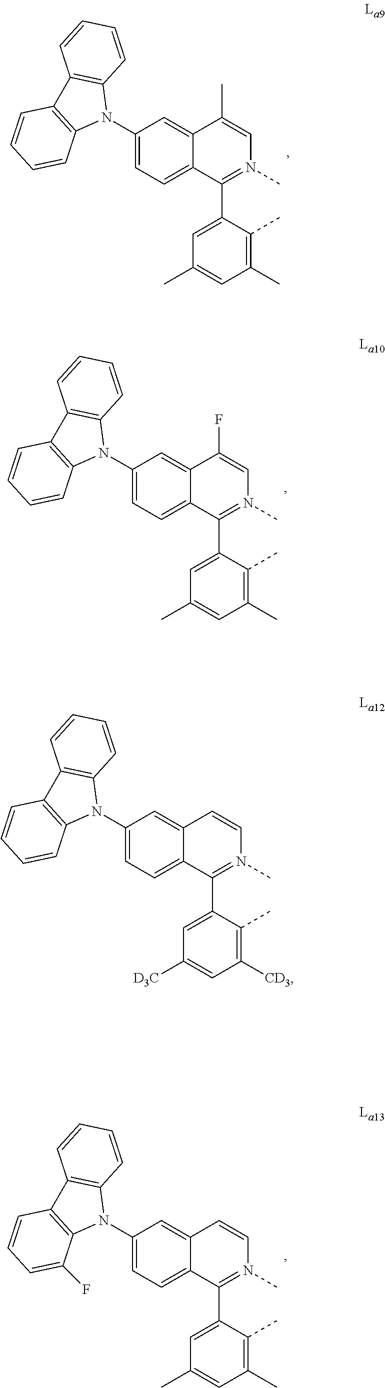

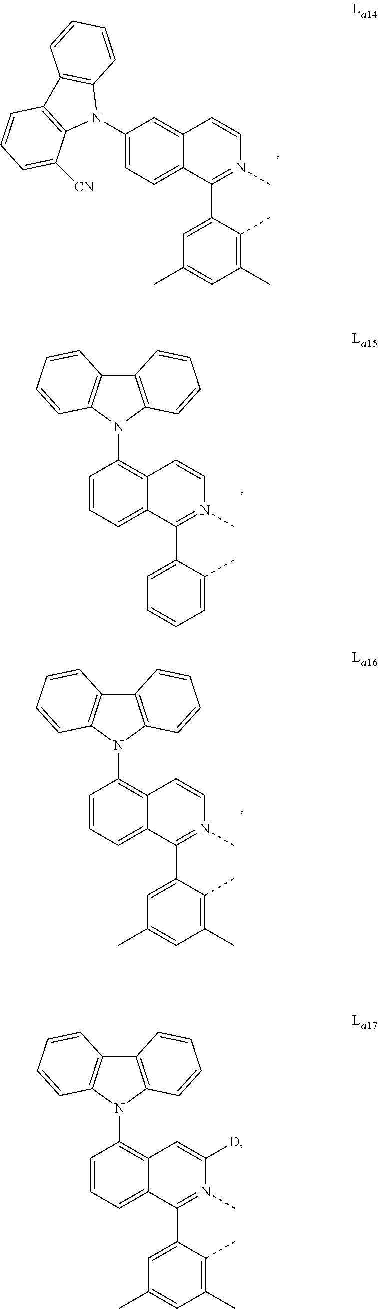

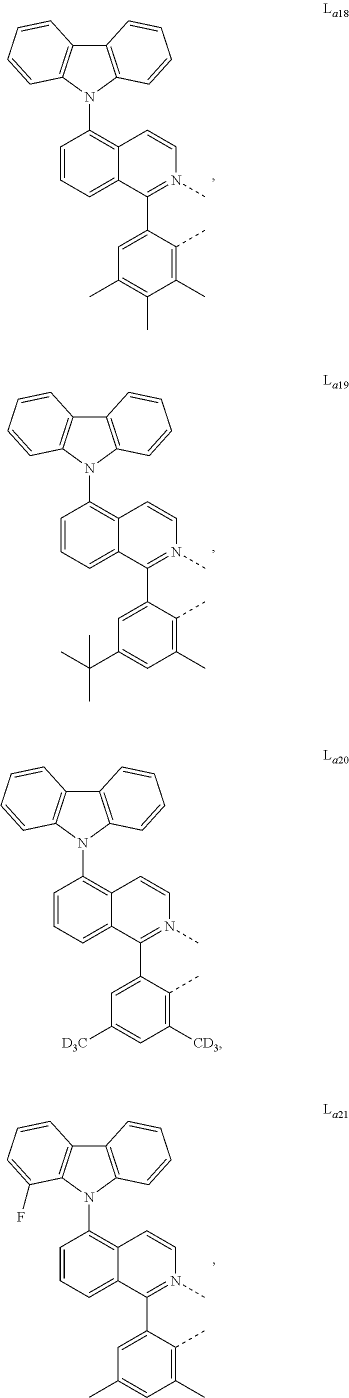

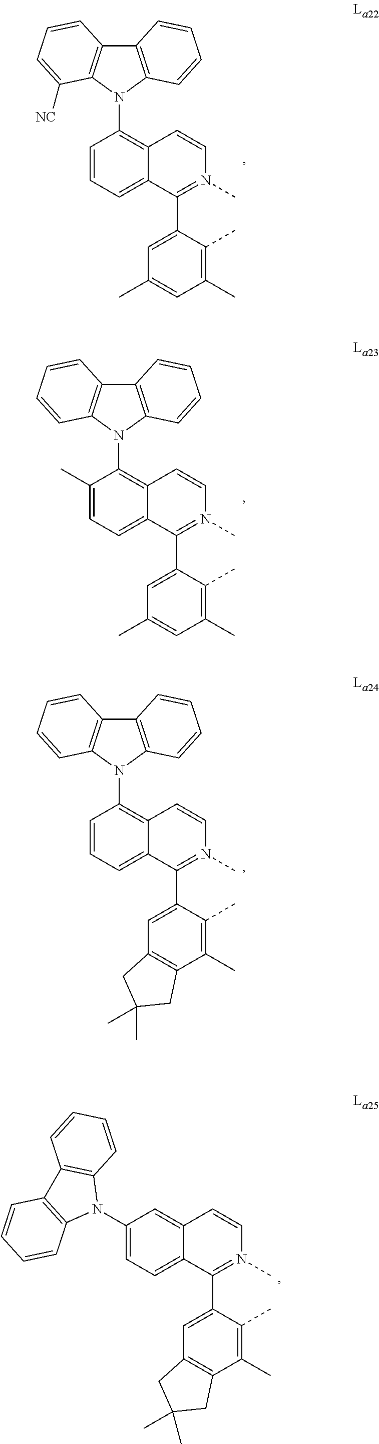

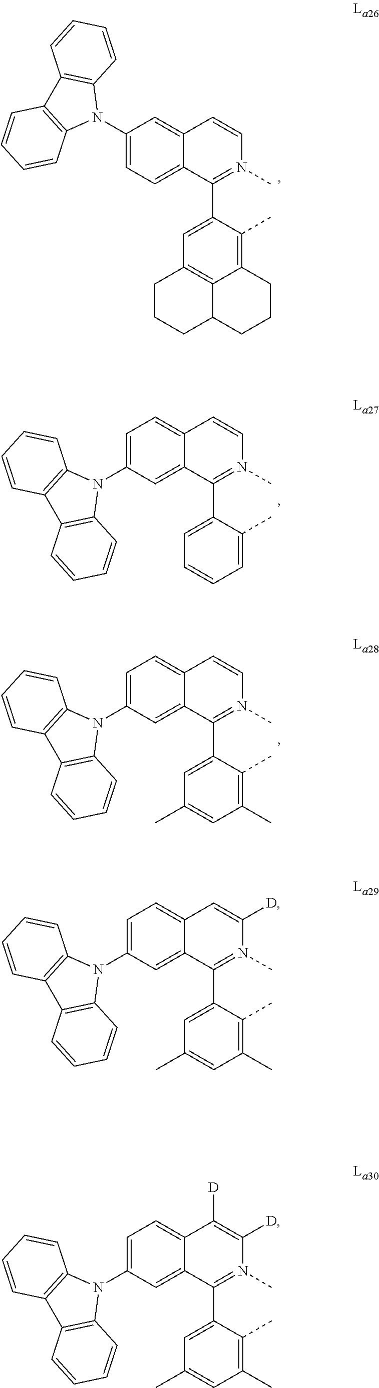

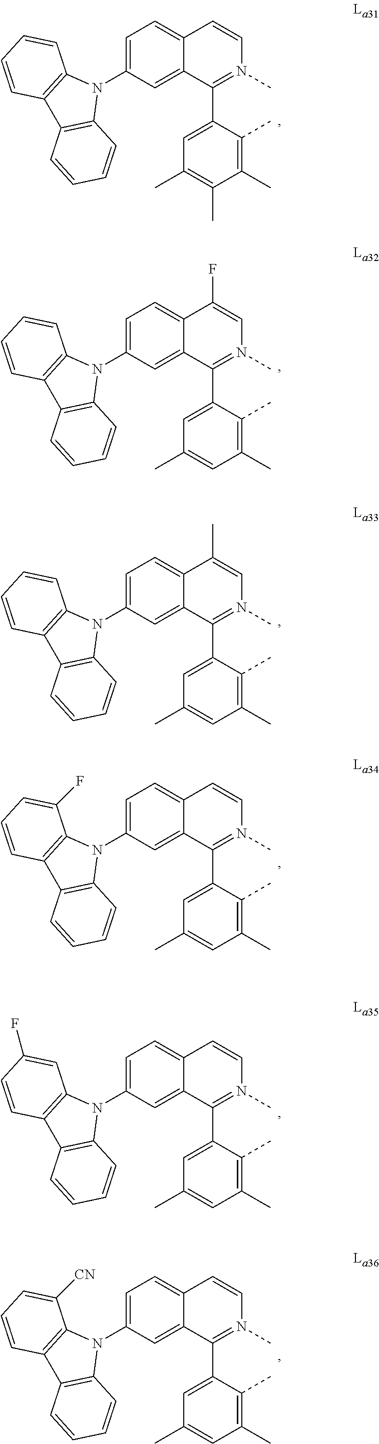

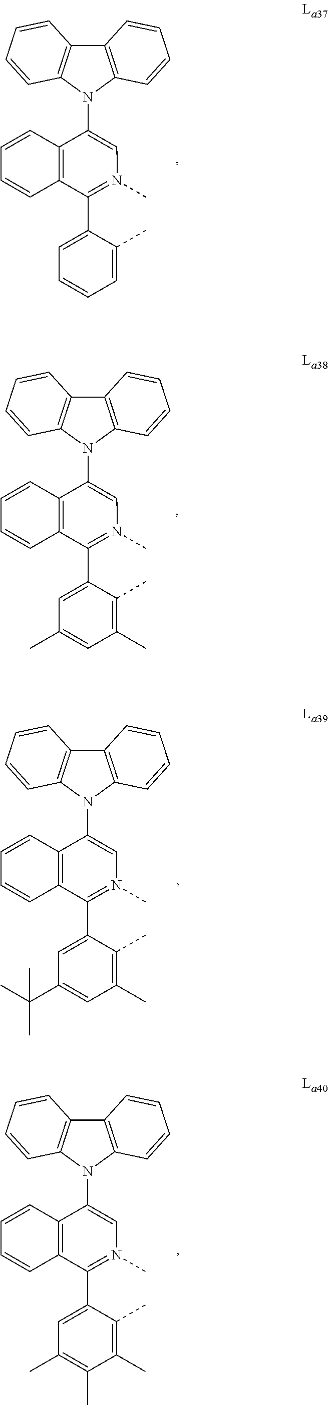

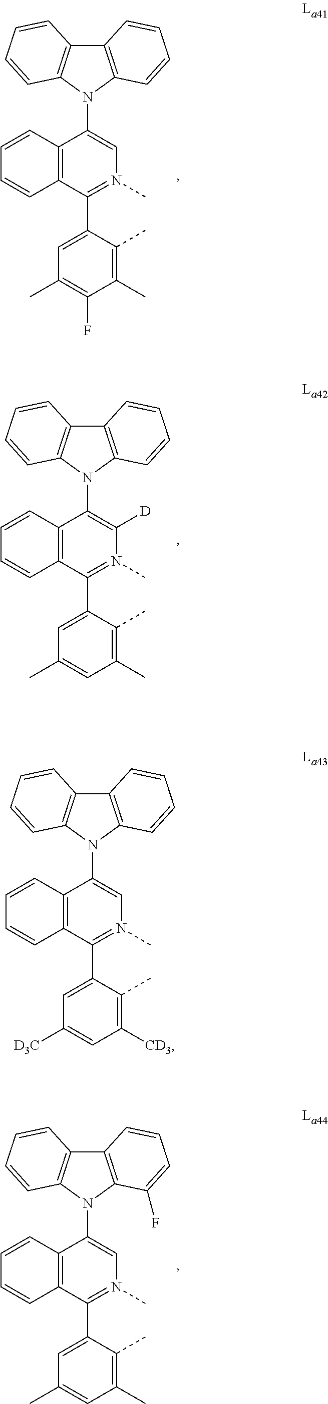

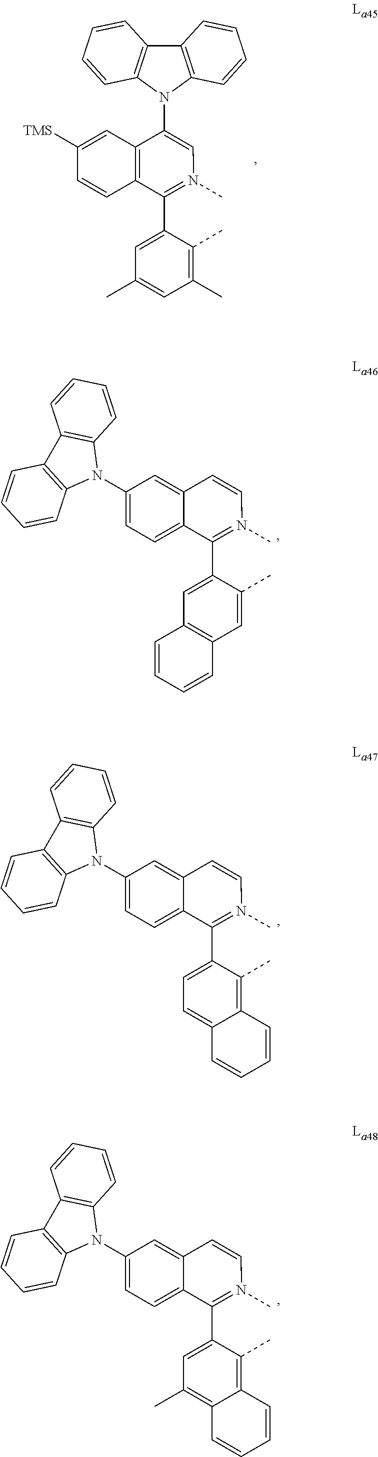

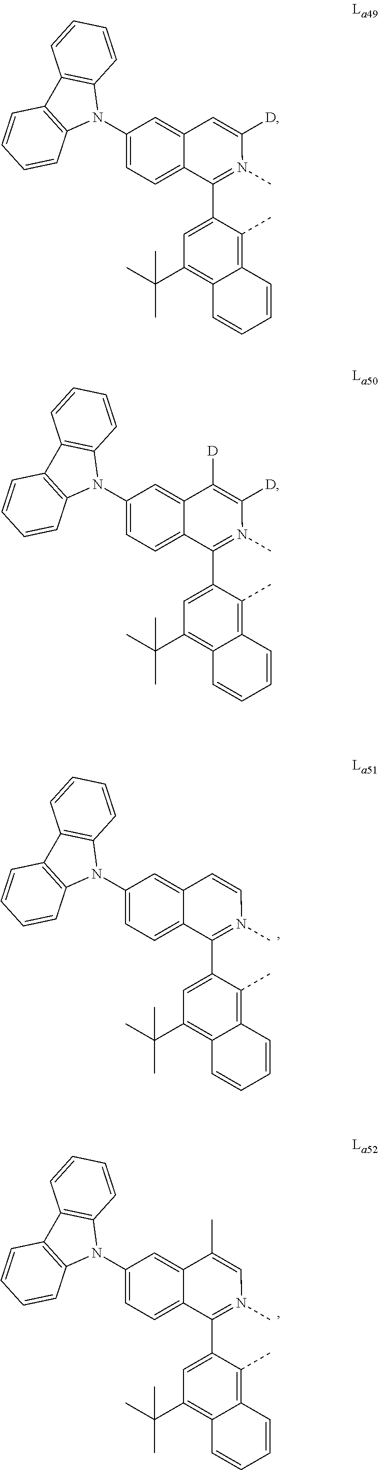

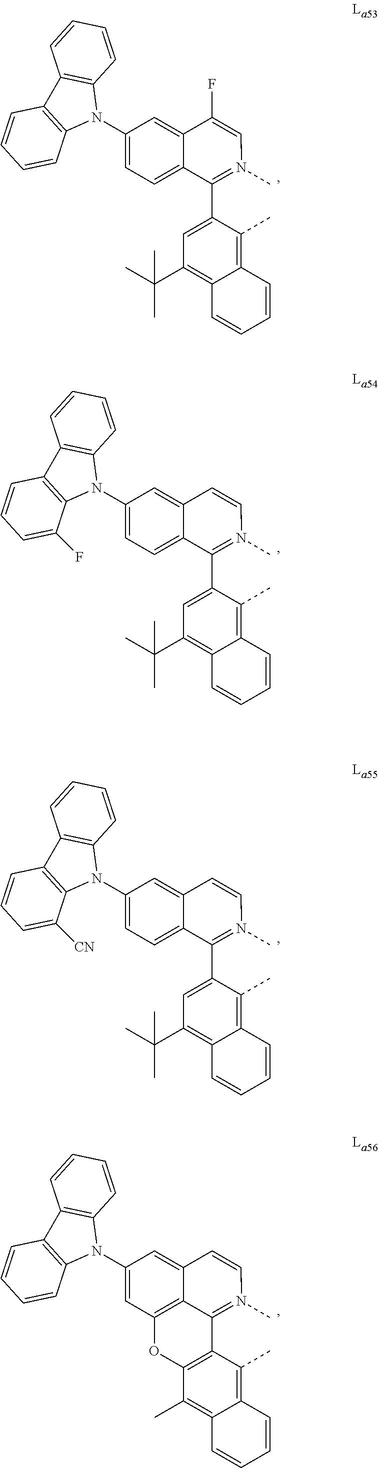

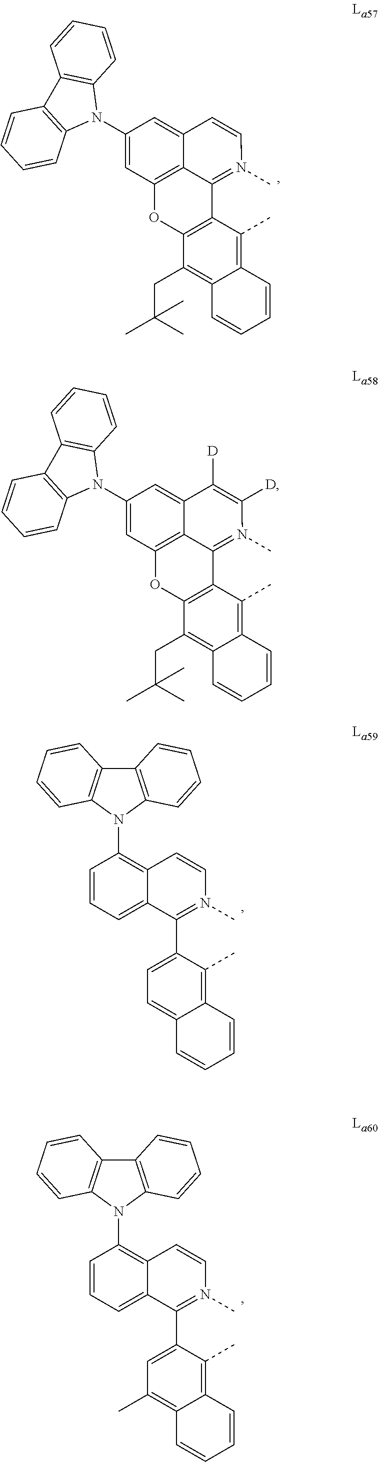

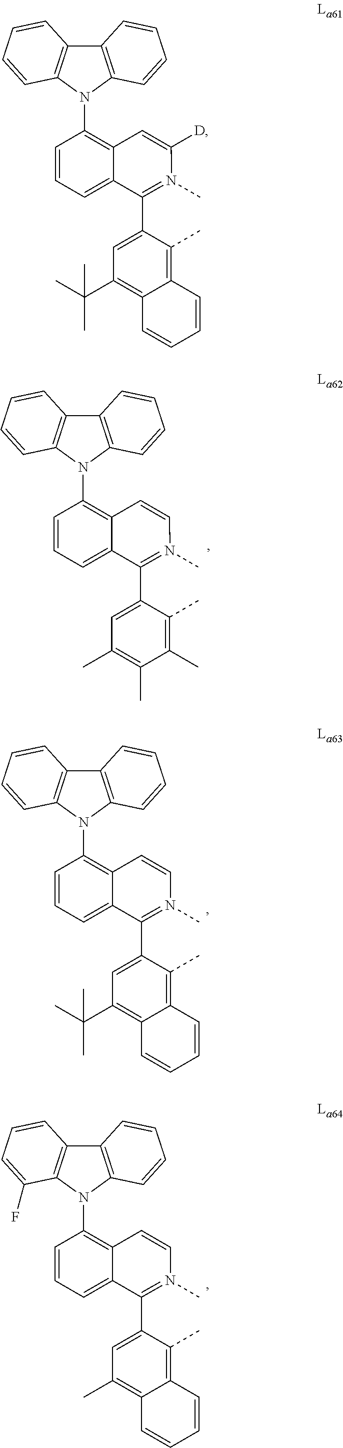

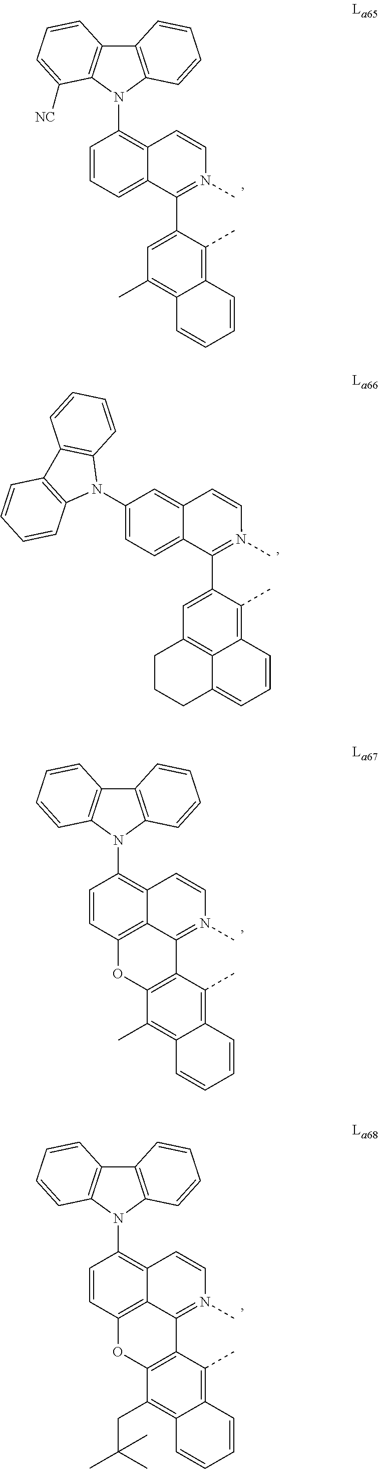

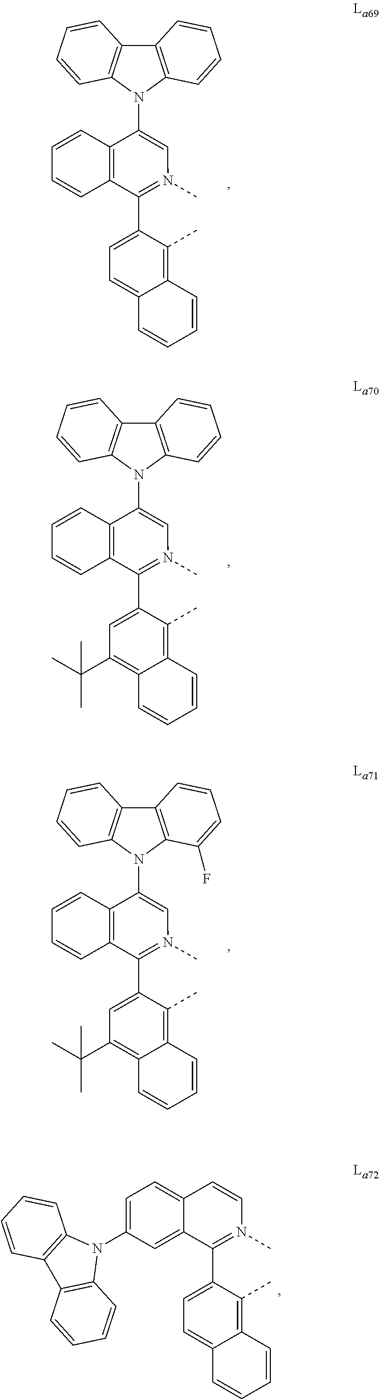

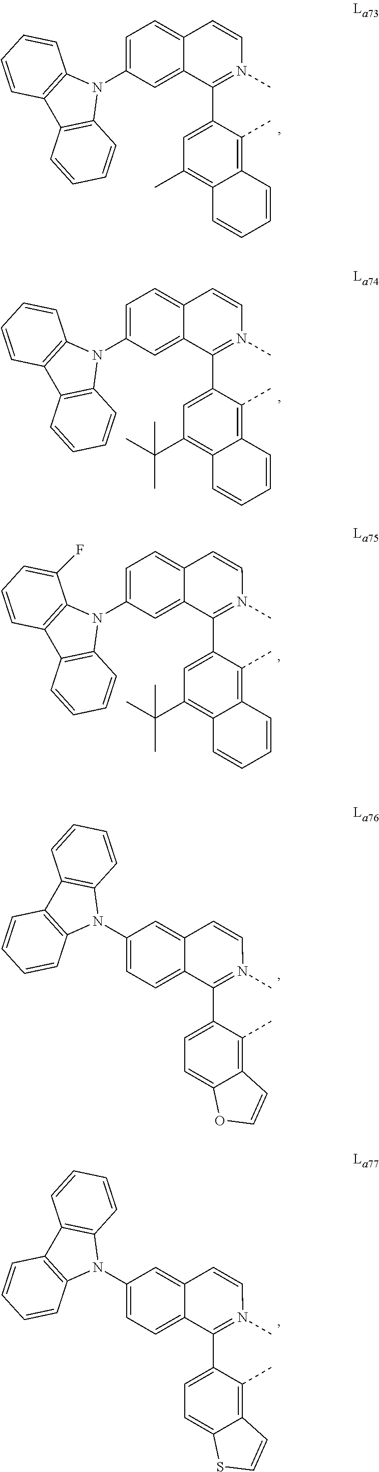

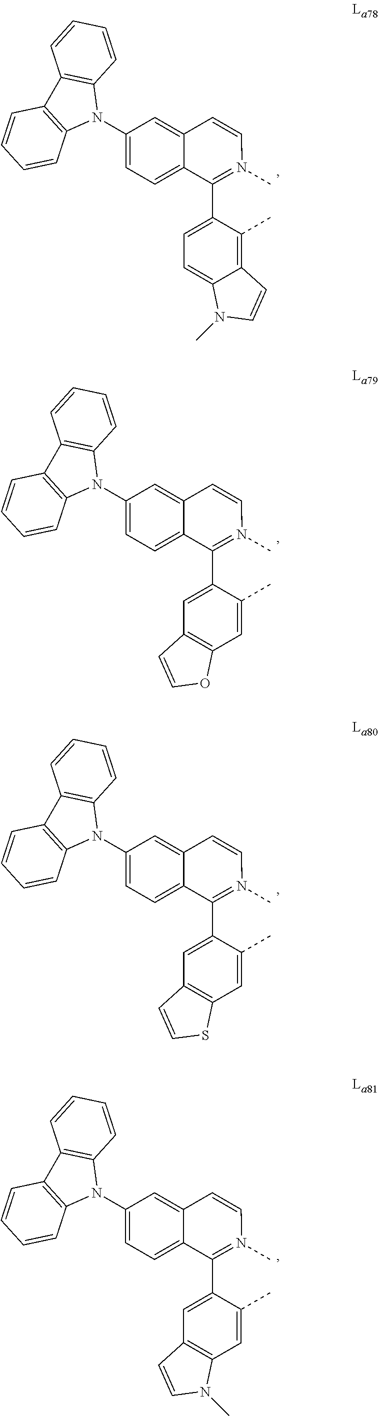

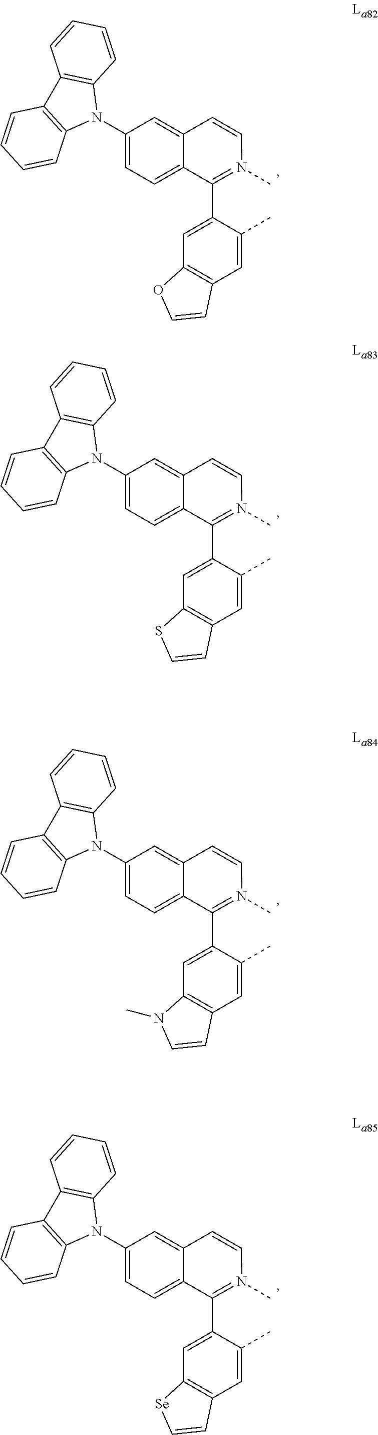

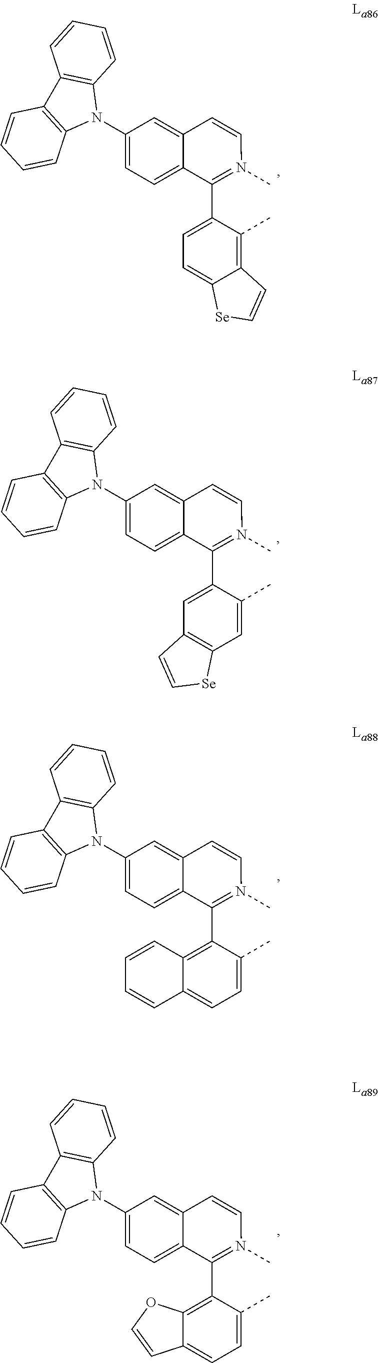

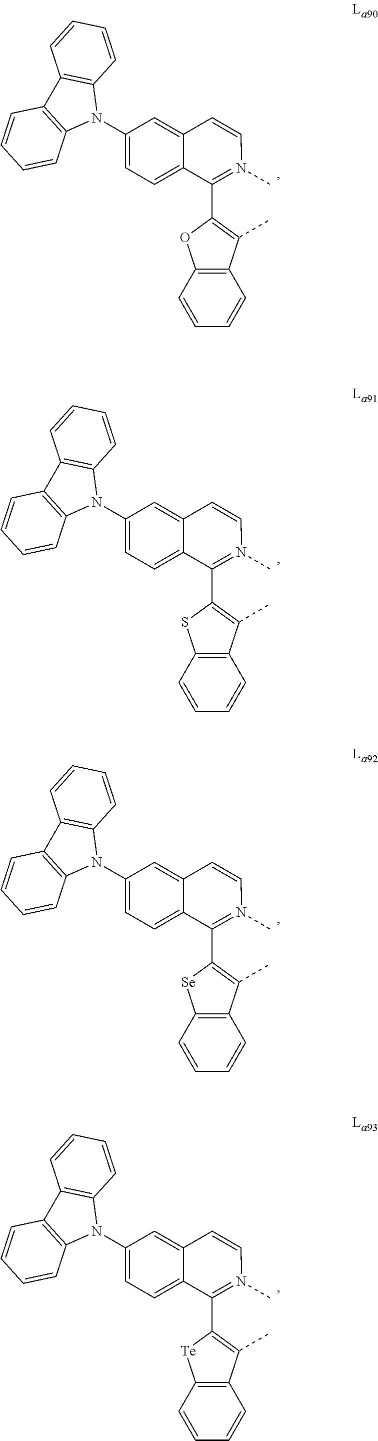

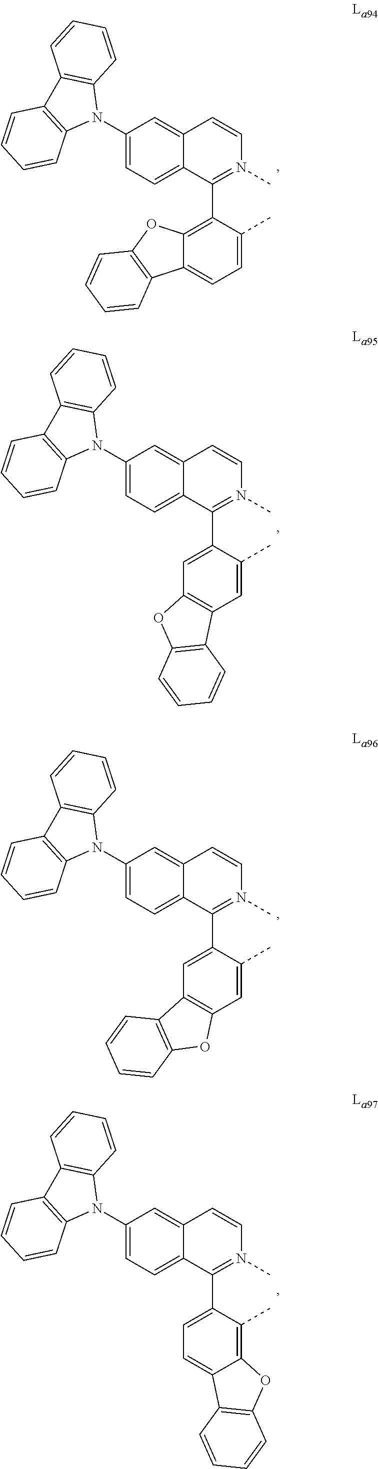

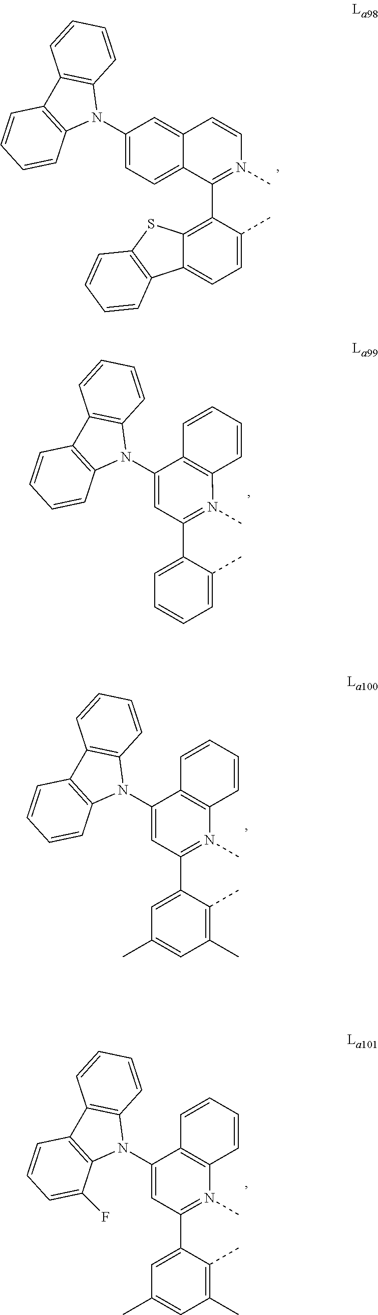

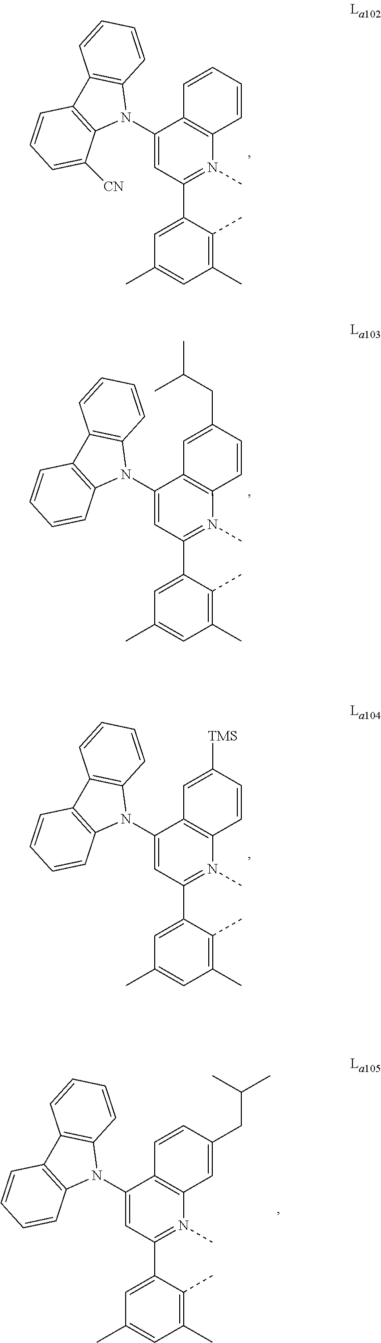

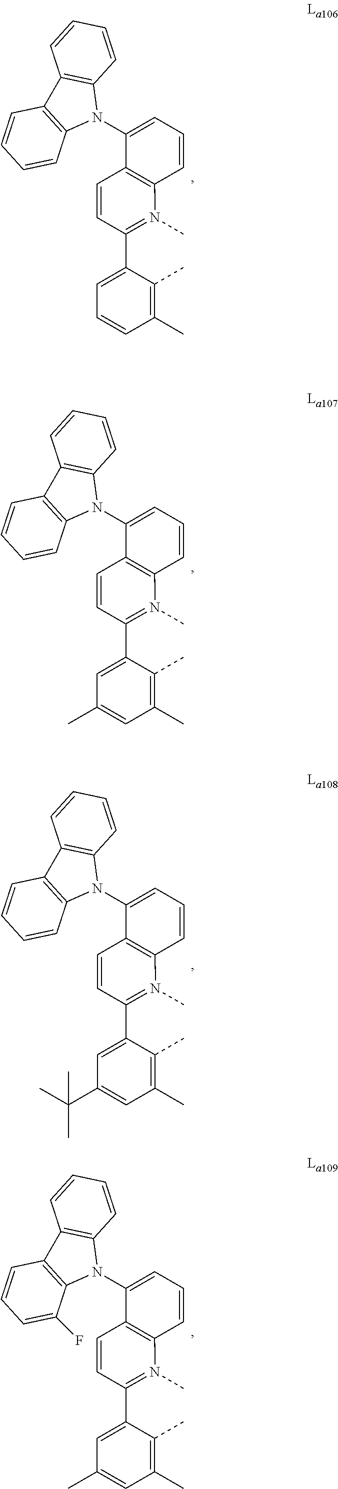

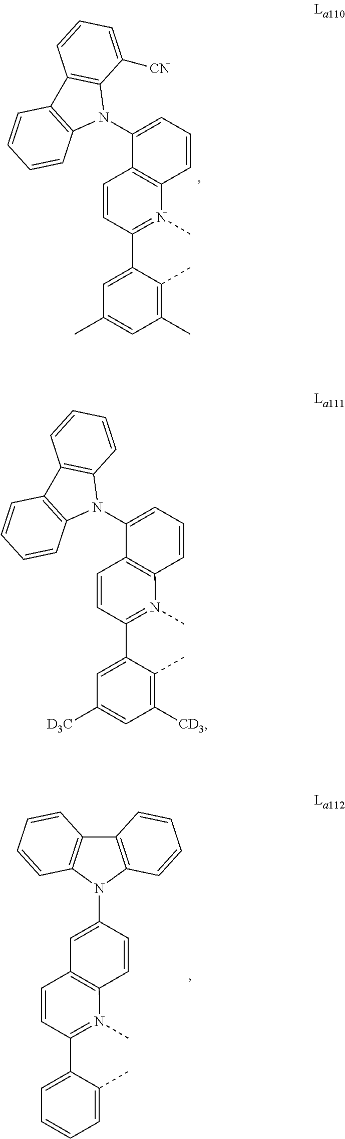

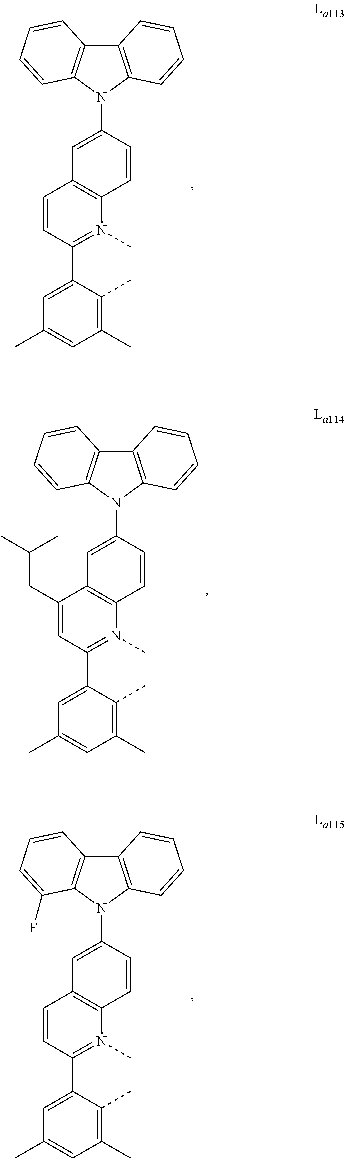

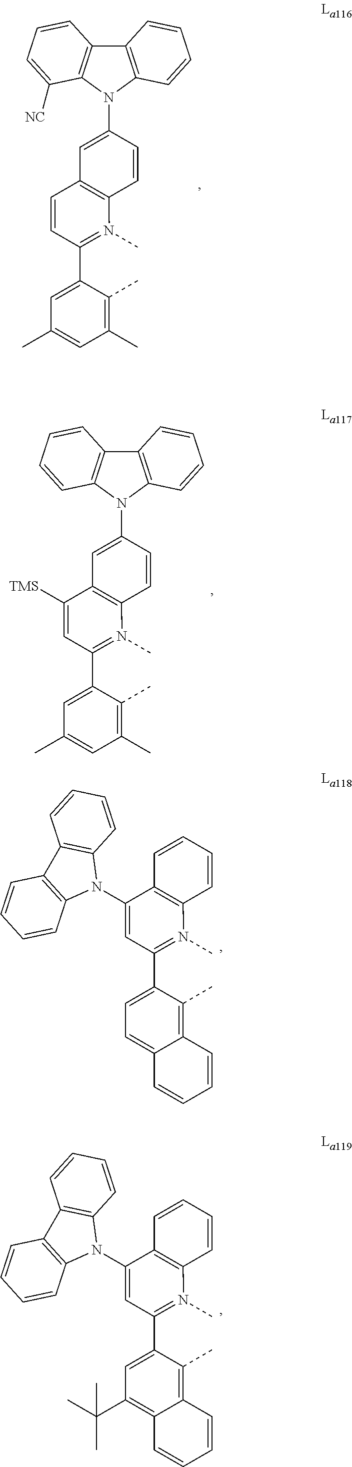

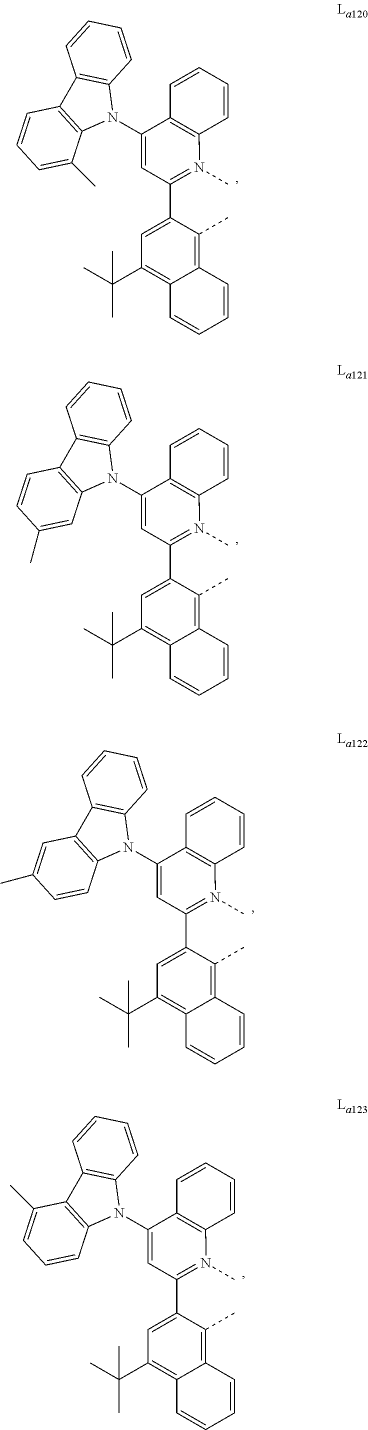

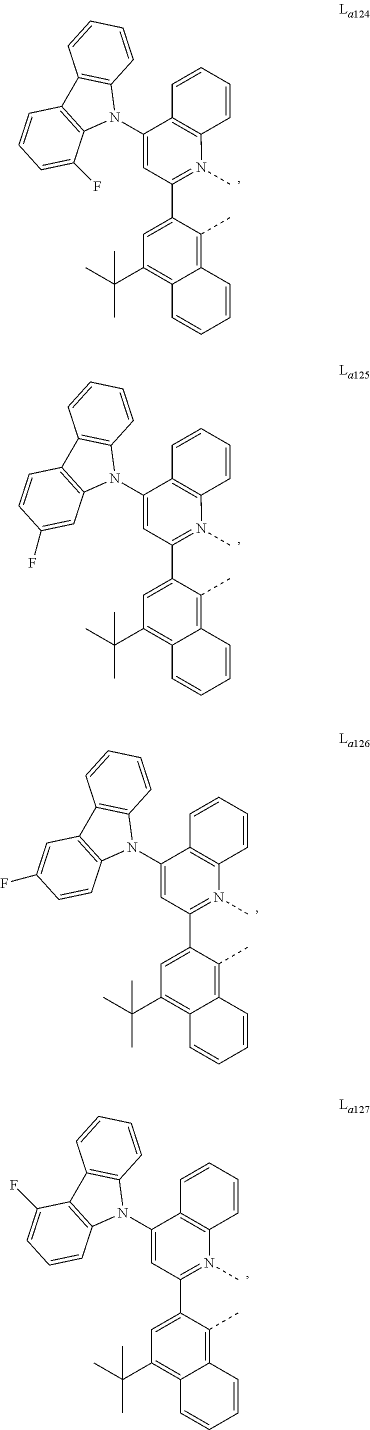

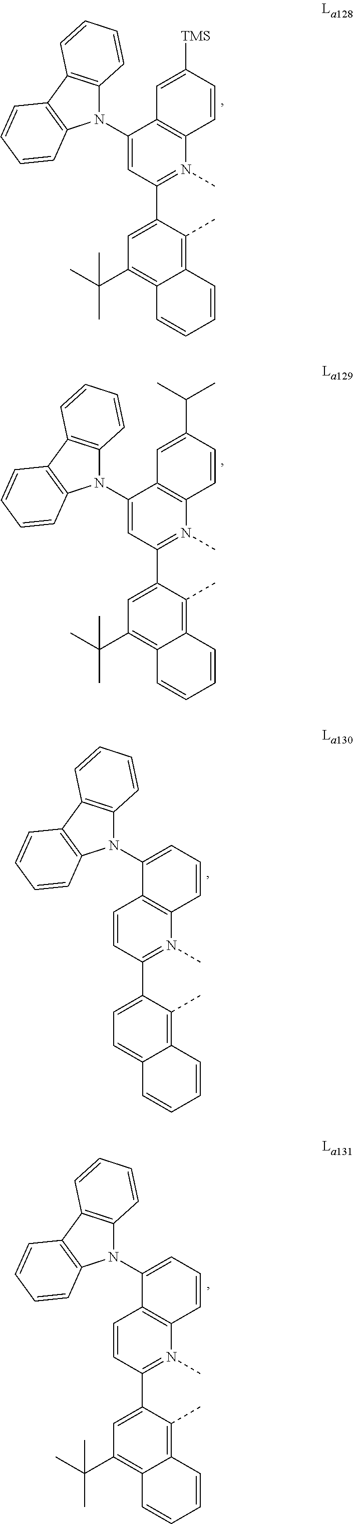

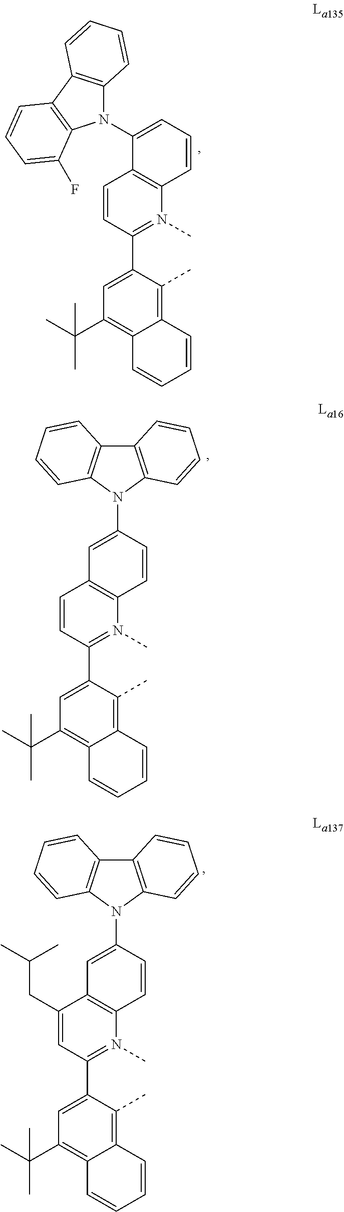

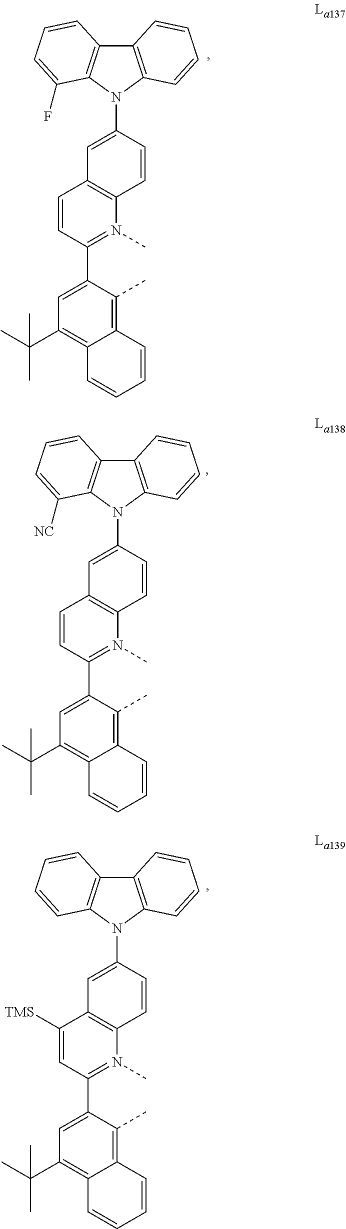

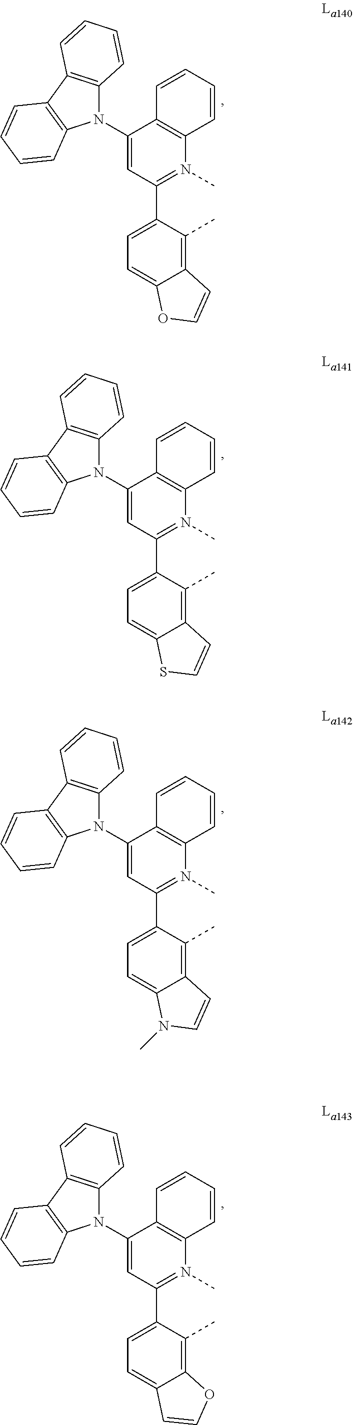

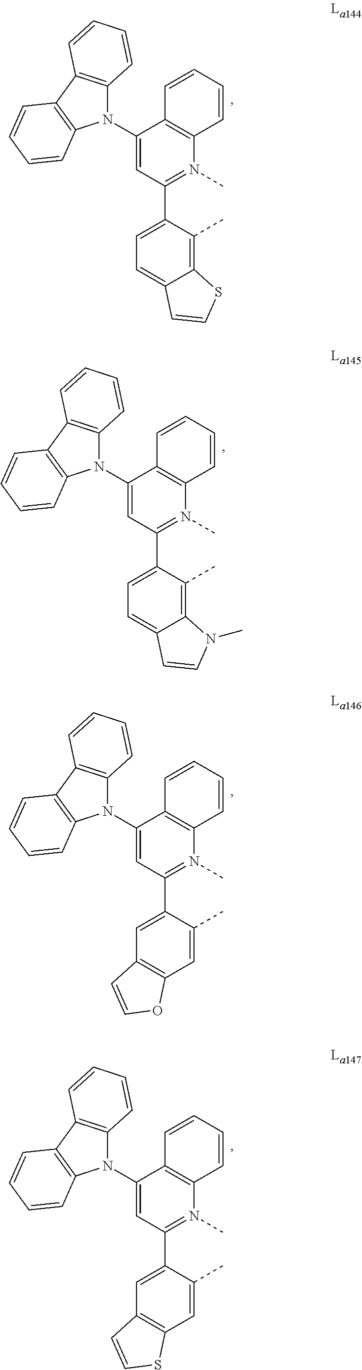

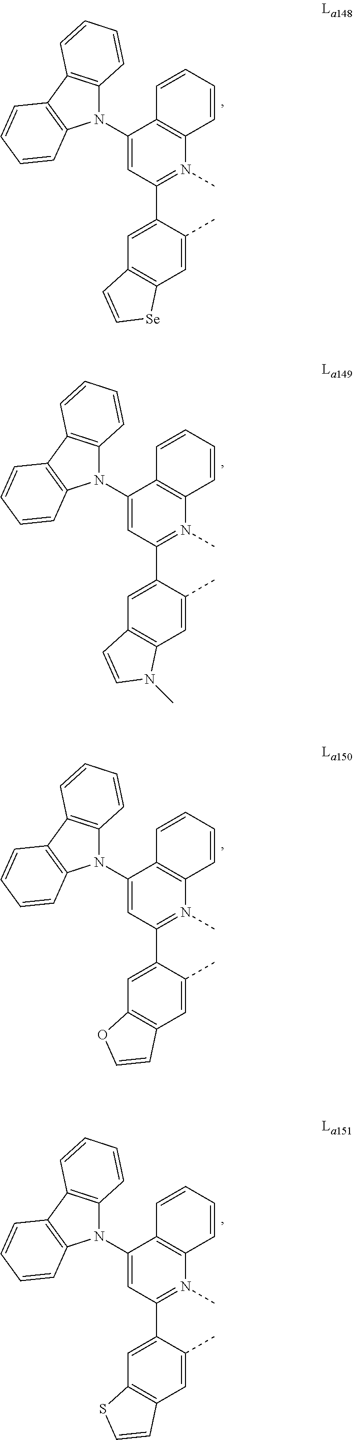

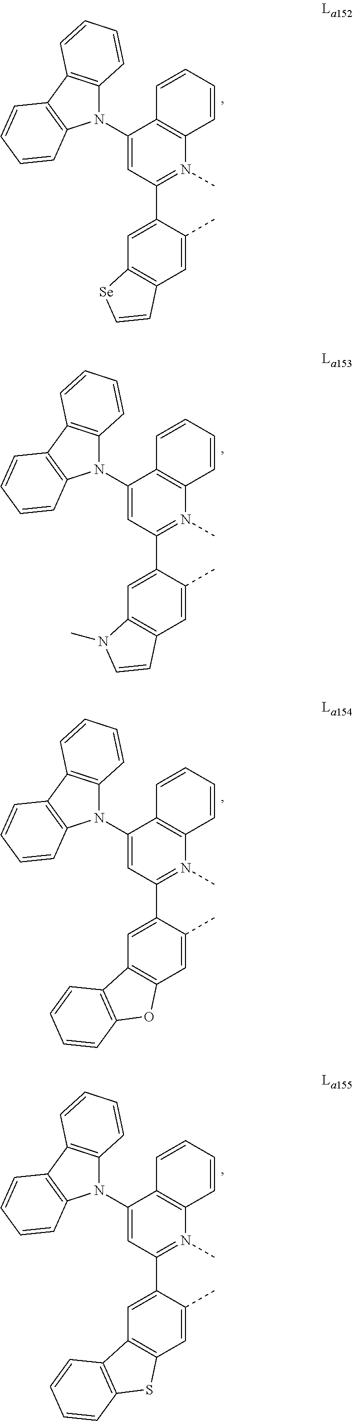

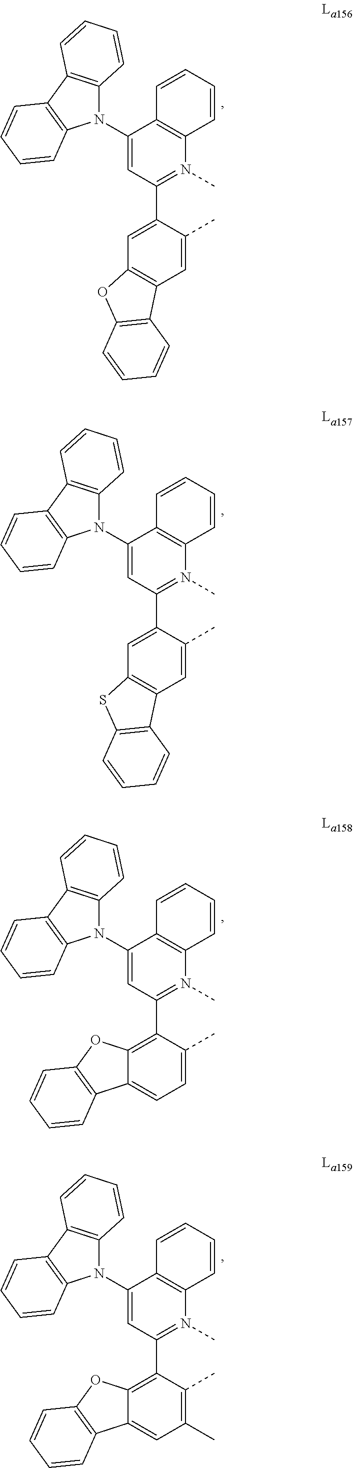

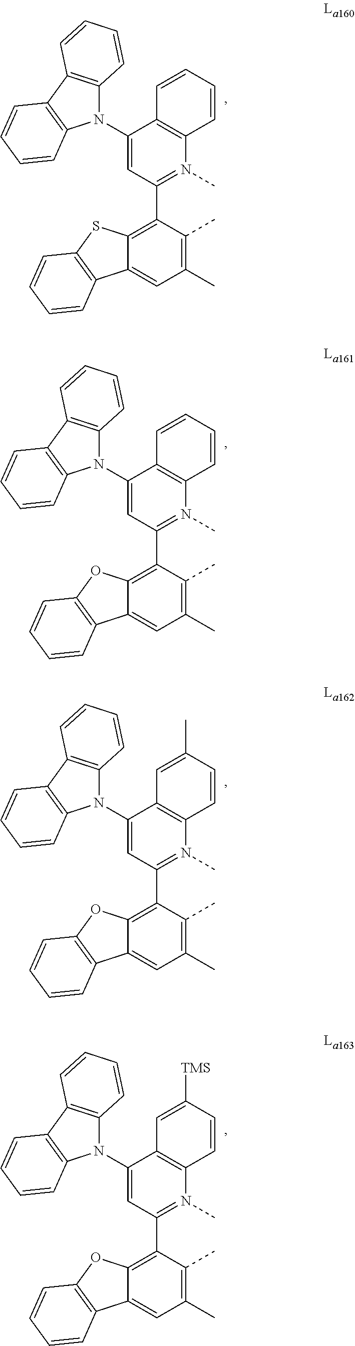

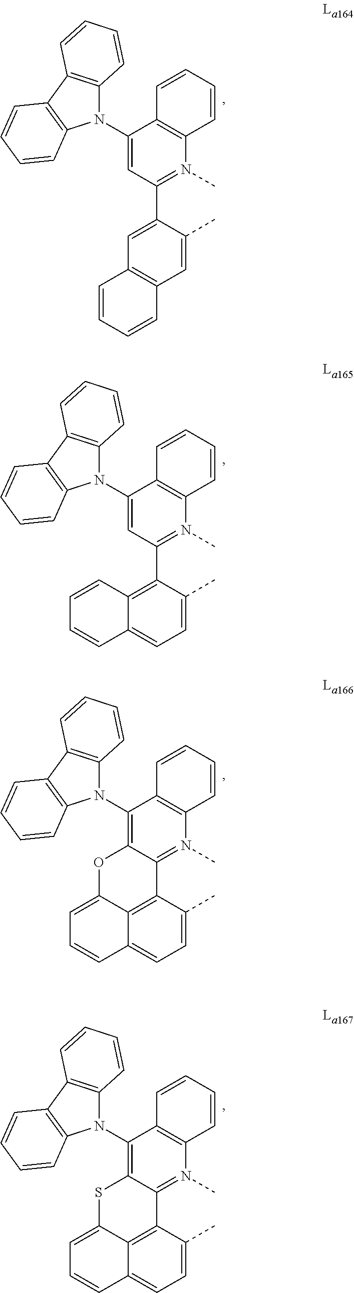

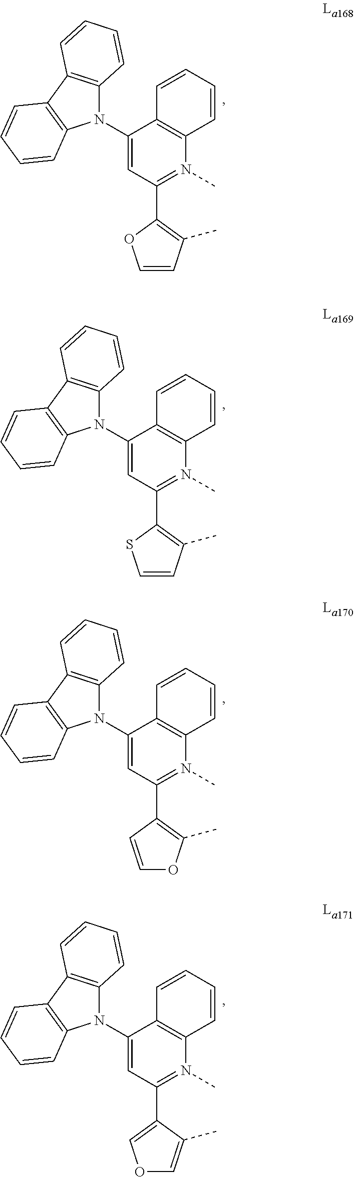

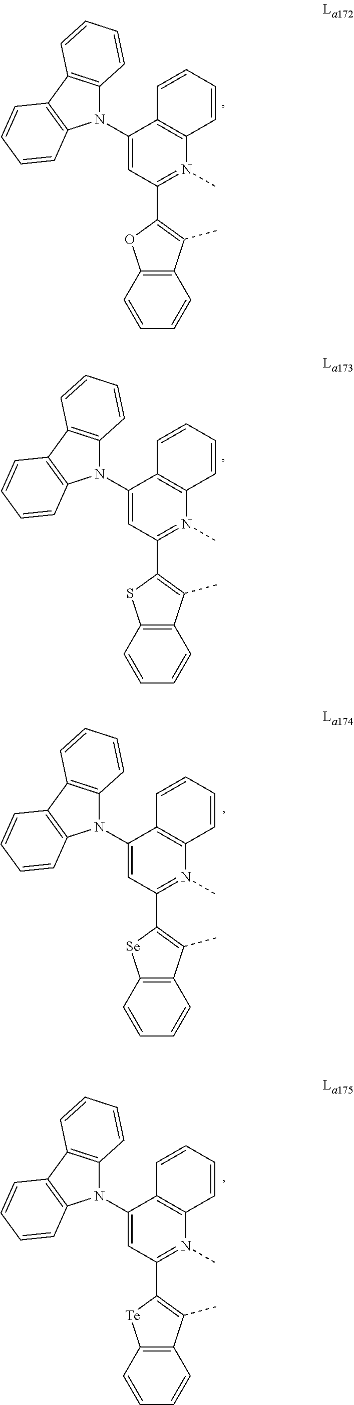

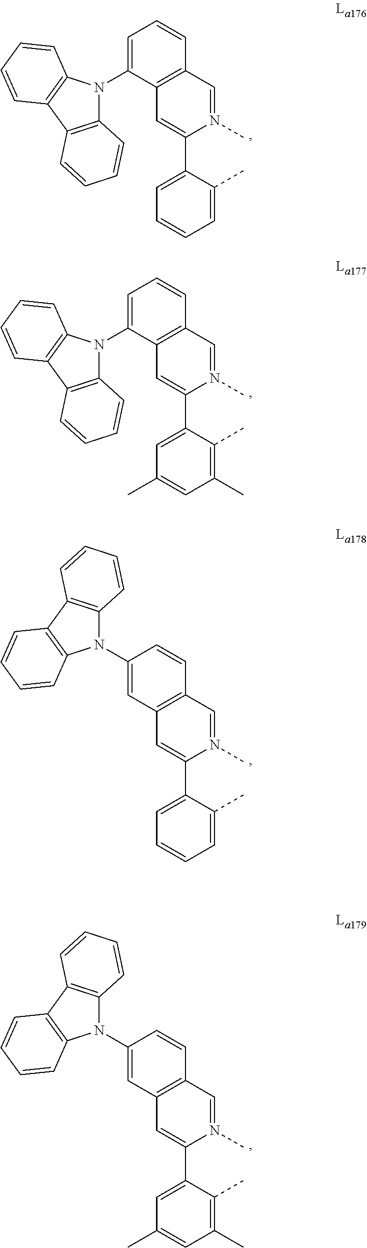

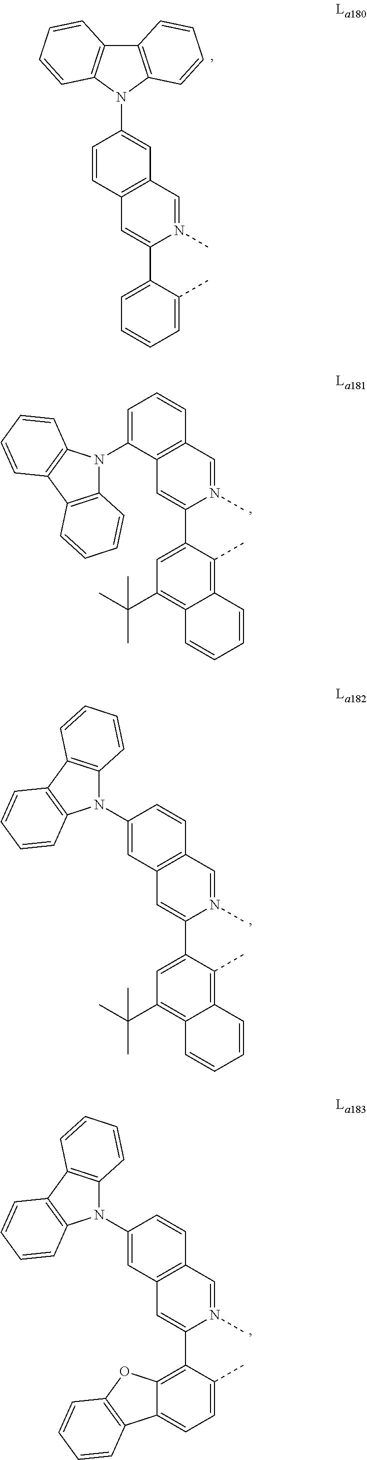

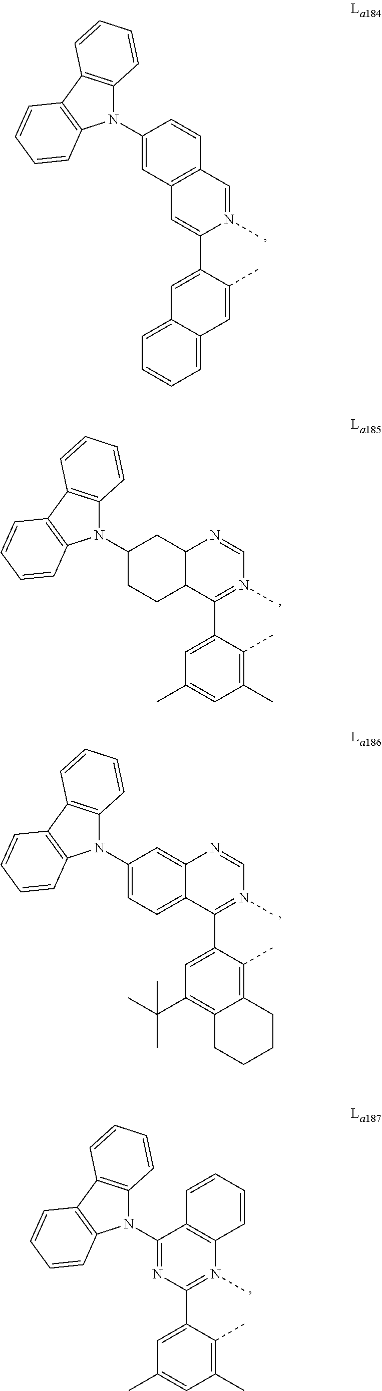

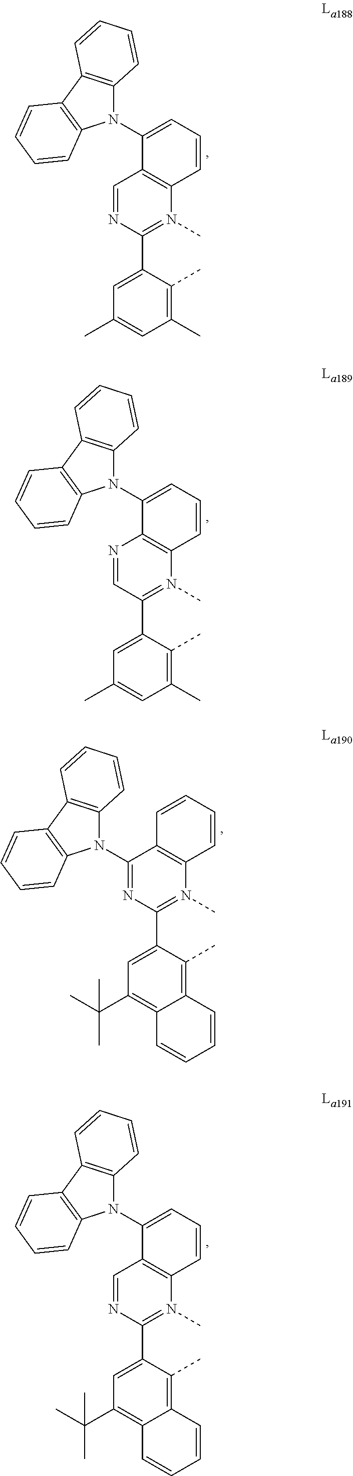

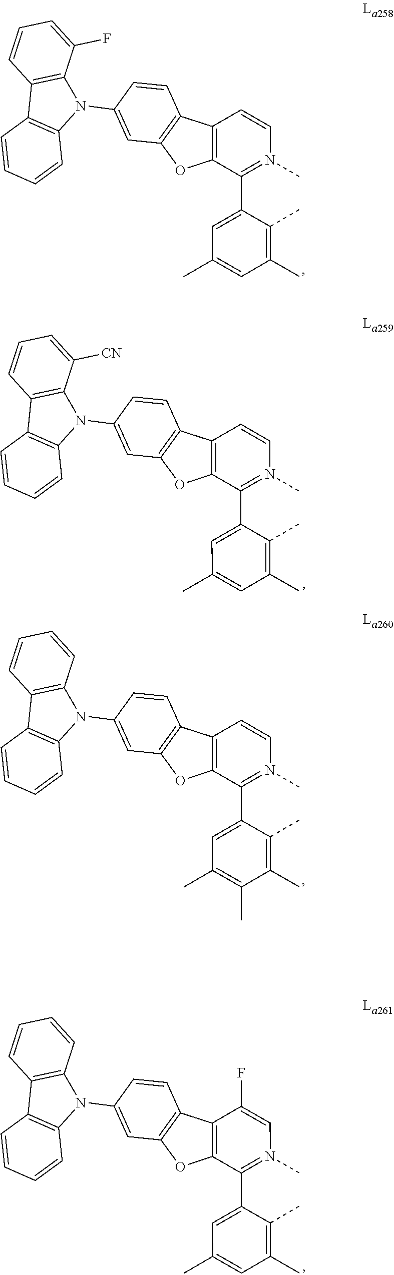

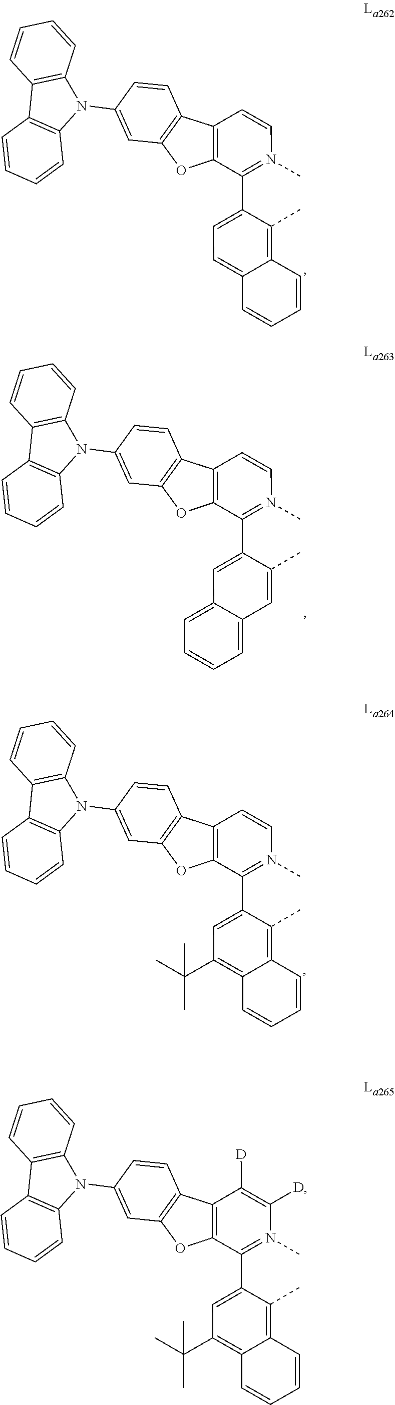

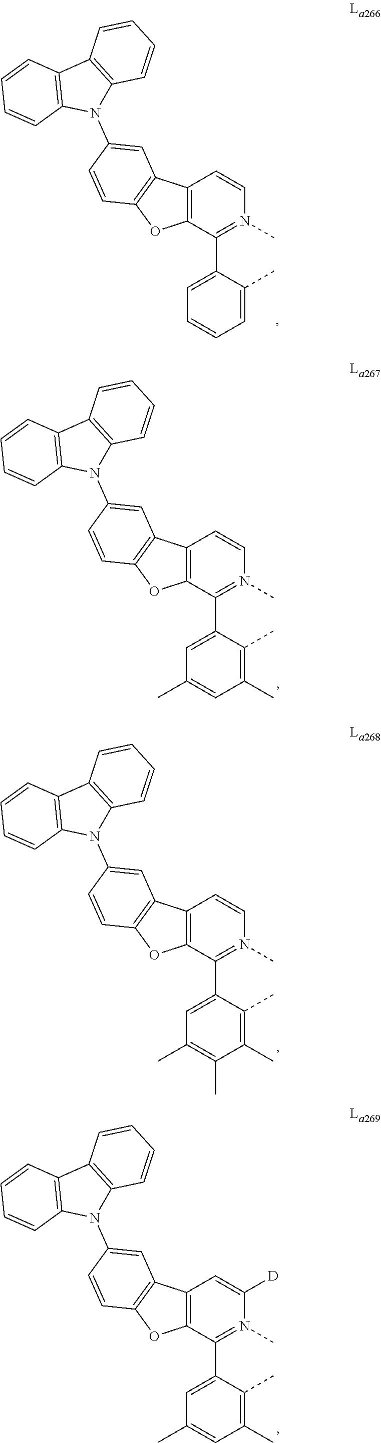

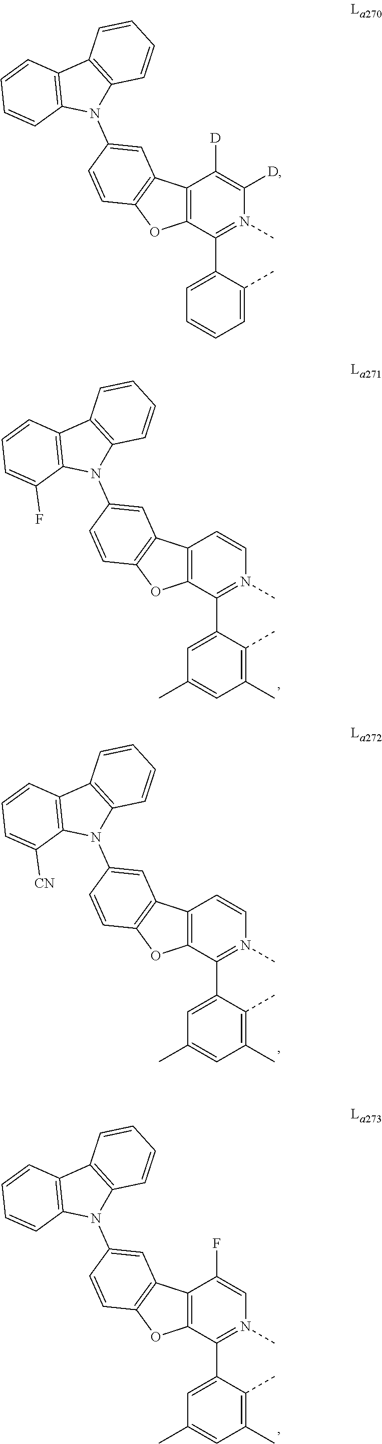

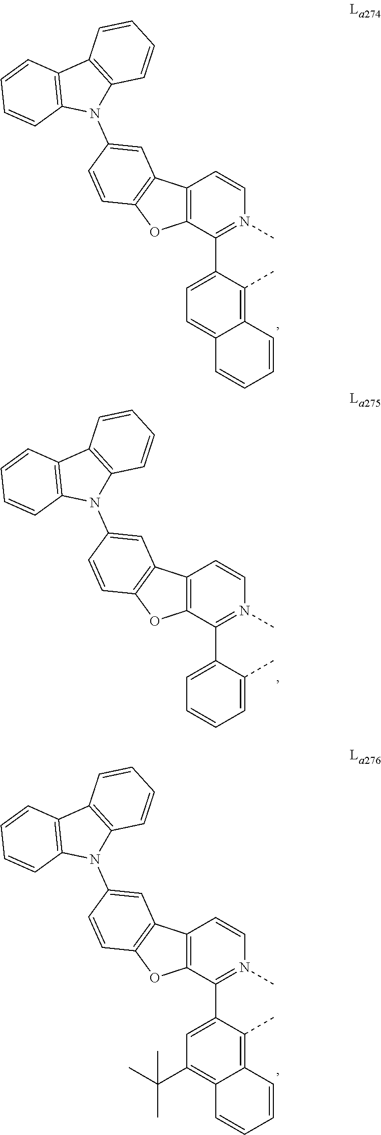

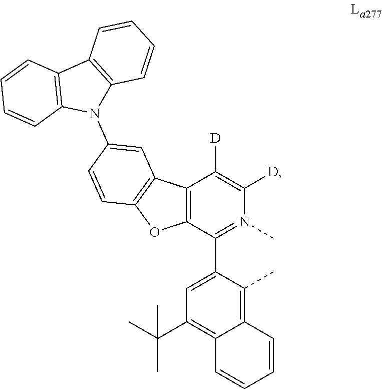

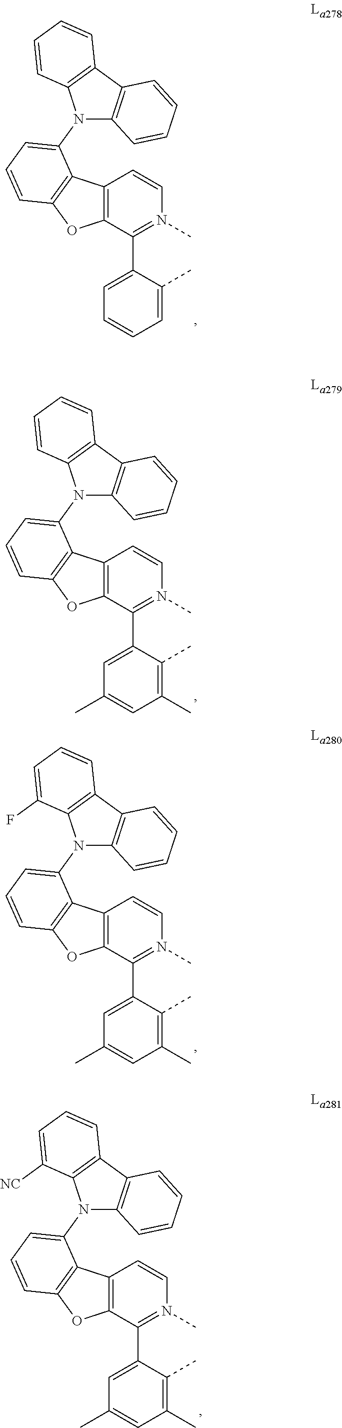

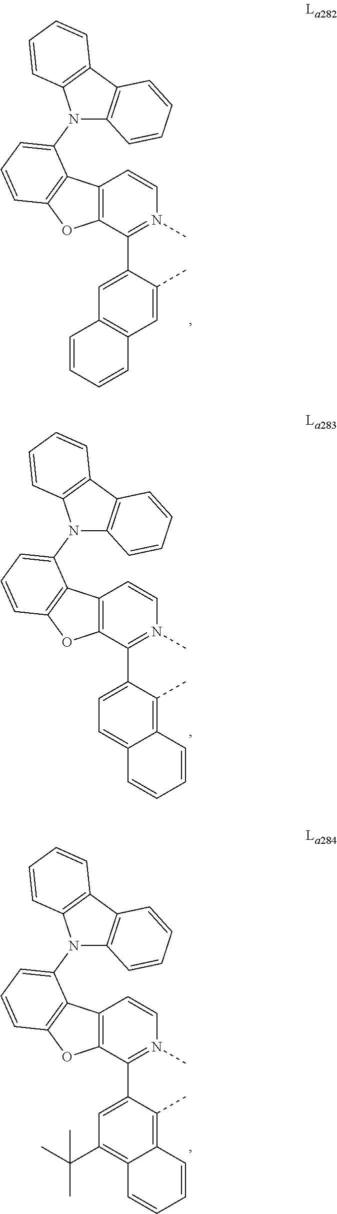

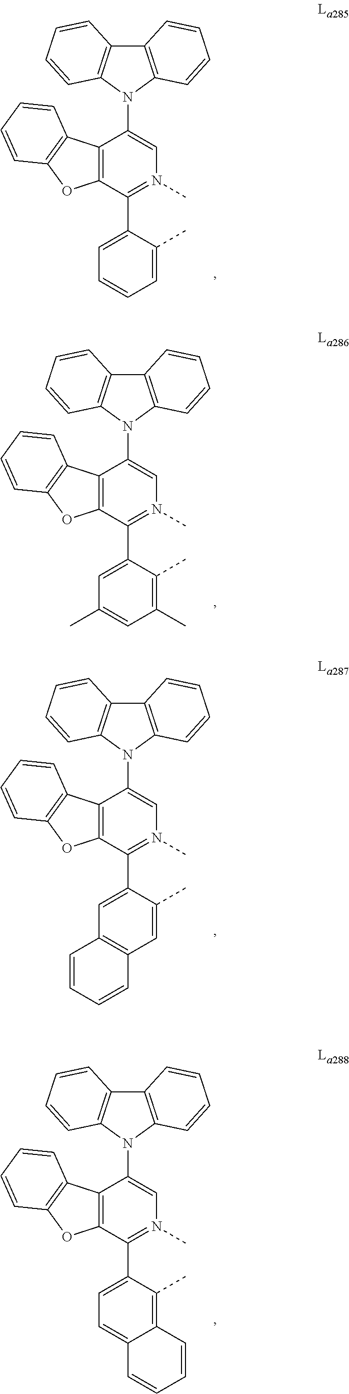

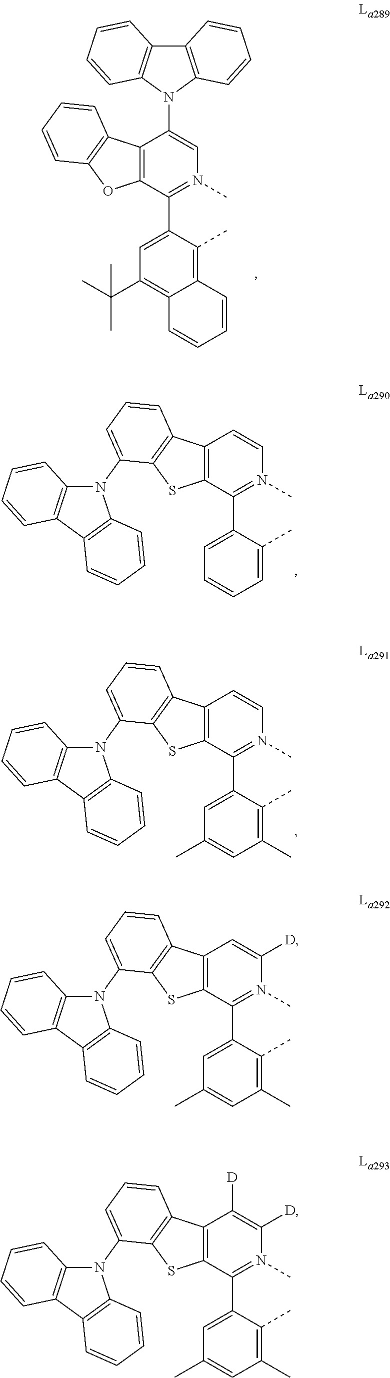

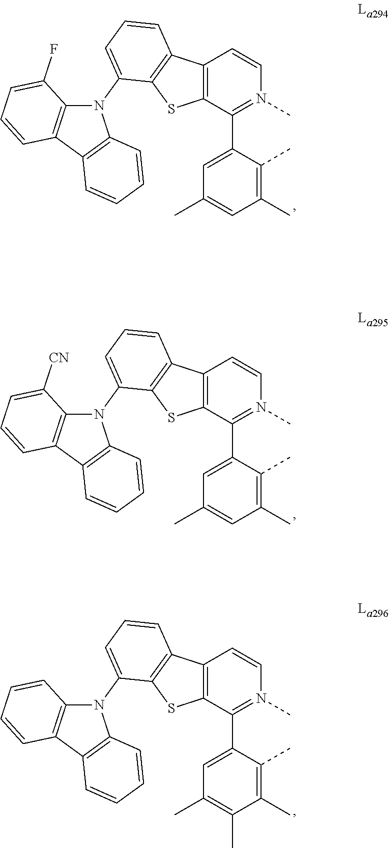

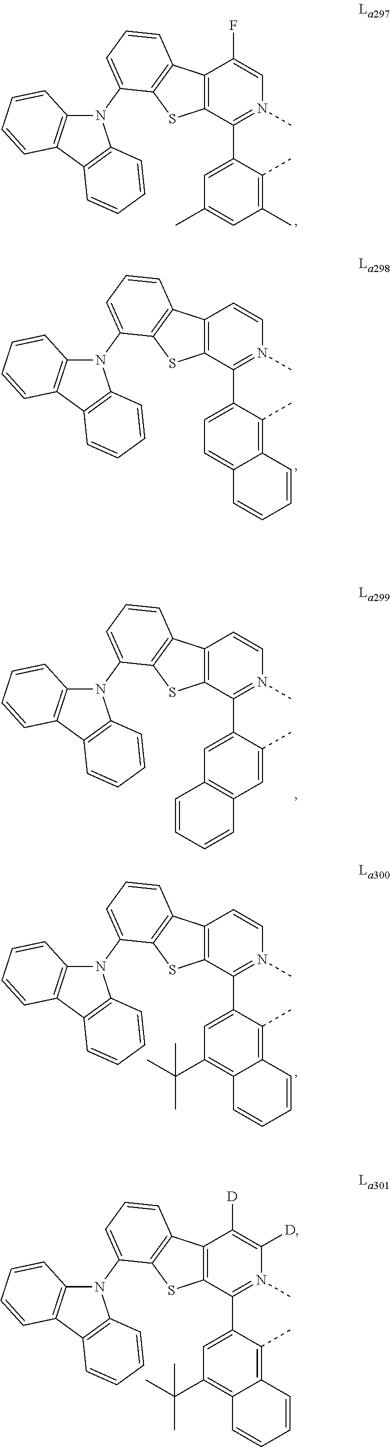

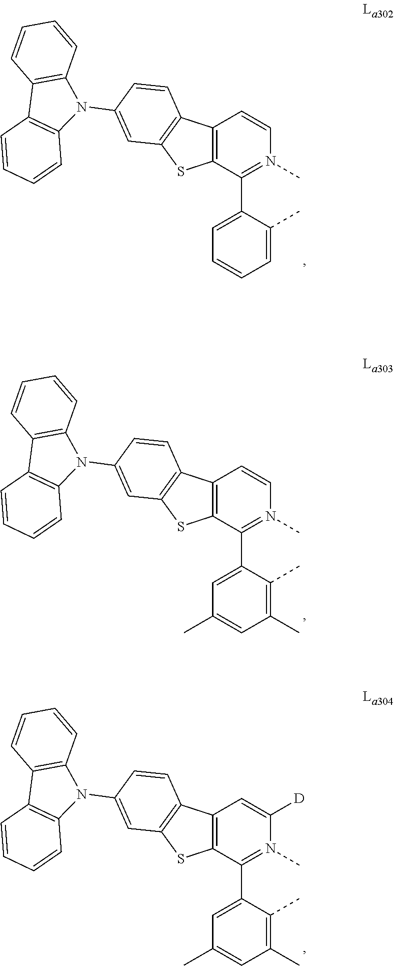

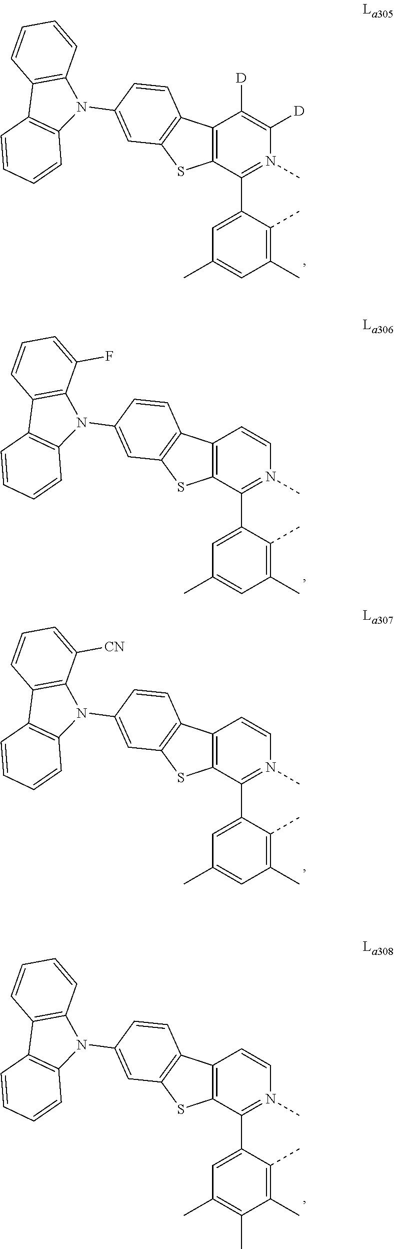

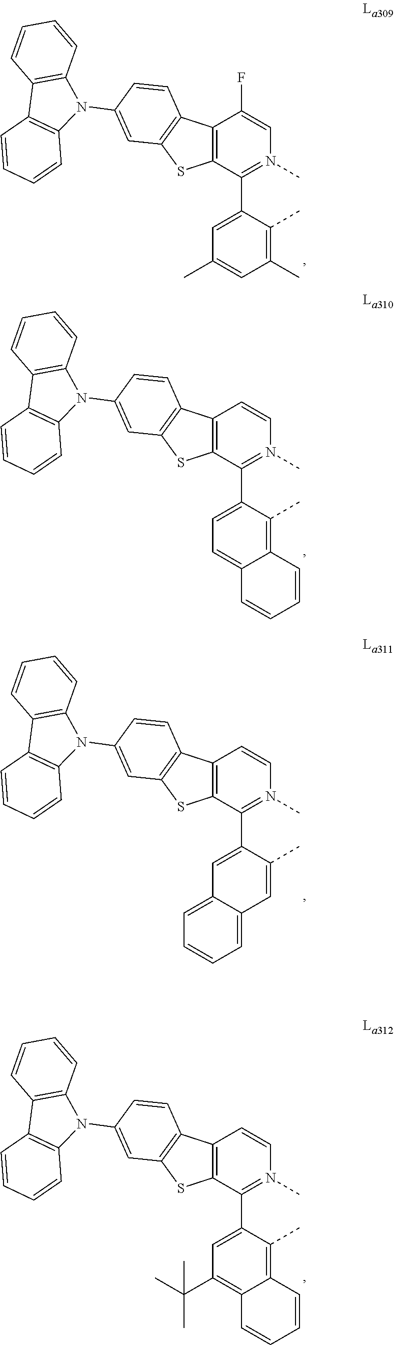

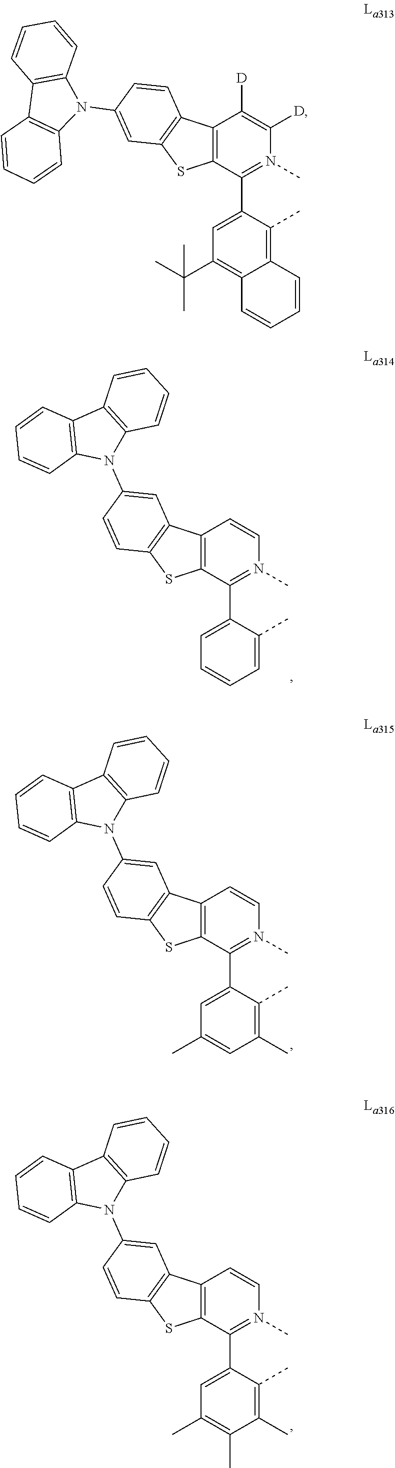

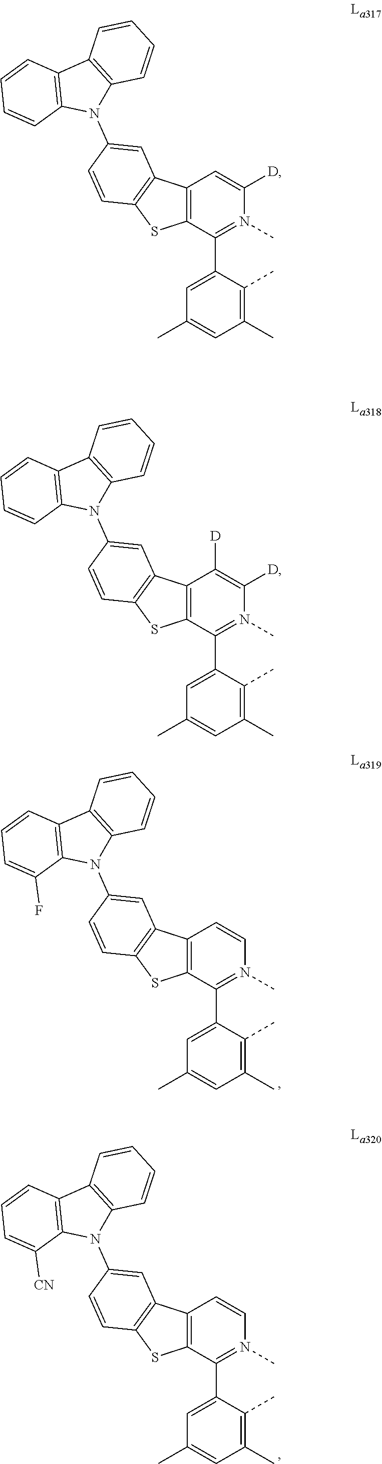

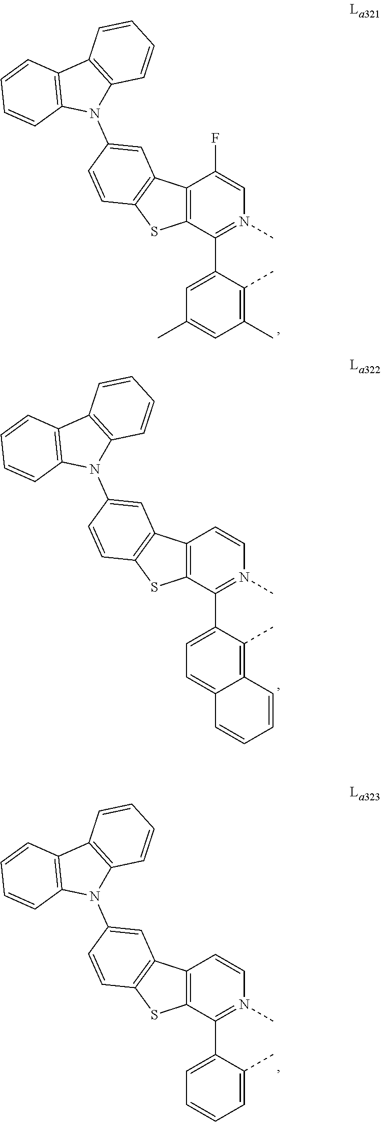

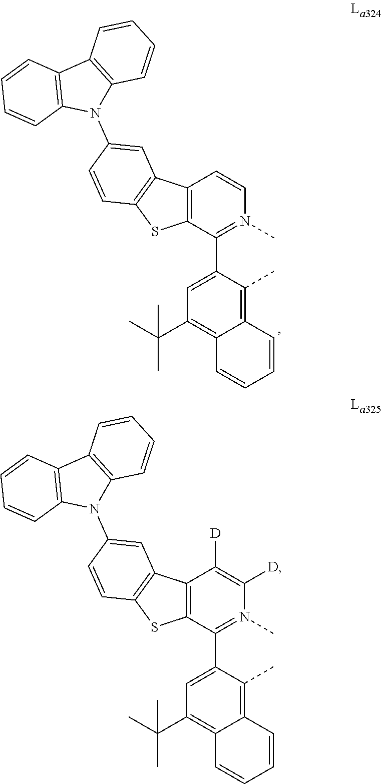

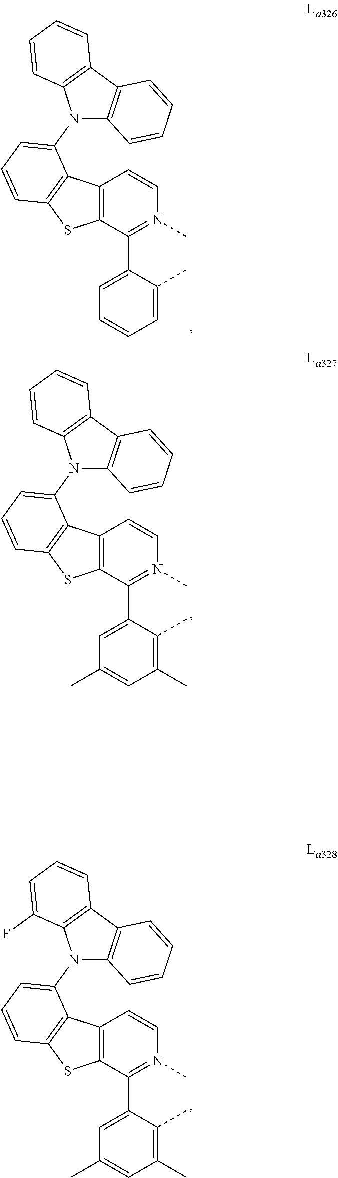

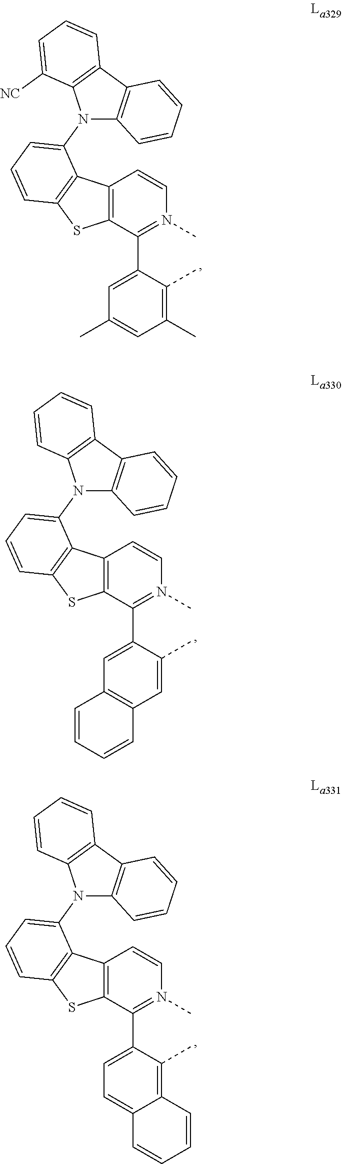

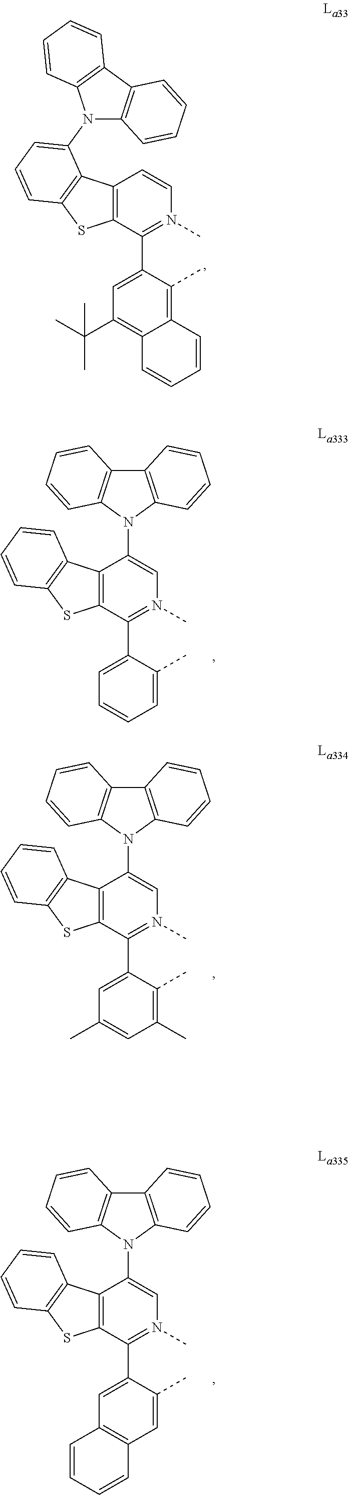

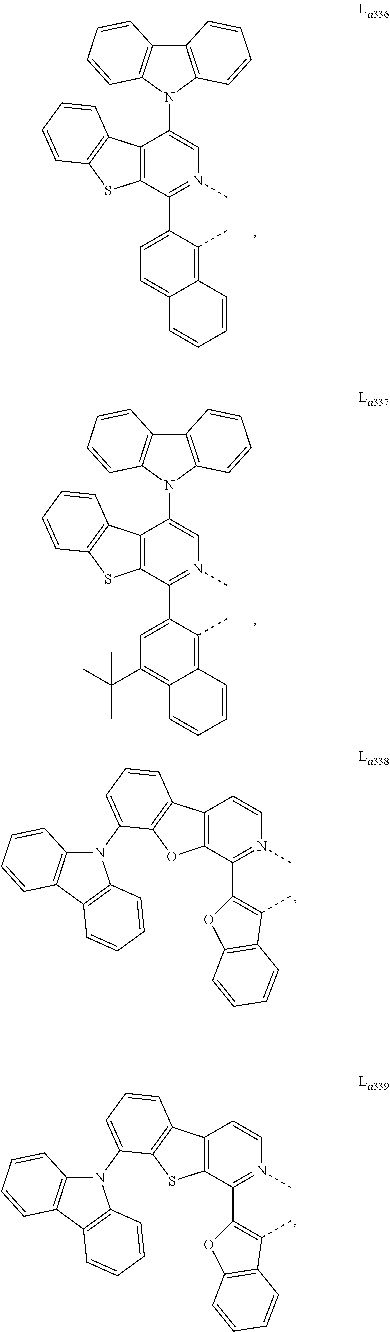

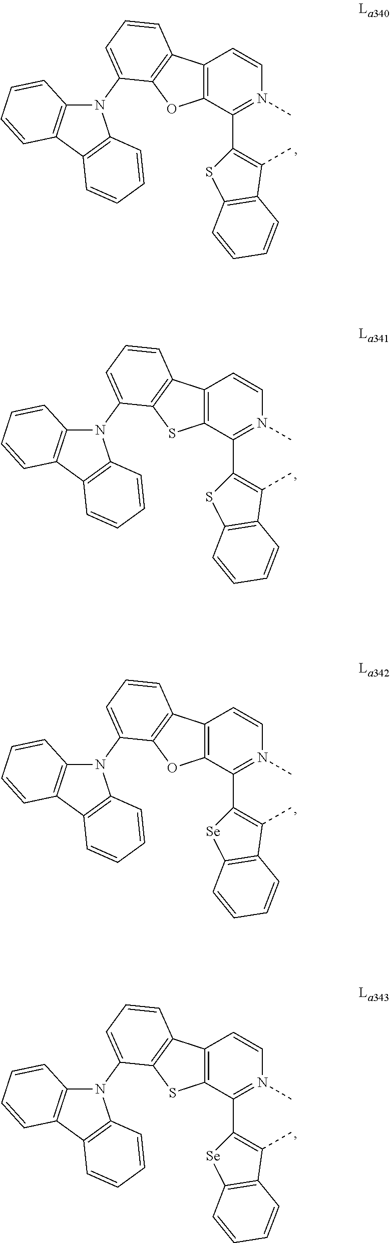

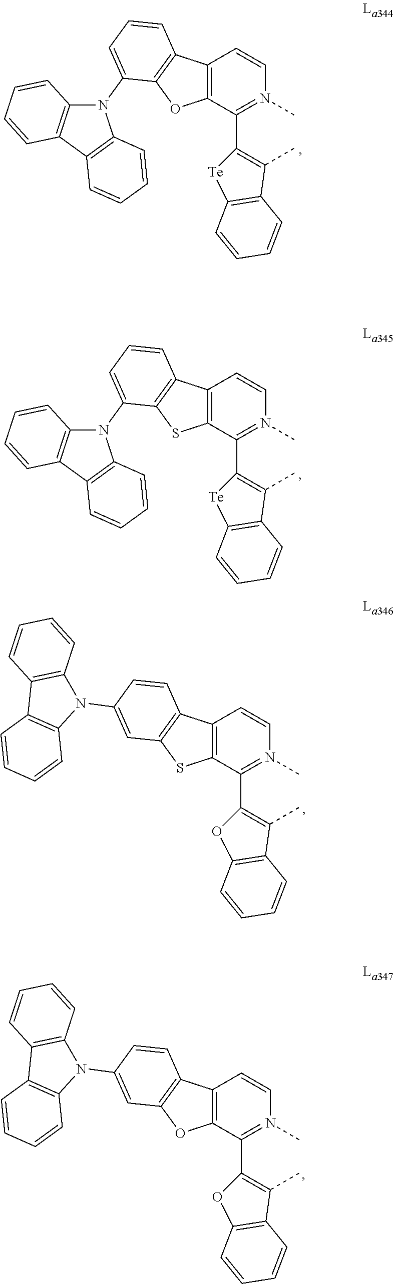

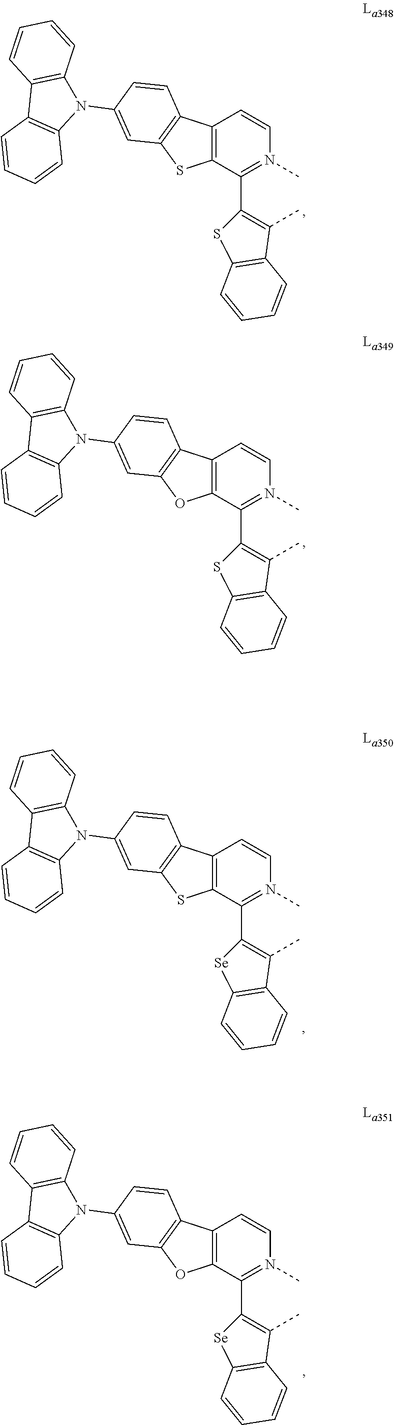

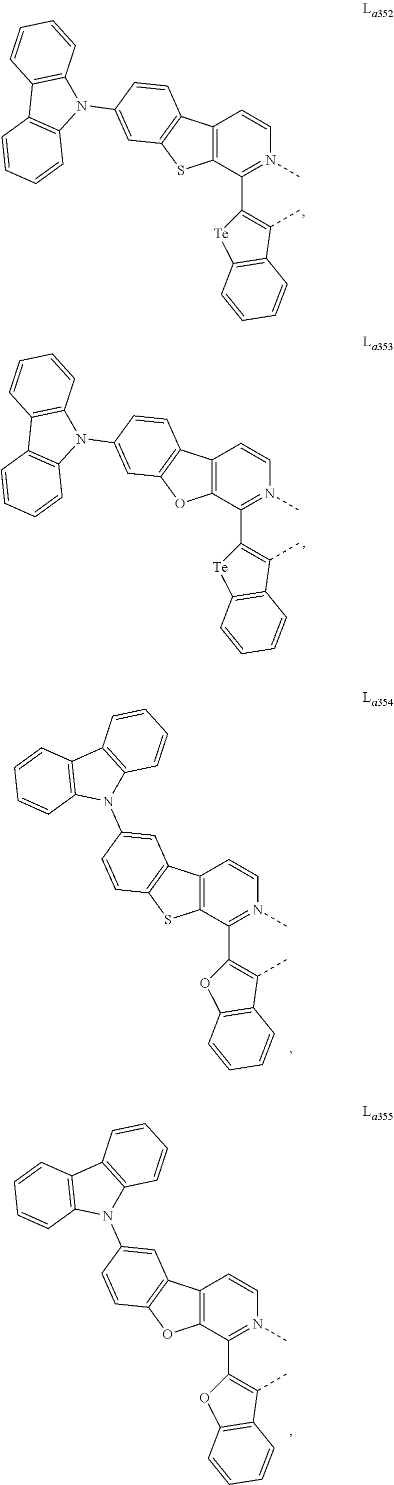

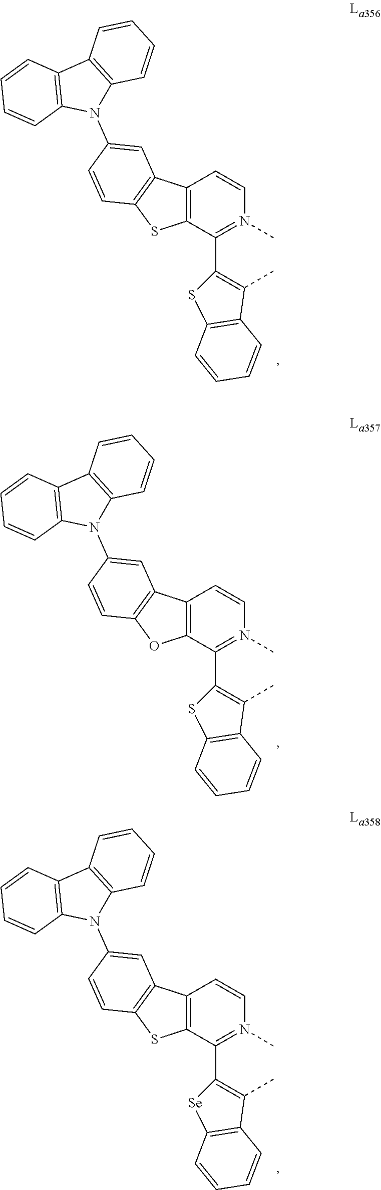

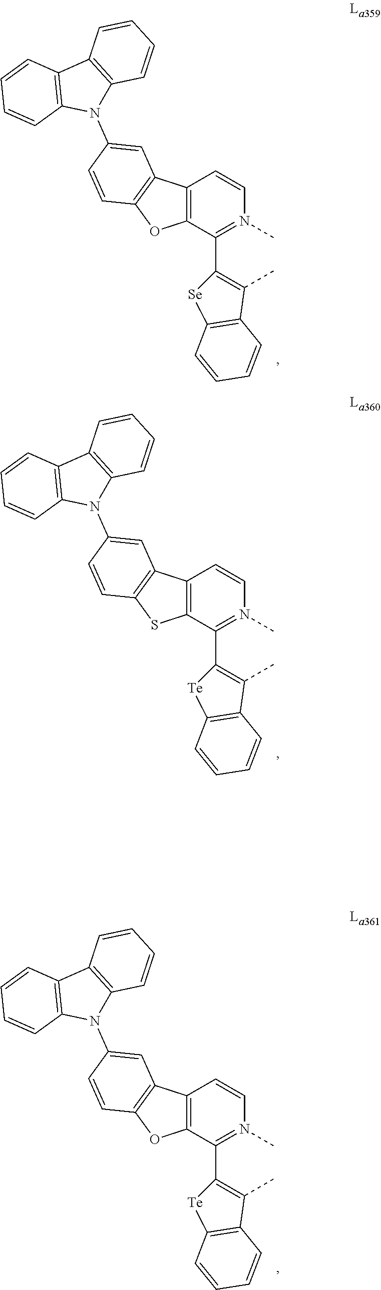

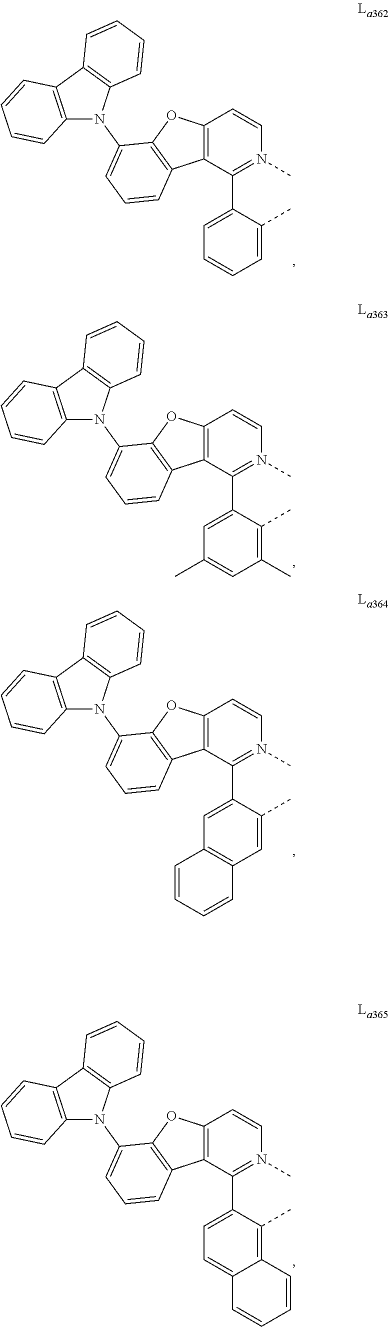

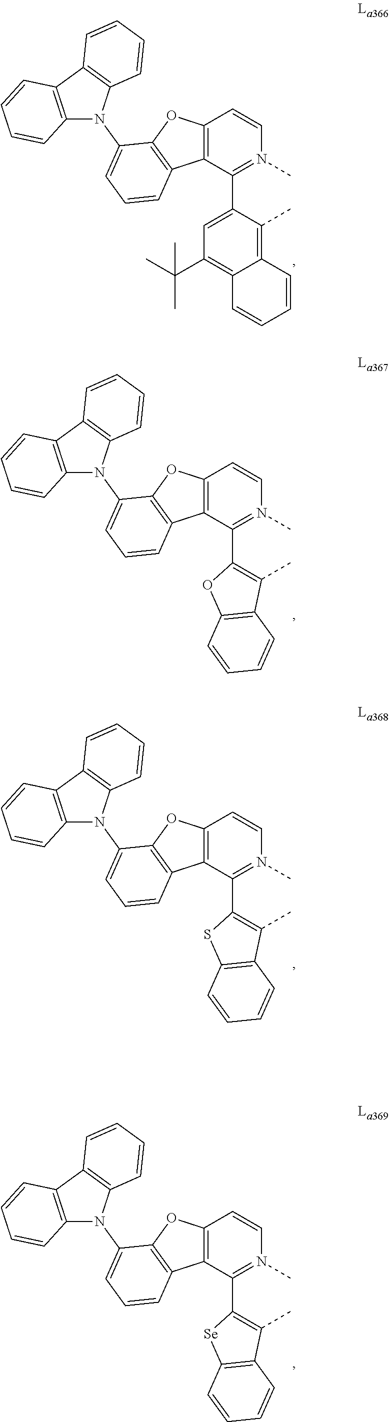

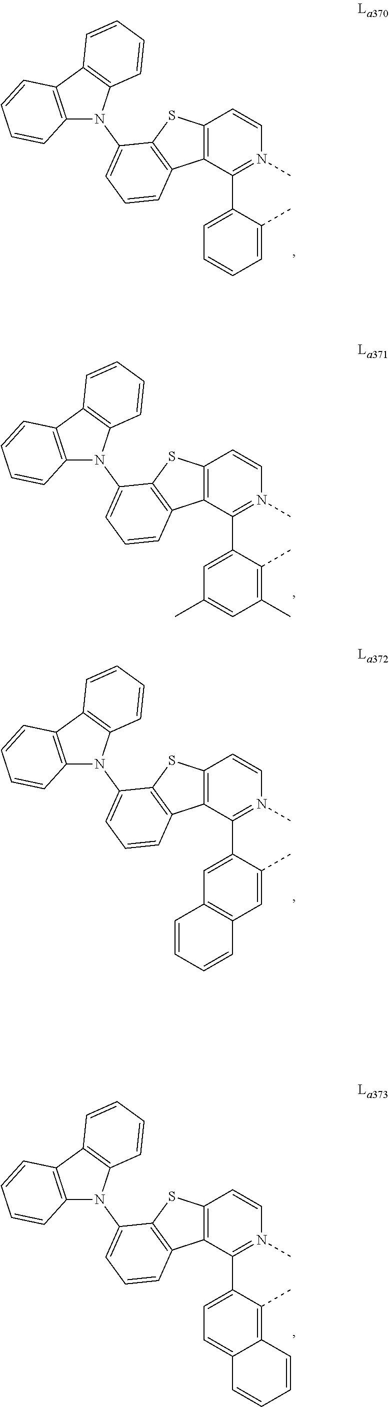

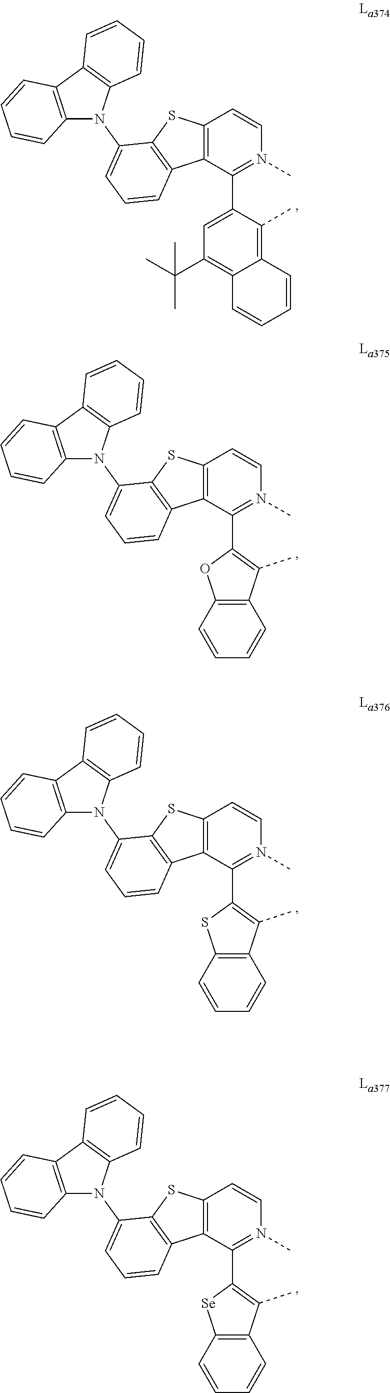

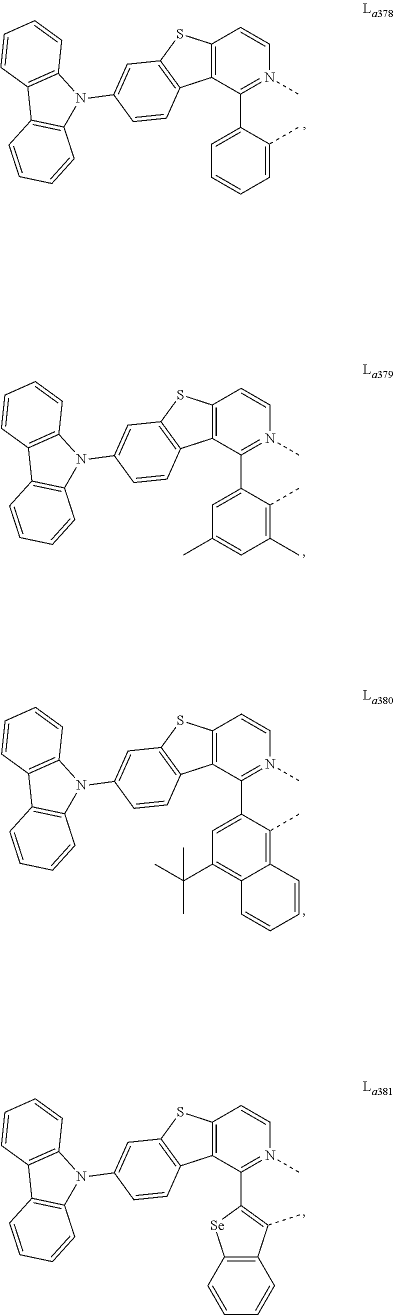

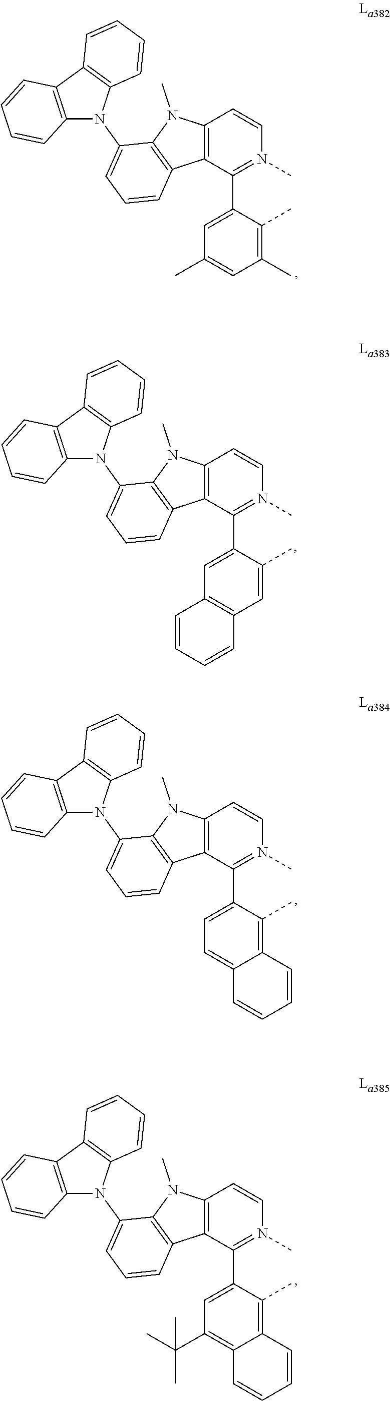

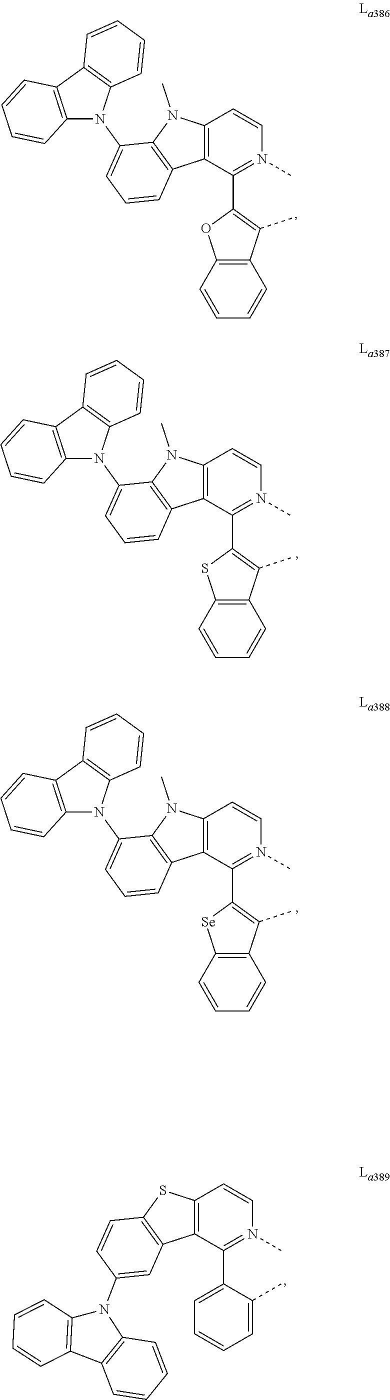

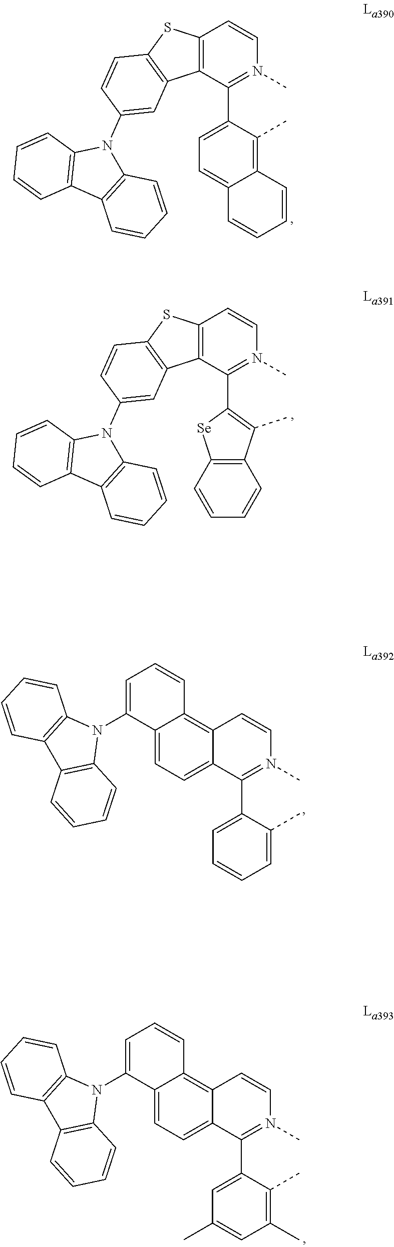

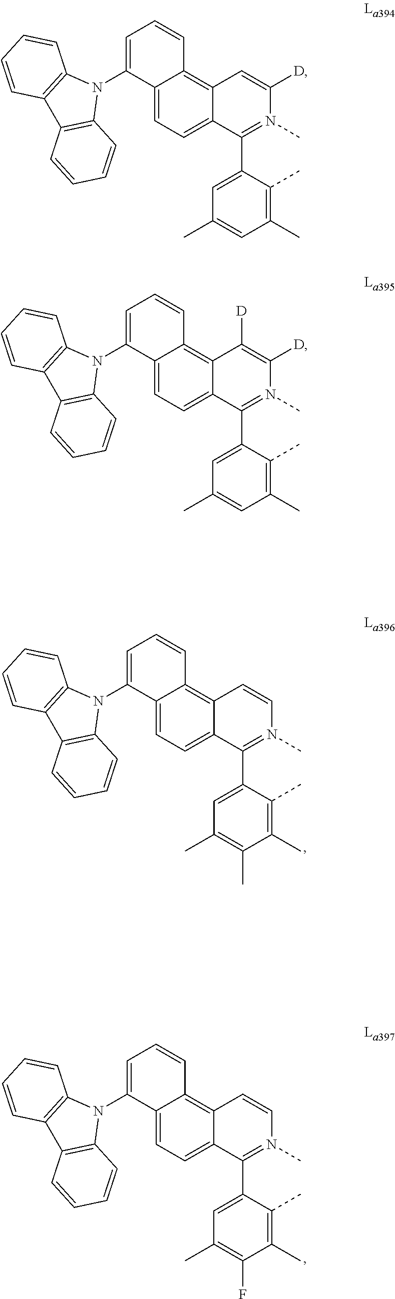

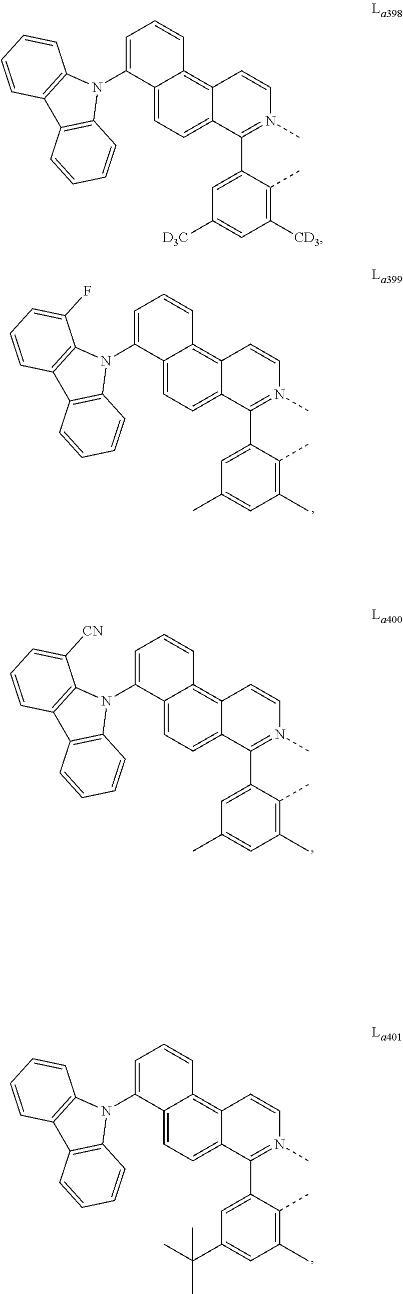

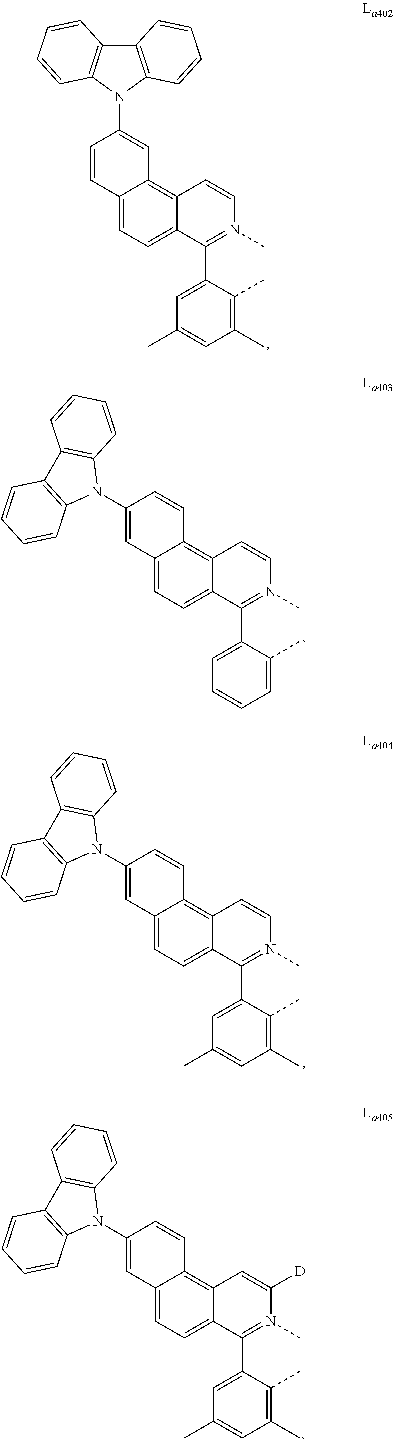

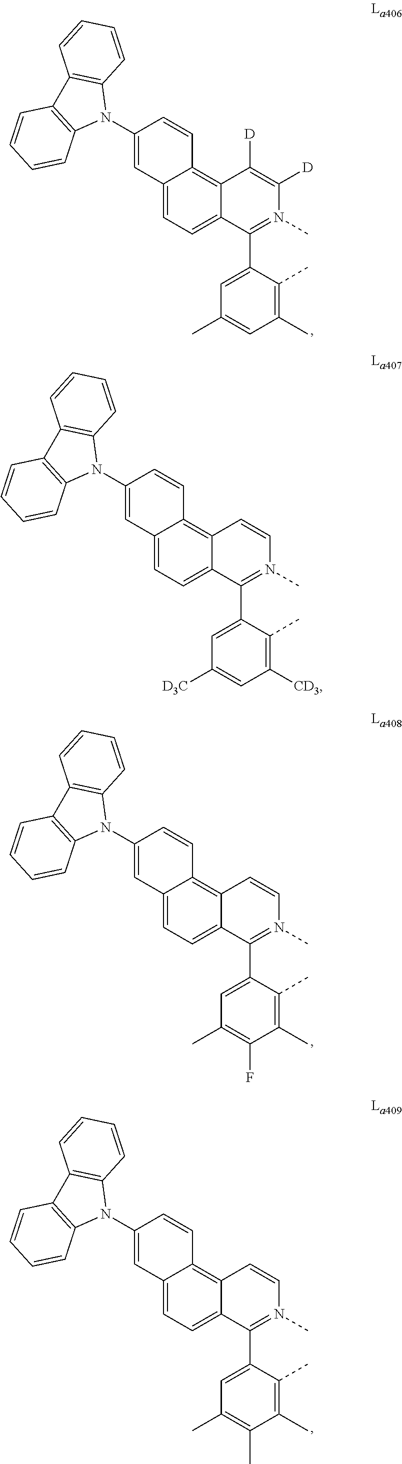

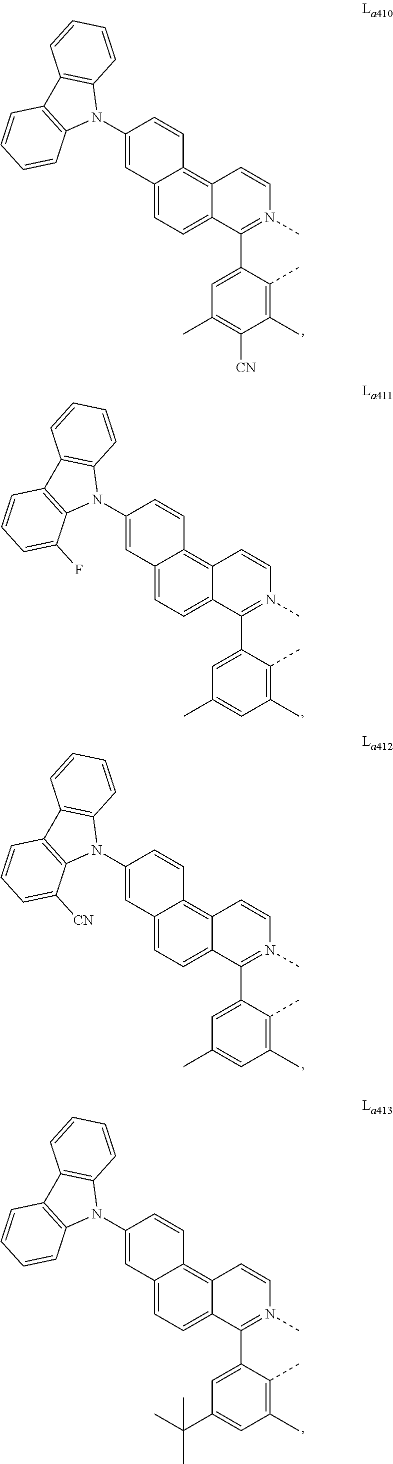

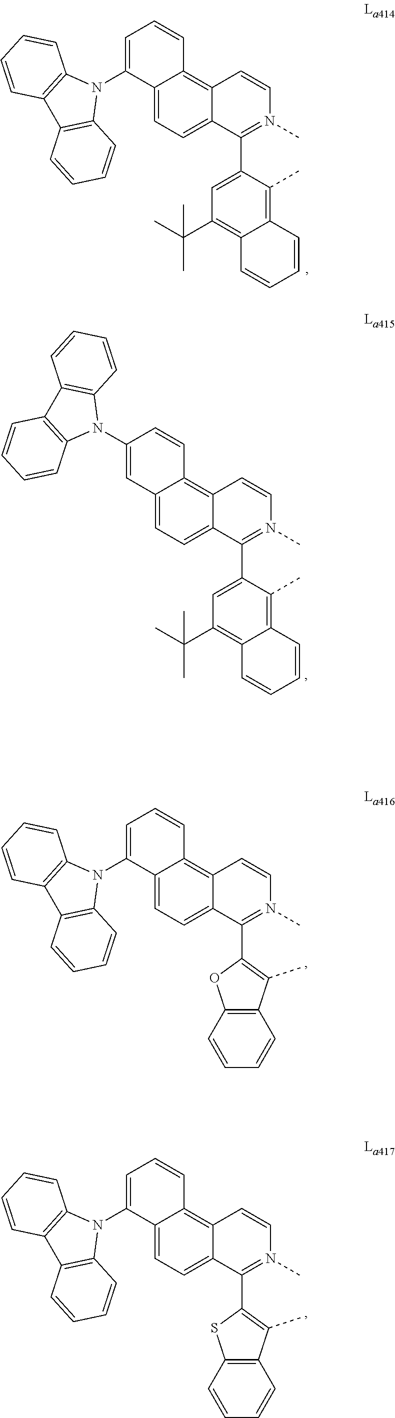

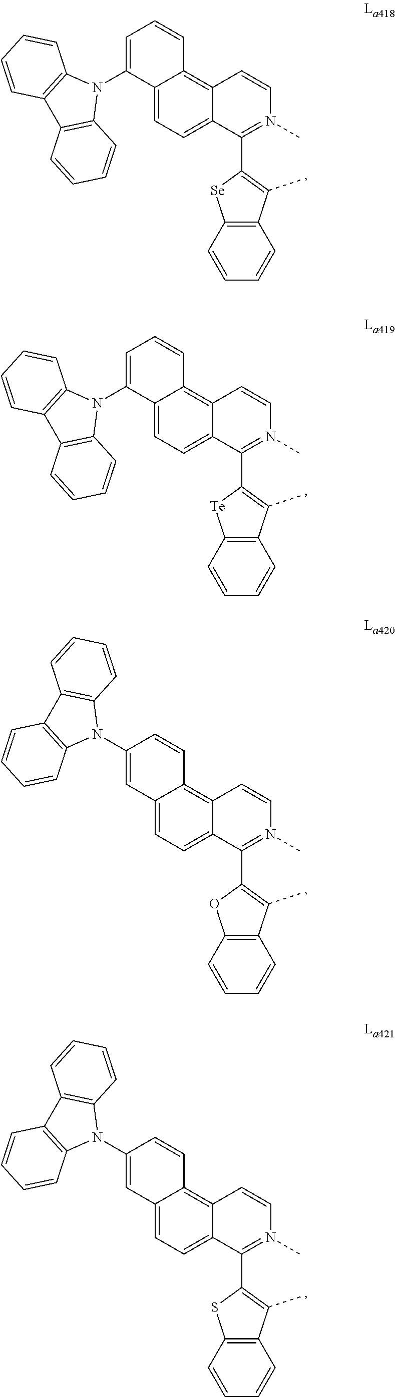

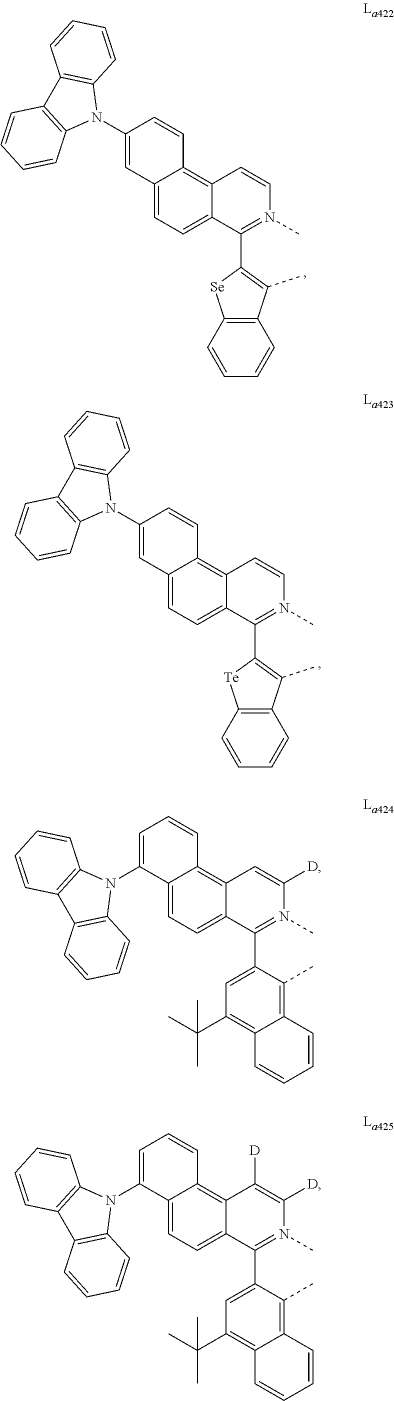

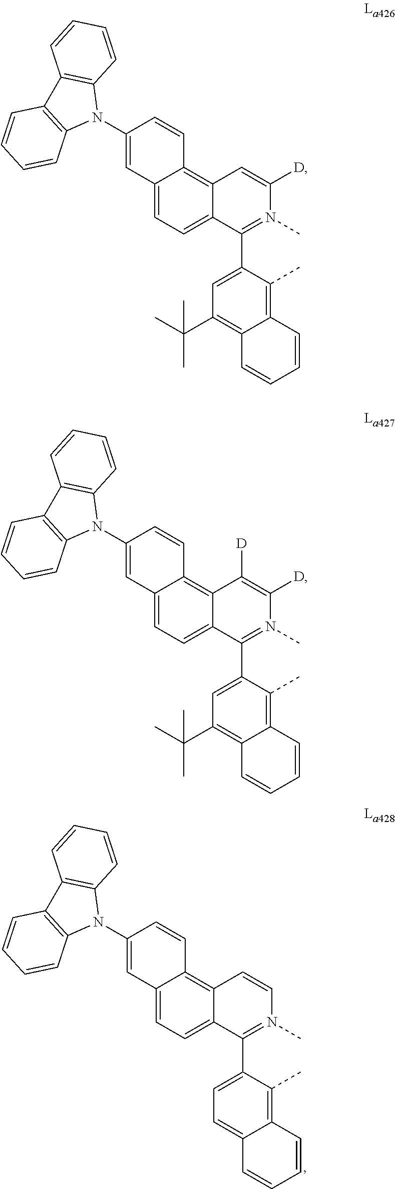

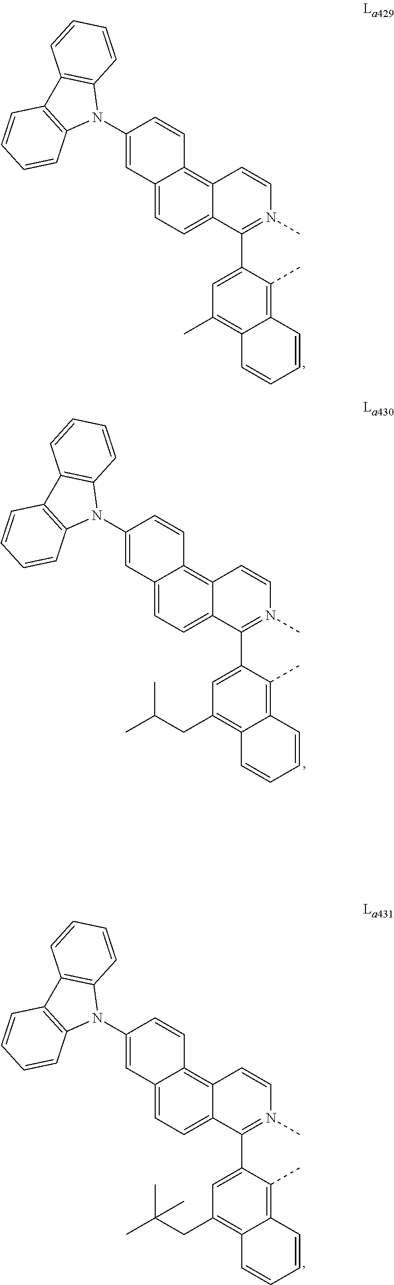

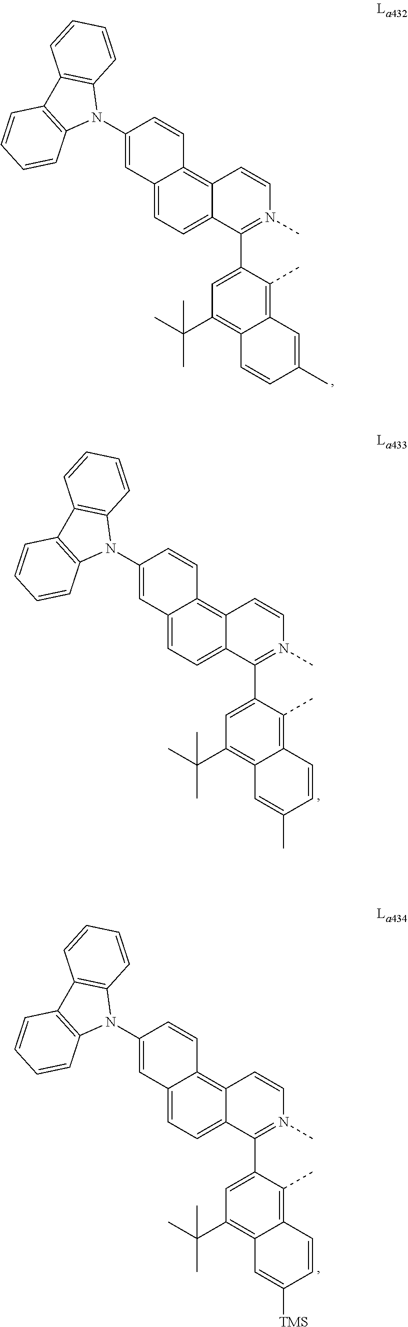

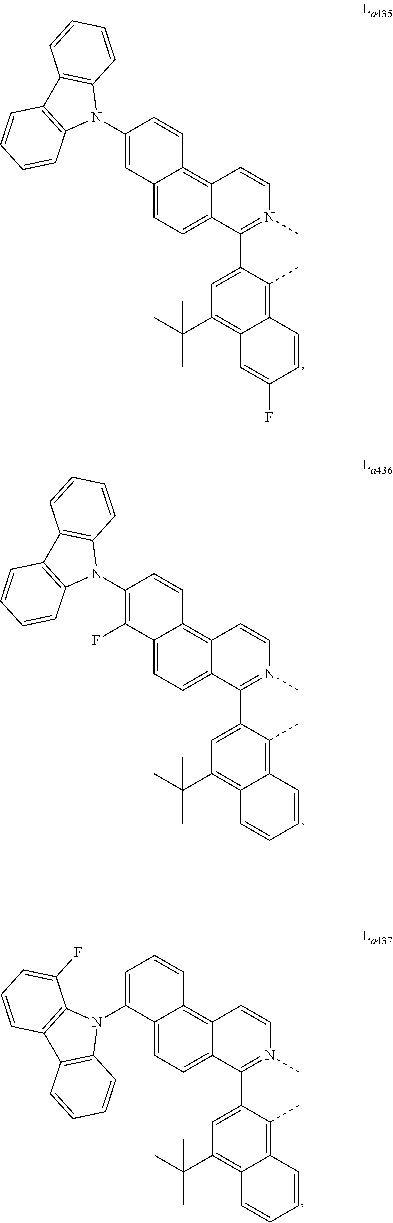

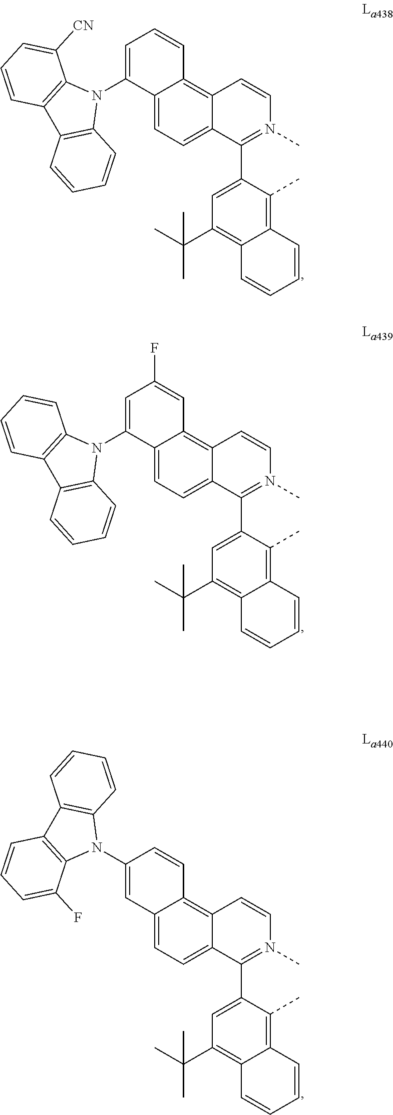

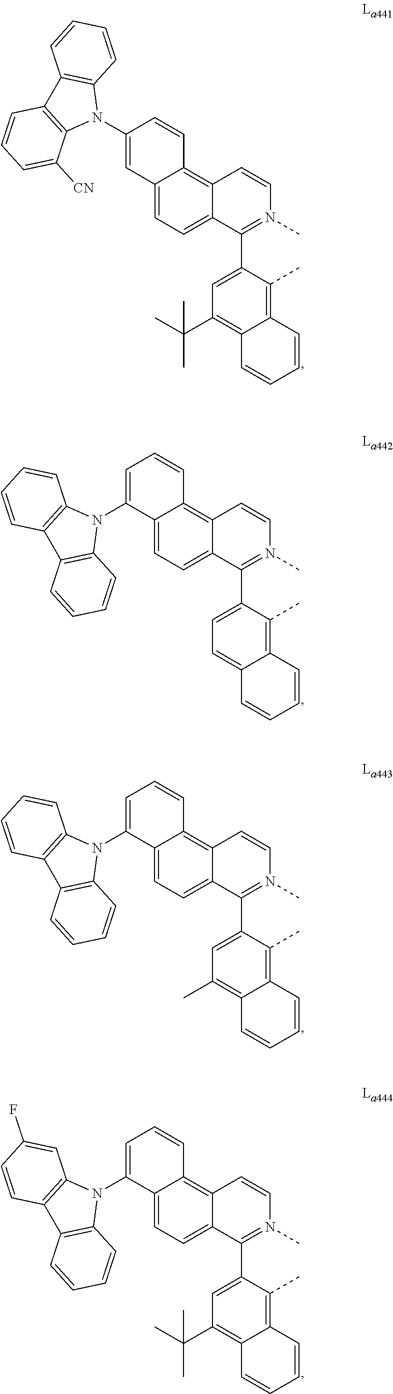

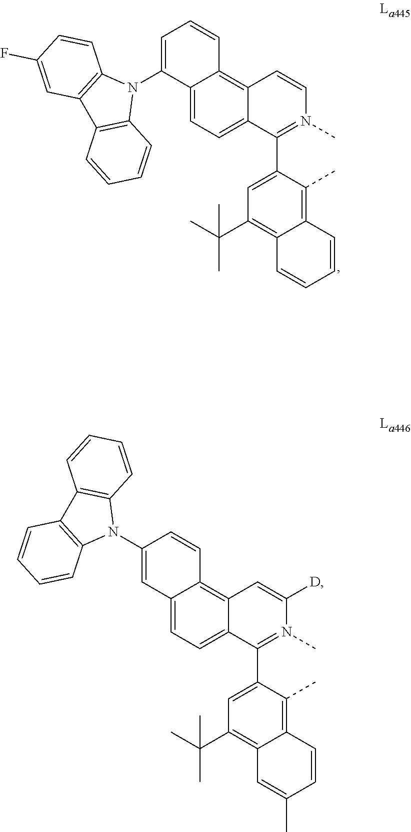

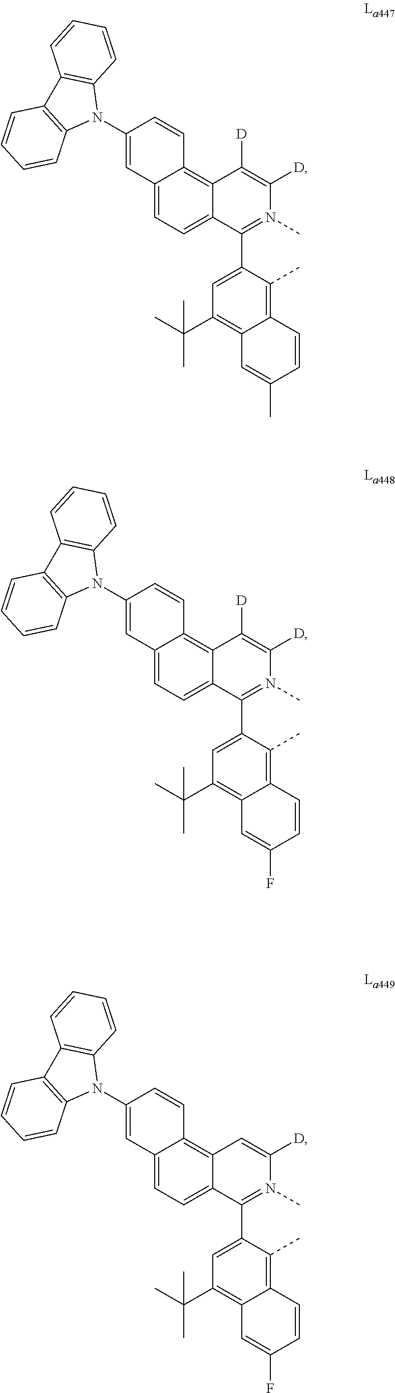

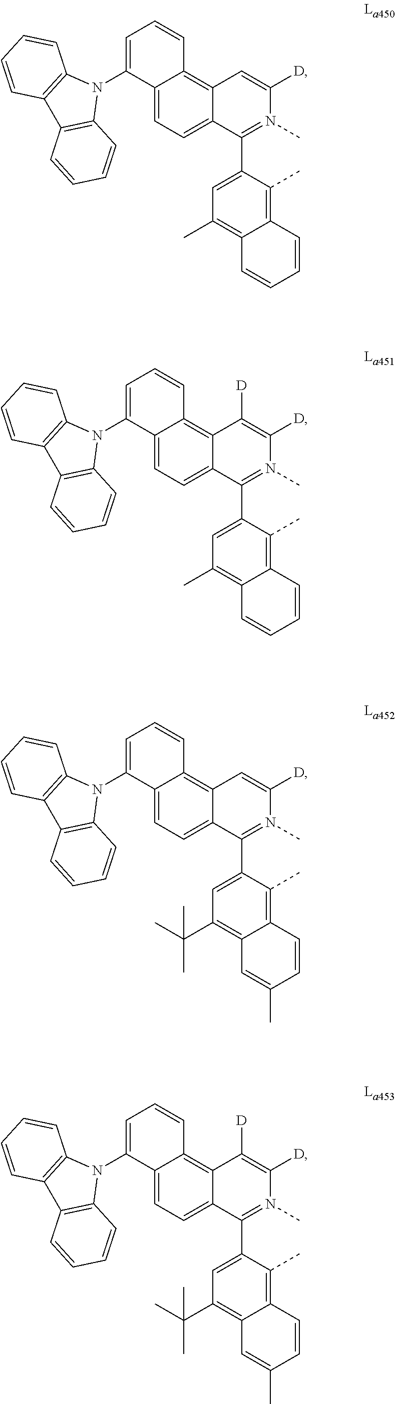

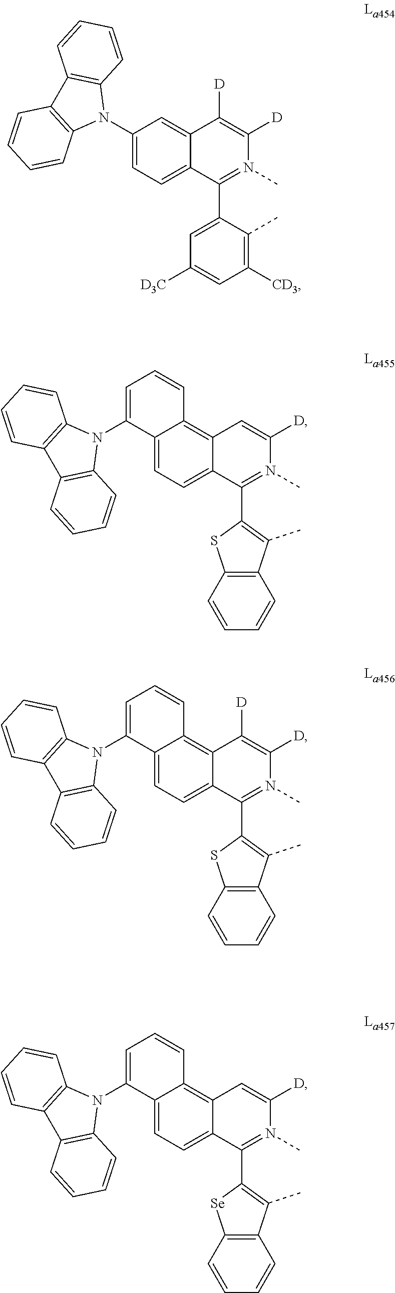

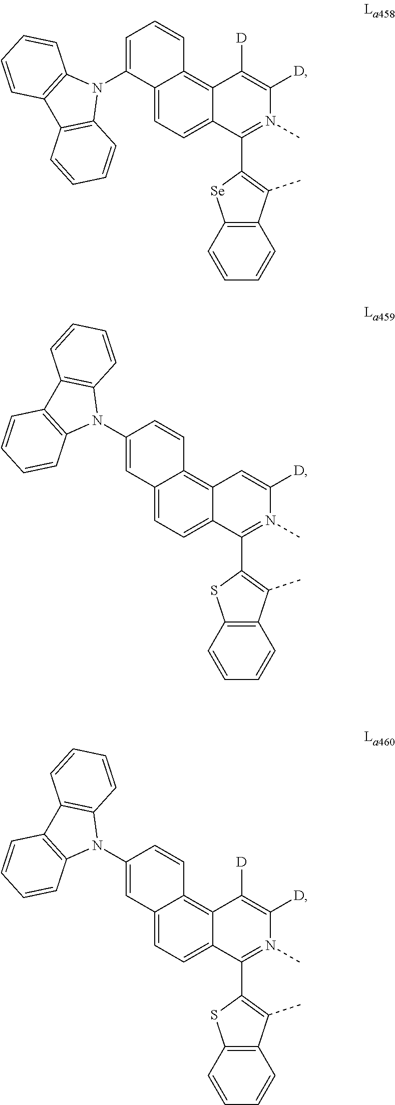

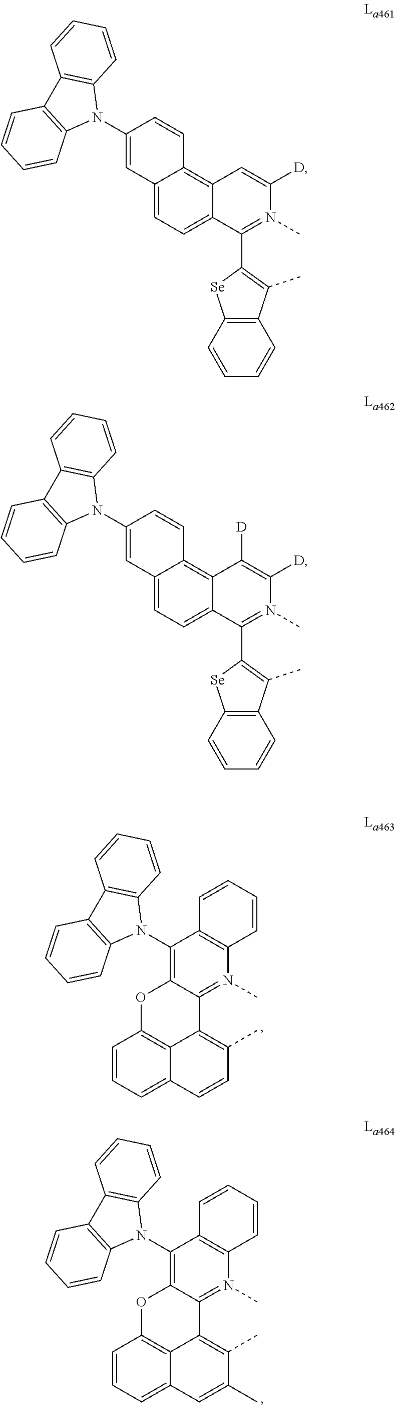

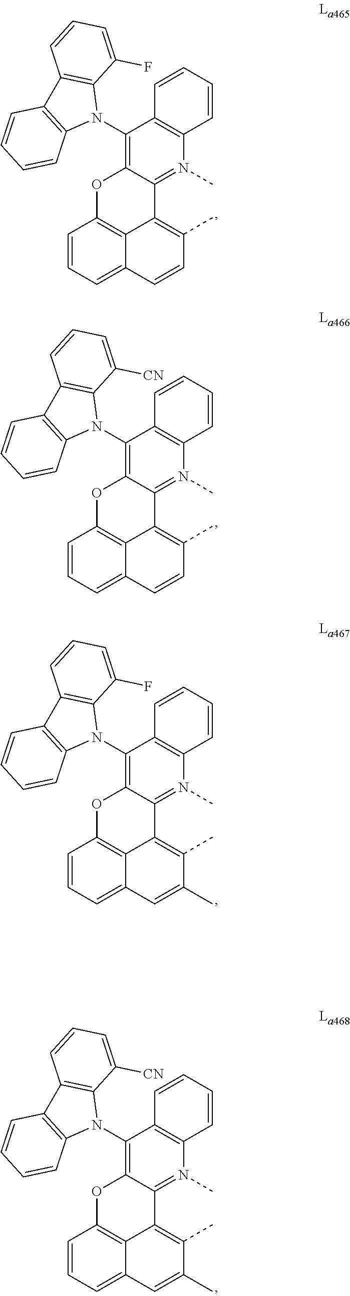

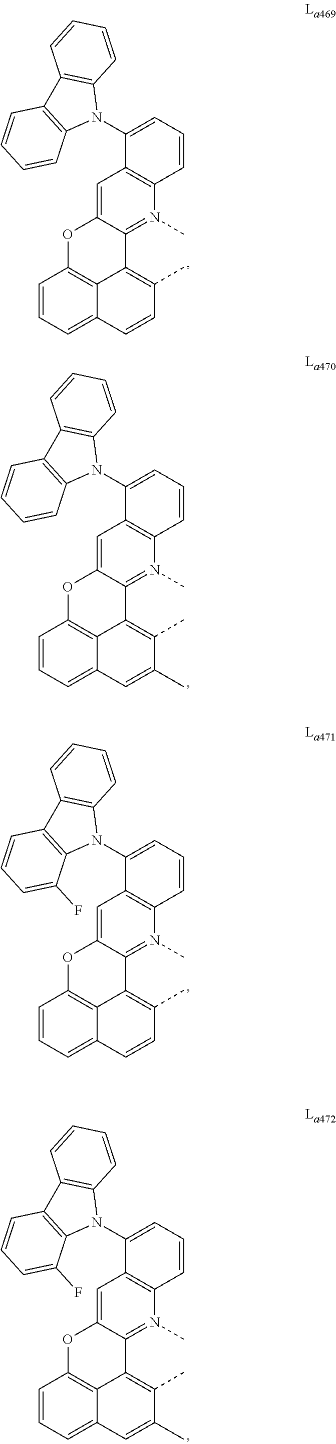

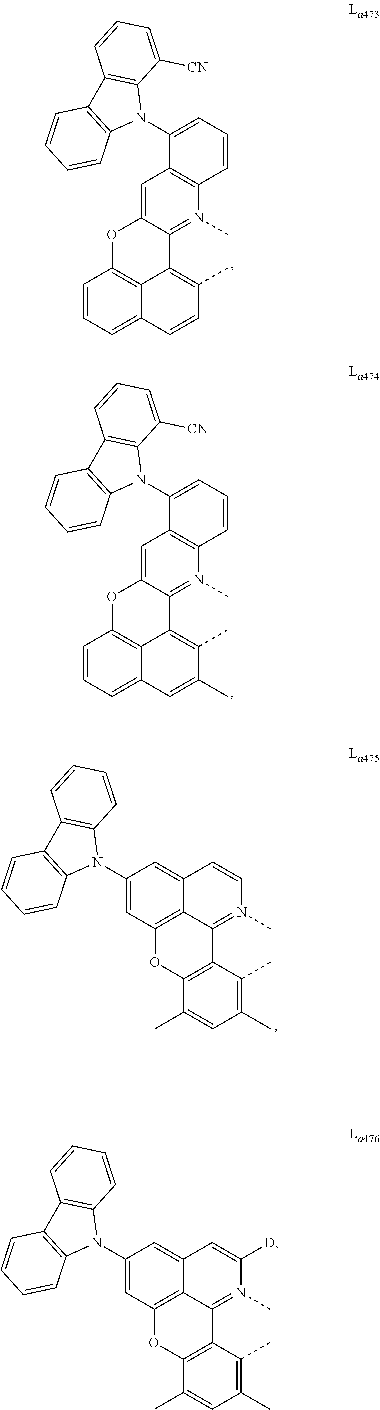

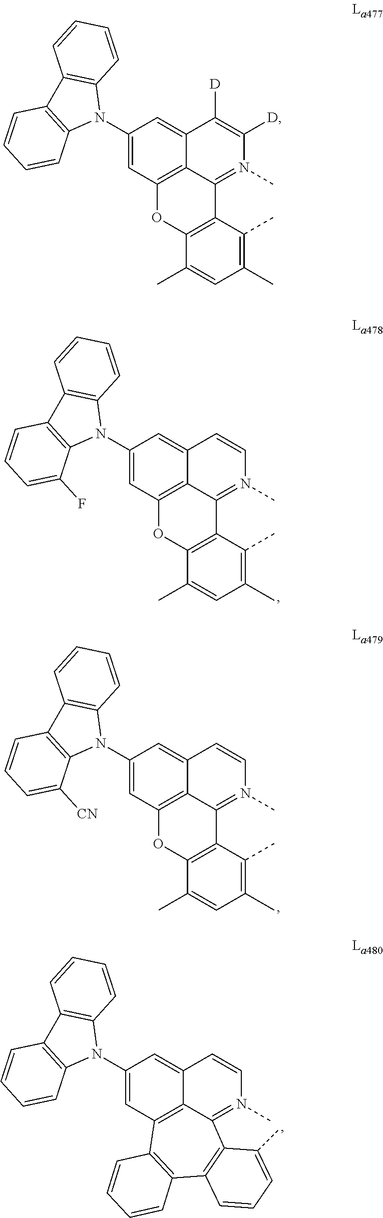

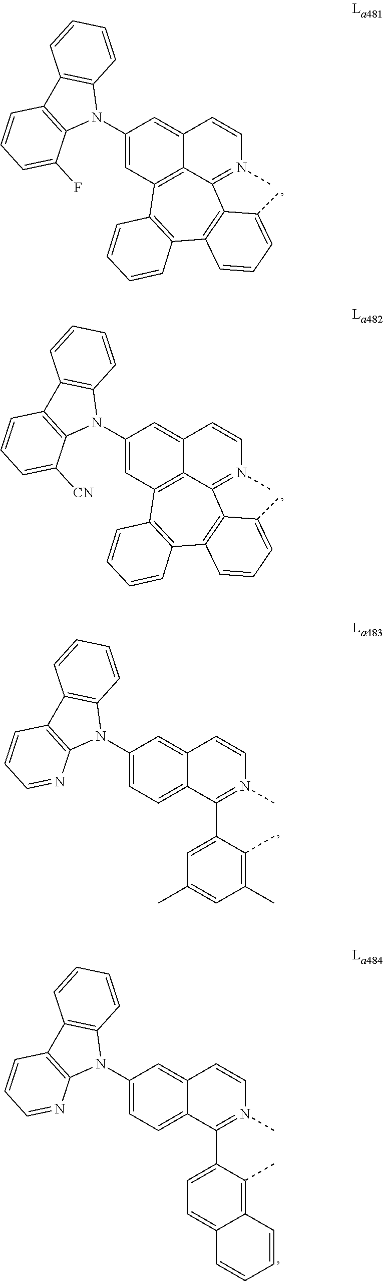

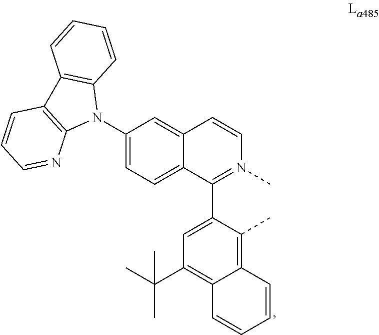

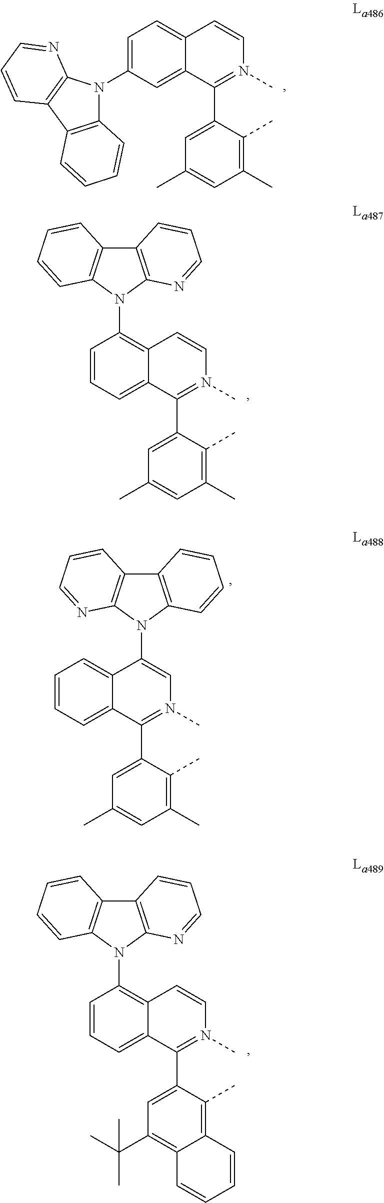

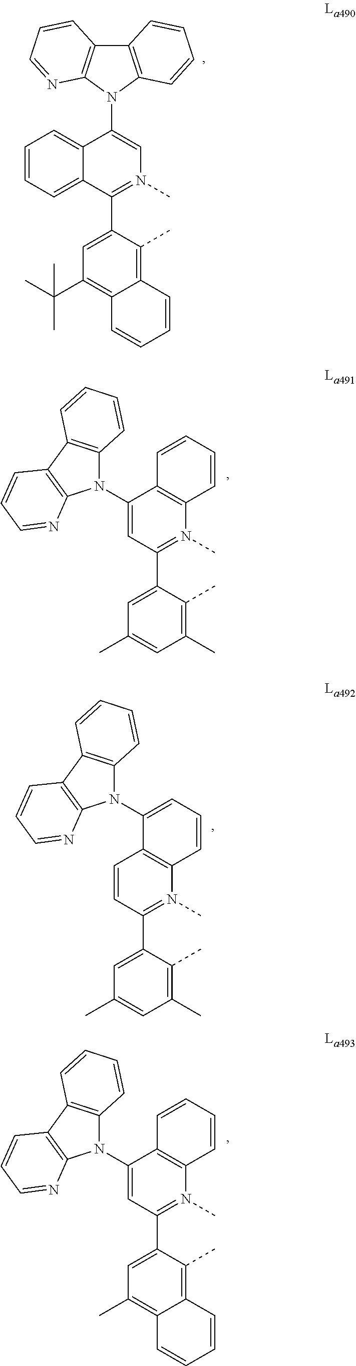

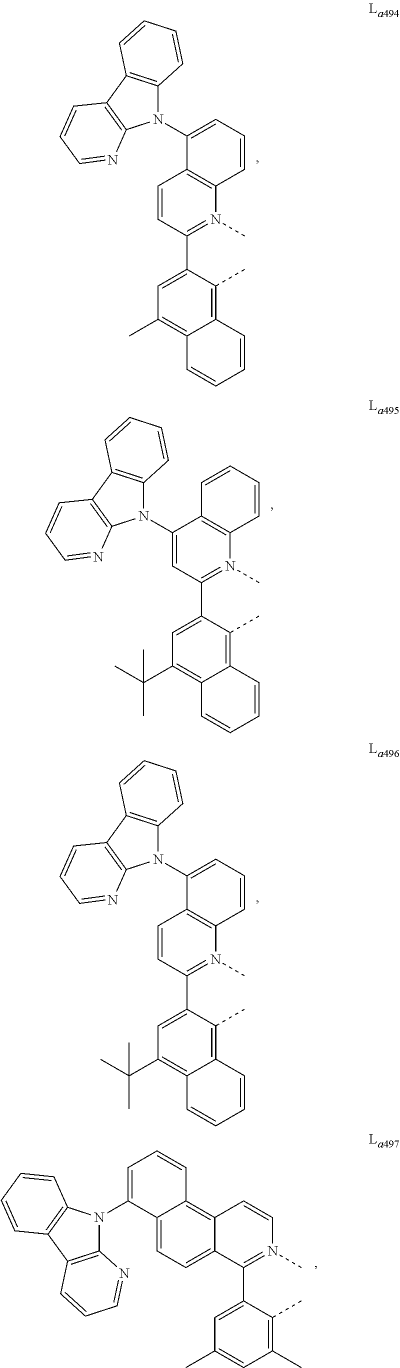

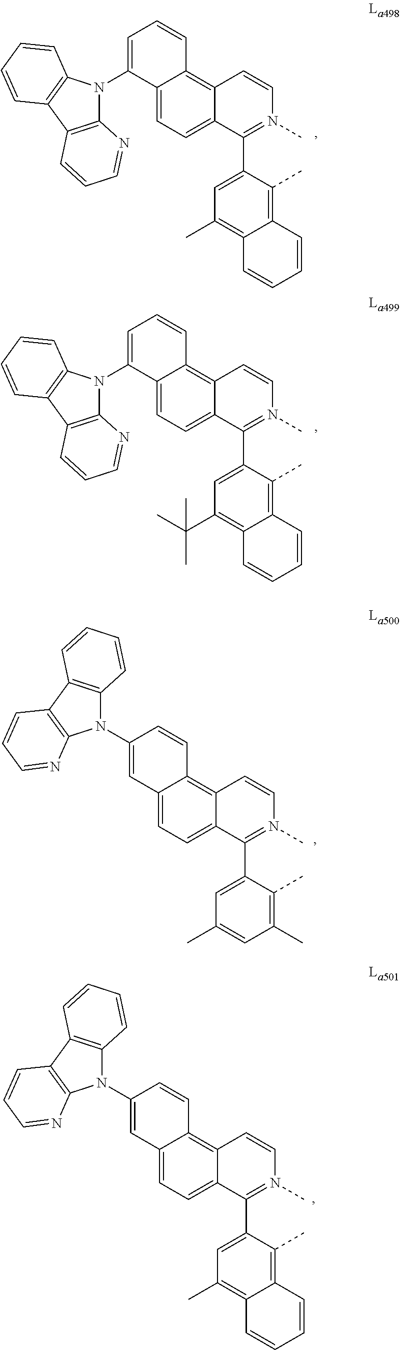

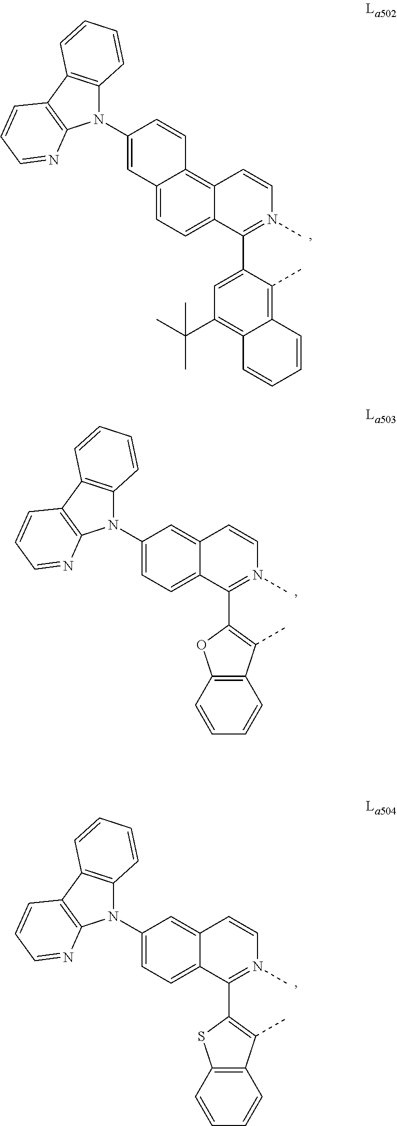

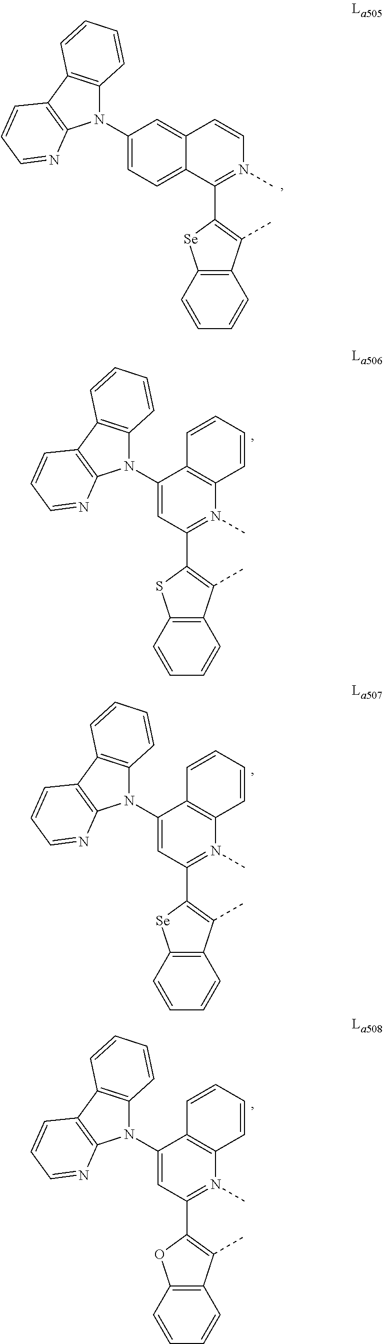

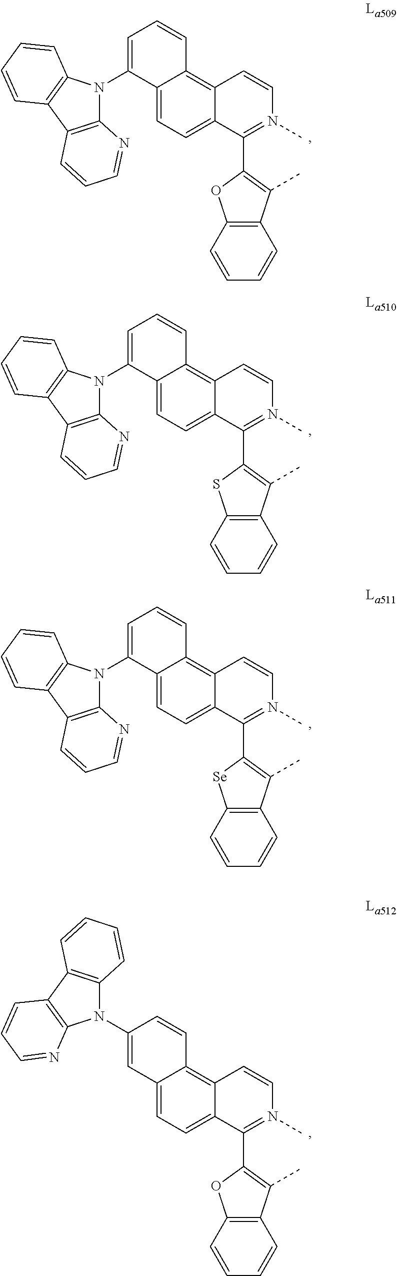

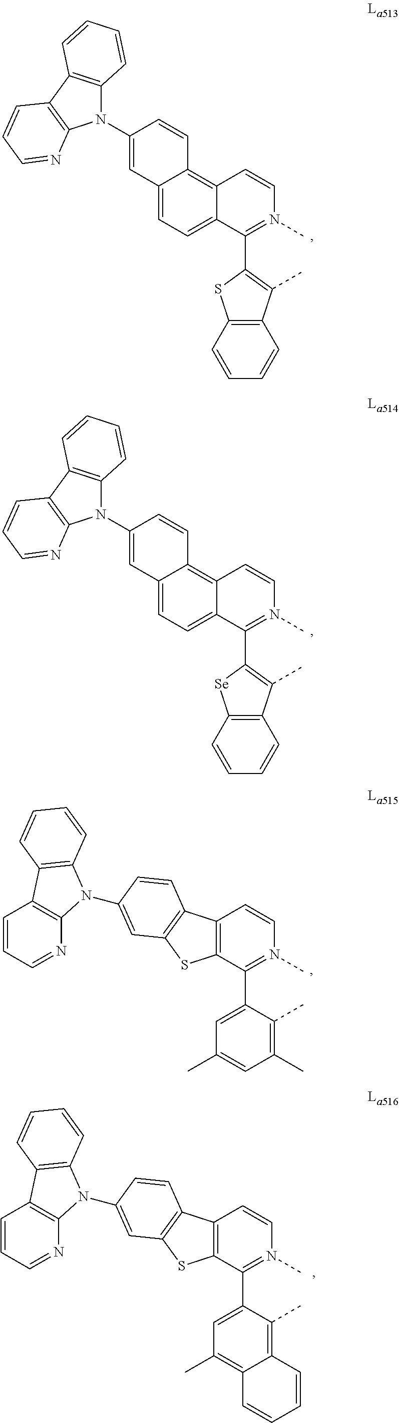

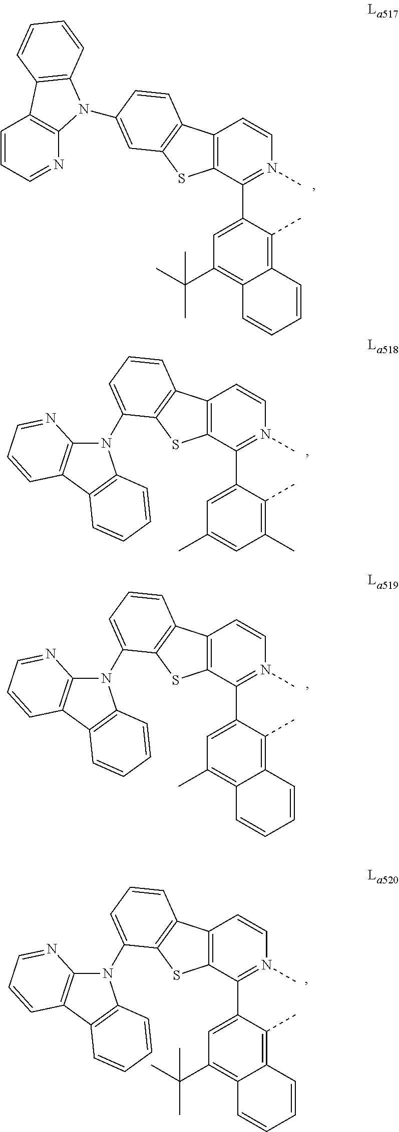

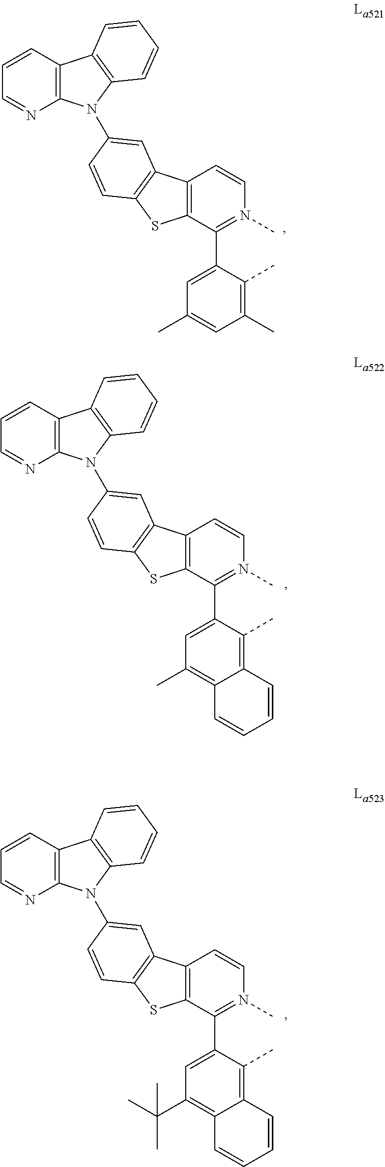

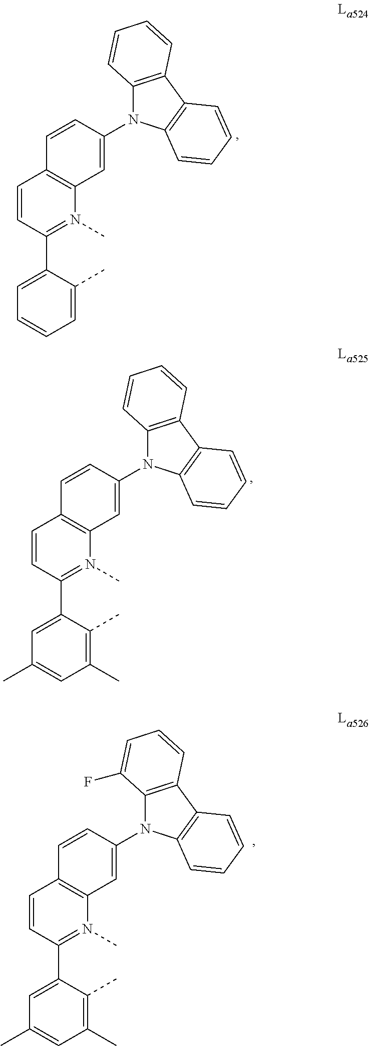

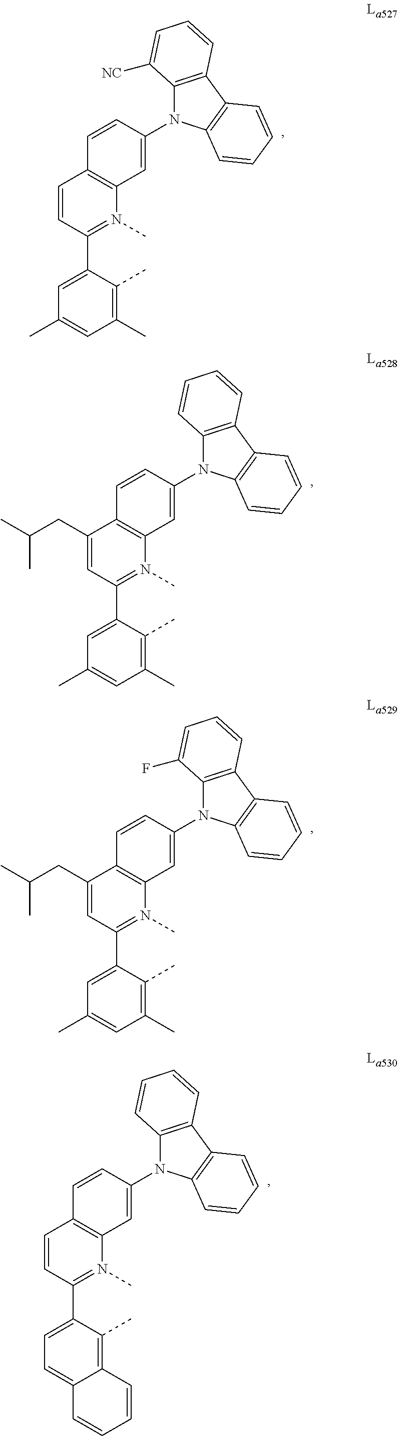

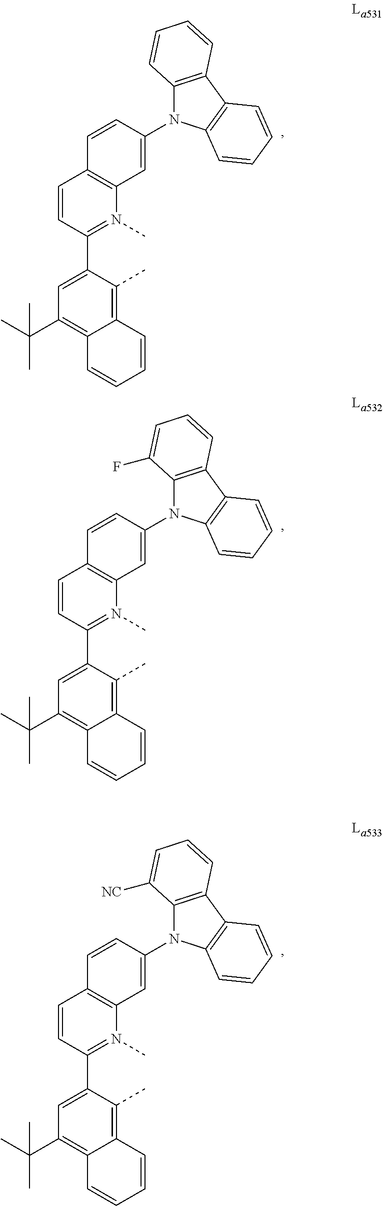

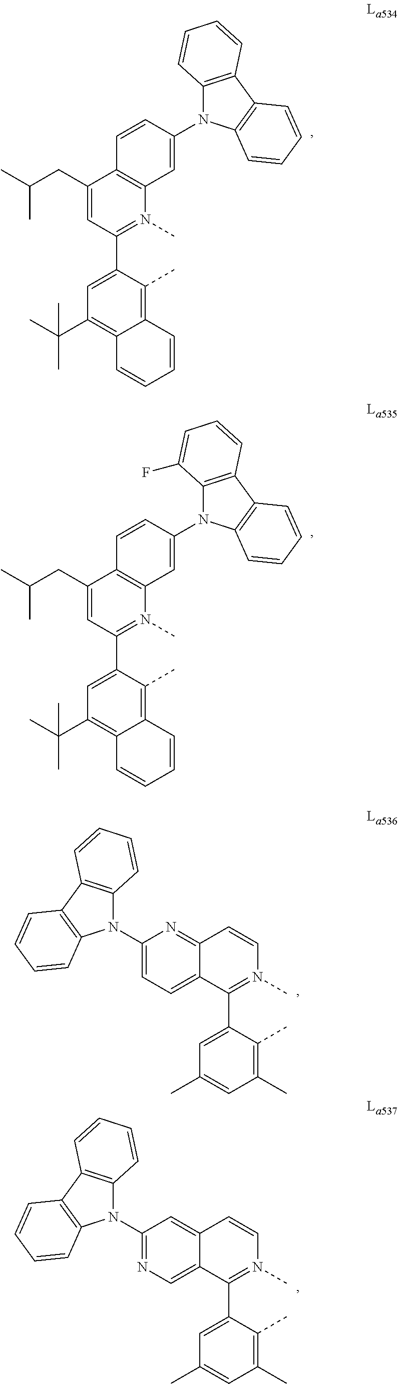

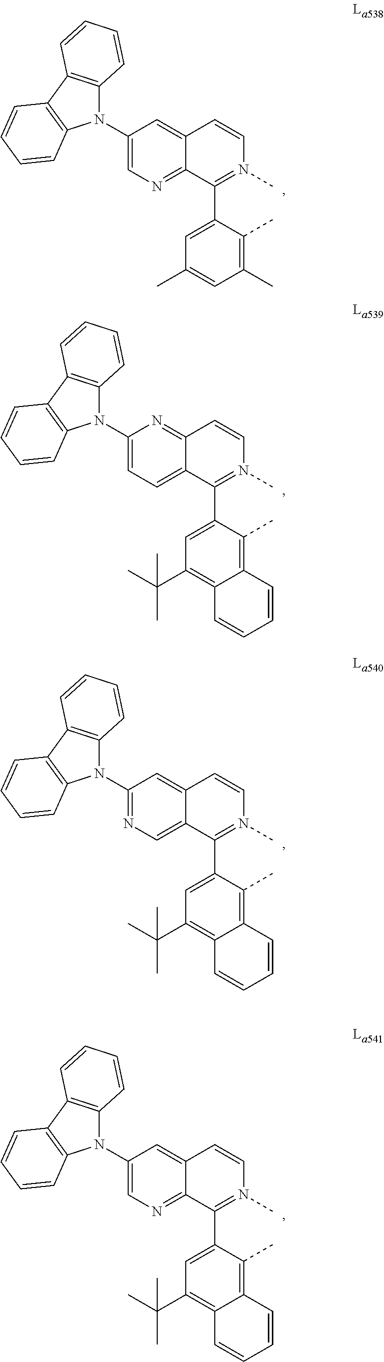

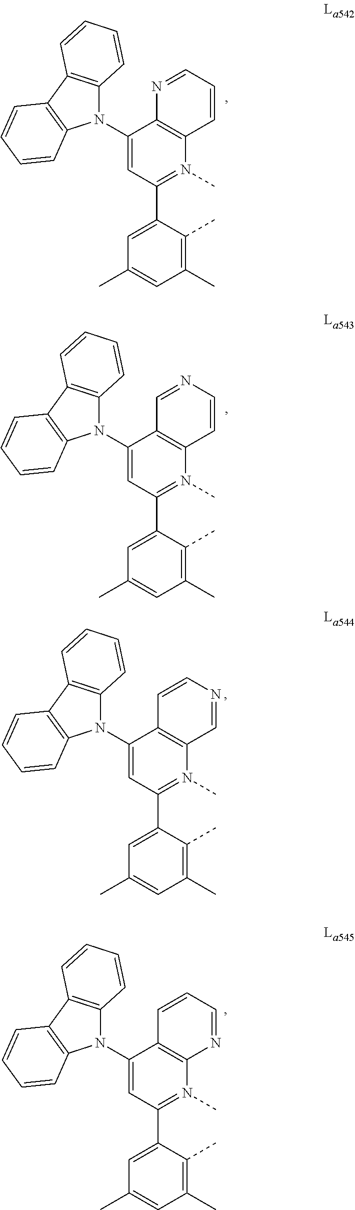

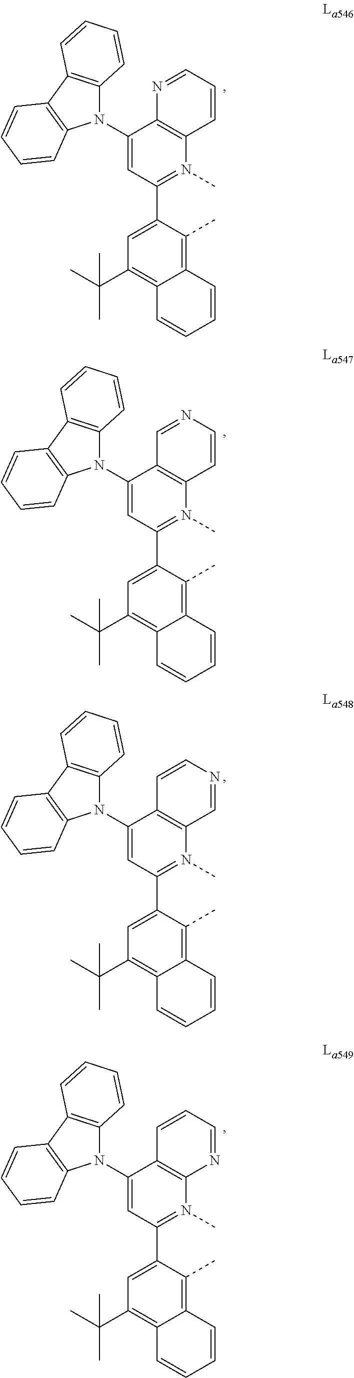

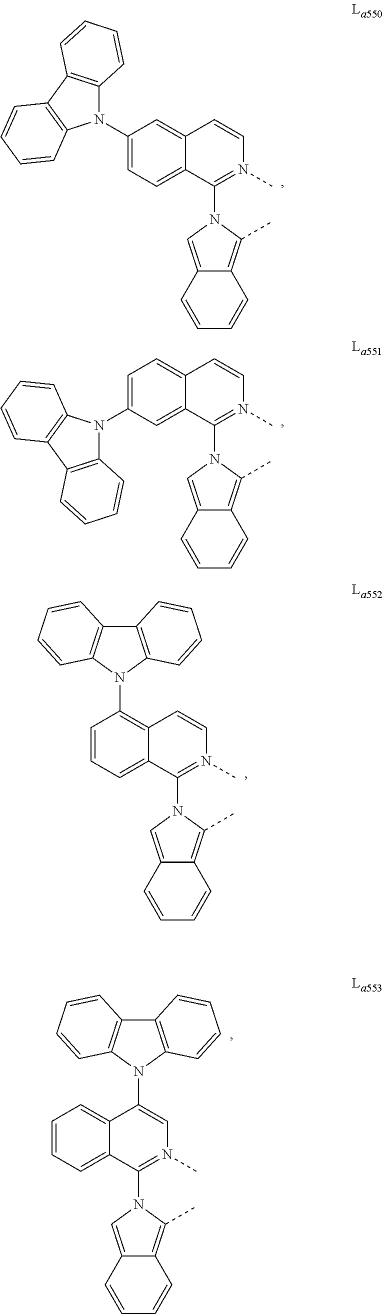

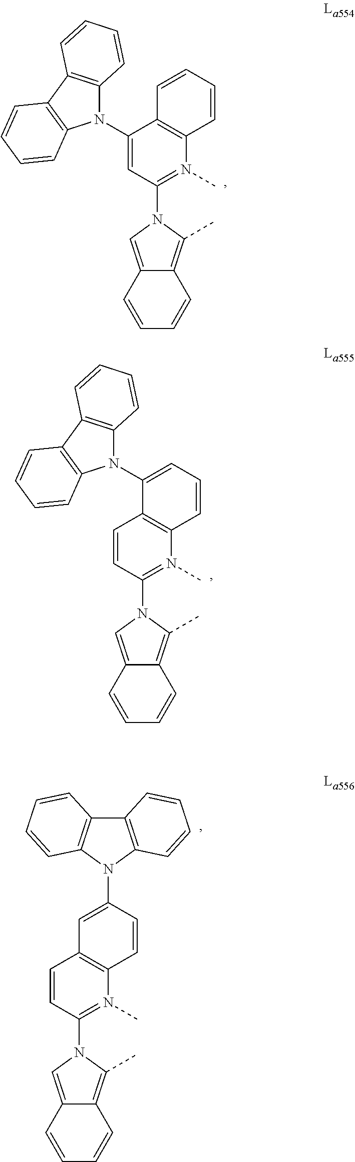

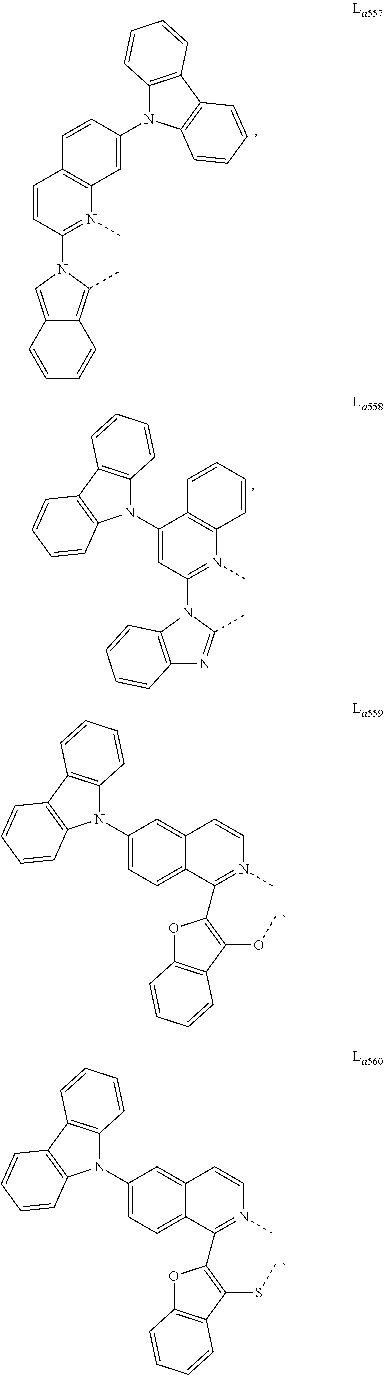

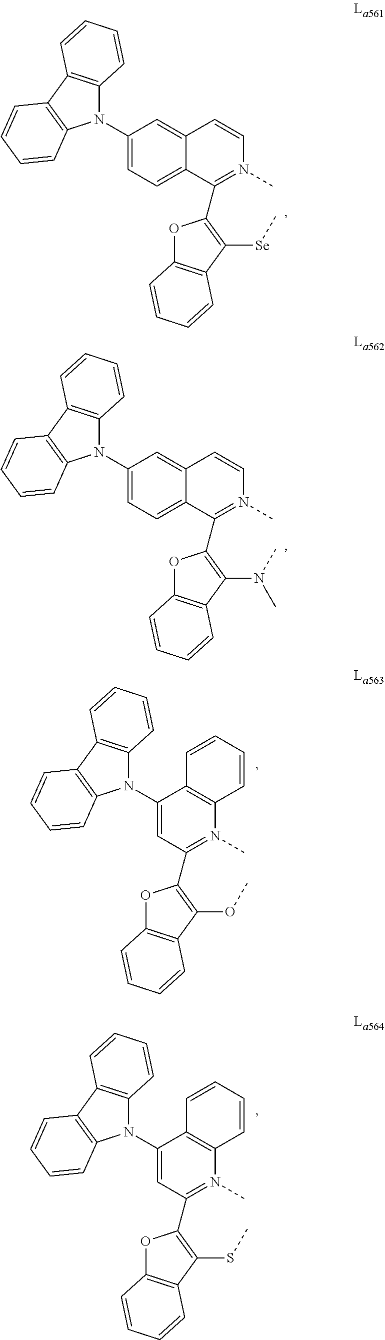

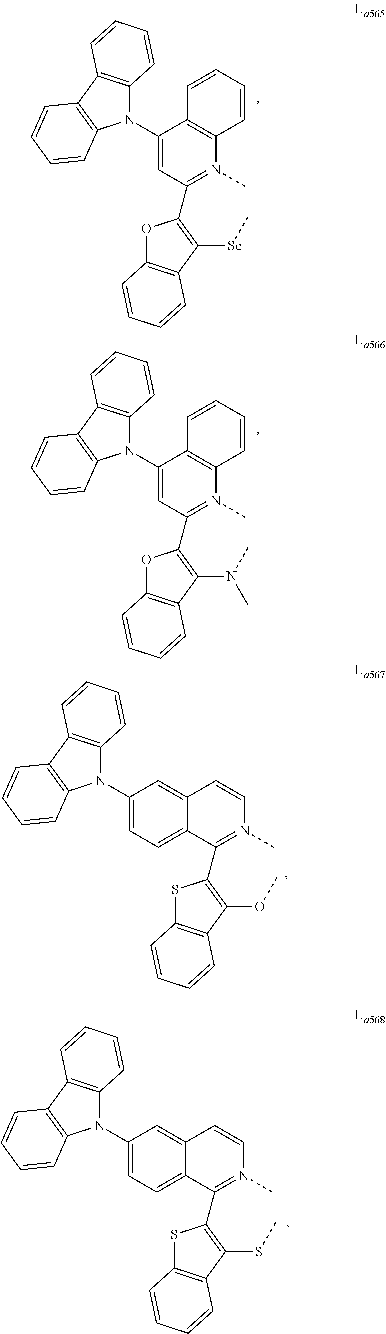

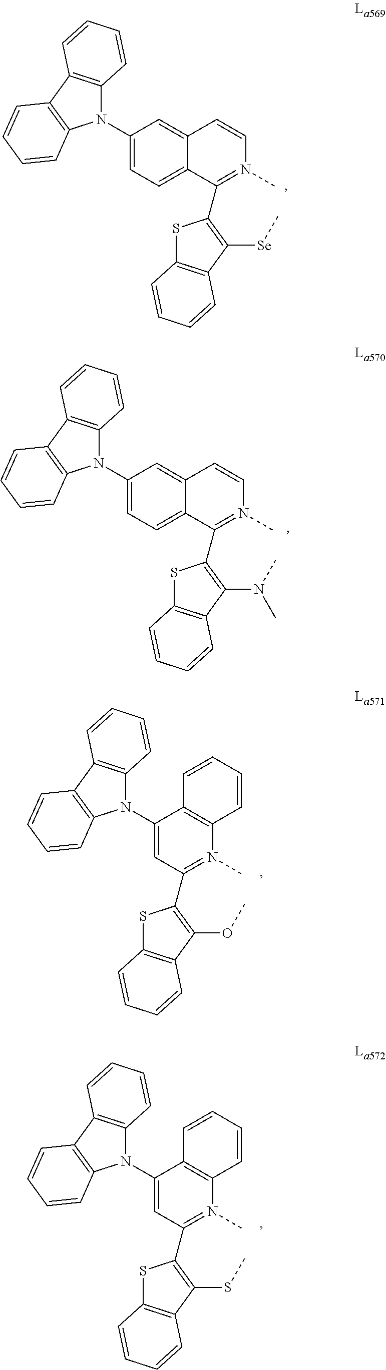

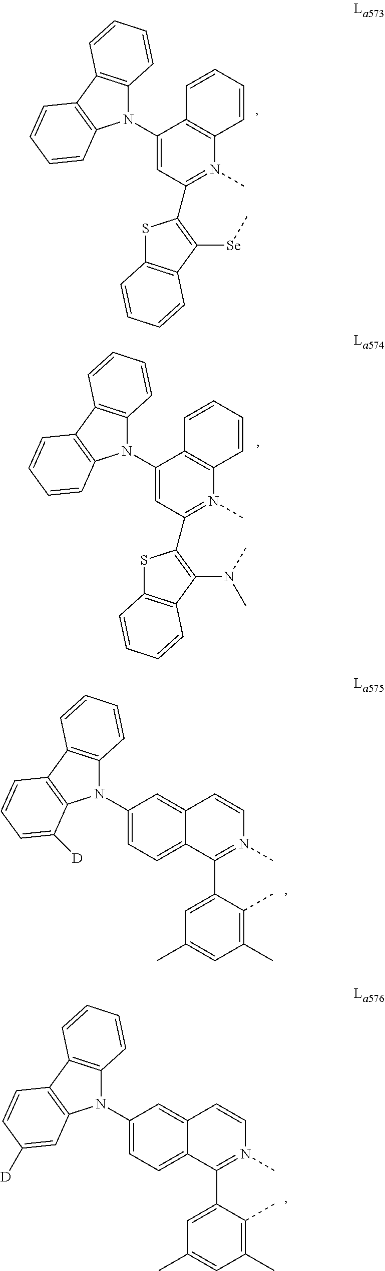

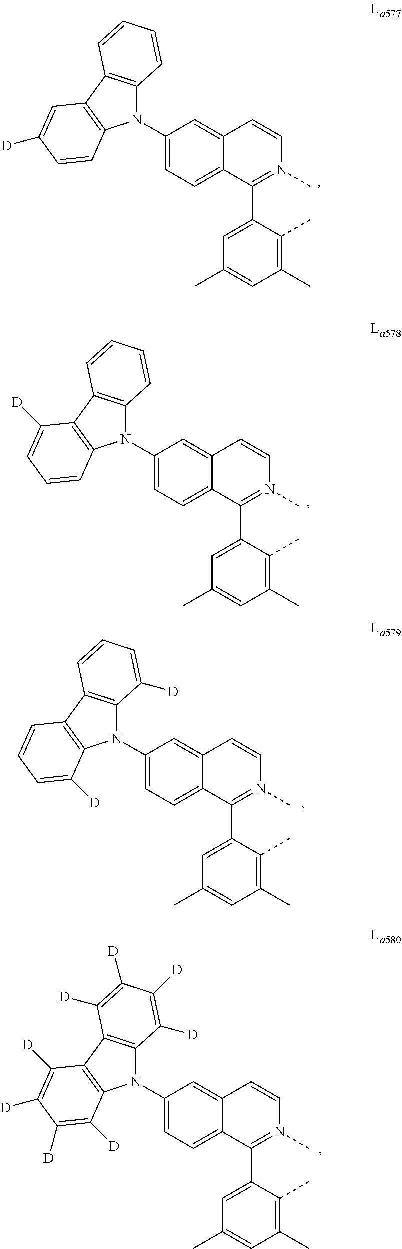

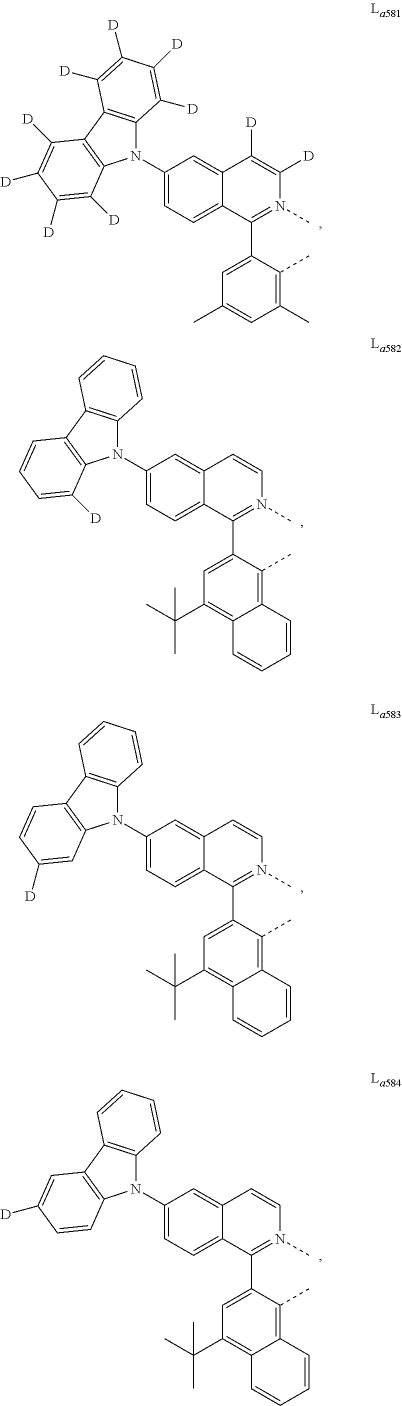

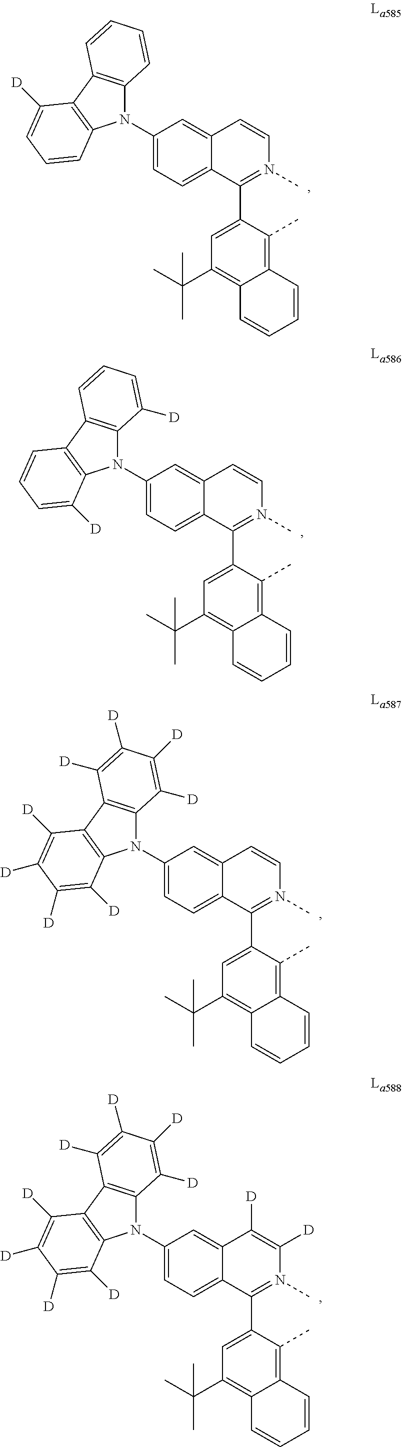

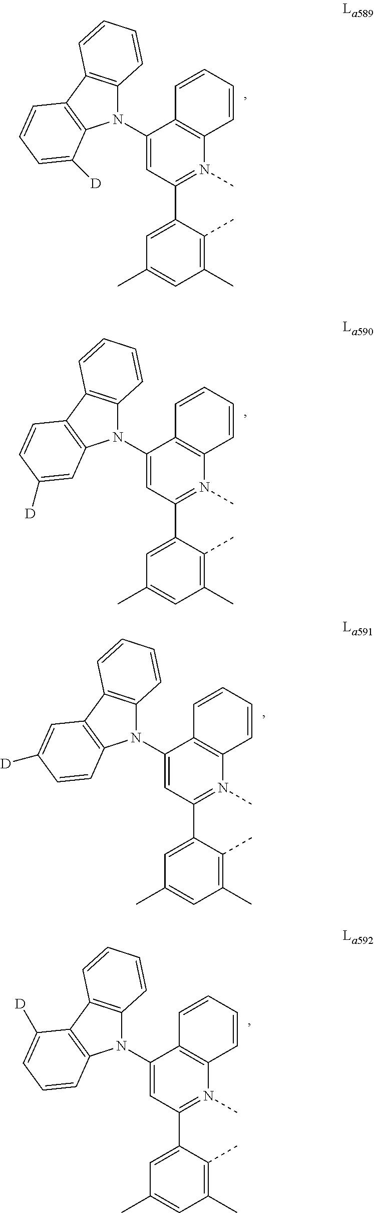

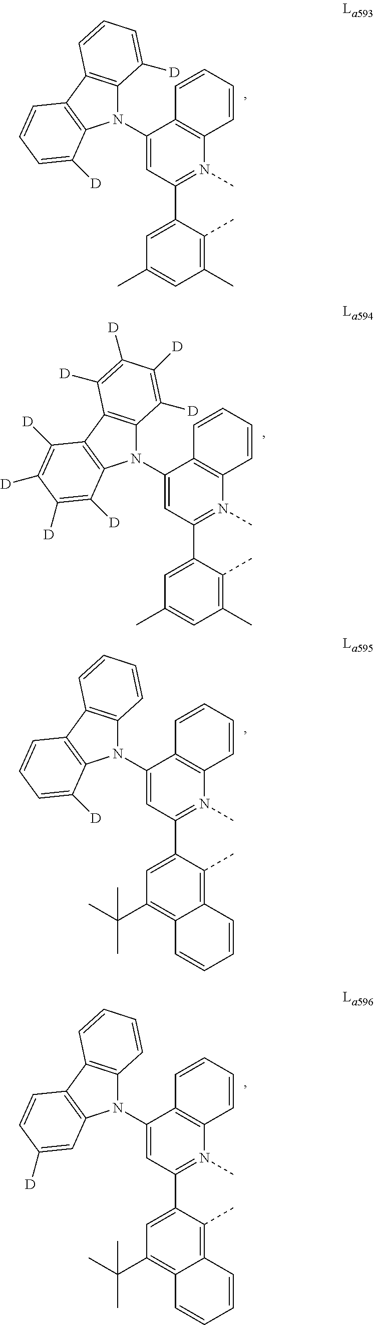

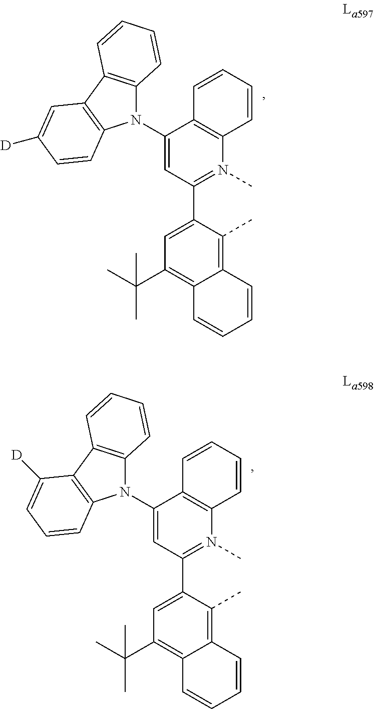

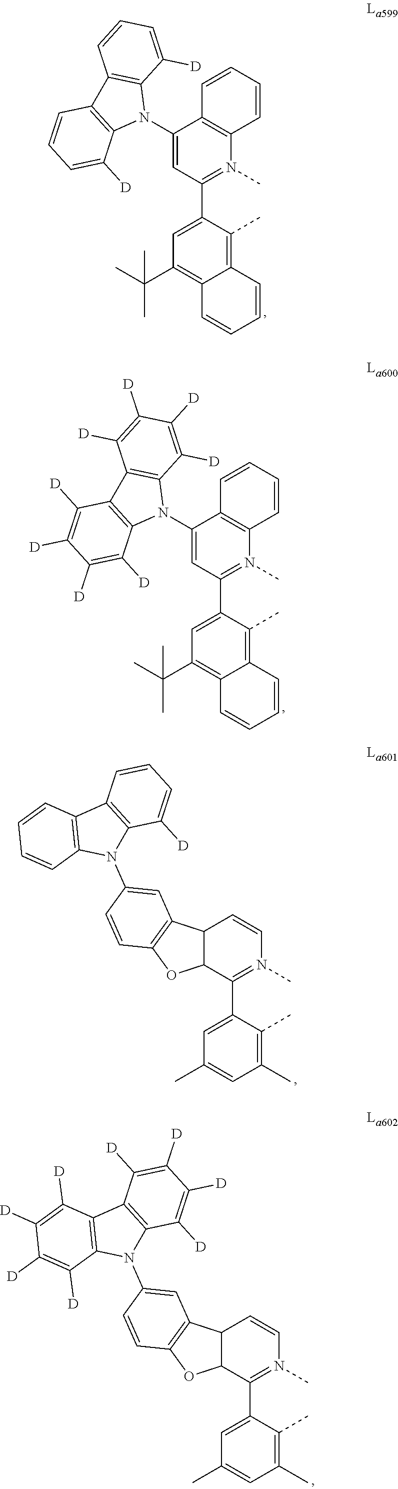

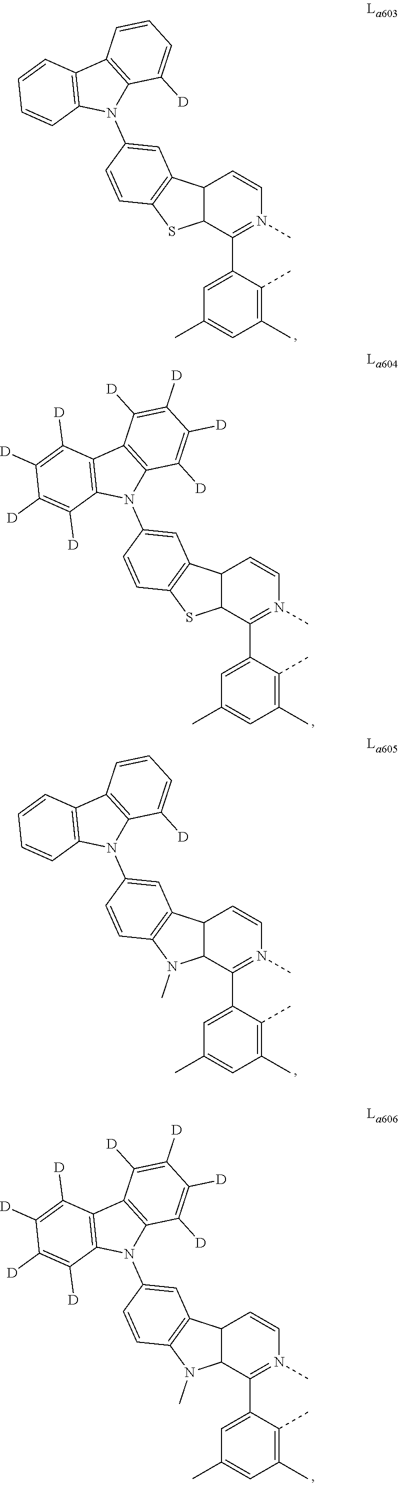

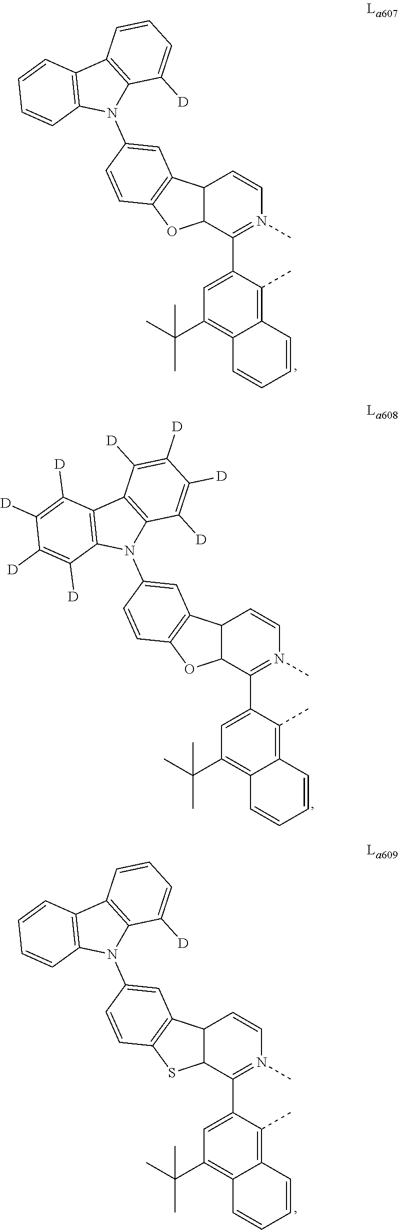

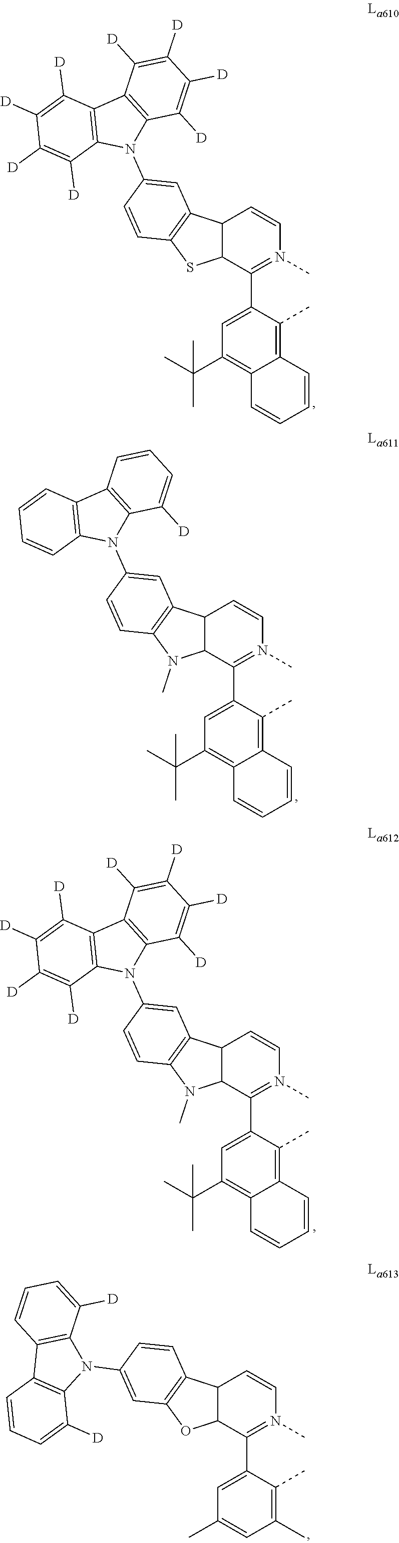

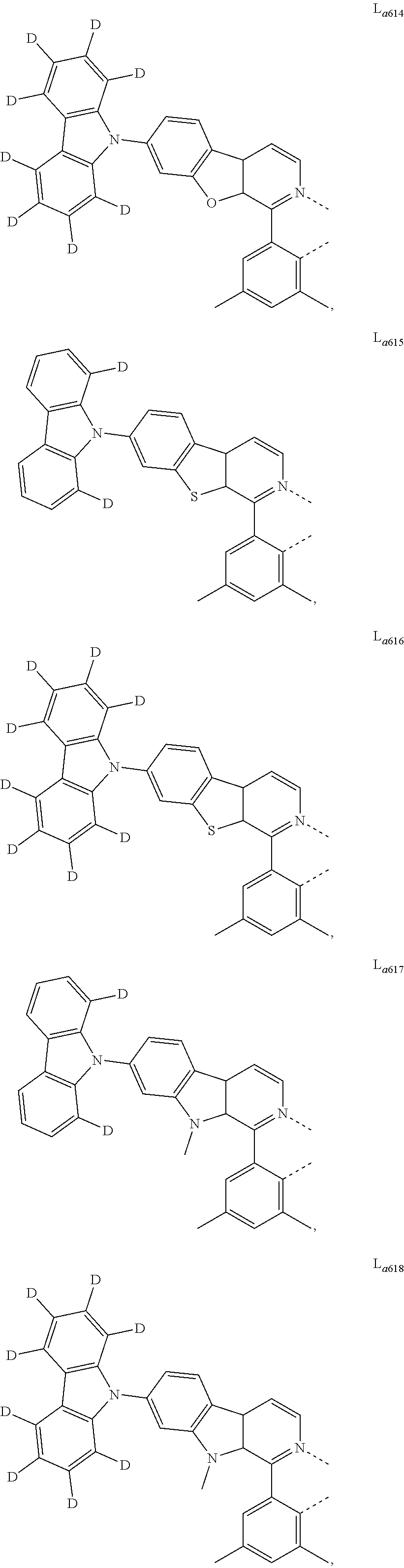

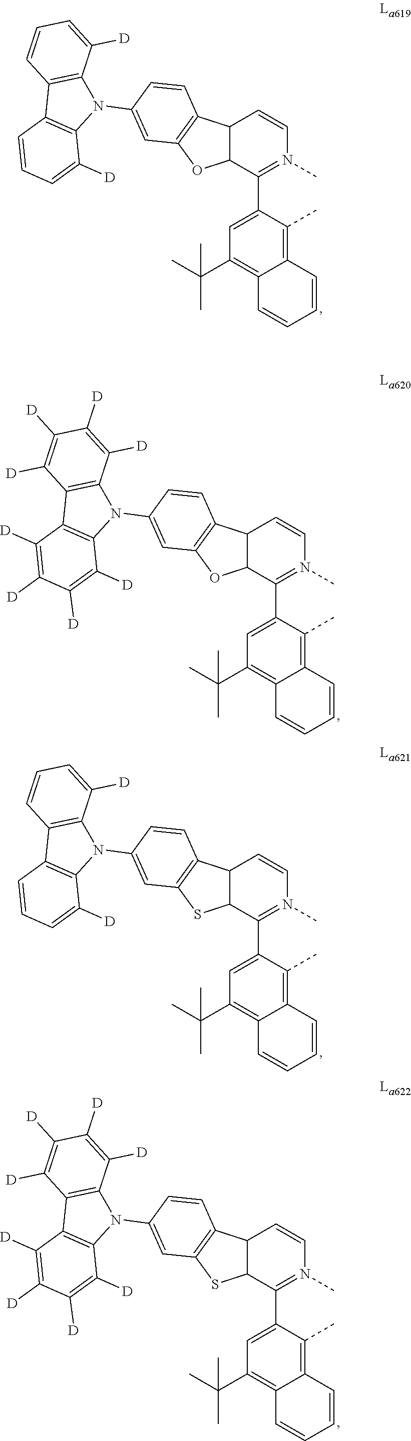

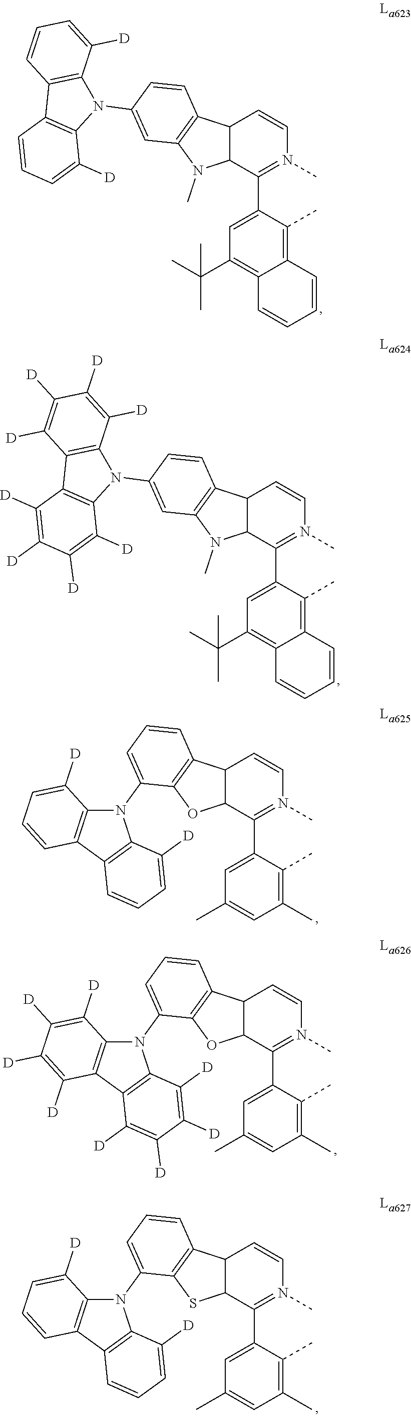

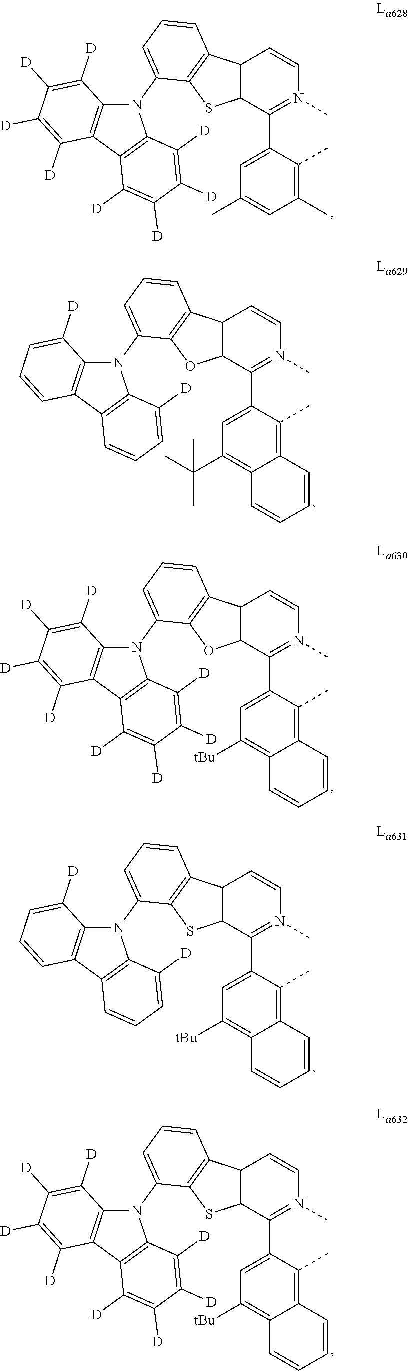

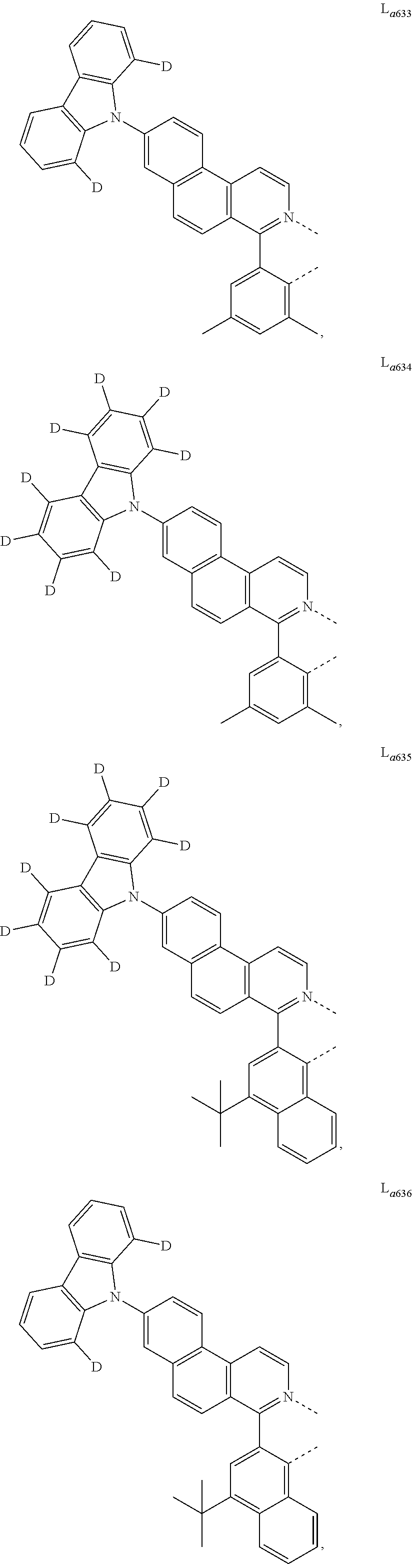

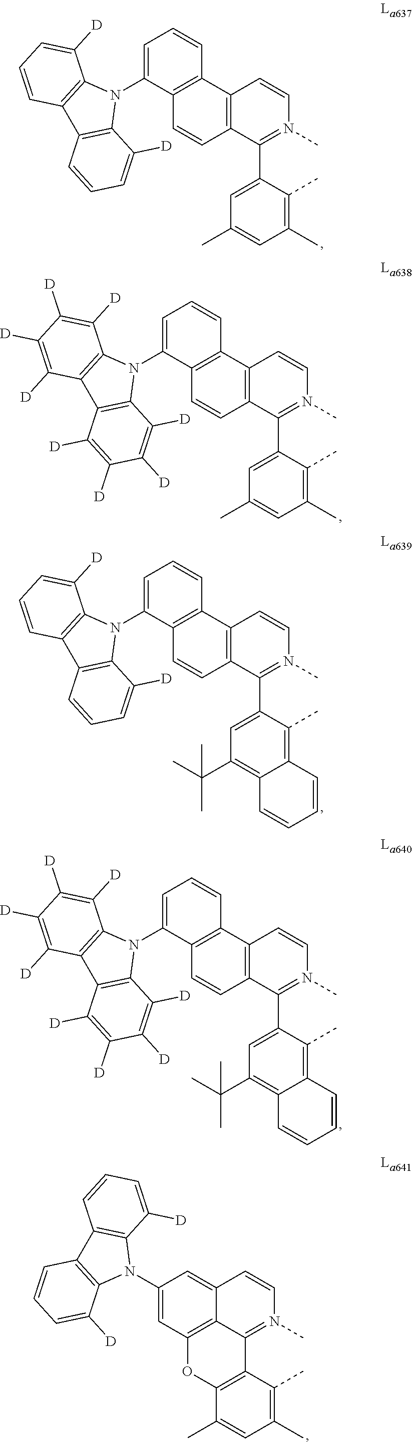

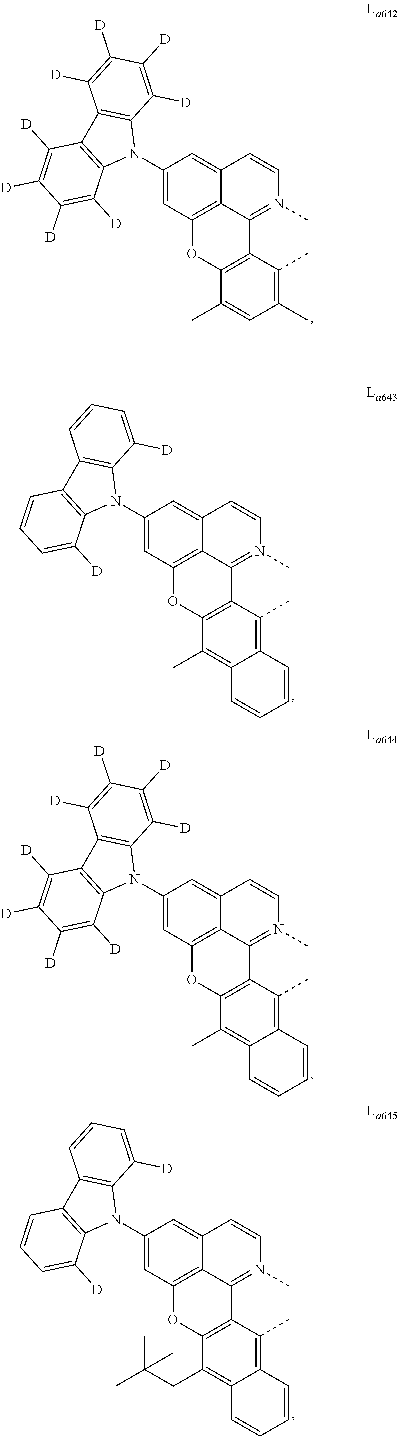

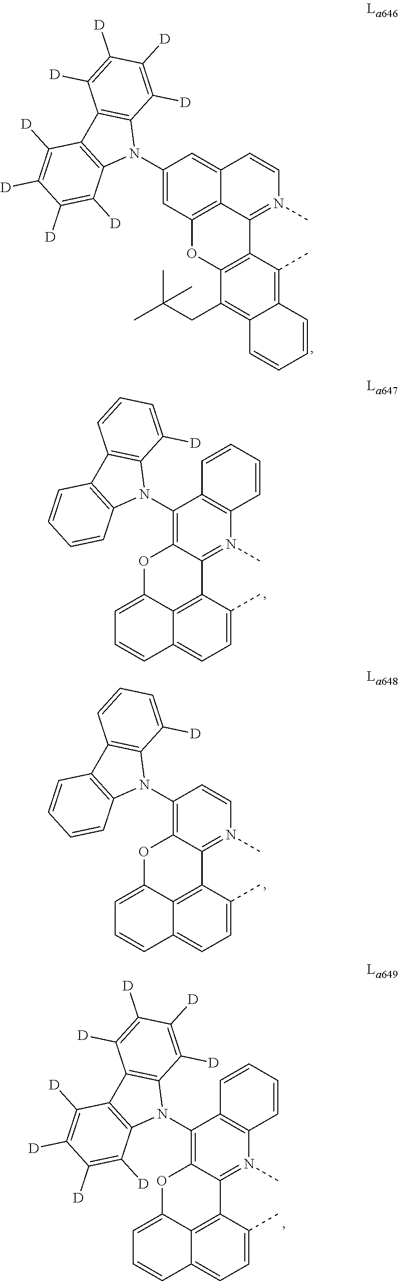

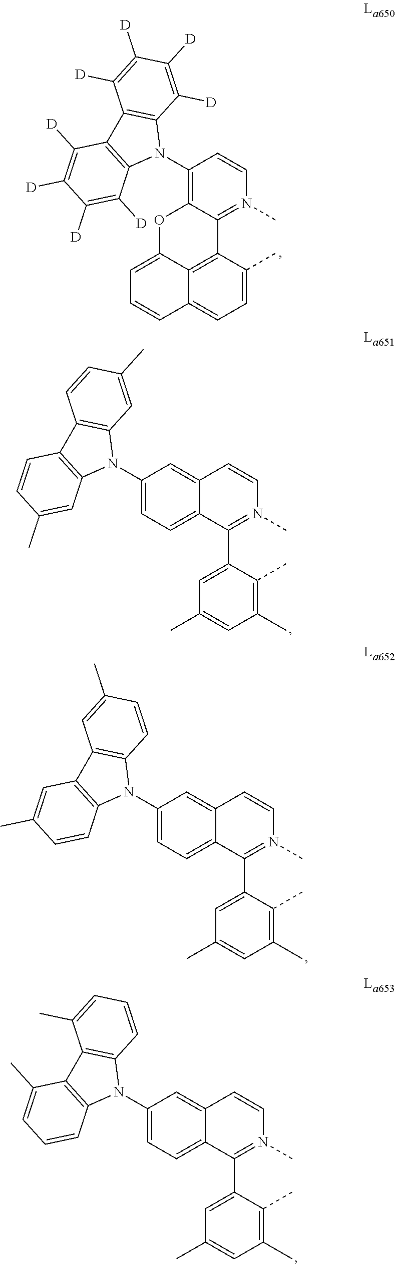

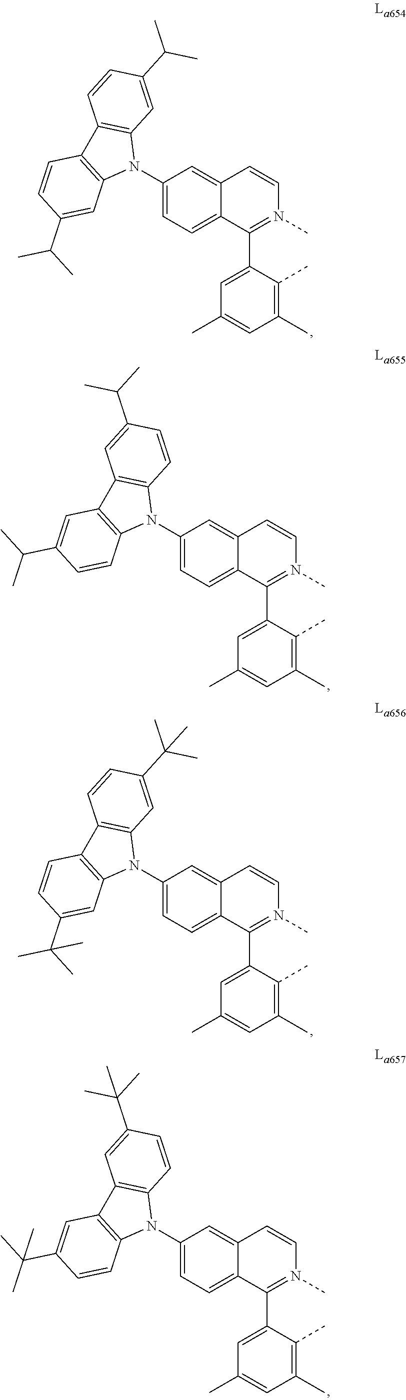

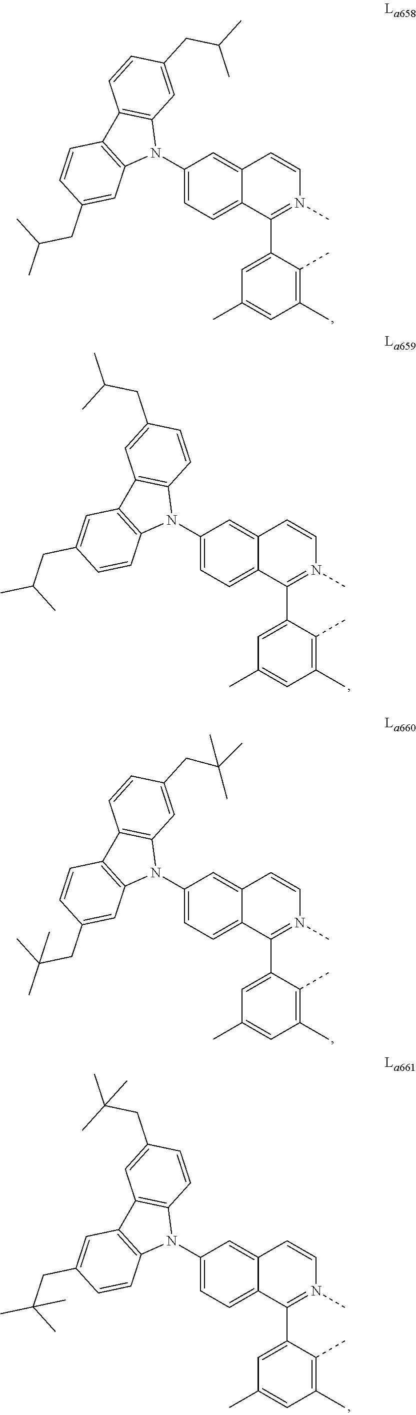

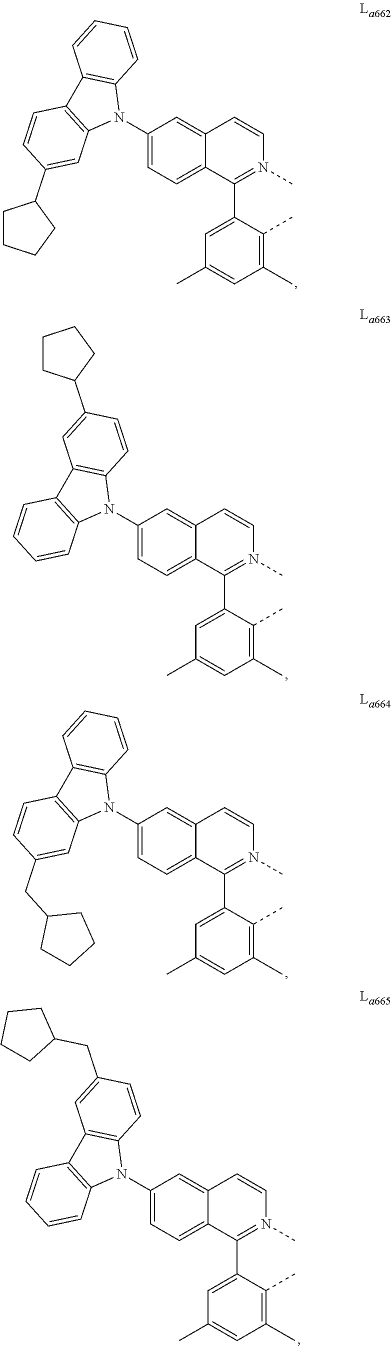

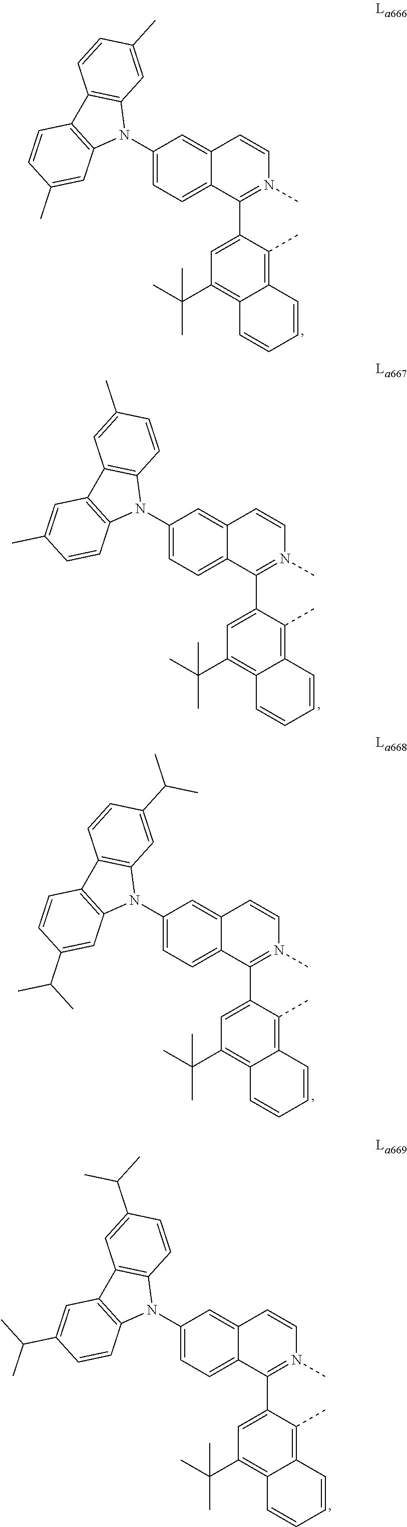

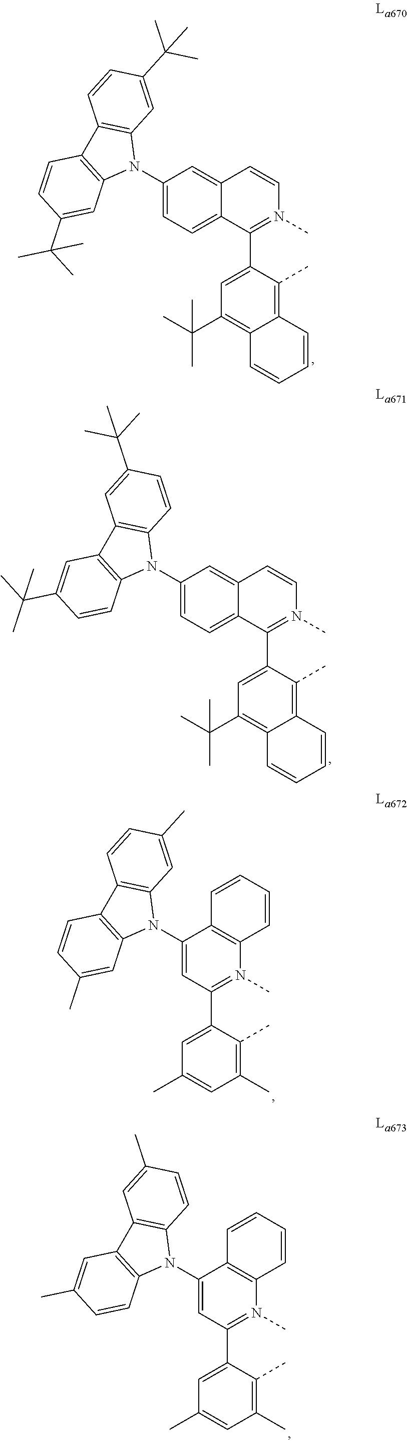

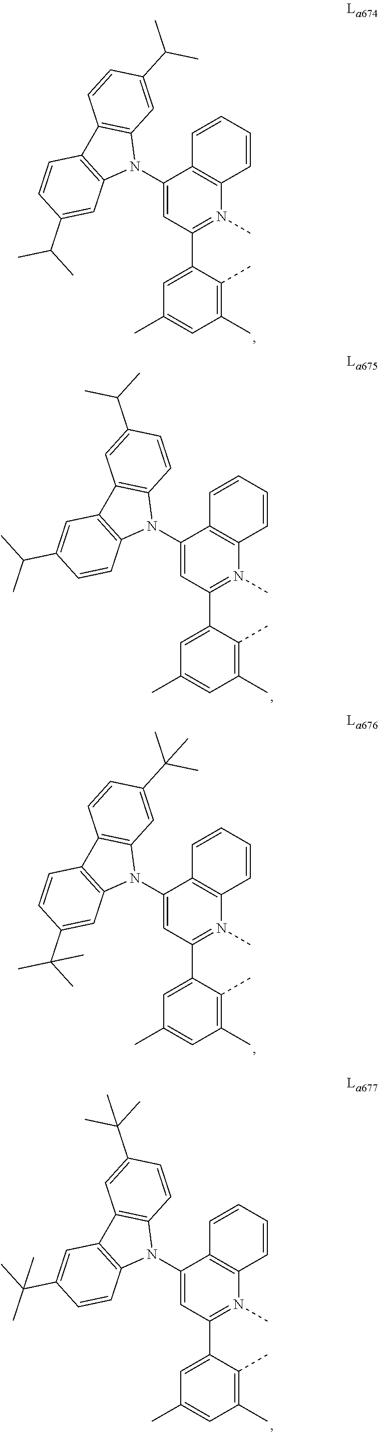

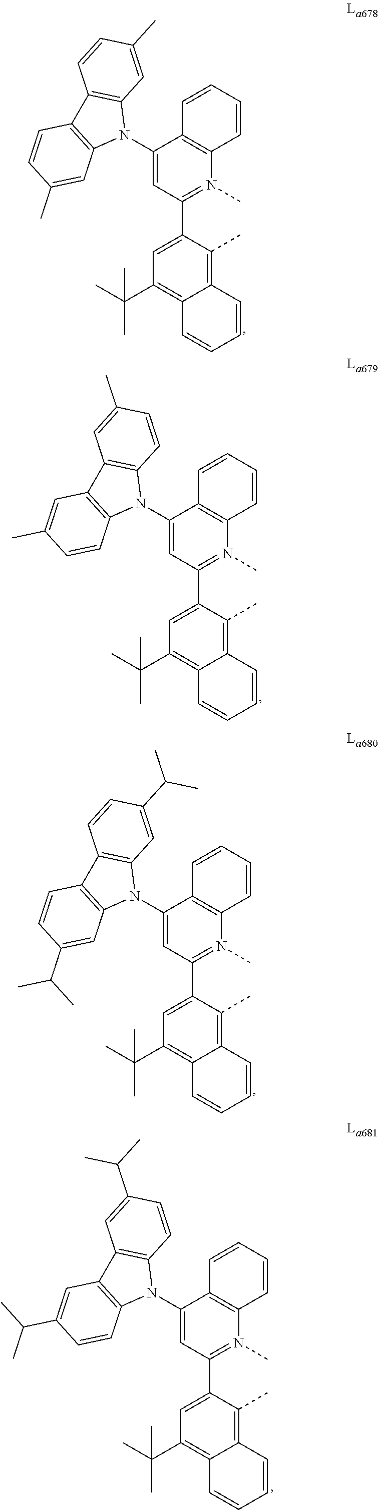

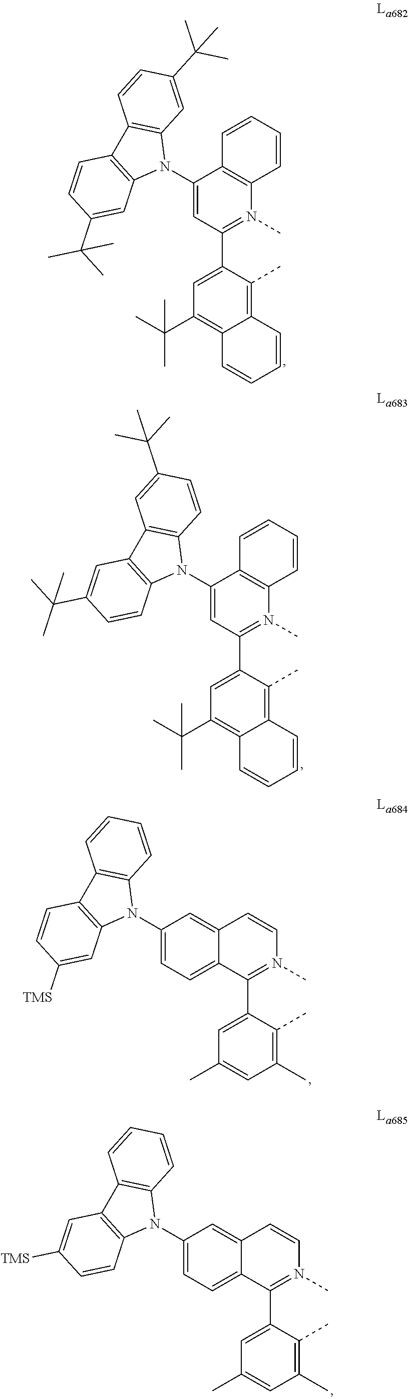

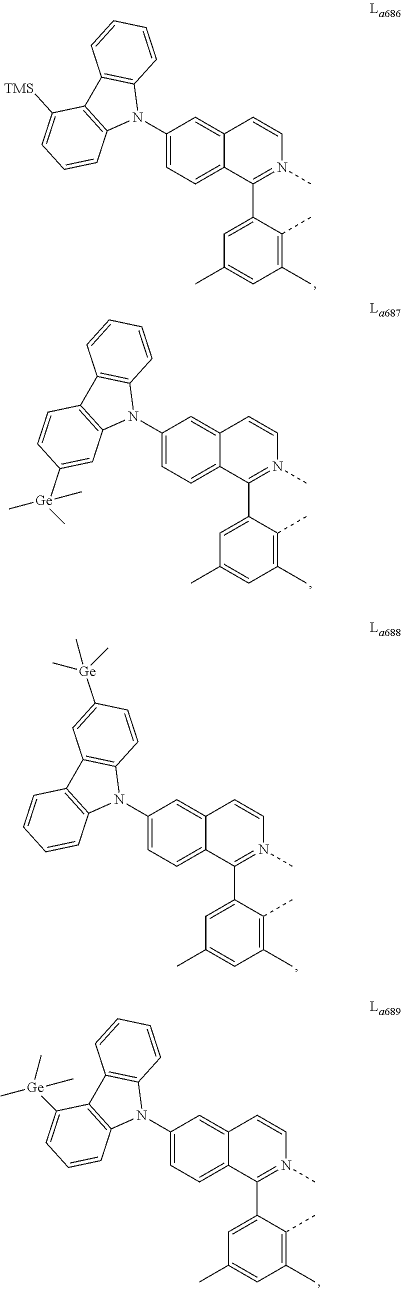

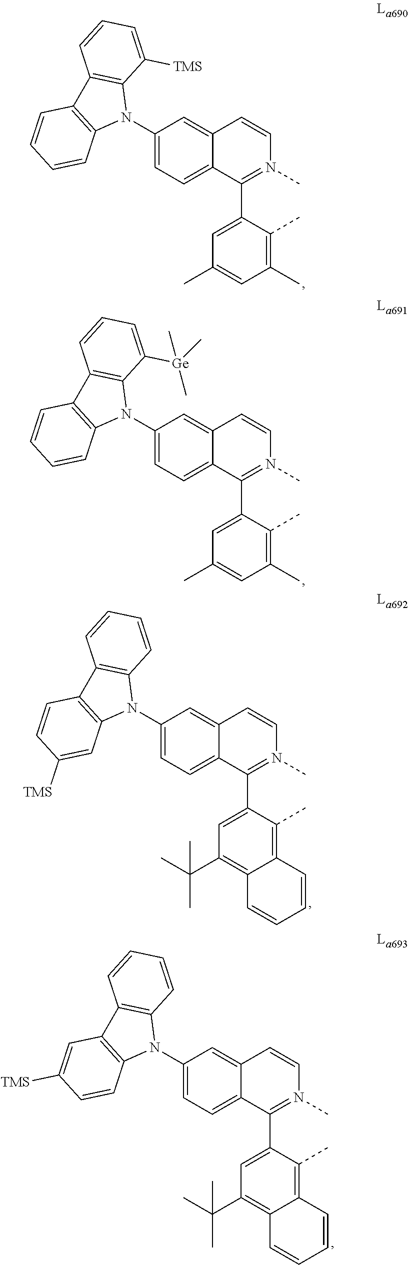

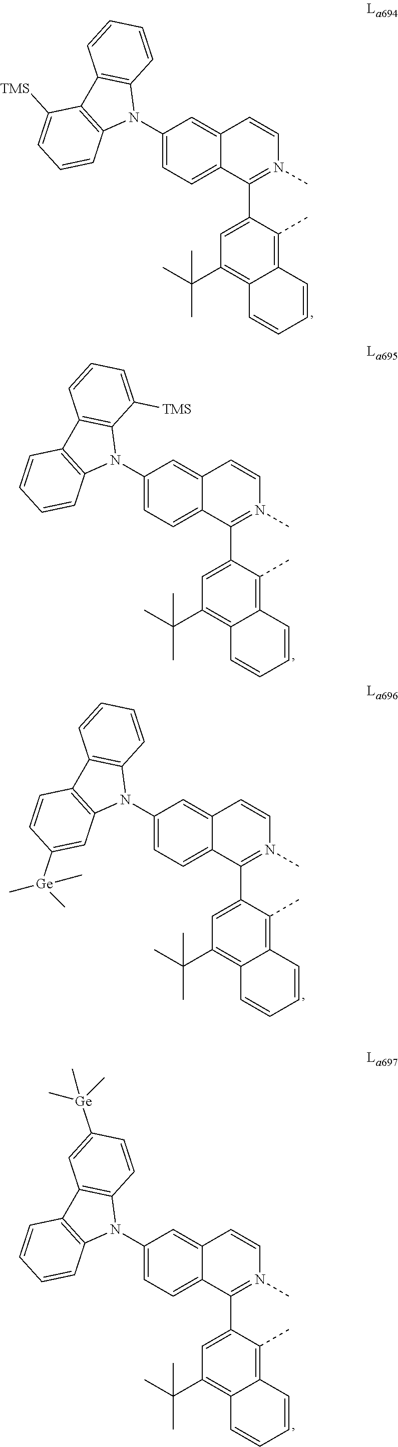

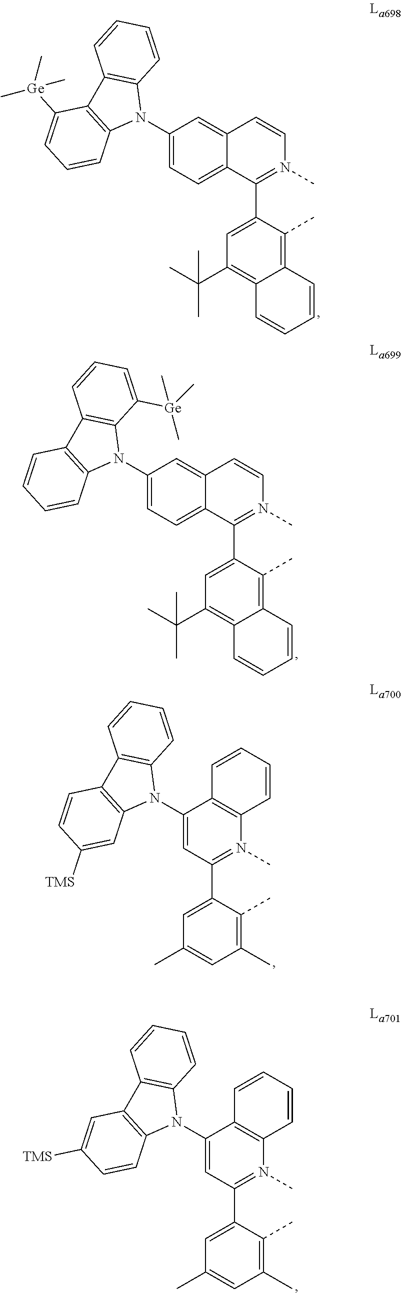

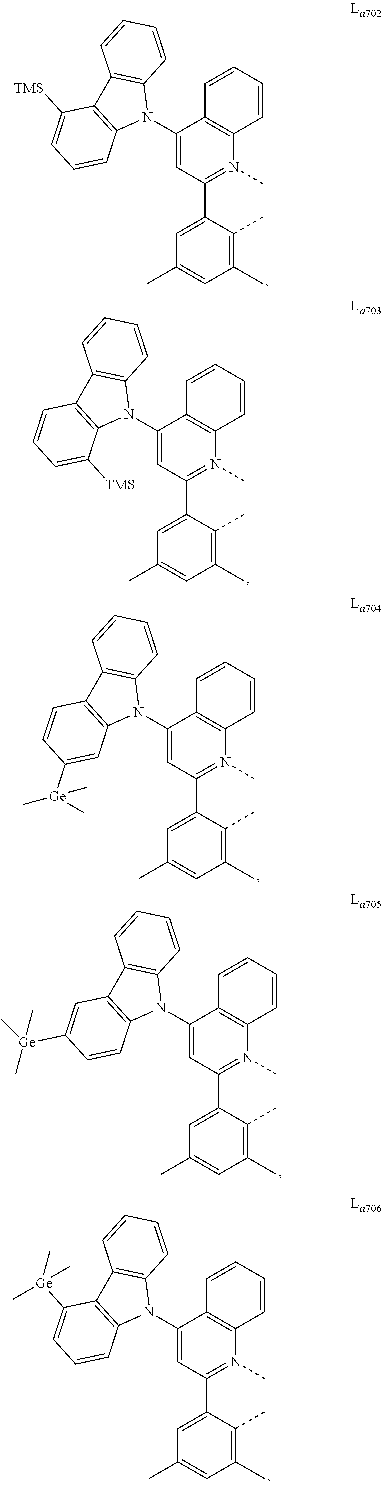

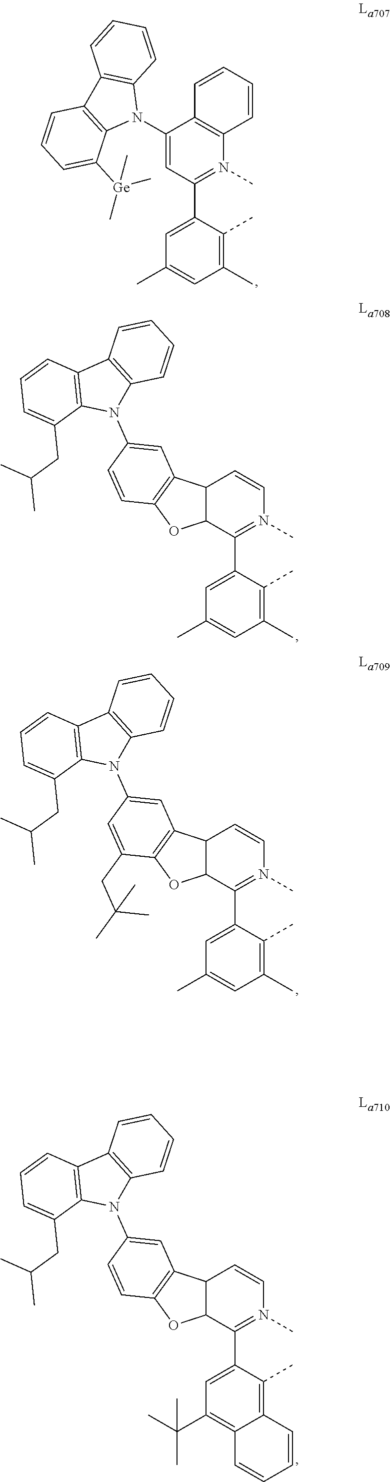

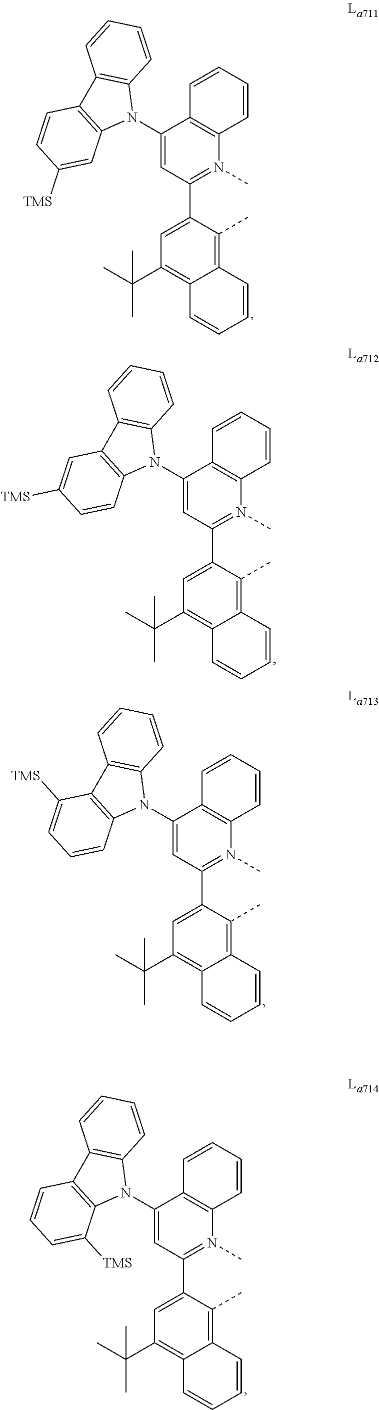

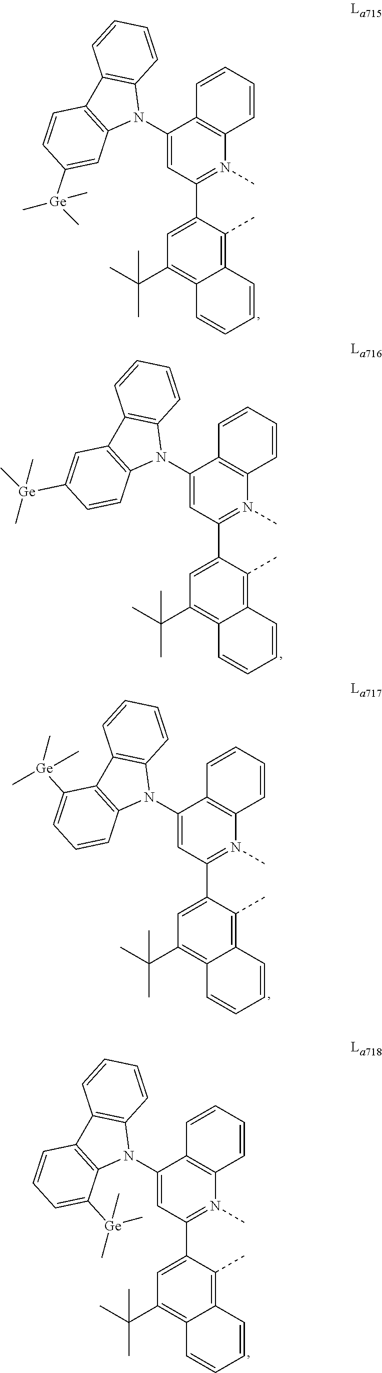

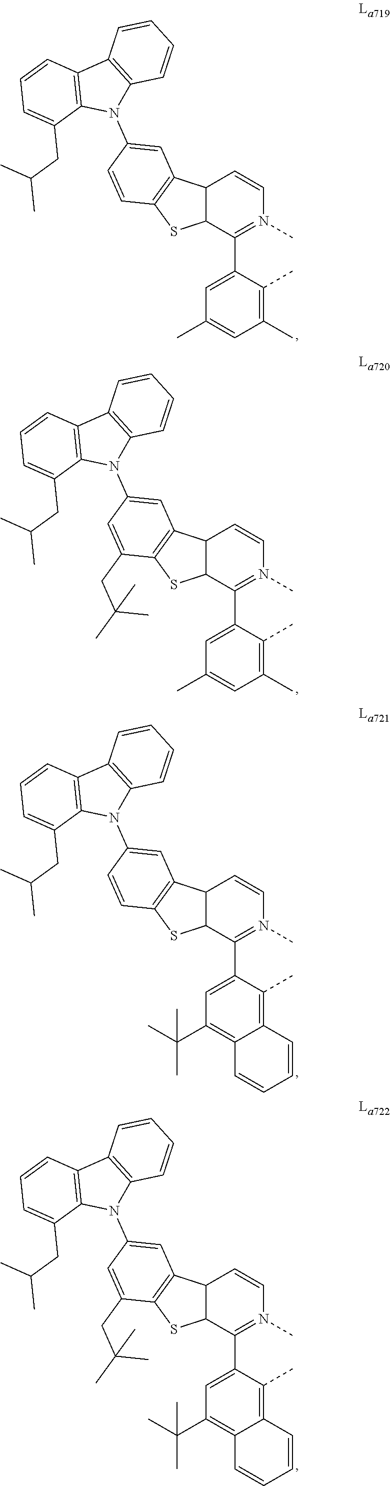

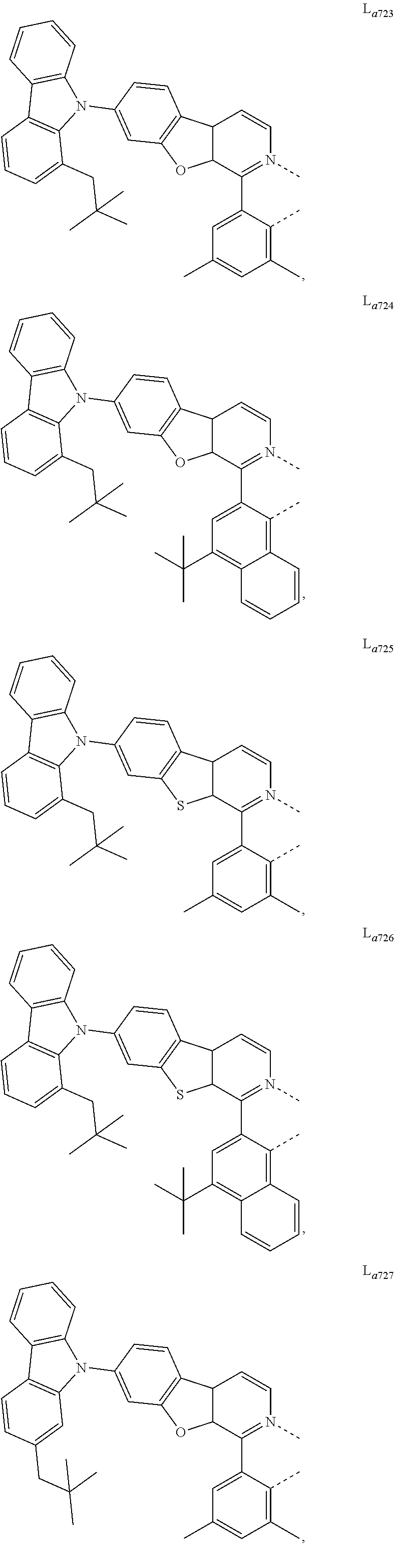

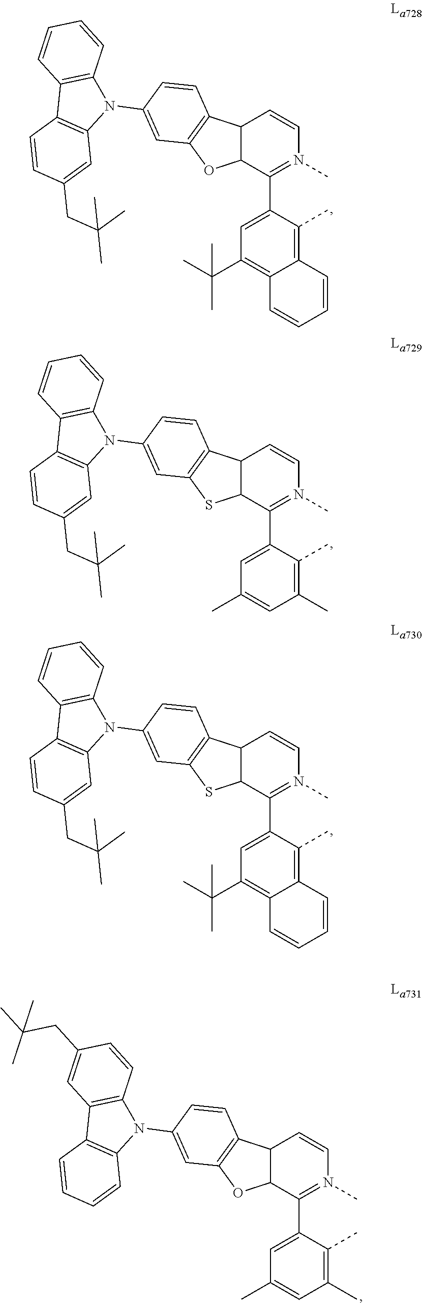

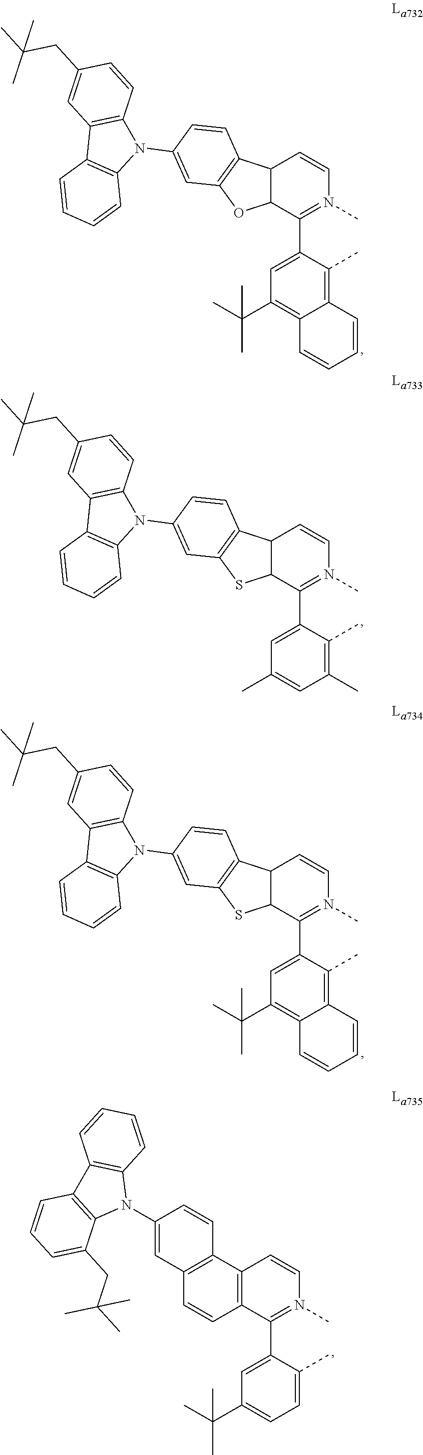

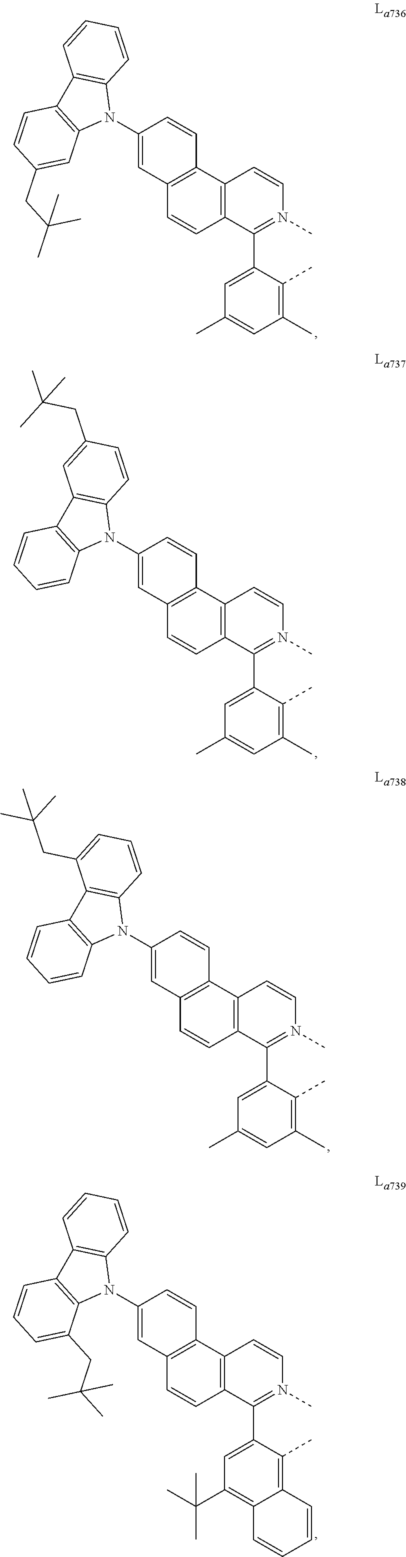

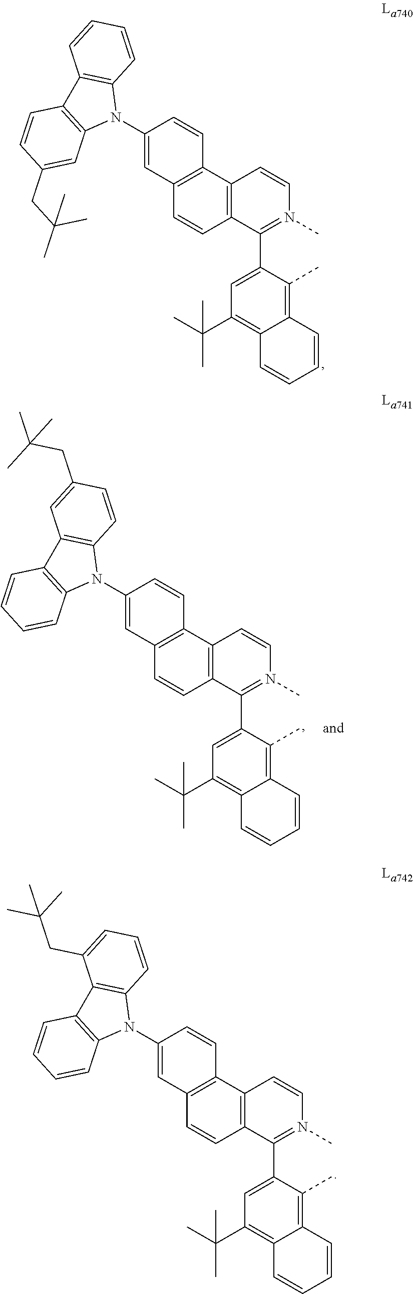

13. The metal complex according to claim 1, having a structure of M(Lₐ)ₘ(L_{b})ₘ(L_{c})_{q}; wherein the metal M is selected from a metal with a relative atomic mass greater than 40; Lₐ, L_{b}, and L_{c} are a first ligand, a second ligand and a third ligand of the complex, respectively; m is 1, 2 or 3, n is 0, 1 or 2, q is 0, 1 or 2, and m+n+q equals an oxidation state of the metal M; when m is greater than 1, a plurality of Lₐ are identical or different; when n is 2, two L_{b} are identical or different; when q is 2, two L_{c} are identical or different;
L_{b} and L_{c} are, at each occurrence identically or differently, selected from the group consisting of the following structures: 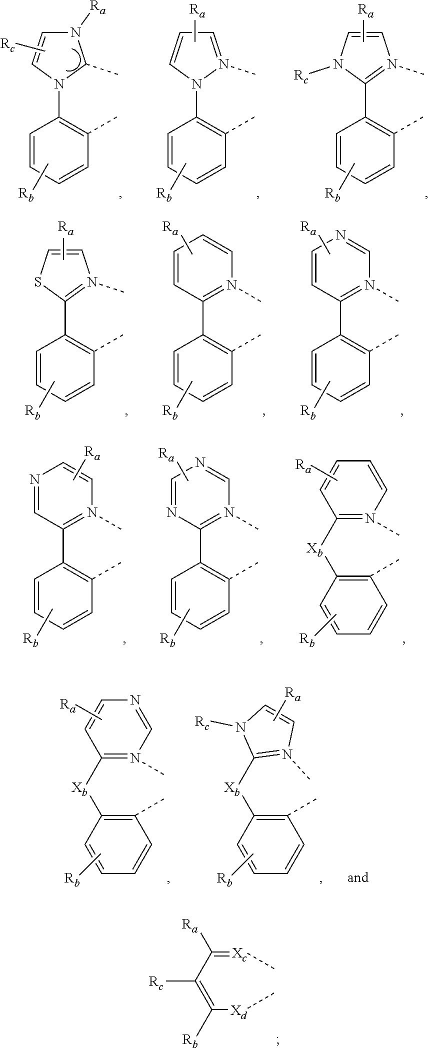
wherein Rₐ, R_{b}, and R_{c} represent, at each occurrence identically or differently, mono-substitution, multiple substitutions or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{N1}, R_{N2}, R_{C1}, and R_{C2} can be optionally joined to form a ring.

14. The metal complex according to claim 13, wherein the metal M is selected from Ir, Rh, Re, Os, Pt, Au or Cu;
preferably, the metal M is selected from Ir, Pt or Os;
more preferably, the metal M is Ir.

15. The metal complex according to claim 13, wherein L_{b} is, at each occurrence identically or differently, selected from the following structure: 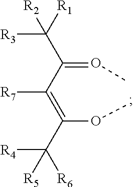
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one or two of R₁ to R₃ is(are) selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof; and/or at least one of R₄ to R₆ is substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms or combinations thereof:
more preferably, at least two of R₁ to R₃ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof; and/or at least two of R₄ to R₆ are selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms or combinations thereof.

16. The metal complex according to claim 15, wherein L_{b} is, at each occurrence identically or differently, selected from the group consisting of the following structures: 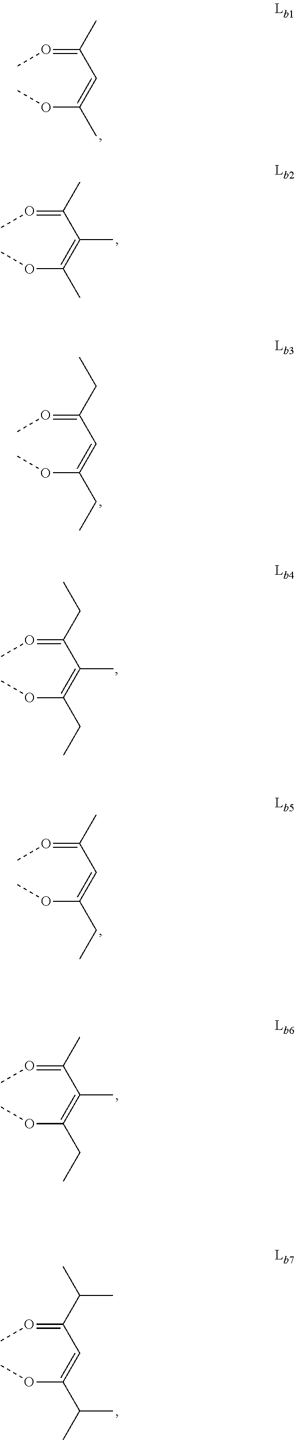 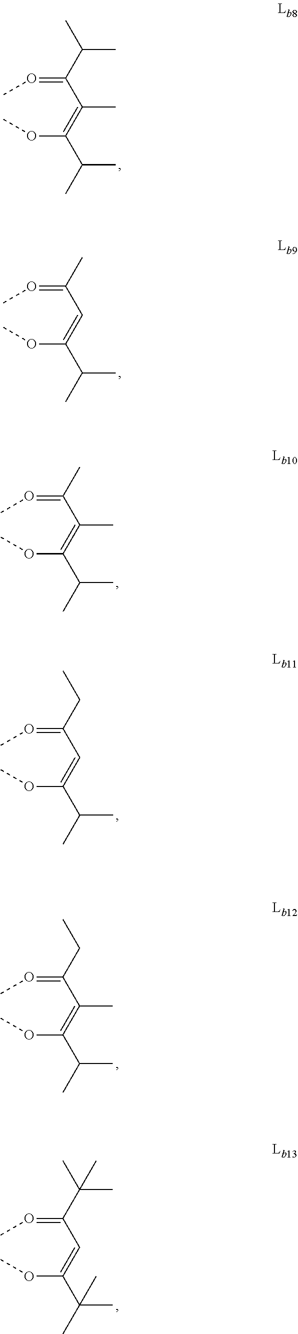 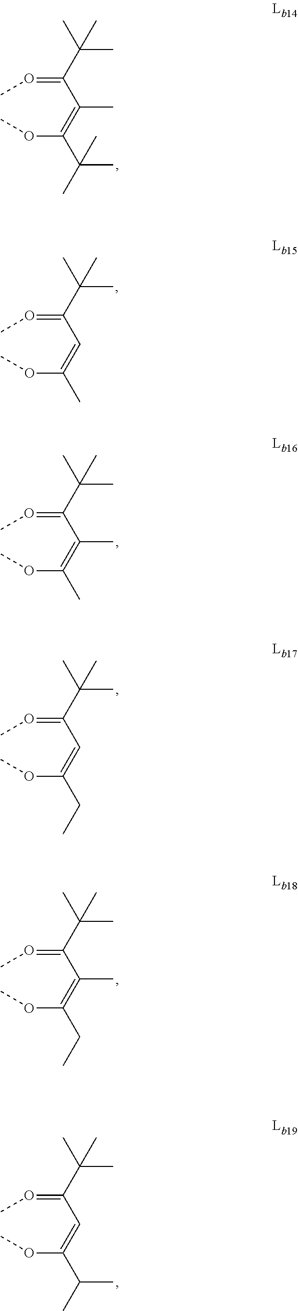 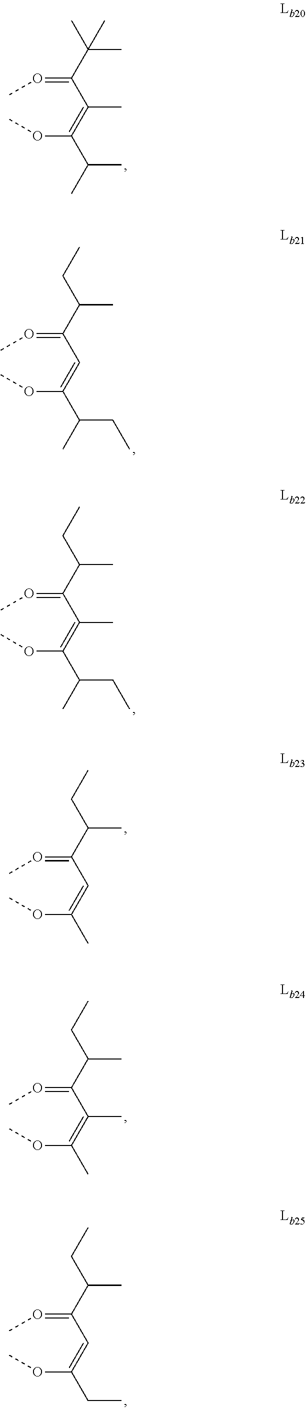 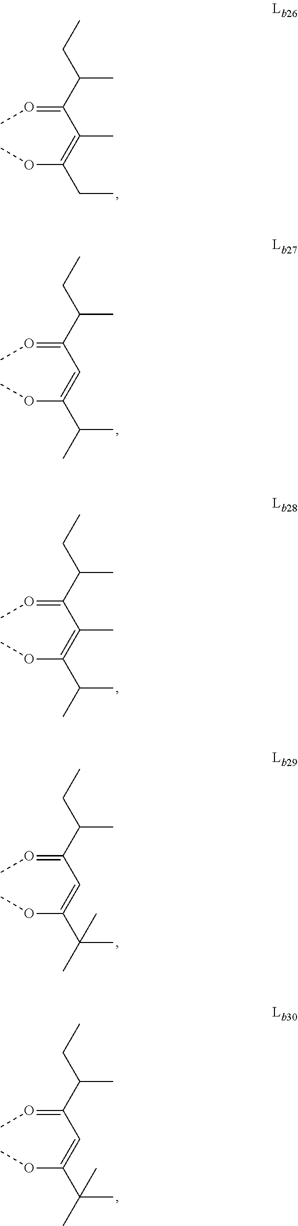 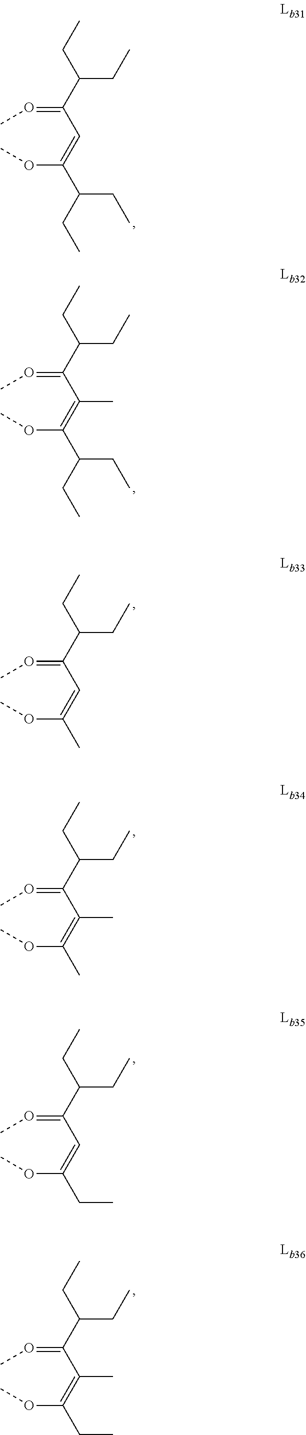 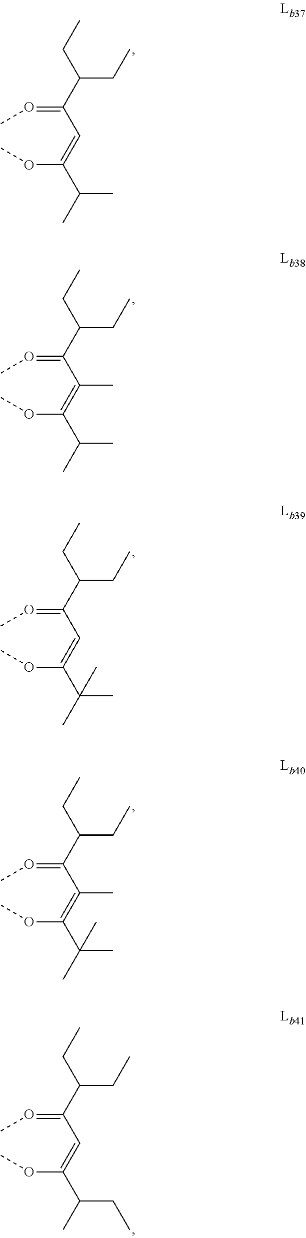 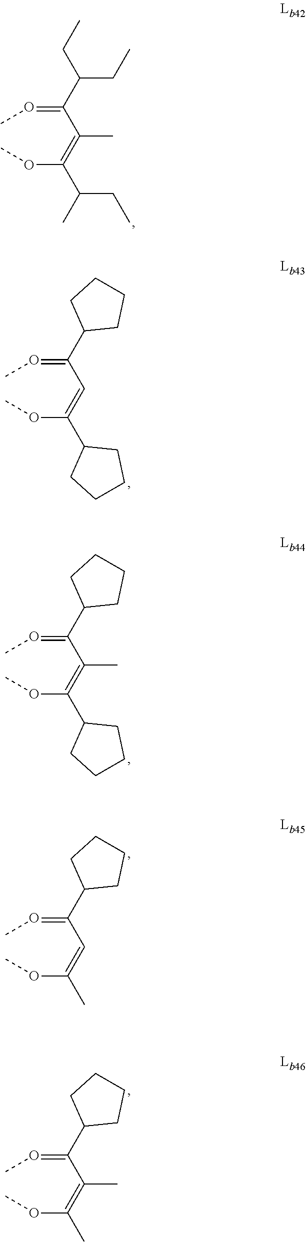 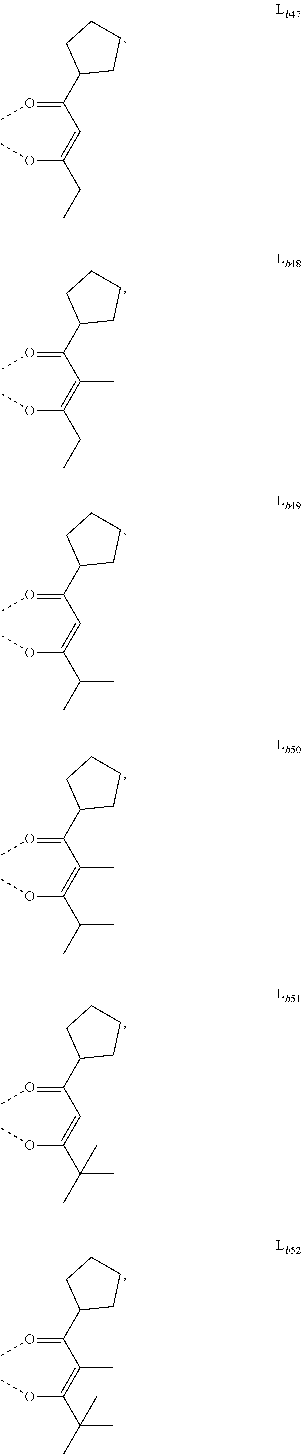 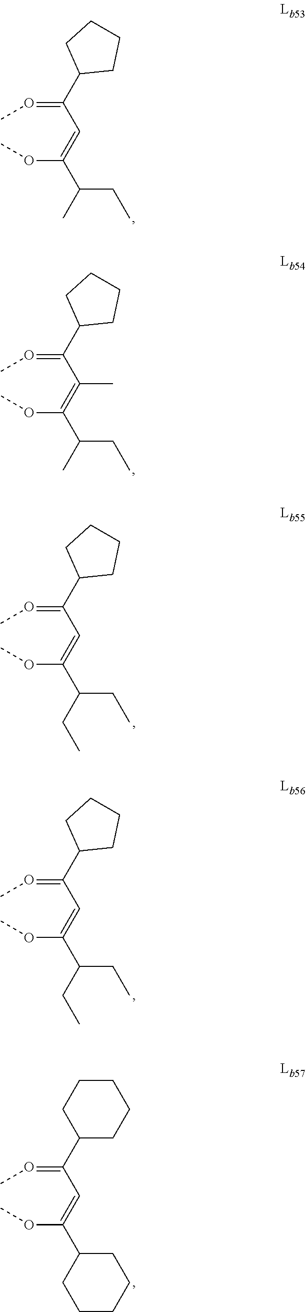 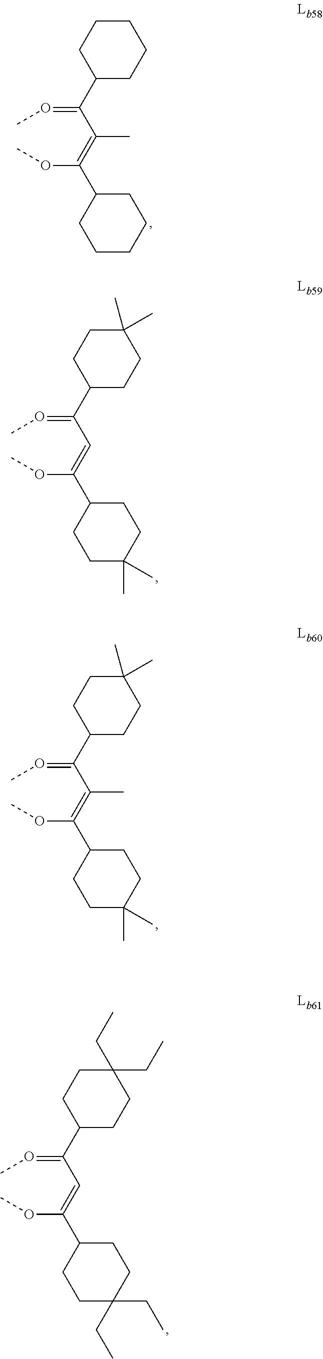 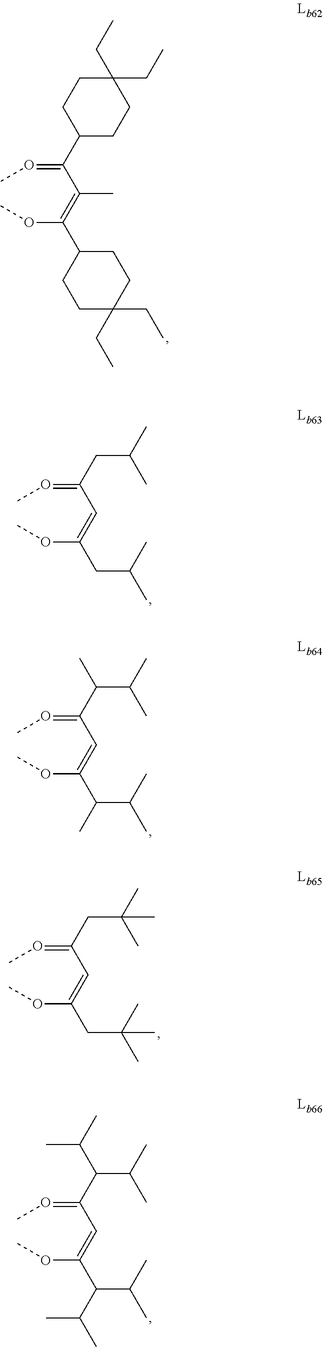 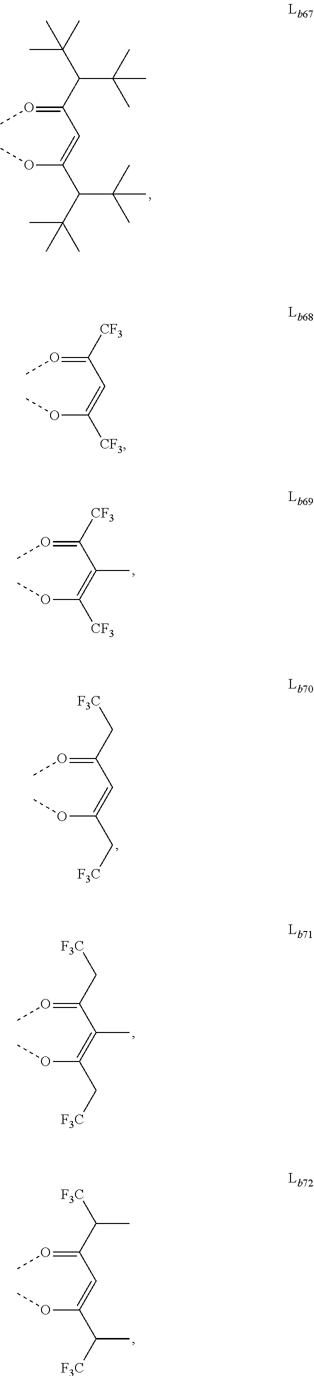 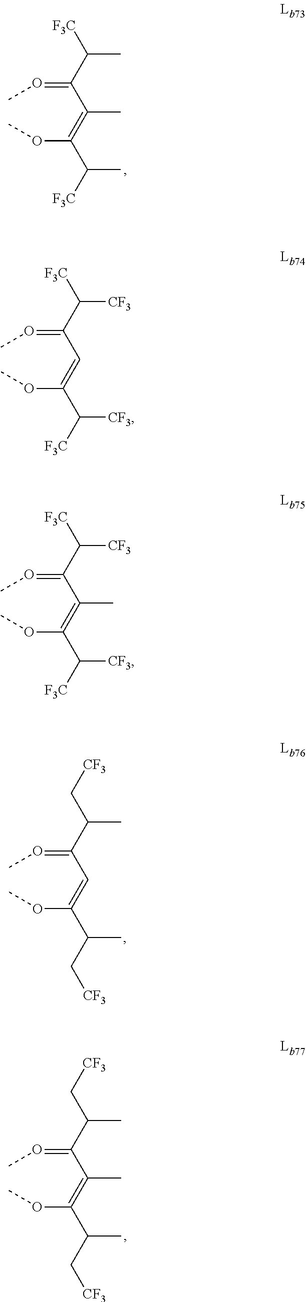 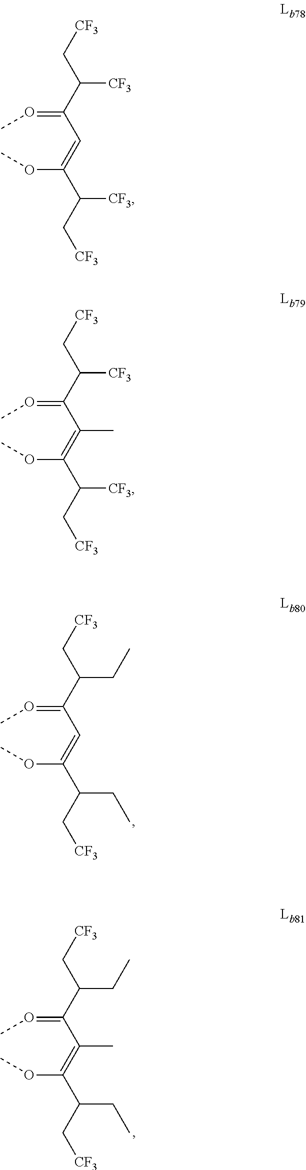 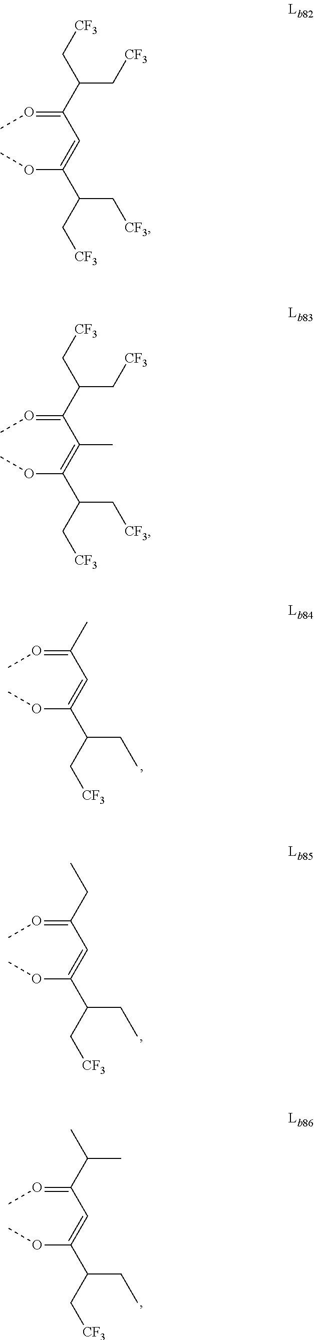 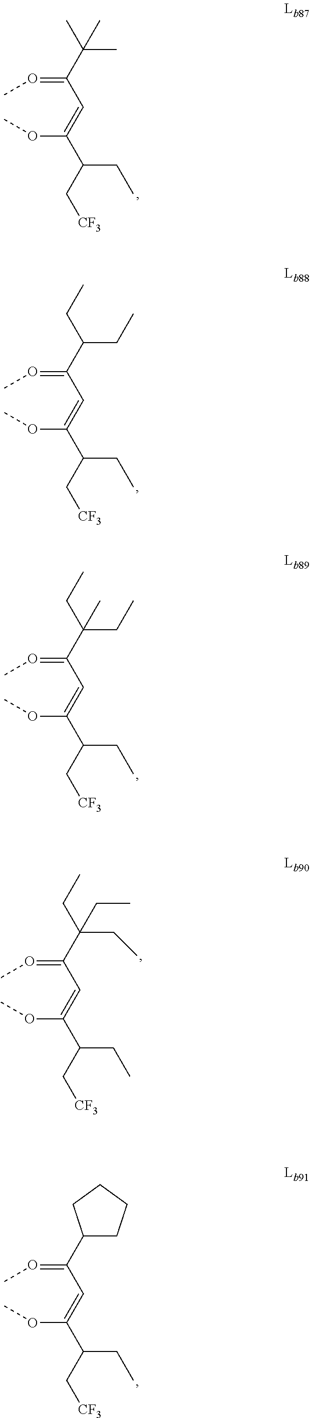 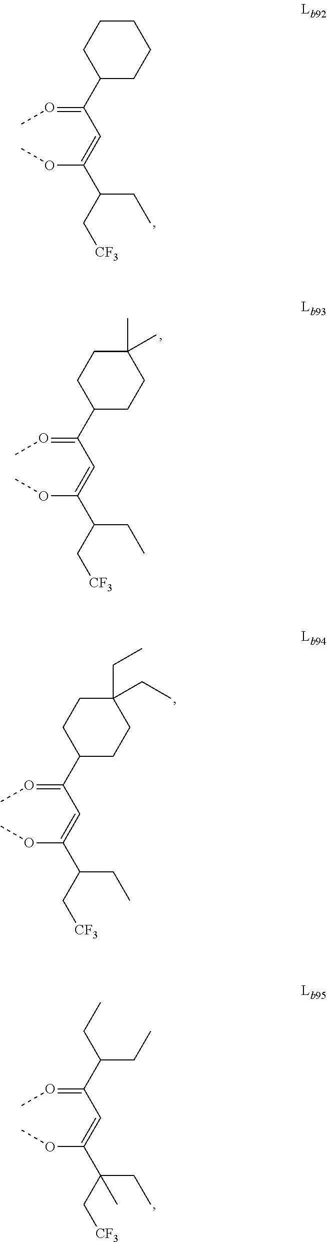 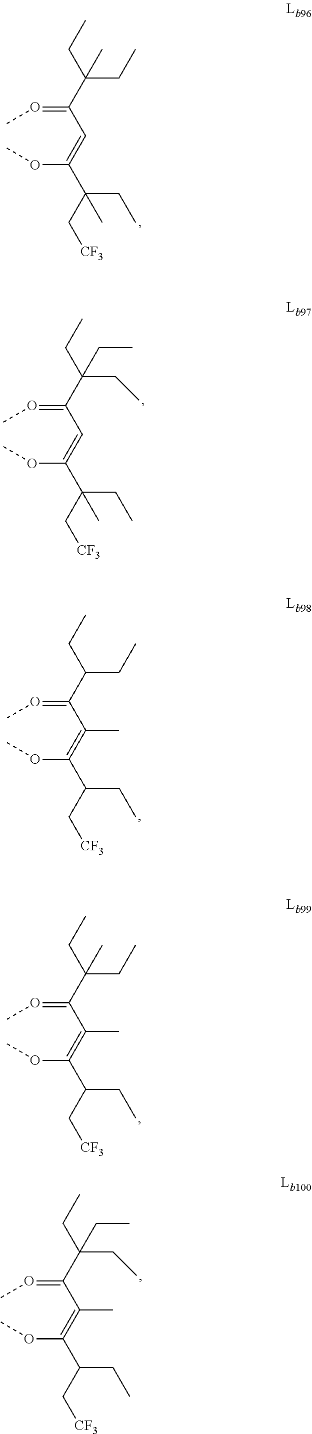 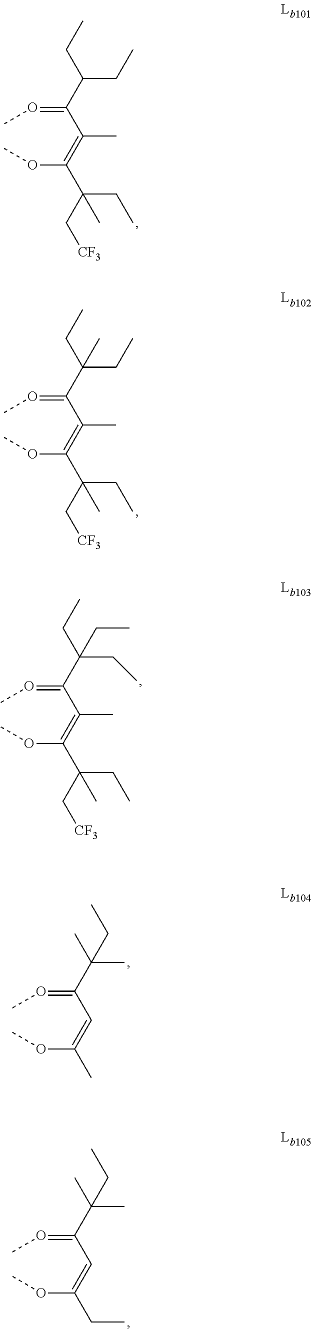 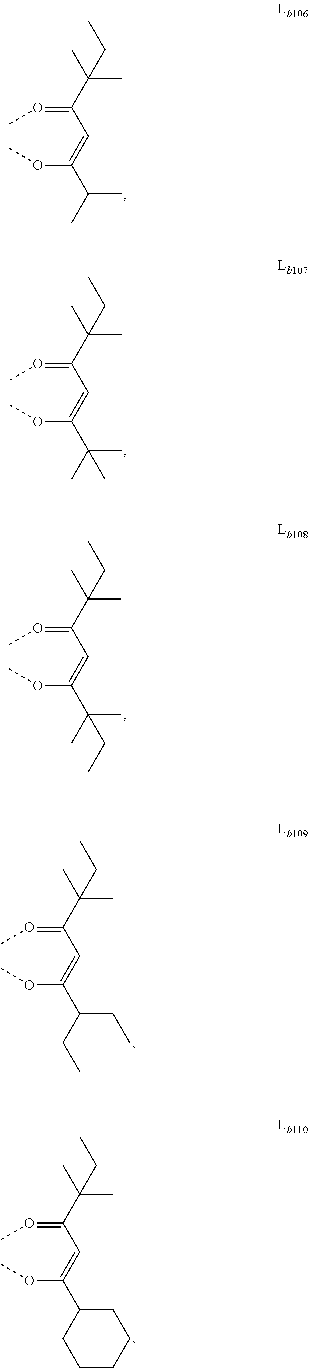 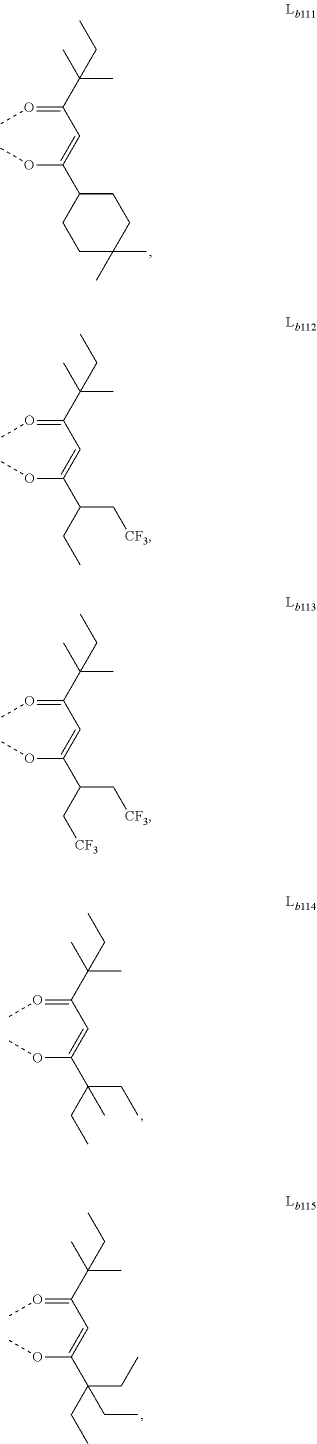 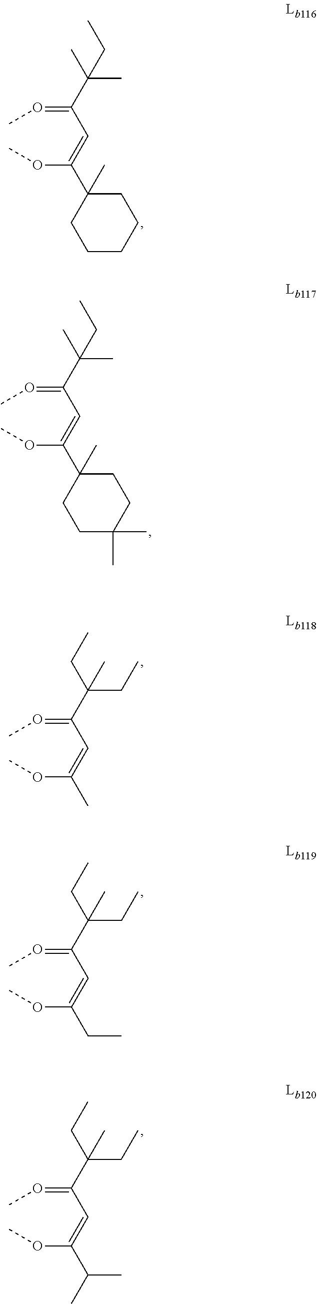 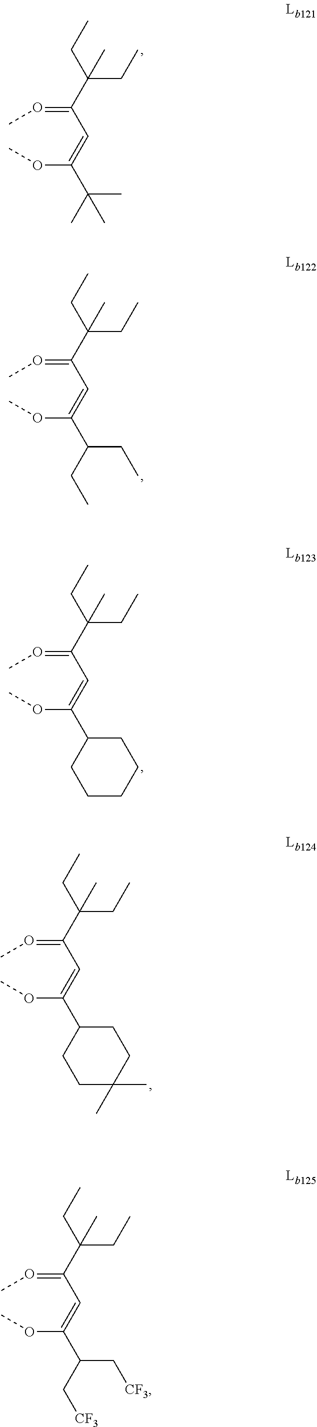 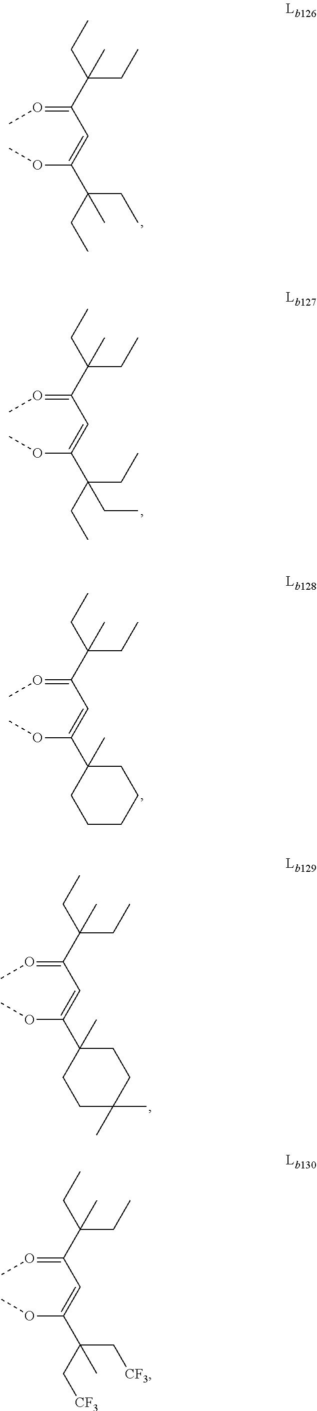 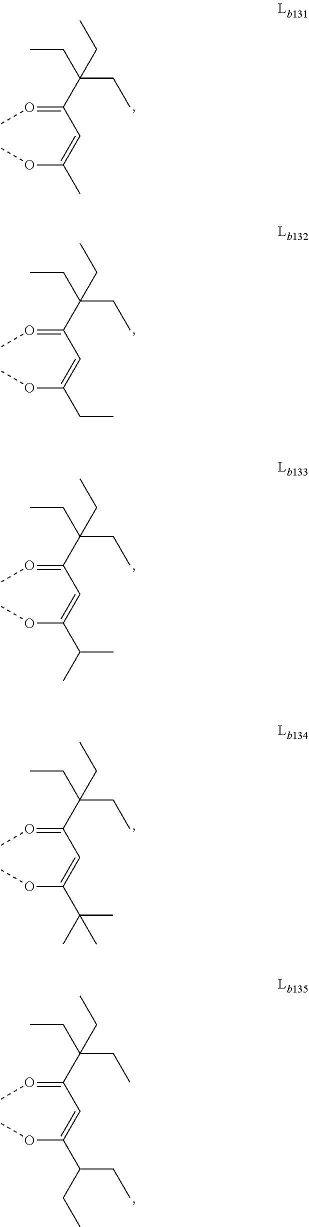 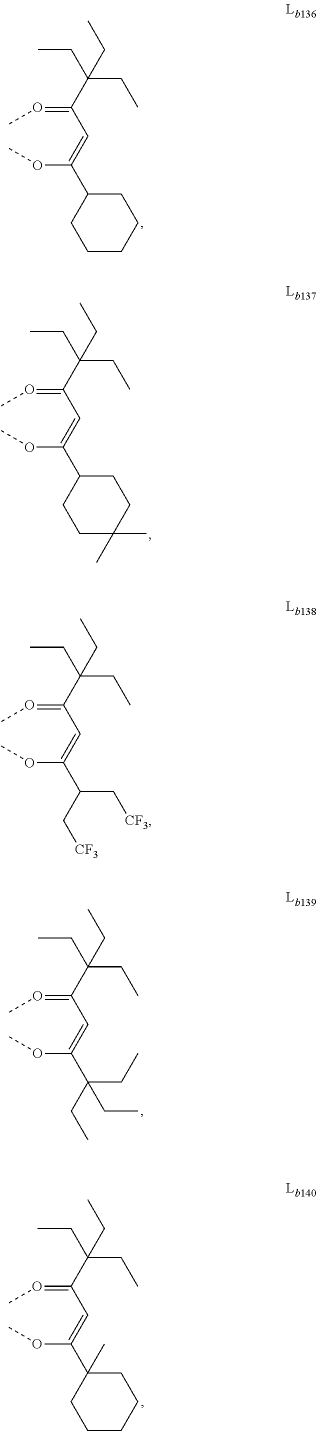 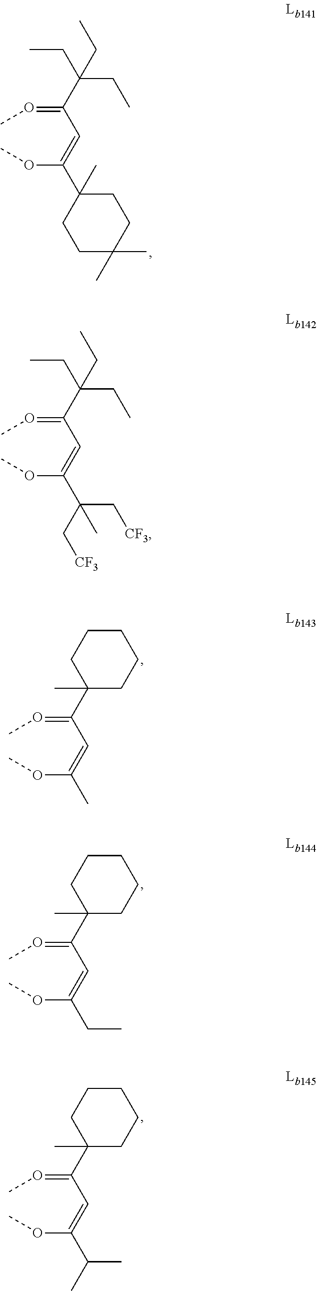 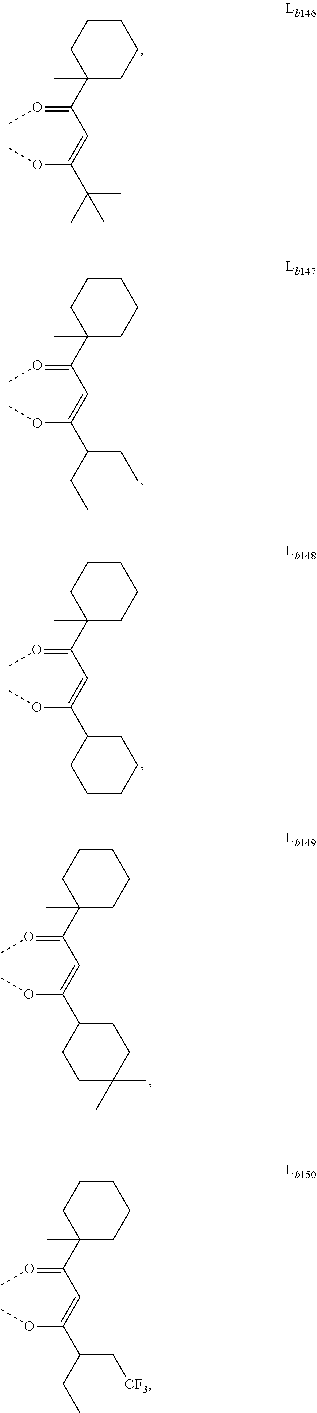 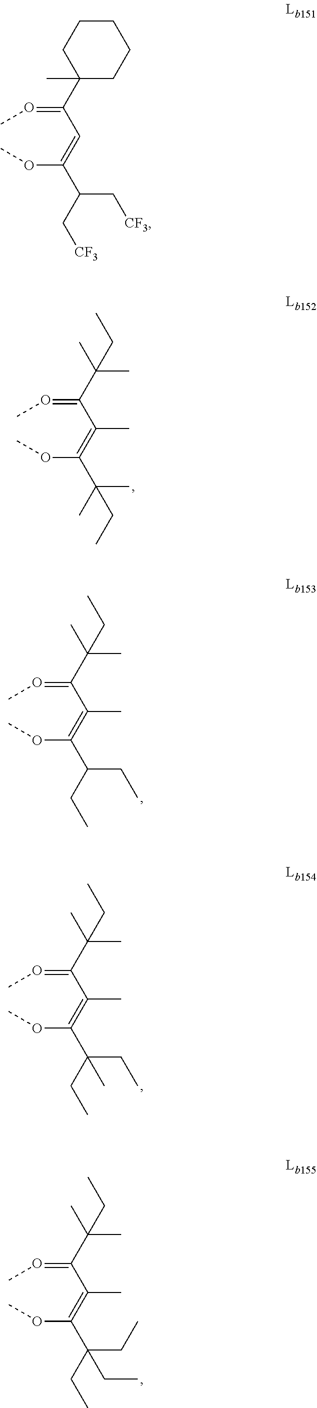 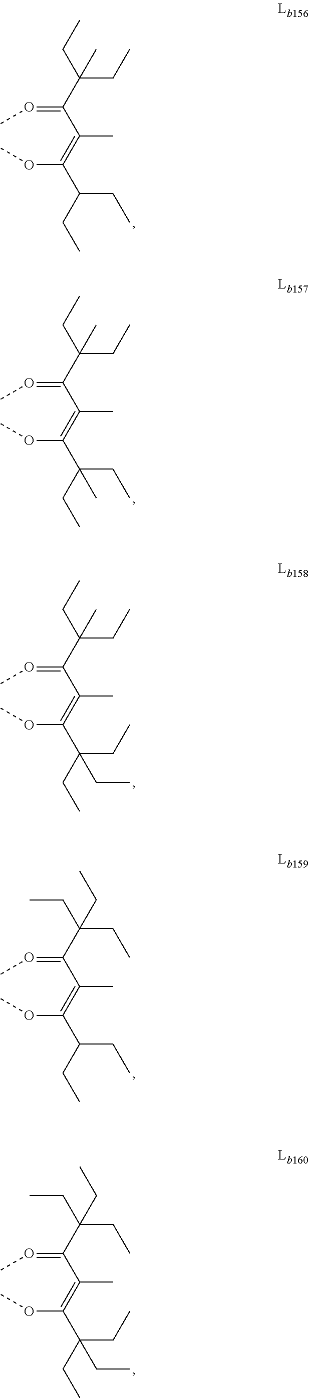 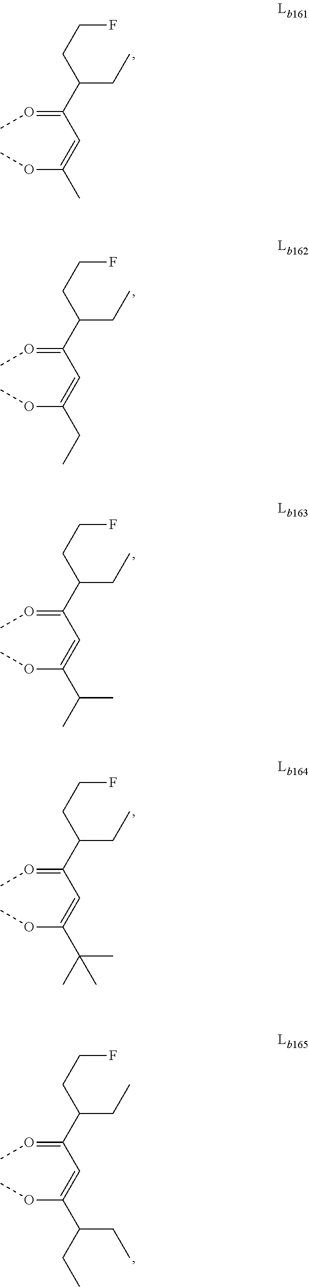 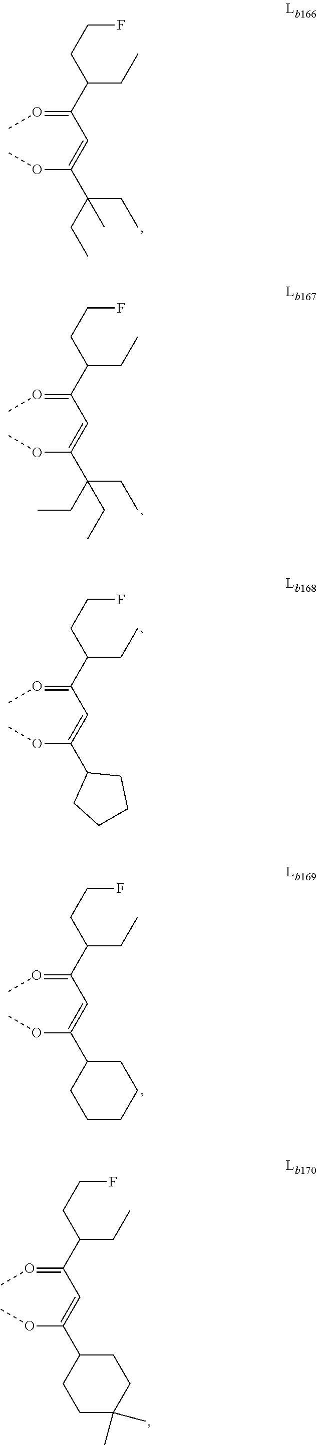 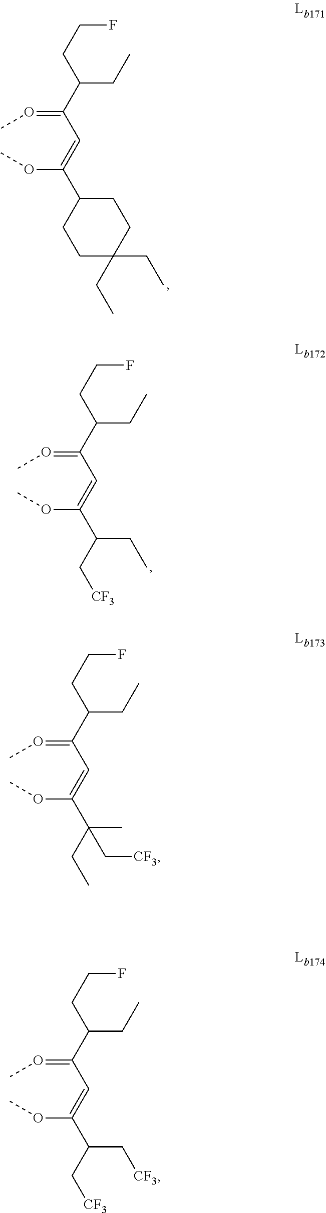 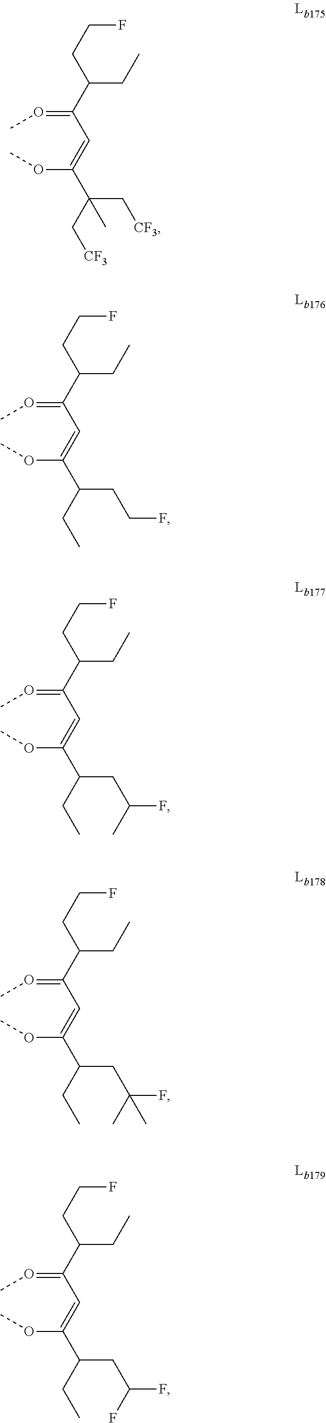 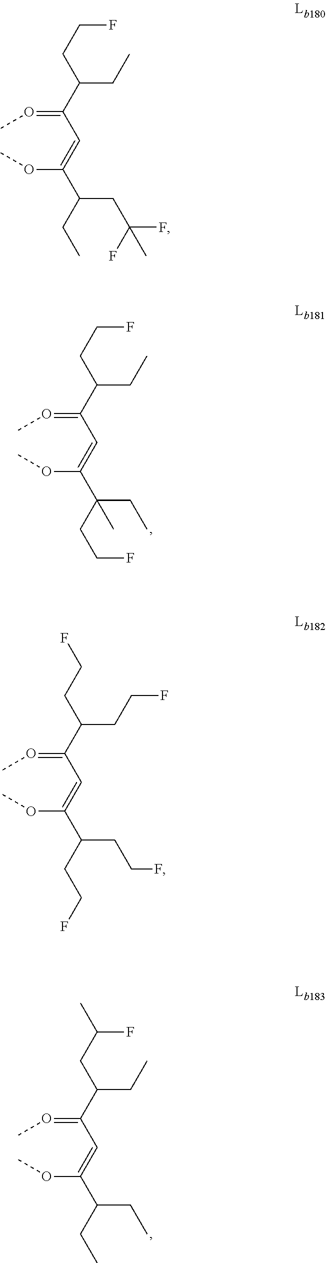 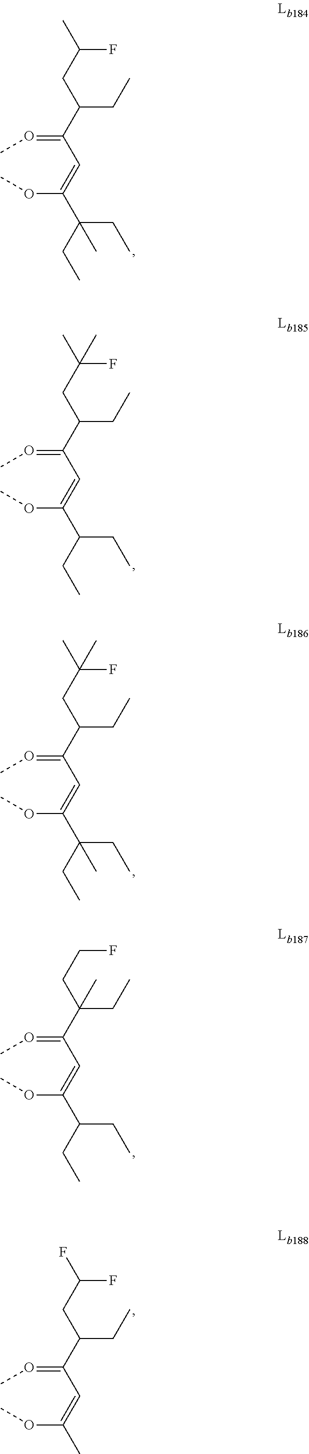 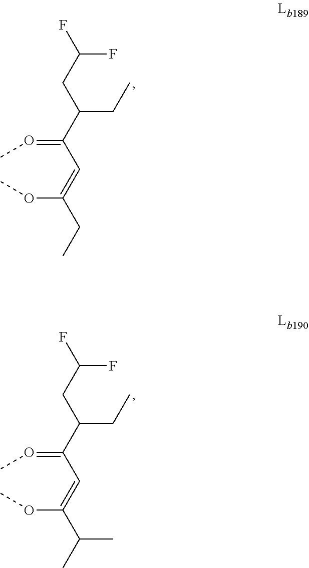 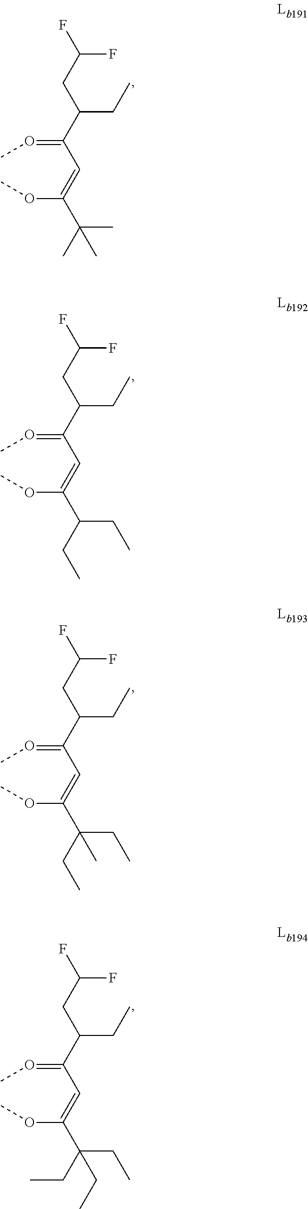 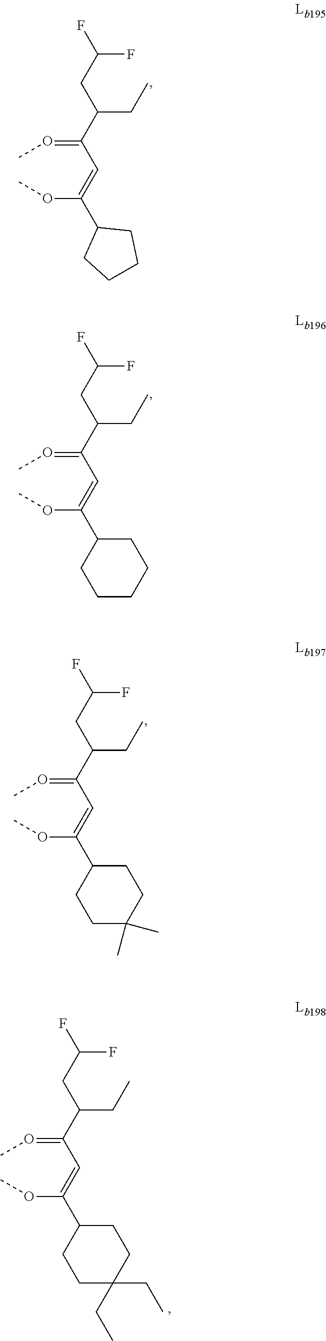 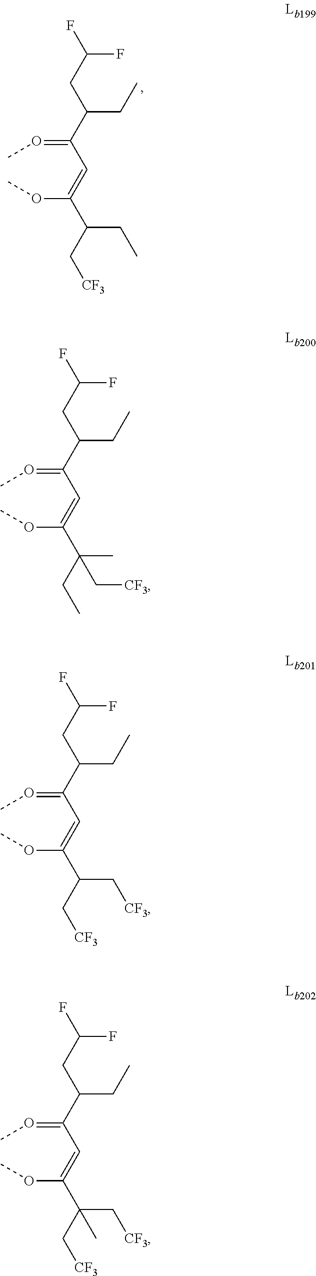 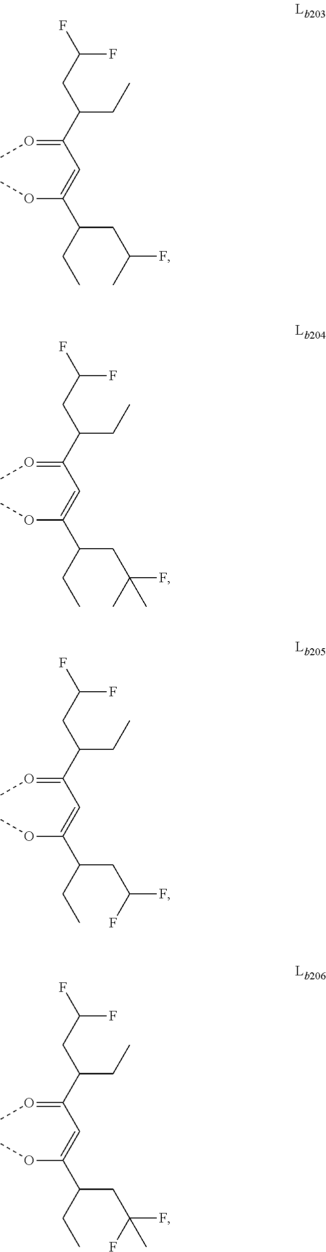 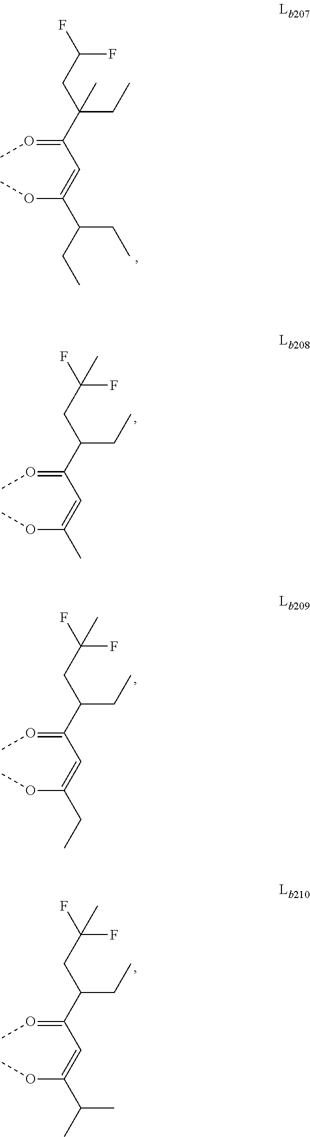 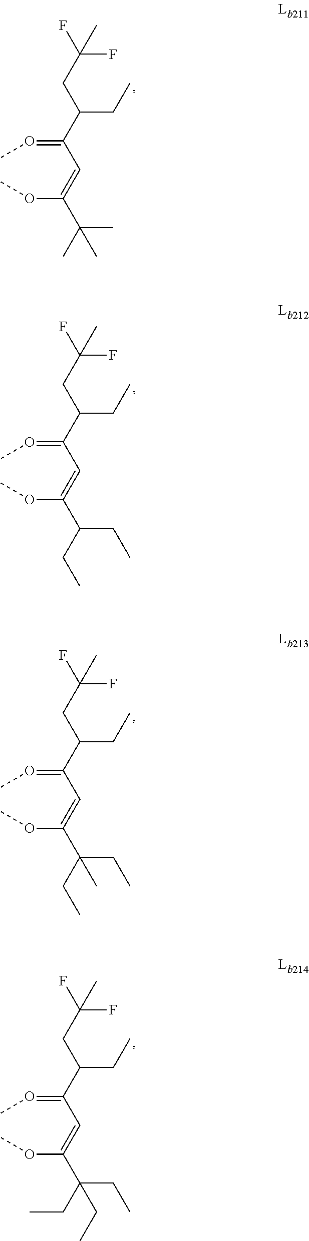 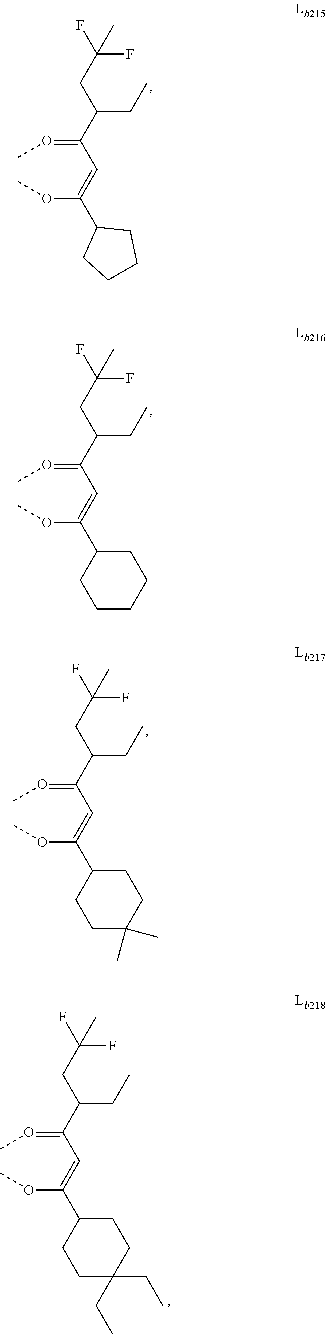 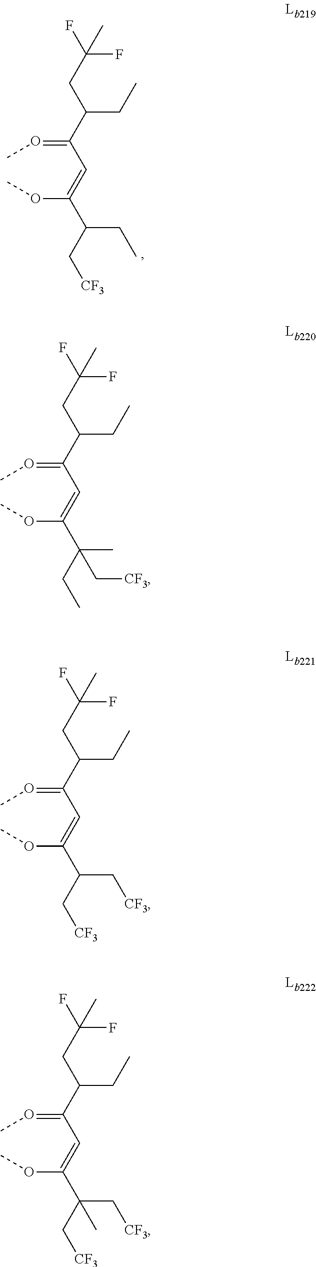 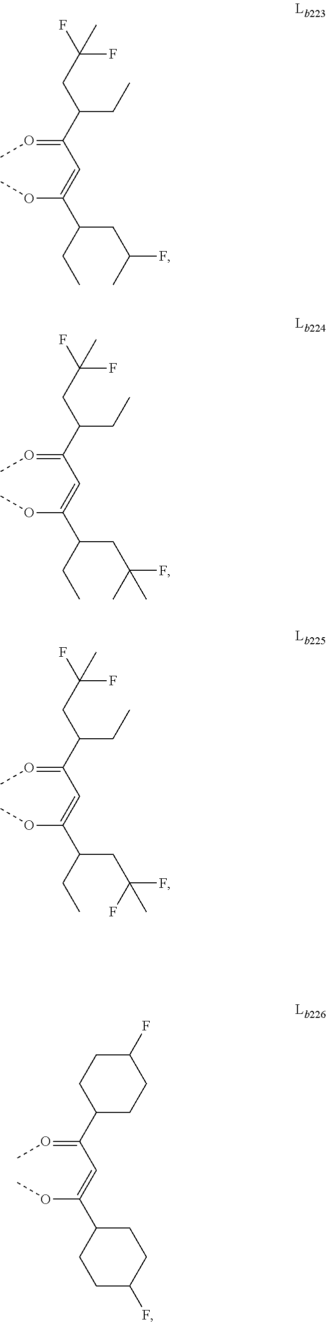 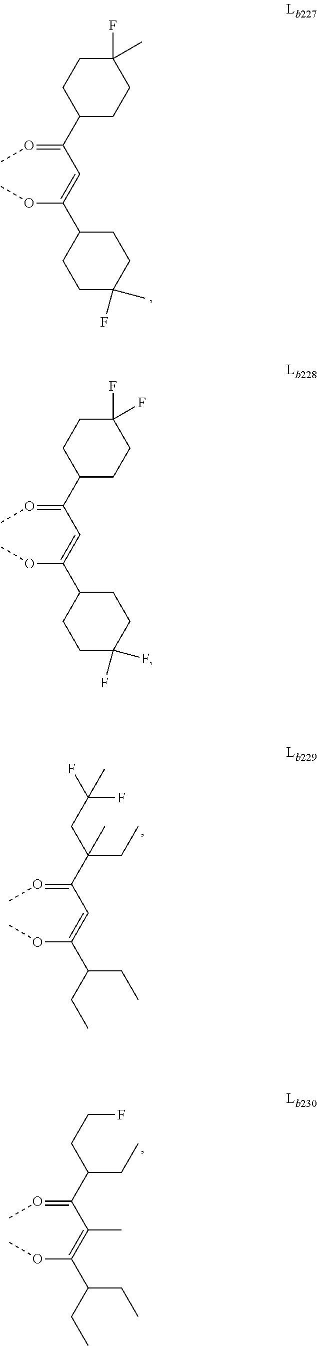 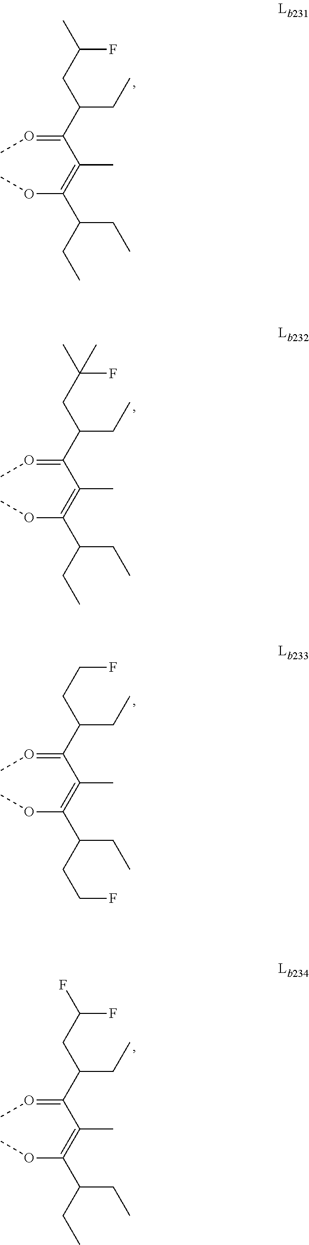 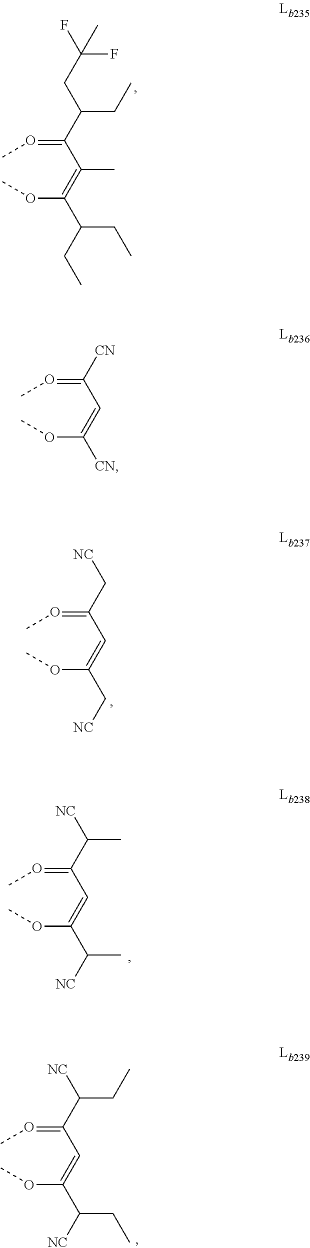 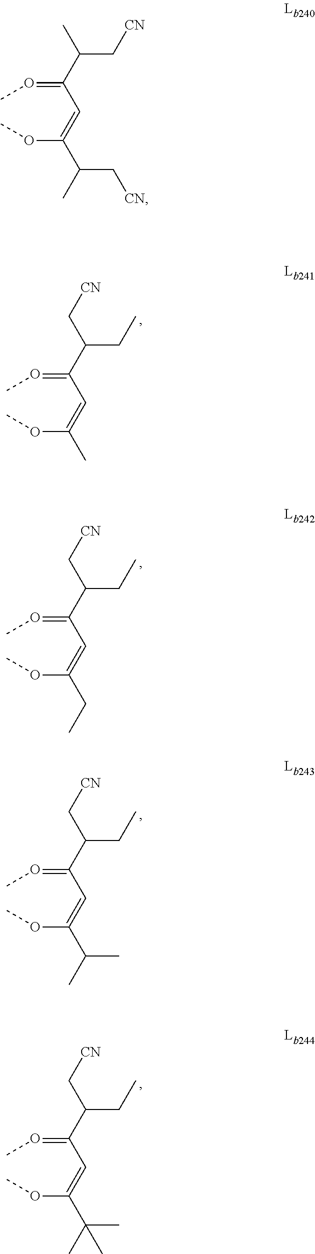 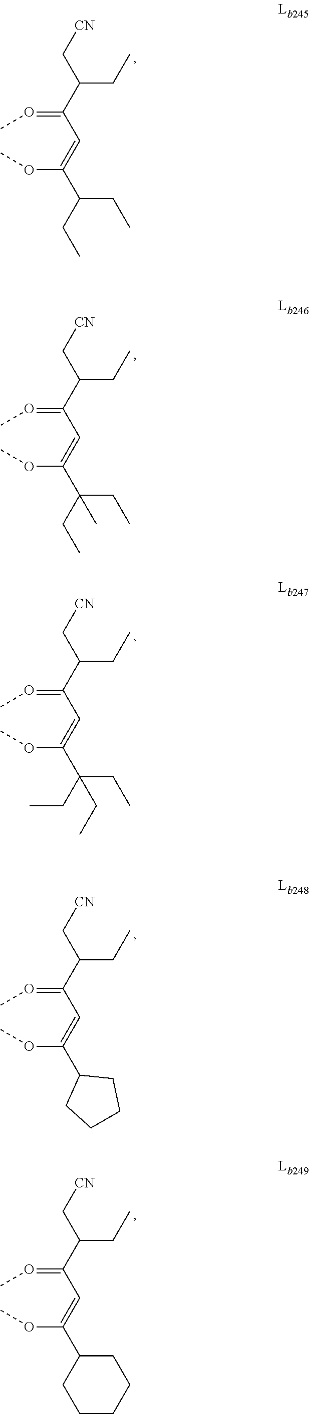 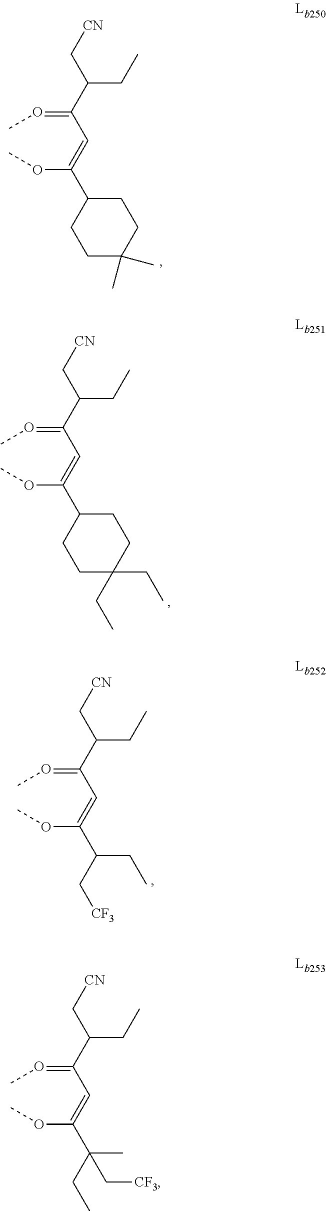 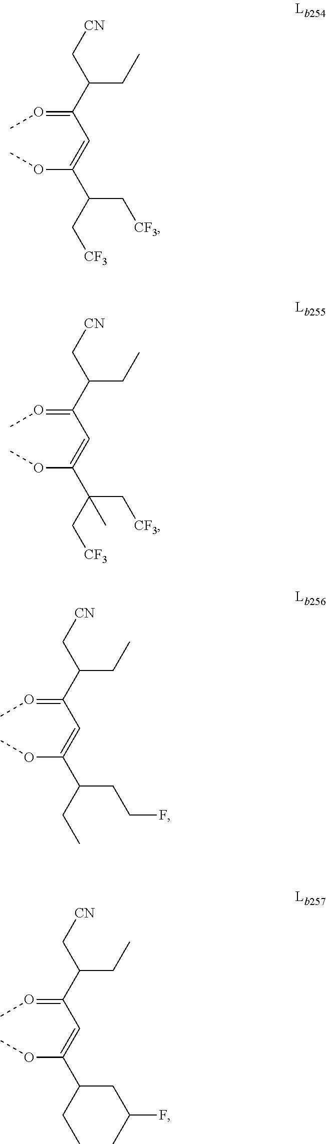 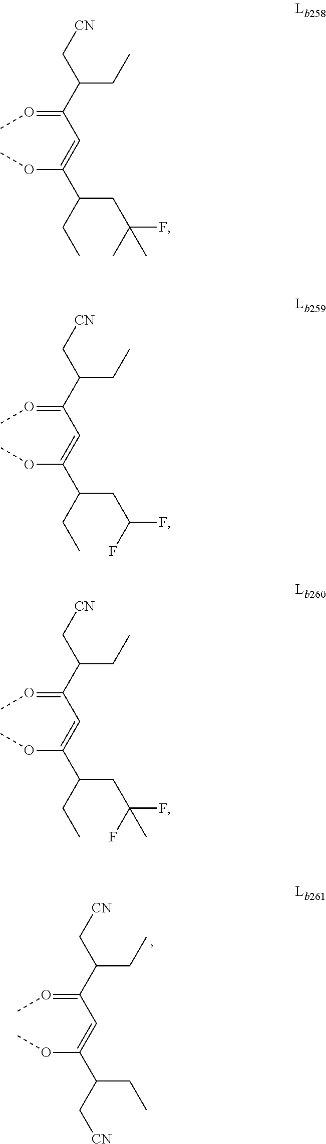 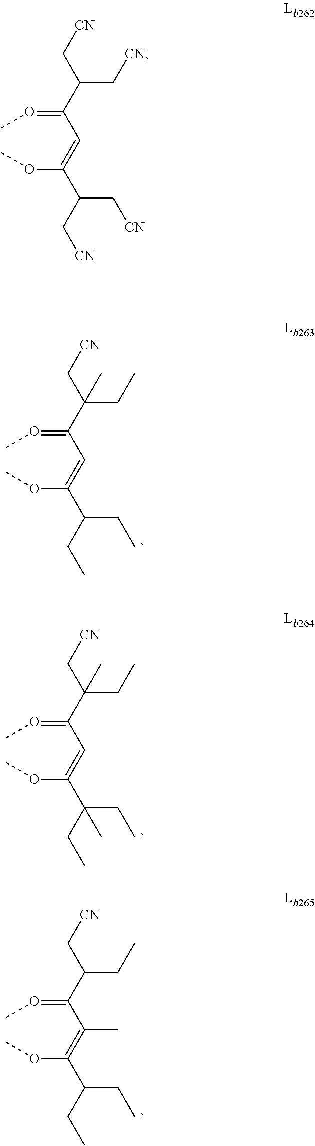 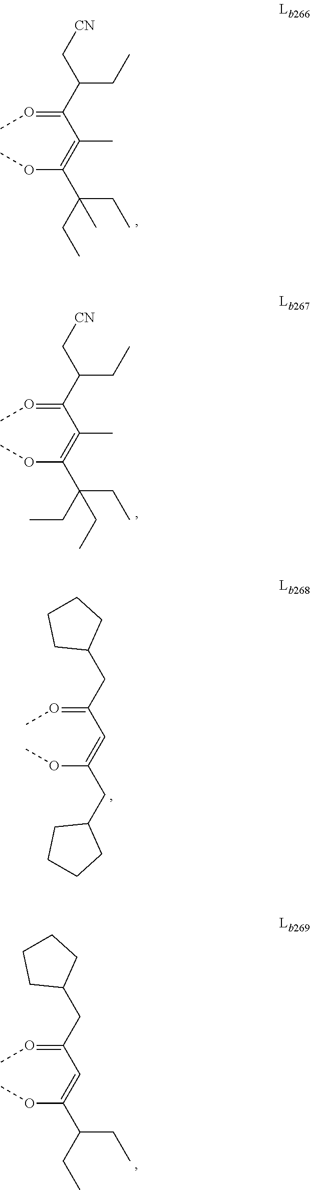 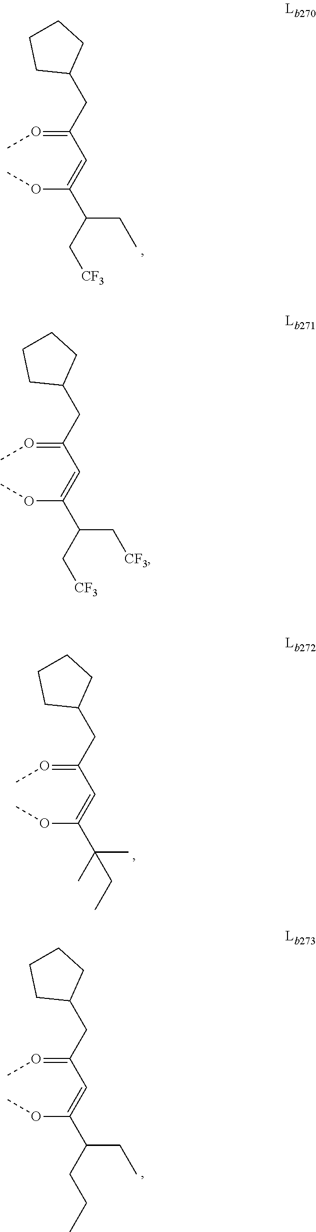 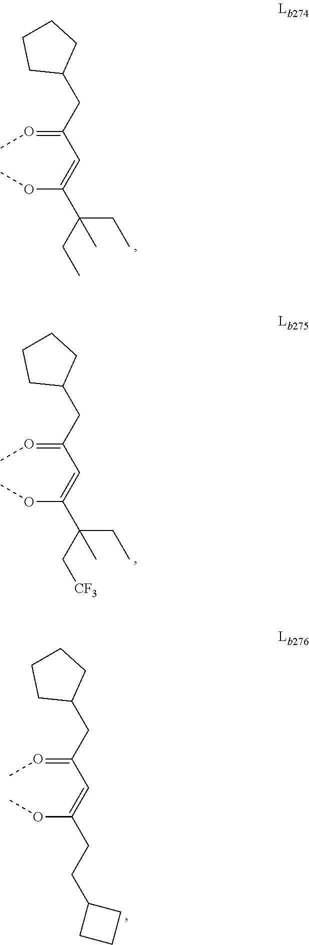 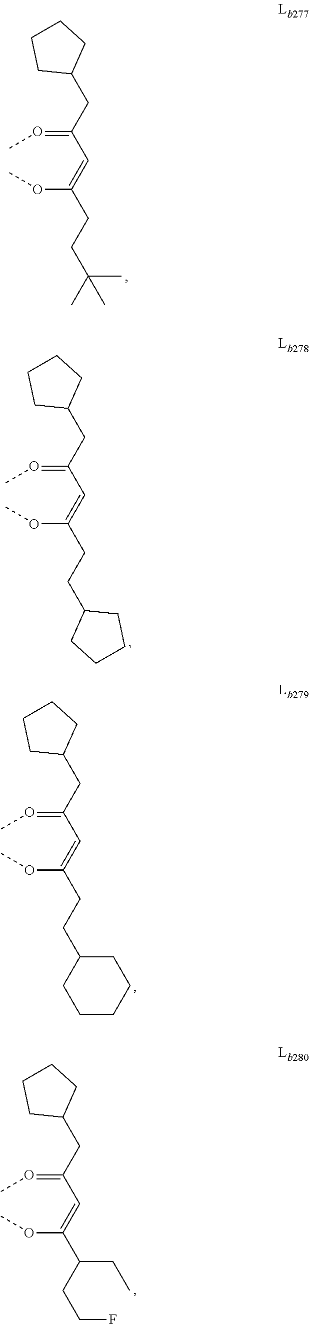 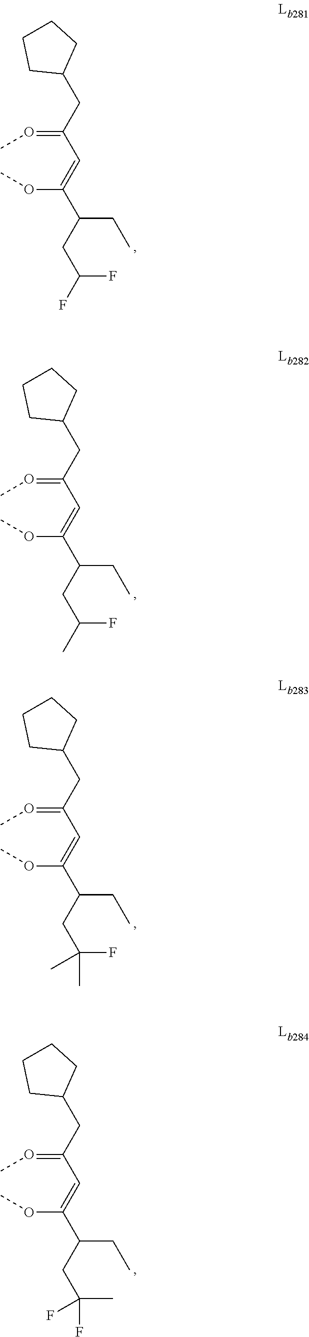 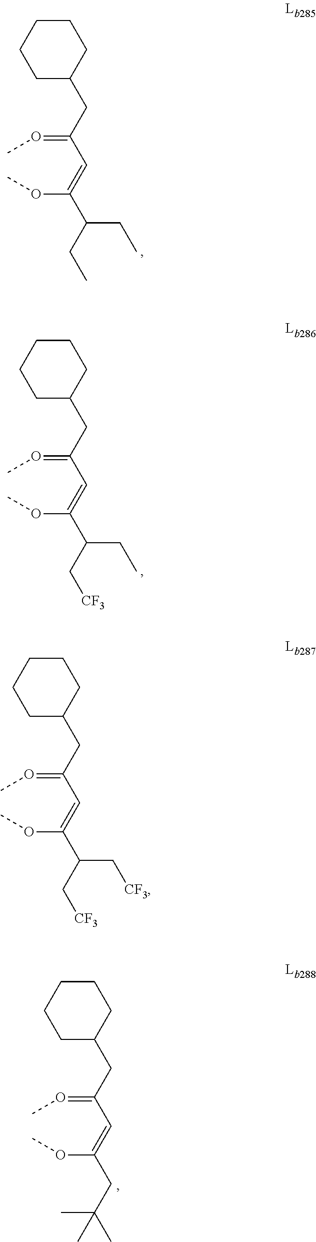 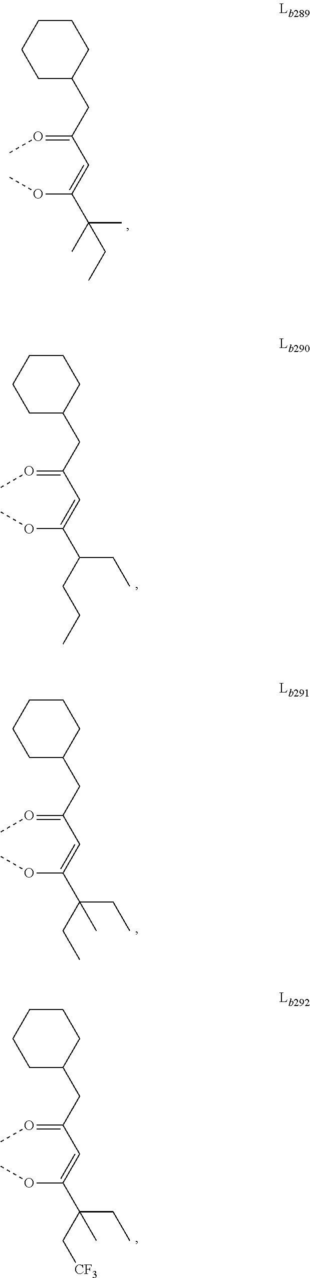 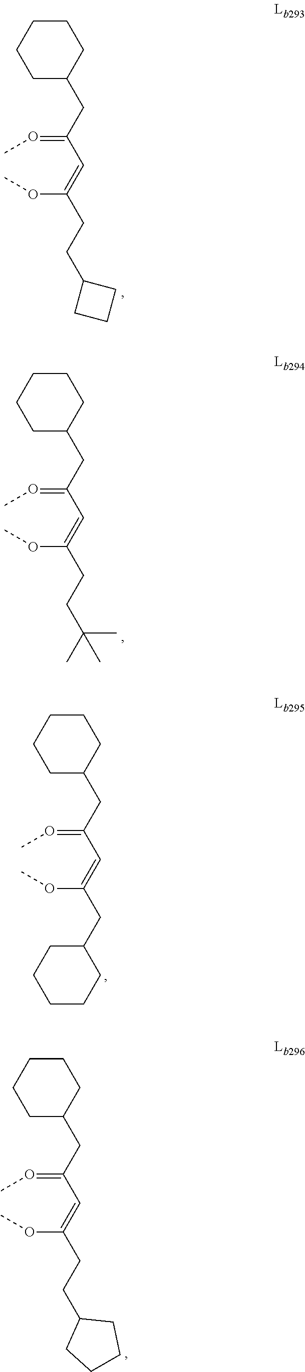 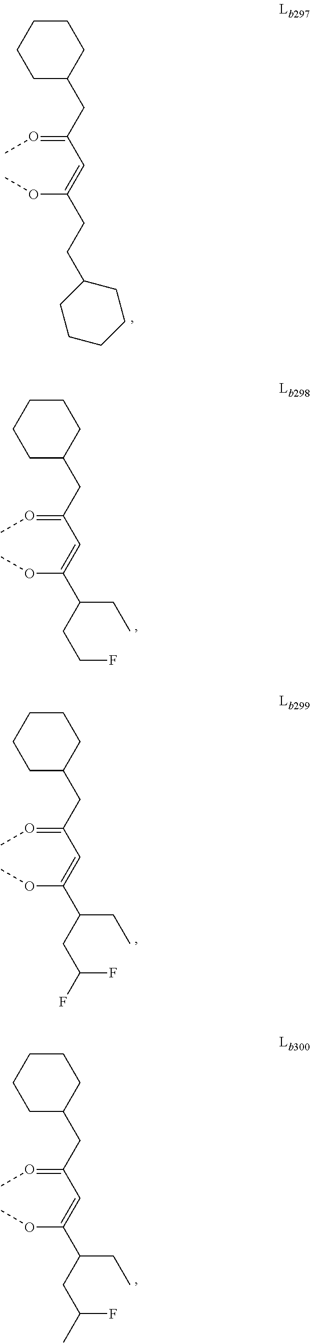 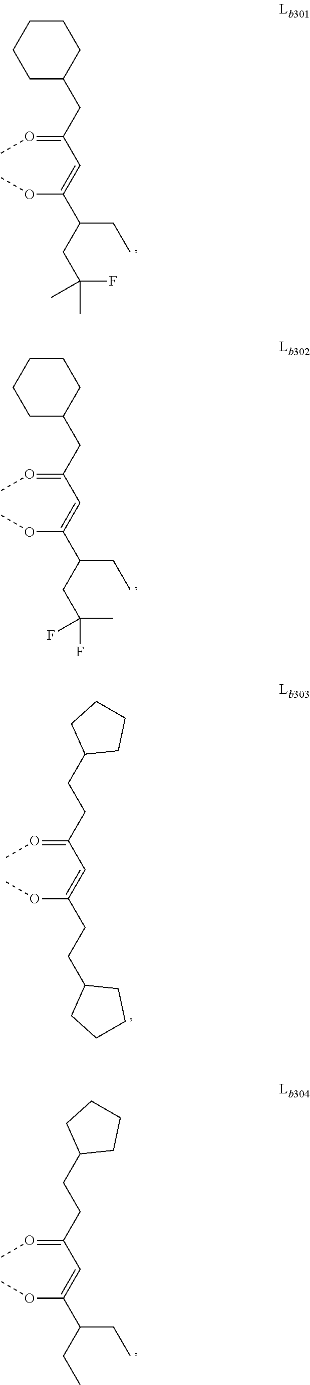 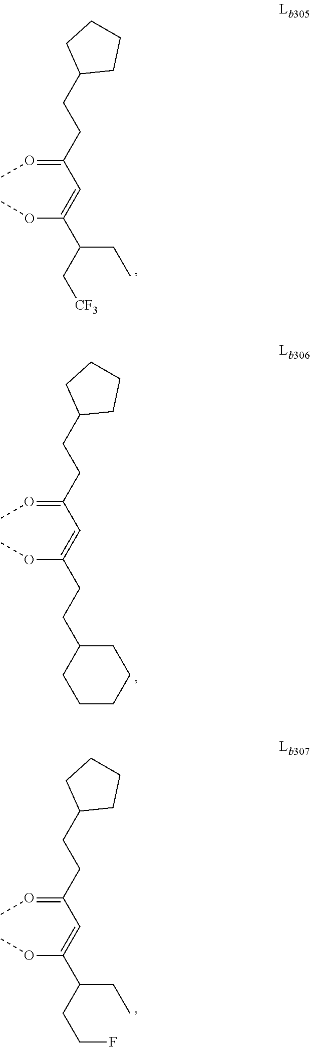 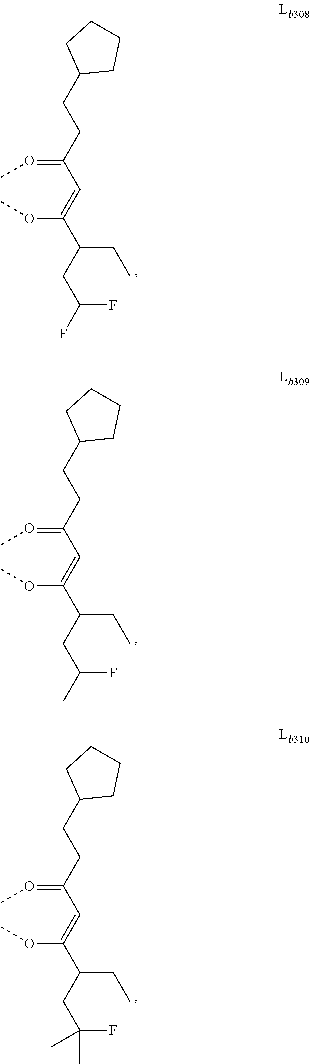 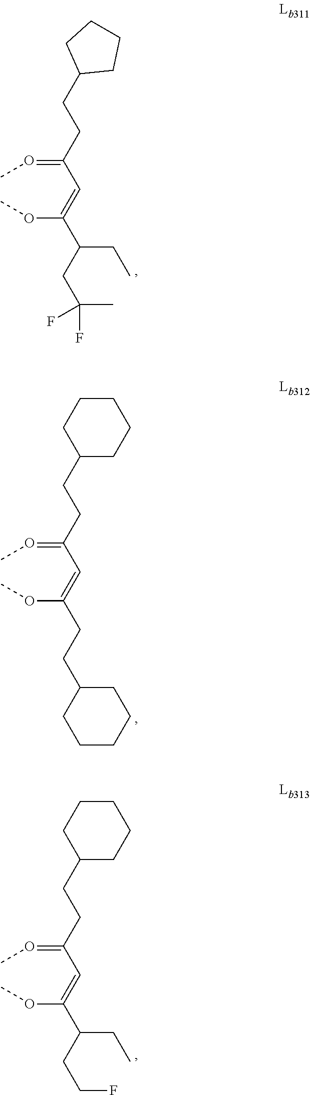 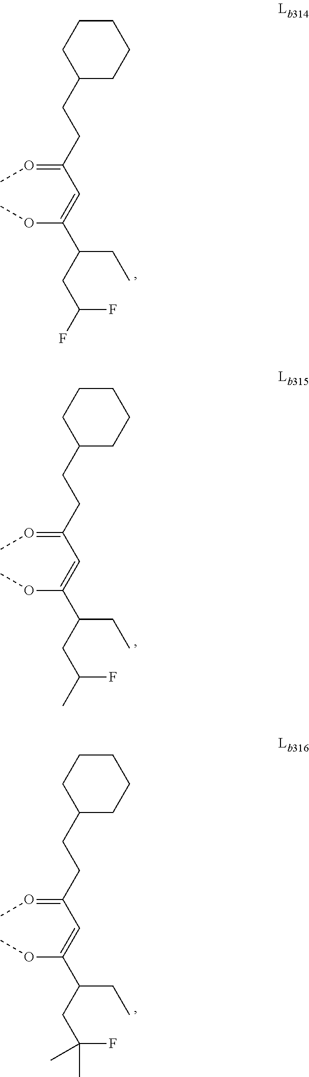 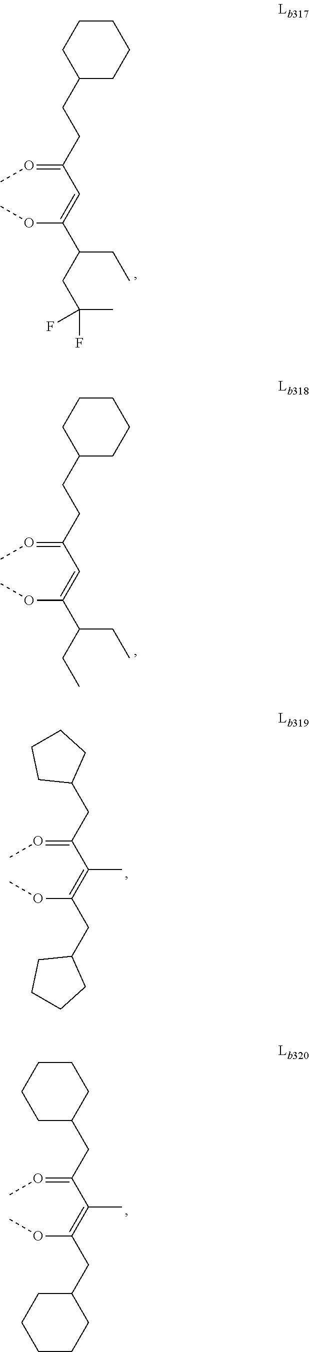 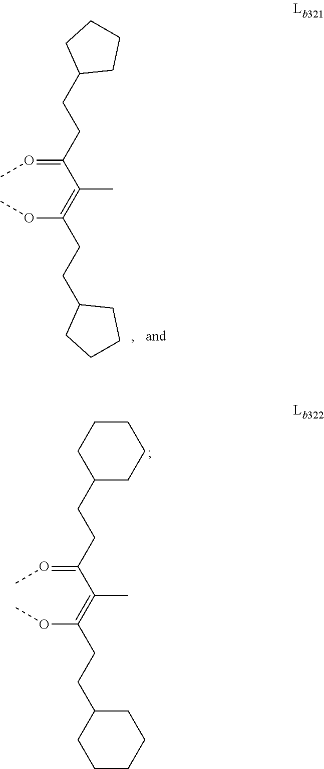
L_{c} is, at each occurrence identically or differently, selected from the group consisting of the following structures:

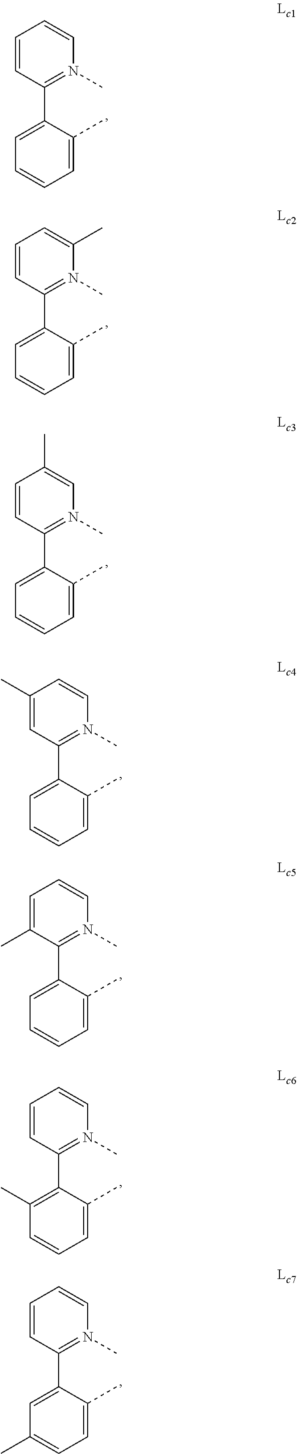

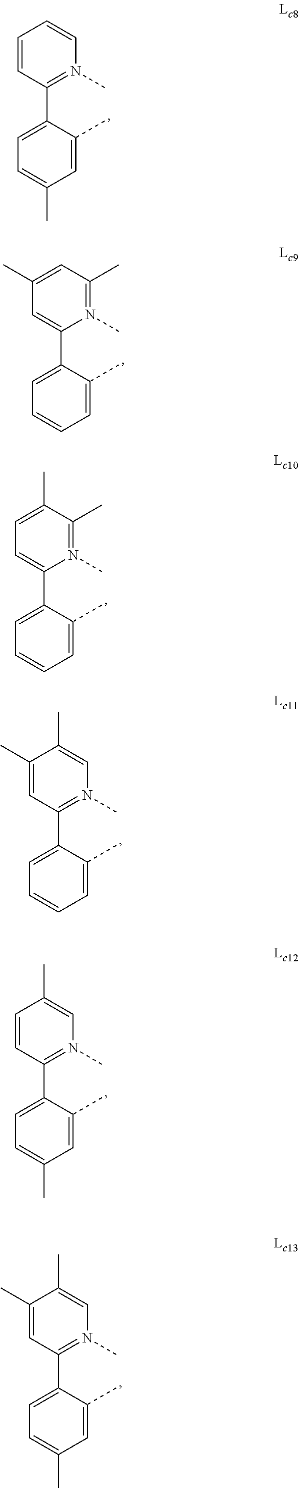

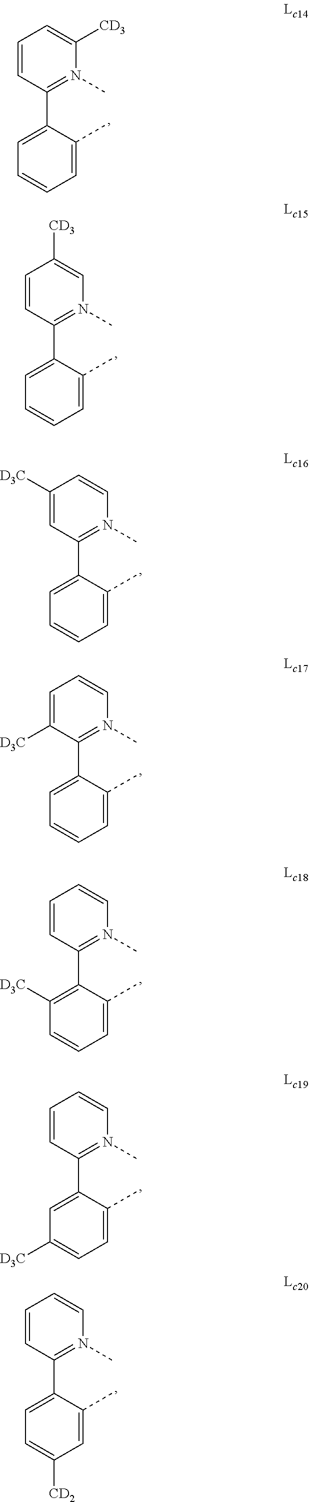

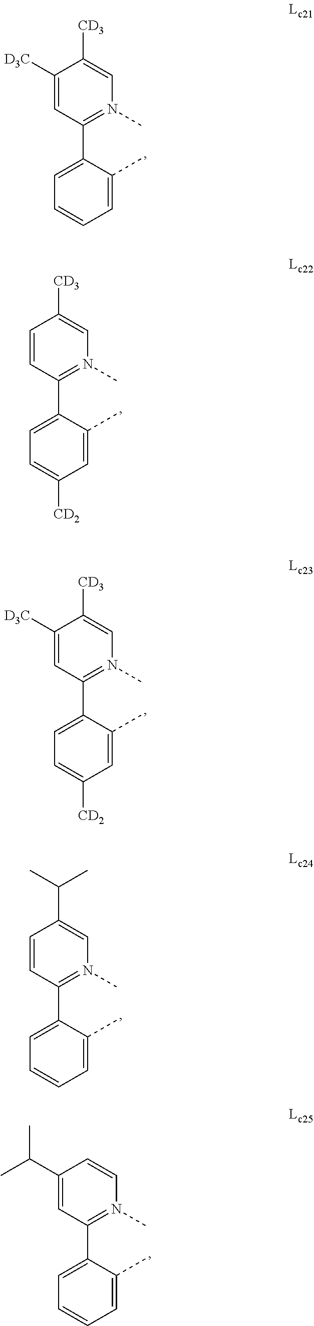

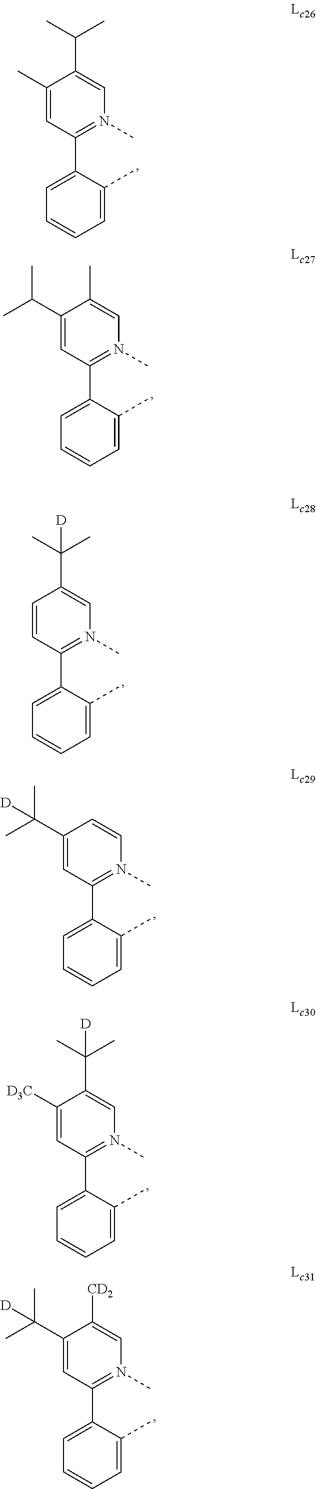

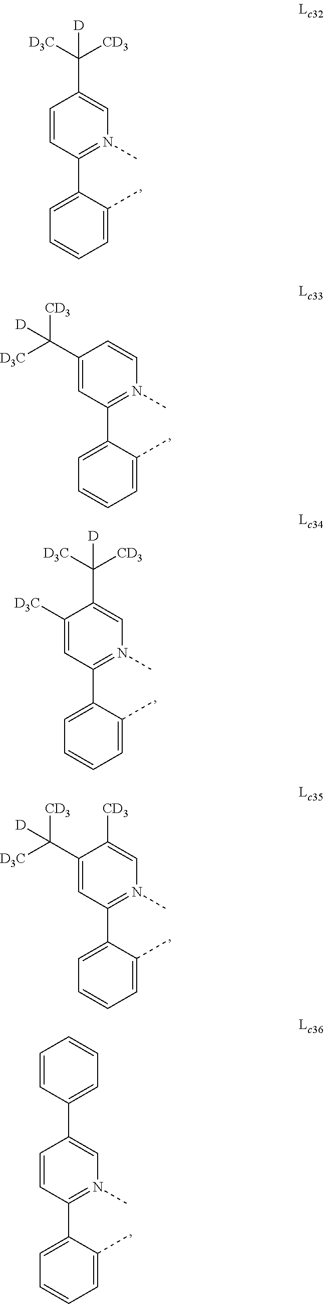

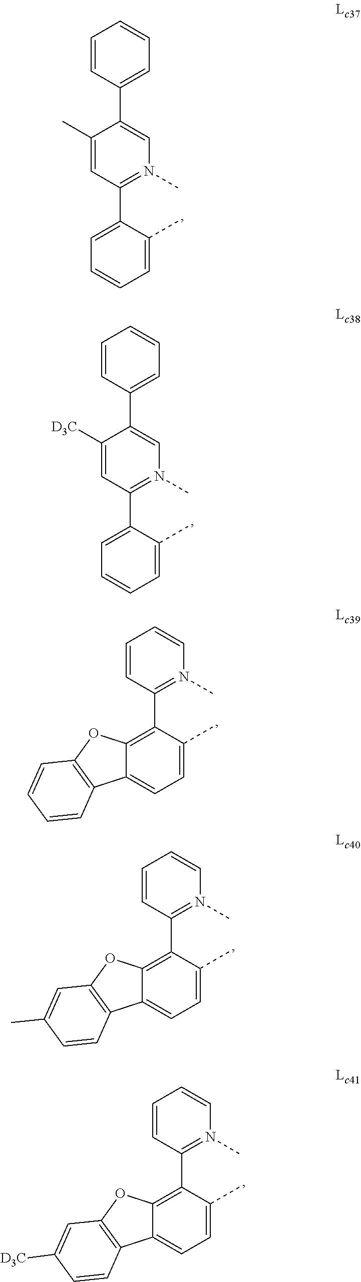

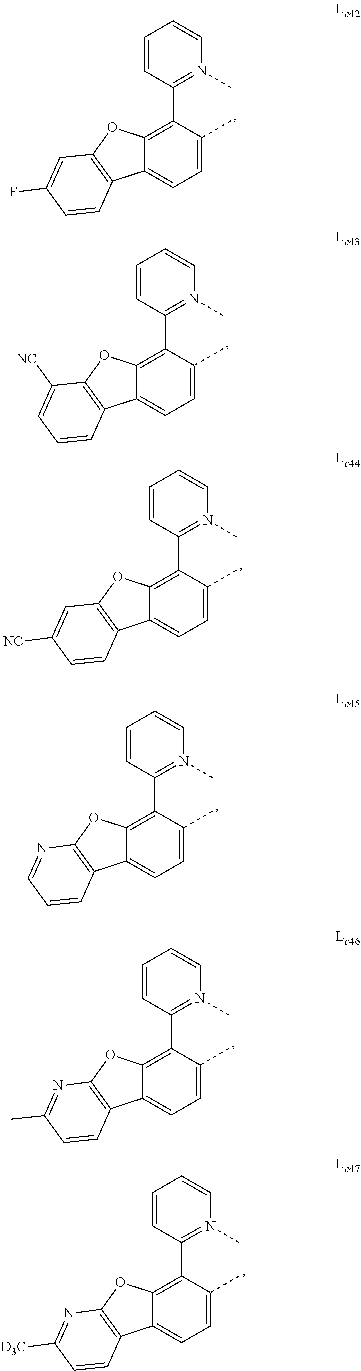

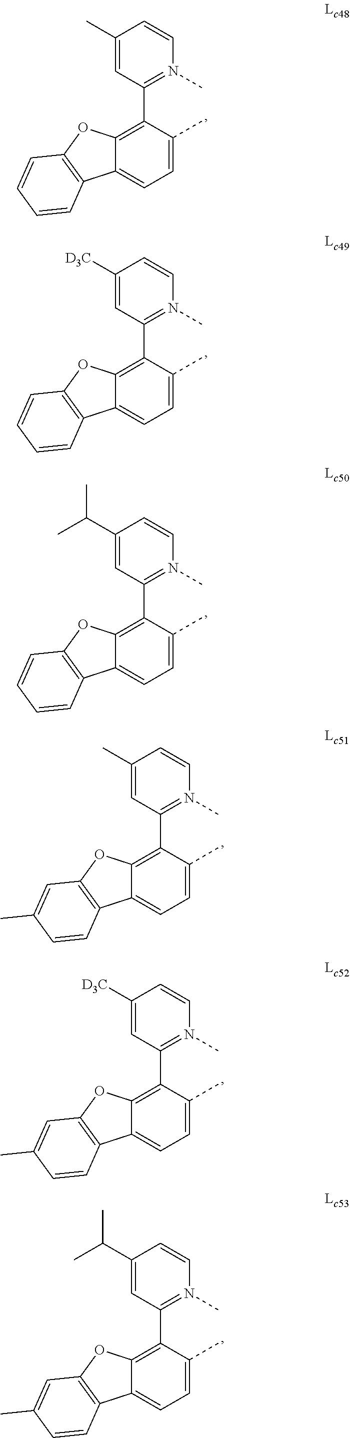

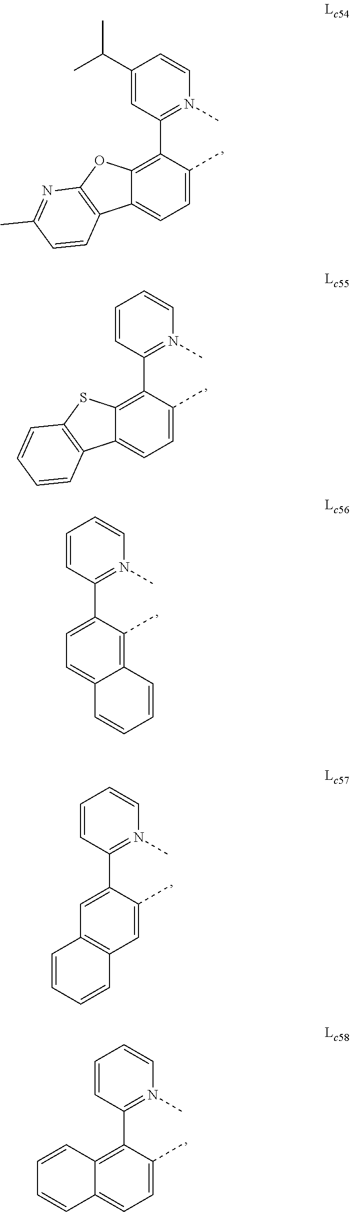

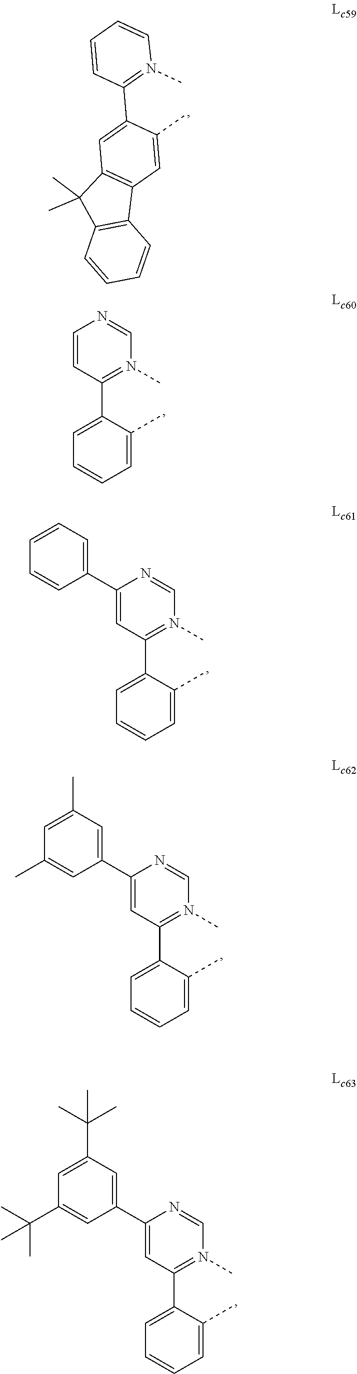

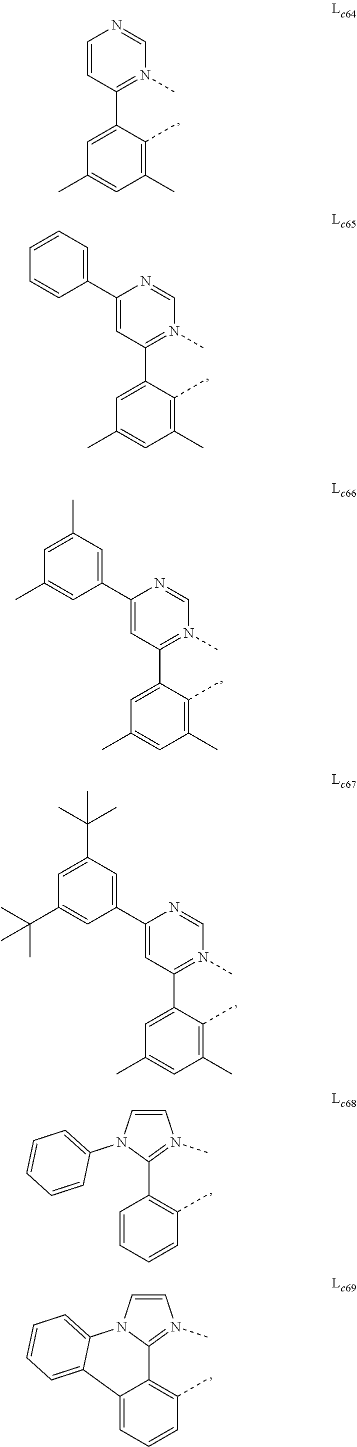

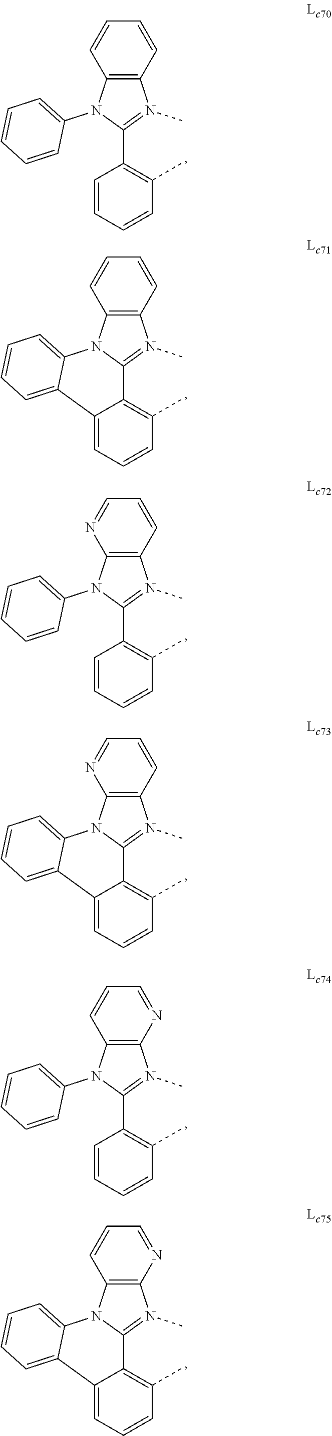

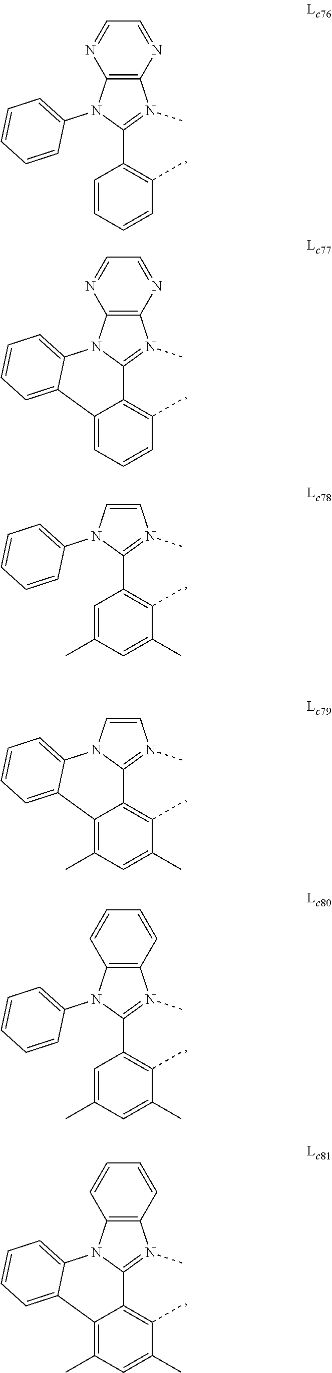

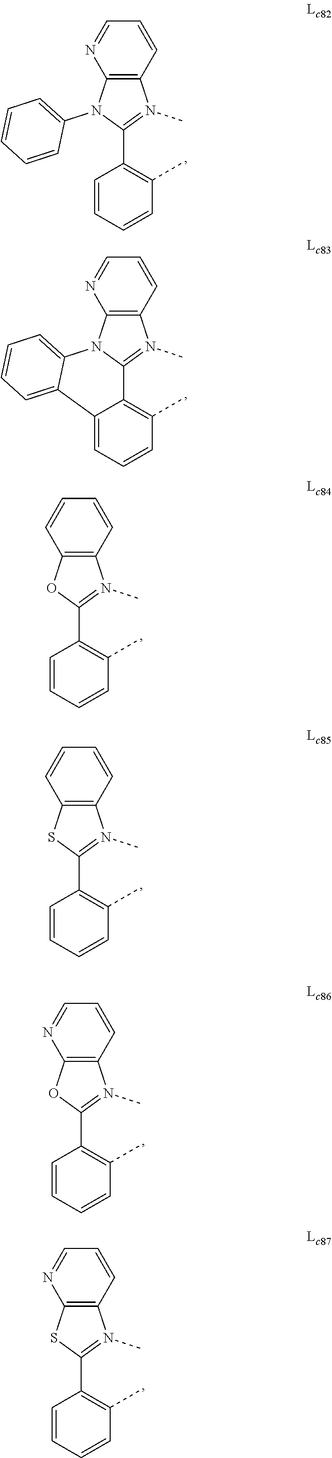

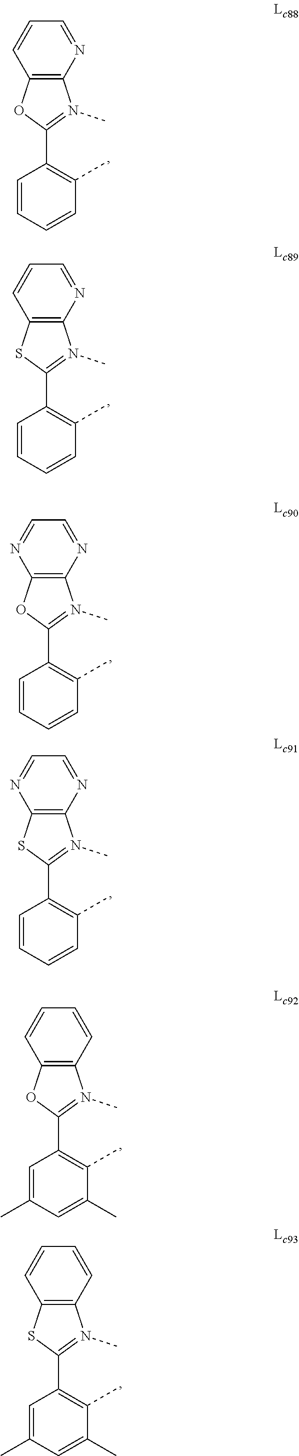

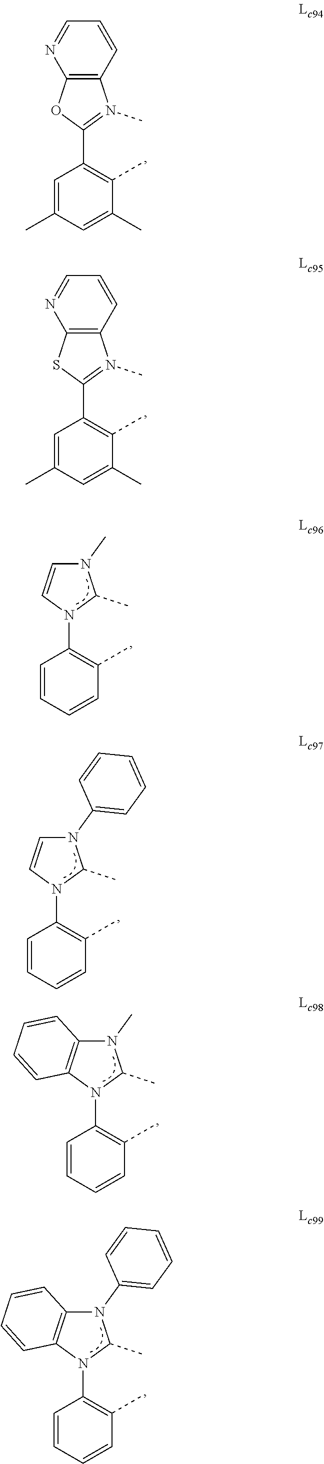

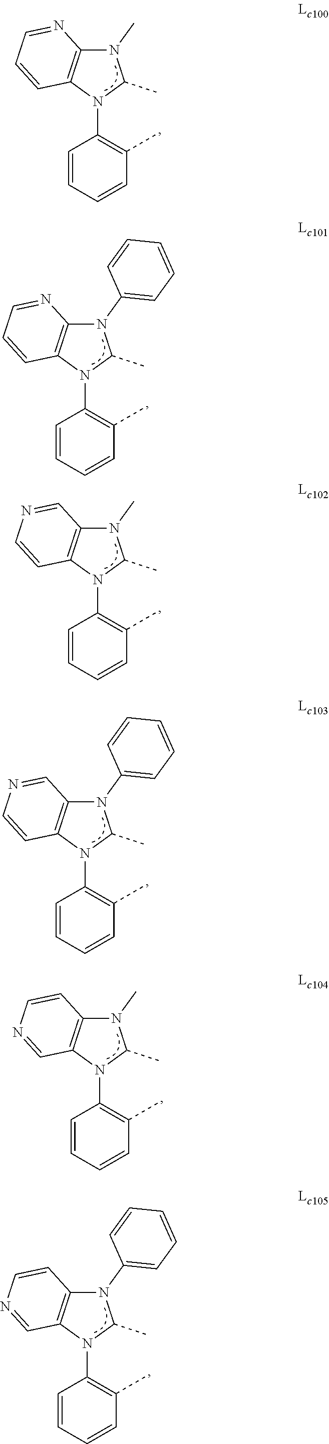

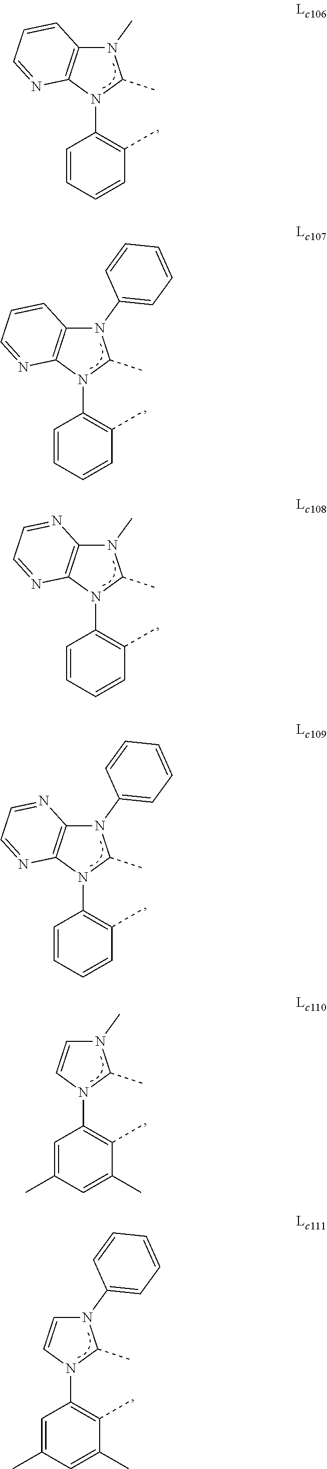

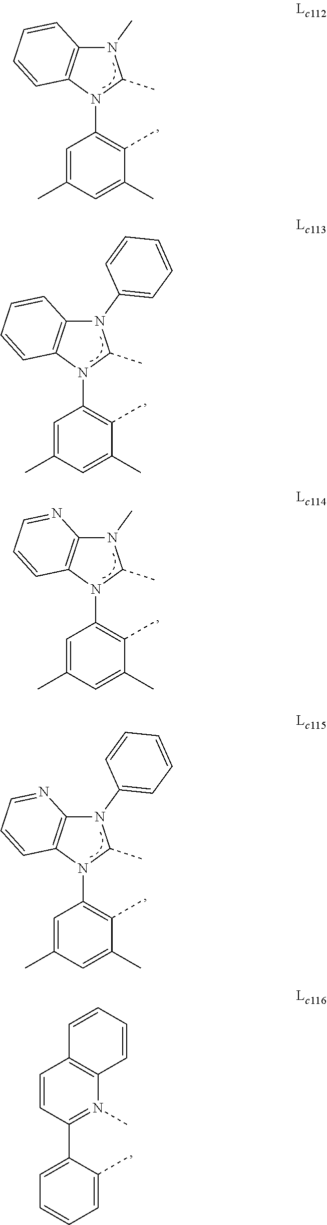

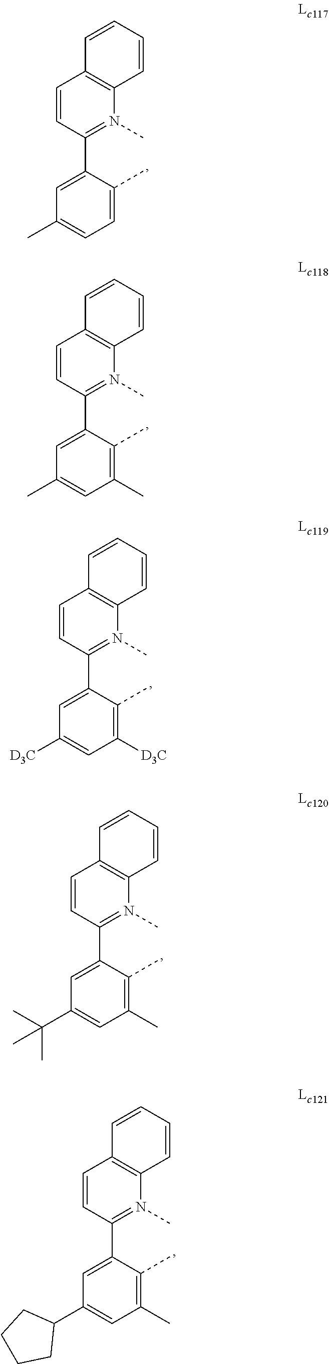

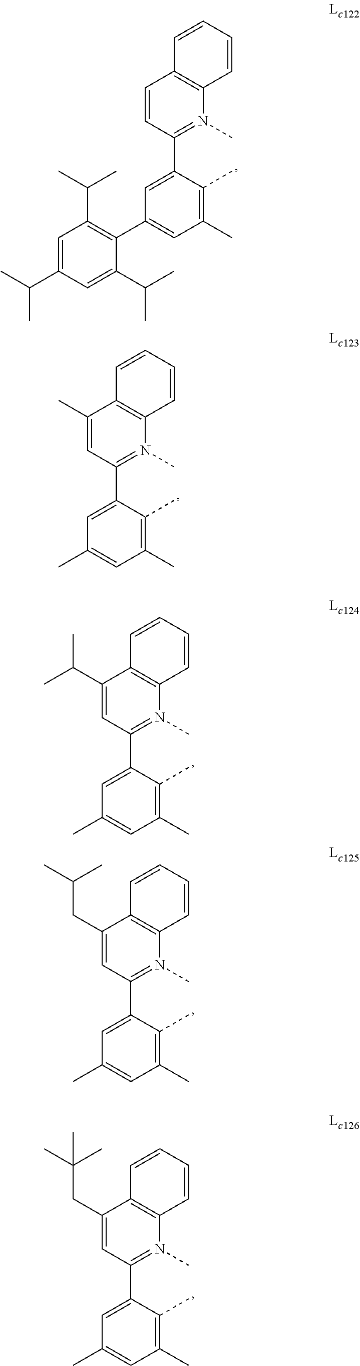

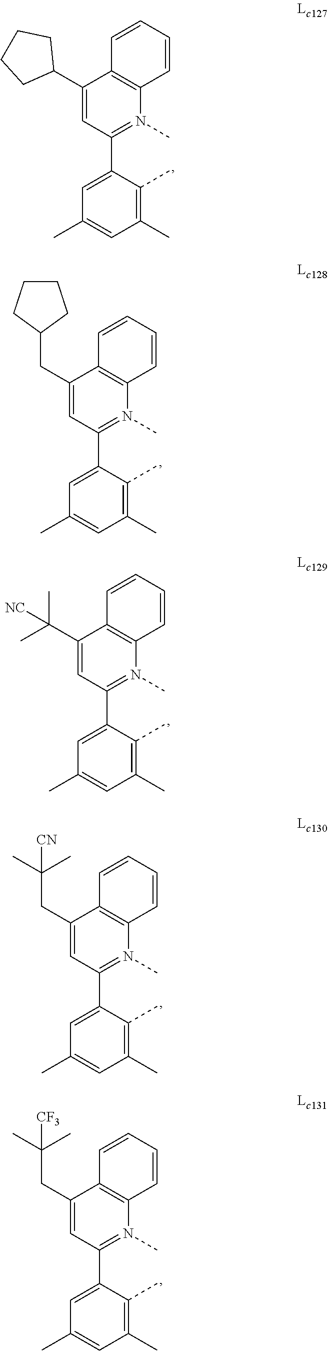

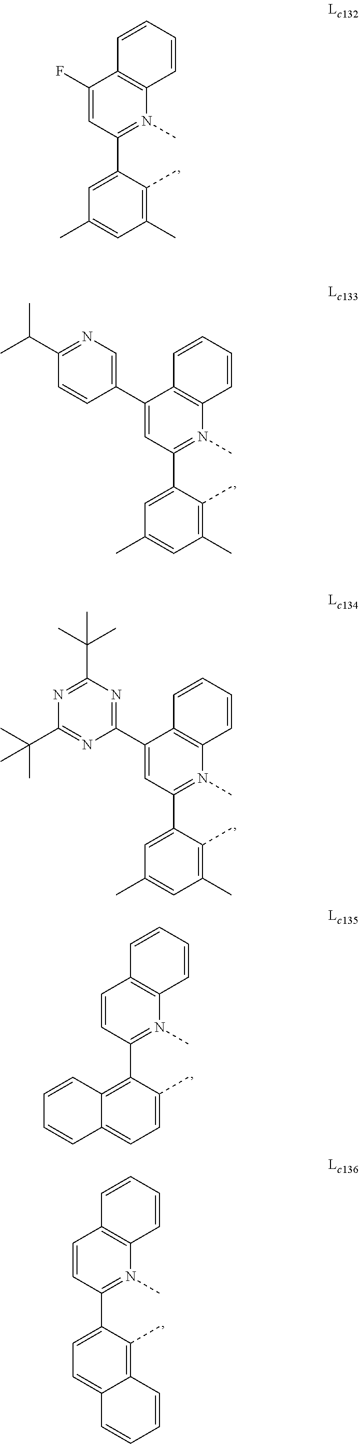

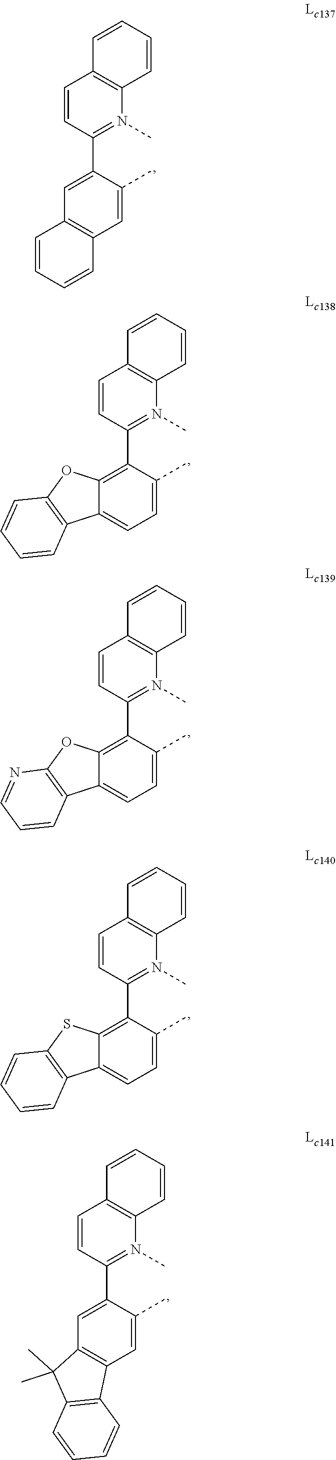

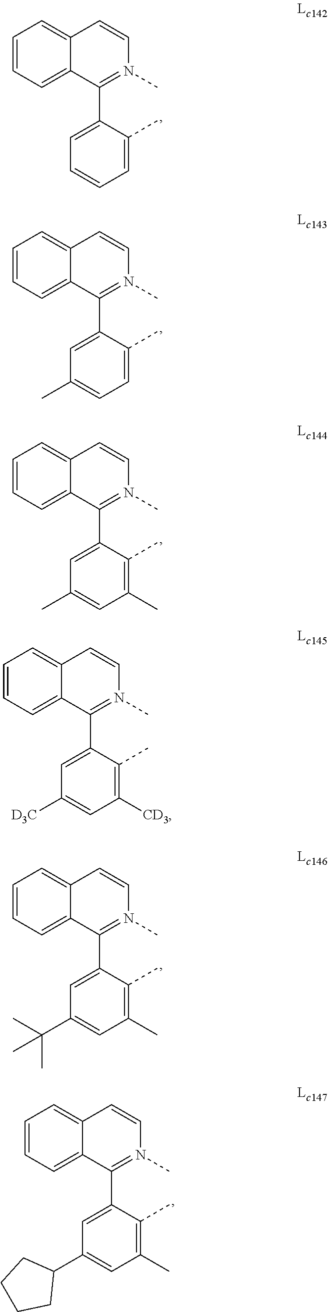

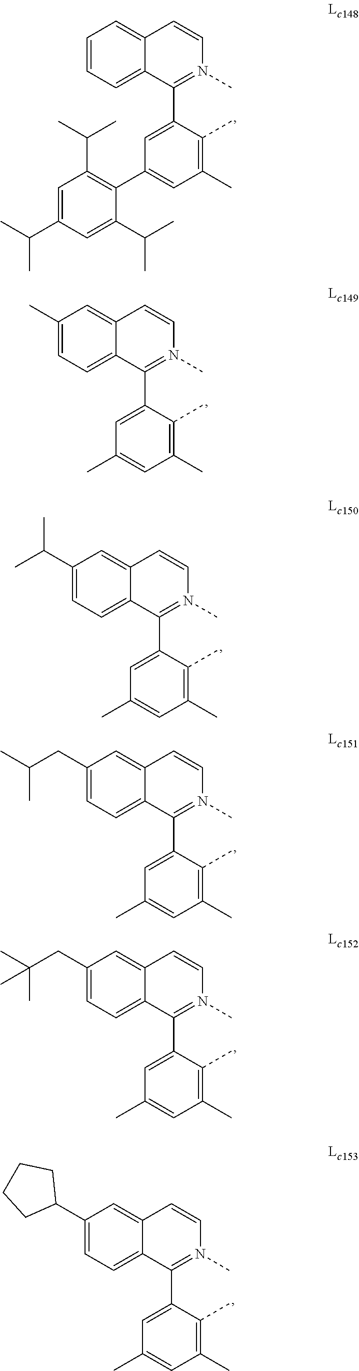

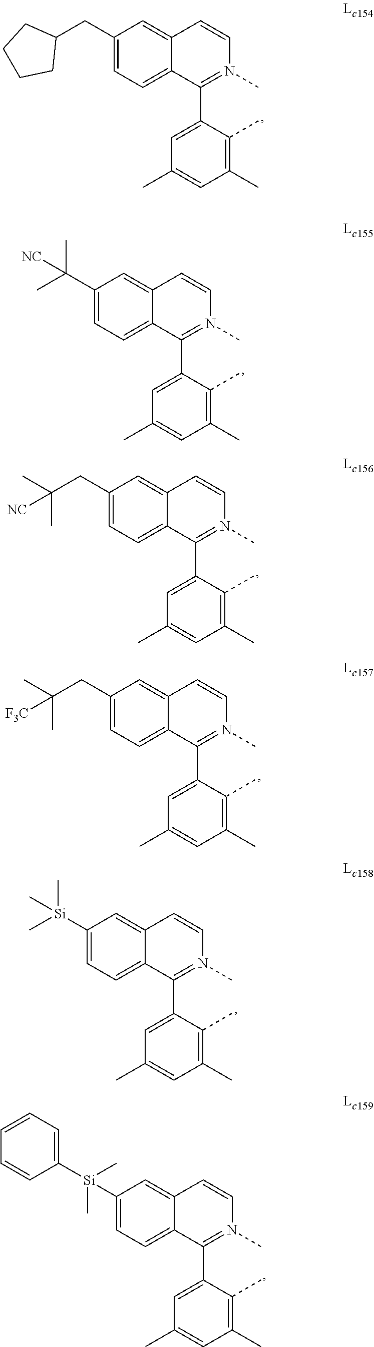

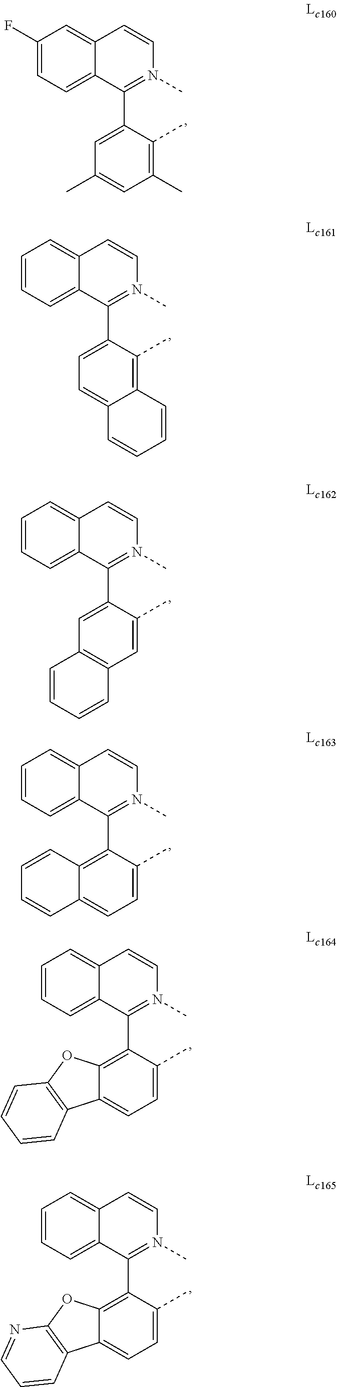

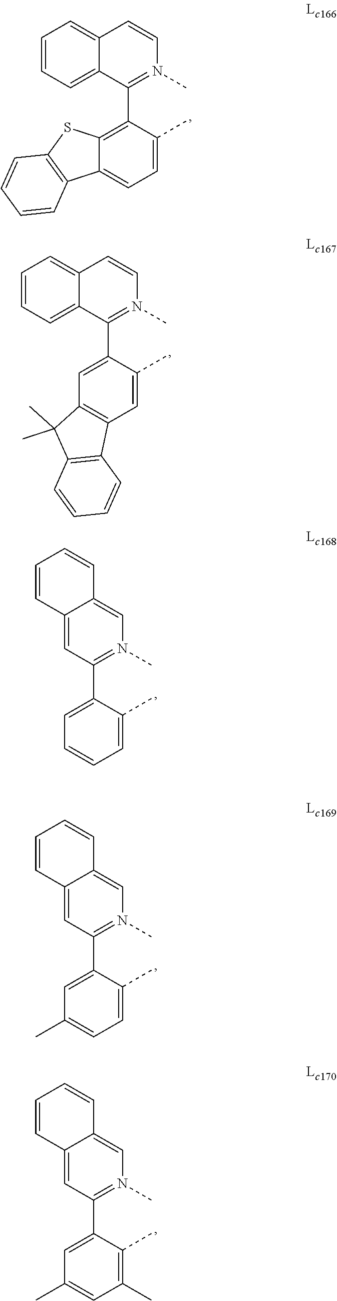

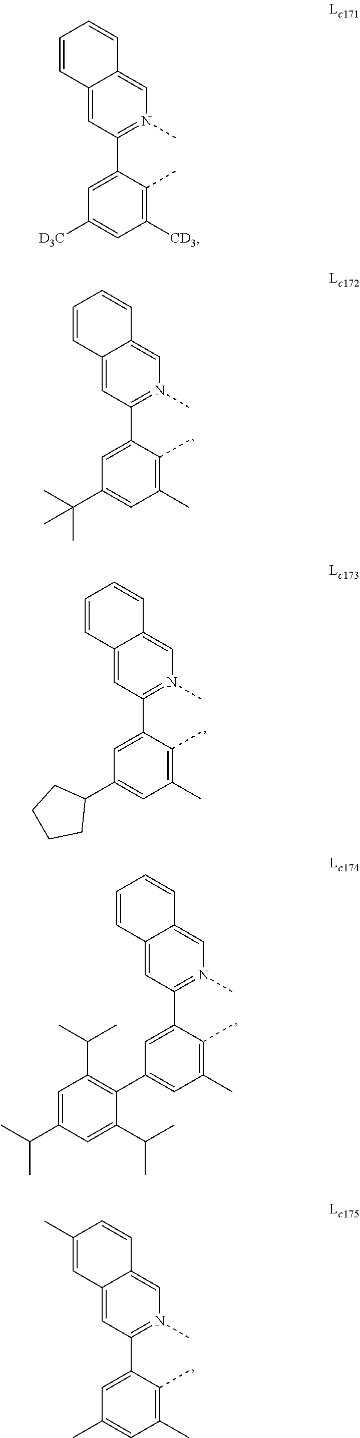

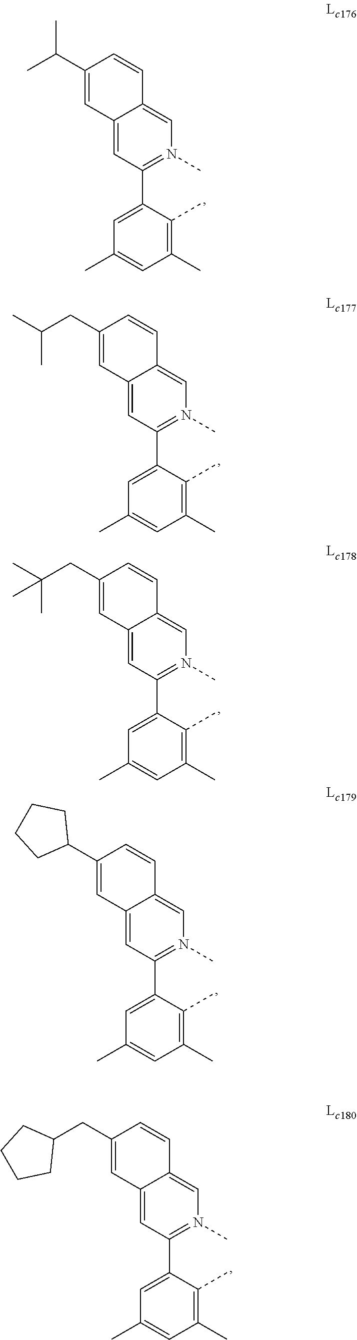

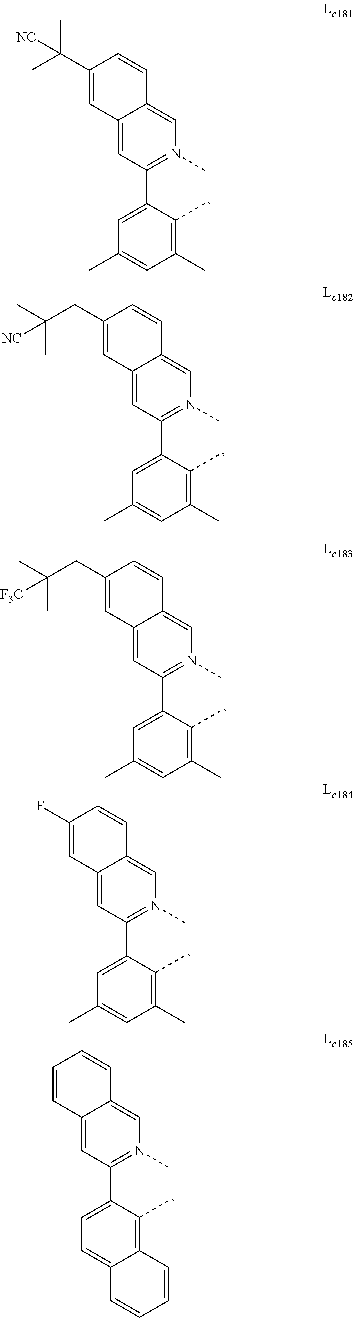

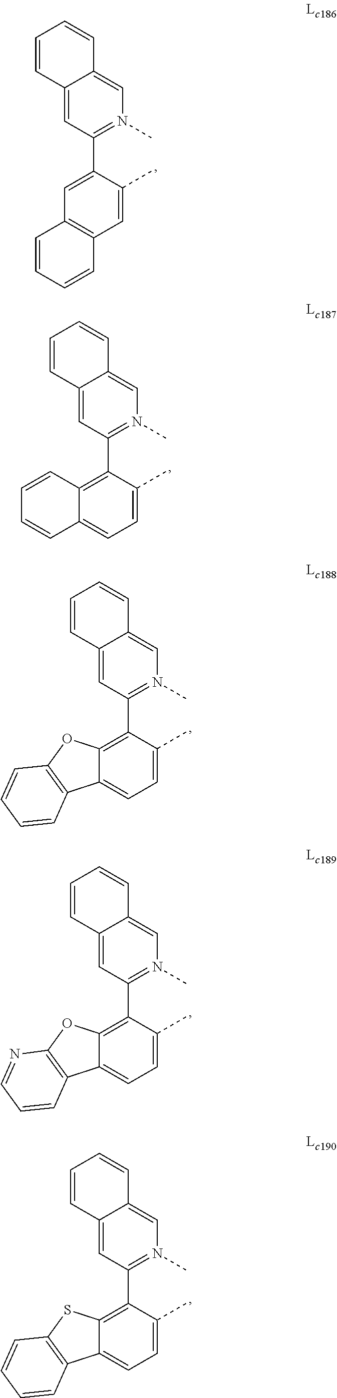

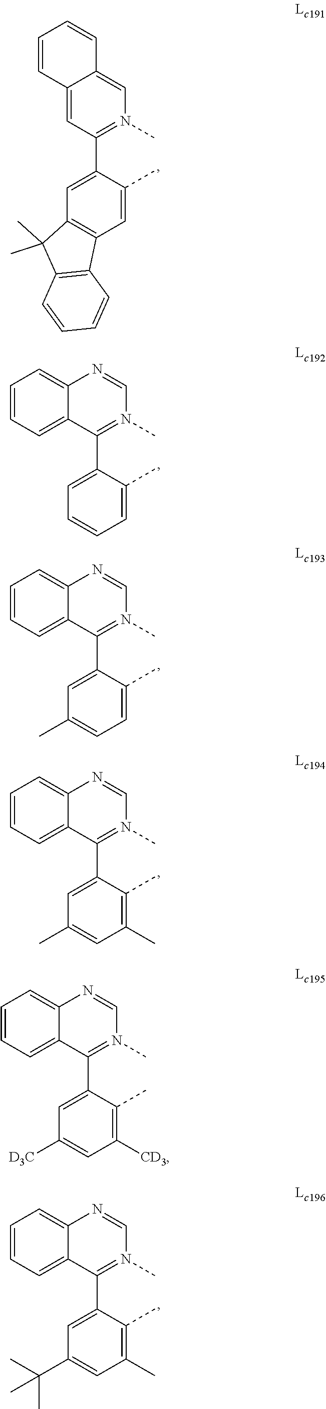

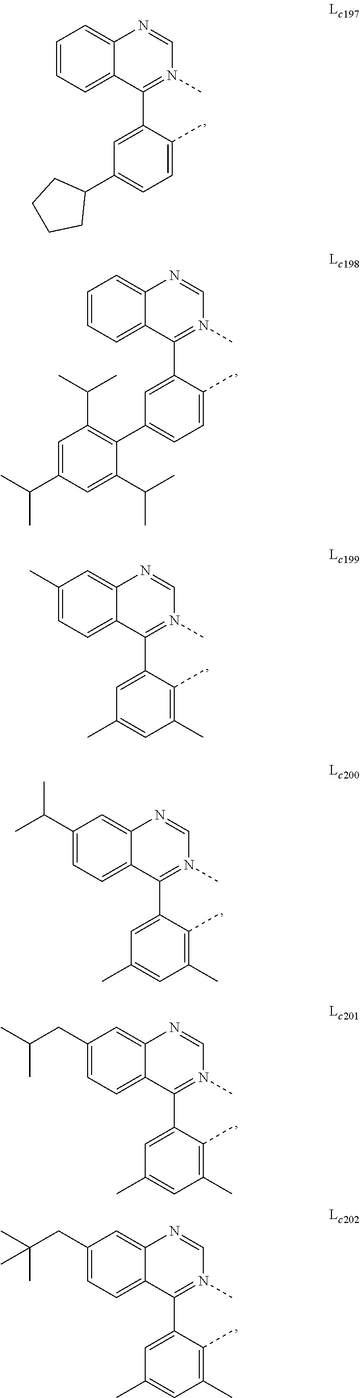

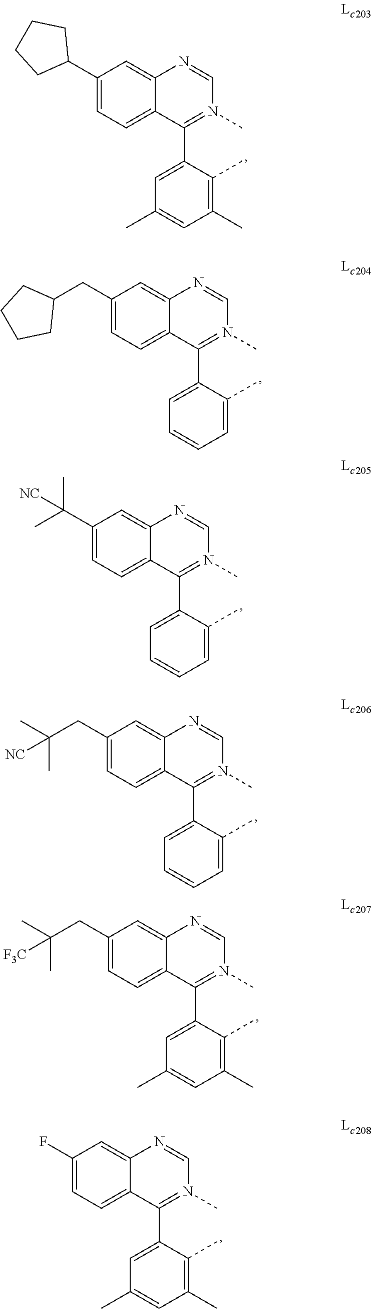

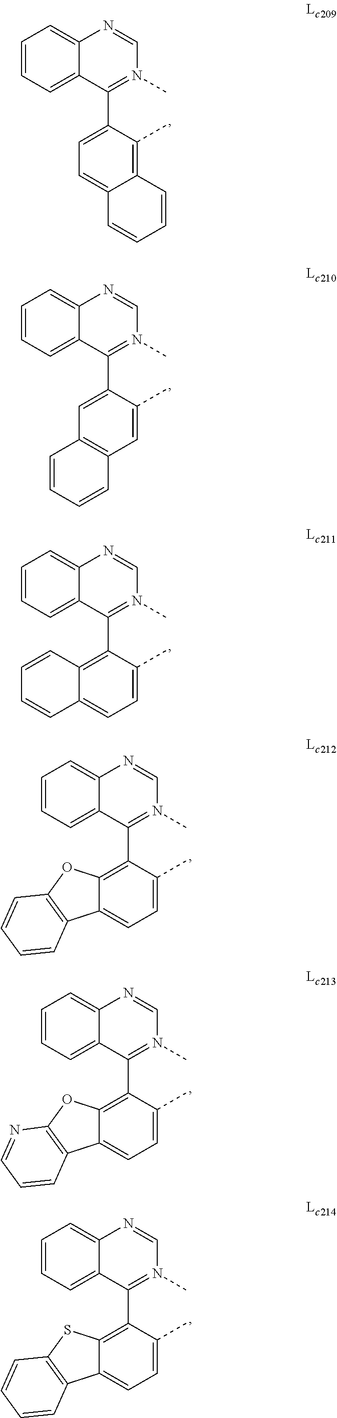

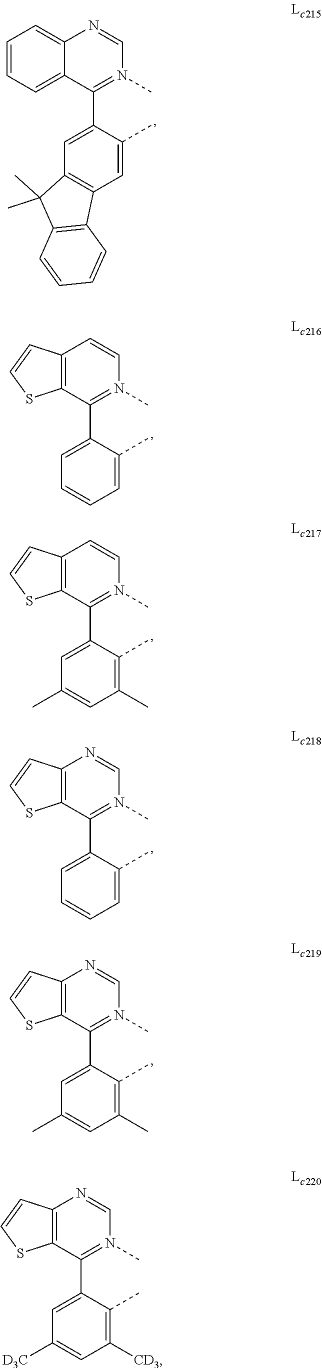

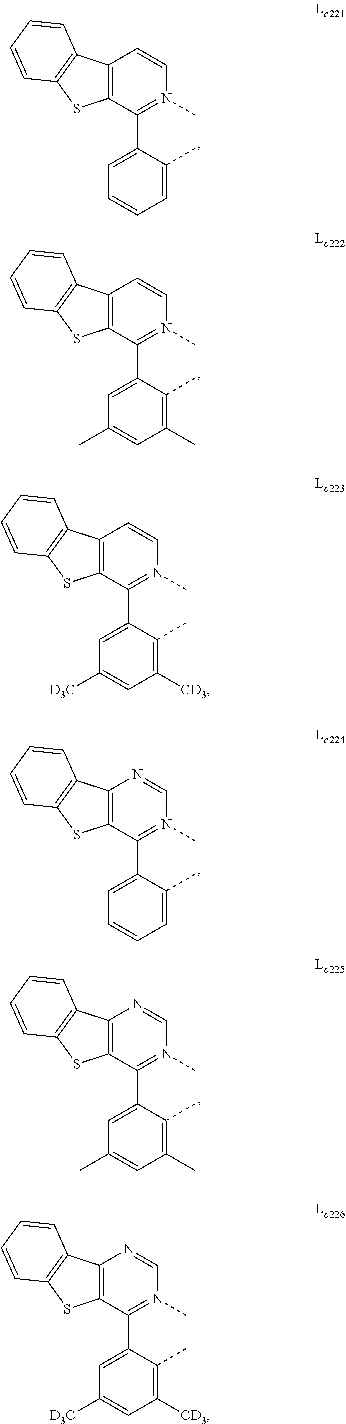

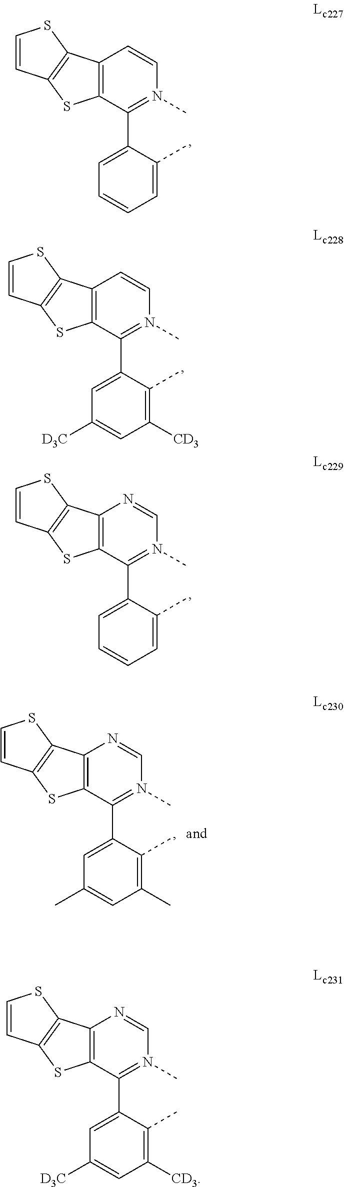

17. The metal complex according to claim 16, having a structure of Ir(Lₐ)₂(L_{b}), a structure of Ir(Lₐ)₂(L_{c}) or a structure of Ir(Lₐ)(L_{c})₂;
wherein when the metal complex has the structure of Ir(Lₐ)₂(L_{b}), Lₐ is, at each occurrence identically or differently, selected from any one or any two of the group consisting of Lₐ₁ to Lₐ₇₄₂, and L_{b} is selected from any one of the group consisting of L_{b1} to L_{b322};
when the metal complex has the structure of Ir(Lₐ)₂(L_{c}), Lₐ is, at each occurrence identically or differently, selected from any one or any two of the group consisting of Lₐ₁ to Lₐ₇₄₂, and L_{c} is selected from any one of the group consisting of L_{c1} to L_{c233};
when the metal complex has the structure of Ir(Lₐ)(L_{c})₂, Lₐ is selected from any one of the group consisting of Lₐ₁ to Lₐ₇₄₂, and L_{c} is, at each occurrence identically or differently, selected from any one or any two of the group consisting of L₁ to L_{c231};
preferably, the metal complex is selected from the group consisting of Compound 1 to Compound 160, and Compound 1 to Compound 120 have a structure of Ir(Lₐ)₂(L_{b}), wherein two Lₐ are identical, and Lₐ and L_{b} correspond to structures selected from the following table, respectively:

| Compound | | | Compound | | |
|---|---|---|---|---|---|
| No. | Lₐ | L_{b} | No. | Lₐ | L_{b} |
| 1 | Lₐ₂ | L_{b31} | 2 | Lₐ₃₀ | L_{b31} |
| 3 | Lₐ₅₀ | L_{b31} | 4 | Lₐ₉₂ | L_{b31} |
| 5 | Lₐ₁₀₁ | L_{b31} | 6 | Lₐ₁₁₉ | L_{b31} |
| 7 | Lₐ₁₃₁ | L_{b31} | 8 | Lₐ₁₆₇ | L_{b31} |
| 9 | Lₐ₁₈₆ | L_{b31} | 10 | Lₐ₁₉₂ | L_{b31} |
| 11 | Lₐ₃₀₀ | L_{b31} | 12 | Lₐ₃₁₂ | L_{b31} |
| 13 | Lₐ₃₂₄ | L_{b31} | 14 | Lₐ₄₄₈ | L_{b31} |
| 15 | Lₐ₄₉₅ | L_{b31} | 16 | Lₐ₂ | L_{b88} |
| 17 | Lₐ₃₀ | L_{b88} | 18 | Lₐ₅₀ | L_{b88} |
| 19 | Lₐ₉₂ | L_{b88} | 20 | Lₐ₁₀₁ | L_{b88} |
| 21 | Lₐ₁₁₉ | L_{b88} | 22 | Lₐ₁₃₁ | L_{b88} |
| 23 | Lₐ₁₆₇ | L_{b88} | 24 | Lₐ₁₈₆ | L_{b88} |
| 25 | Lₐ₁₉₂ | L_{b88} | 26 | Lₐ₃₀₀ | L_{b88} |
| 27 | Lₐ₃₁₂ | L_{b88} | 28 | Lₐ₃₂₄ | L_{b88} |
| 29 | Lₐ₄₄₈ | L_{b88} | 30 | Lₐ₄₉₅ | L_{b88} |
| 31 | Lₐ₂ | L_{b122} | 32 | Lₐ₃₀ | L_{b122} |
| 33 | Lₐ₅₀ | L_{b122} | 34 | Lₐ₉₂ | L_{b122} |
| 35 | Lₐ₁₀₁ | L_{b122} | 36 | Lₐ₁₁₉ | L_{b122} |
| 37 | Lₐ₁₃₁ | L_{b122} | 38 | Lₐ₁₆₇ | L_{b122} |
| 39 | Lₐ₁₈₆ | L_{b122} | 40 | Lₐ₁₉₂ | L_{b122} |
| 41 | Lₐ₃₀₀ | L_{b122} | 42 | Lₐ₃₁₂ | L_{b122} |
| 43 | Lₐ₃₂₄ | L_{b122} | 44 | Lₐ₄₄₈ | L_{b122} |
| 45 | Lₐ₄₉₅ | L_{b122} | 46 | Lₐ₂ | L_{b126} |
| 47 | Lₐ₃₀ | L_{b126} | 47 | Lₐ₅₀ | L_{b126} |
| 49 | Lₐ₉₂ | L_{b126} | 50 | Lₐ₁₀₁ | L_{b126} |
| 51 | Lₐ₁₁₉ | L_{b126} | 52 | Lₐ₁₃₁ | L_{b126} |
| 53 | Lₐ₁₆₇ | L_{b126} | 54 | Lₐ₁₈₆ | L_{b126} |
| 55 | Lₐ₁₉₂ | L_{b126} | 56 | Lₐ₃₀₀ | L_{b126} |
| 57 | Lₐ₃₁₂ | L_{b126} | 58 | Lₐ₃₂₄ | L_{b126} |
| 59 | Lₐ₄₄₈ | L_{b126} | 60 | Lₐ₄₉₅ | L_{b126} |
| 61 | Lₐ₂ | L_{b135} | 62 | Lₐ₃₀ | L_{b135} |
| 63 | Lₐ₅₀ | L_{b135} | 64 | Lₐ₉₂ | L_{b135} |
| 65 | Lₐ₁₀₁ | L_{b135} | 66 | Lₐ₁₁₉ | L_{b135} |
| 67 | Lₐ₁₃₁ | L_{b135} | 68 | Lₐ₁₆₇ | L_{b135} |
| 69 | Lₐ₁₈₆ | L_{b135} | 70 | Lₐ₁₉₂ | L_{b135} |
| 71 | Lₐ₃₀₀ | L_{b135} | 72 | Lₐ₃₁₂ | L_{b135} |
| 73 | Lₐ₃₂₄ | L_{b135} | 74 | Lₐ₄₄₈ | L_{b135} |
| 75 | Lₐ₄₉₅ | L_{b135} | 76 | Lₐ₂ | L_{b212} |
| 77 | Lₐ₃₀ | L_{b212} | 78 | Lₐ₅₀ | L_{b212} |
| 79 | Lₐ₉₂ | L_{b212} | 80 | Lₐ₁₀₁ | L_{b212} |
| 81 | Lₐ₁₁₉ | L_{b212} | 82 | Lₐ₁₃₁ | L_{b212} |
| 83 | Lₐ₁₆₇ | L_{b212} | 84 | Lₐ₁₈₆ | L_{b212} |
| 85 | Lₐ₁₉₂ | L_{b212} | 86 | Lₐ₃₀₀ | L_{b212} |
| 87 | Lₐ₃₁₂ | L_{b212} | 88 | Lₐ₃₂₄ | L_{b212} |
| 89 | Lₐ₄₄₈ | L_{b212} | 90 | Lₐ₄₉₅ | L_{b212} |
| 91 | Lₐ₂ | L_{b245} | 92 | Lₐ₃₀ | L_{b245} |
| 93 | Lₐ₅₀ | L_{b245} | 94 | Lₐ₉₂ | L_{b245} |
| 95 | Lₐ₁₀₁ | L_{b245} | 96 | Lₐ₁₁₉ | L_{b245} |
| 97 | Lₐ₁₃₁ | L_{b245} | 98 | Lₐ₁₆₇ | L_{b245} |
| 99 | Lₐ₁₈₆ | L_{b245} | 100 | Lₐ₁₉₂ | L_{b245} |
| 101 | Lₐ₃₀₀ | L_{b245} | 102 | Lₐ₃₁₂ | L_{b245} |
| 103 | Lₐ₃₂₄ | L_{b245} | 104 | Lₐ₄₄₈ | L_{b245} |
| 105 | Lₐ₄₉₅ | L_{b245} | 106 | Lₐ₂ | L_{b268} |
| 107 | Lₐ₃₀ | L_{b268} | 108 | Lₐ₅₀ | L_{b268} |
| 109 | Lₐ₉₂ | L_{b268} | 110 | Lₐ₁₀₁ | L_{b268} |
| 111 | Lₐ₁₁₉ | L_{b268} | 112 | Lₐ₁₃₁ | L_{b268} |
| 113 | Lₐ₁₆₇ | L_{b268} | 114 | Lₐ₁₈₆ | L_{b268} |
| 115 | Lₐ₁₉₂ | L_{b268} | 116 | Lₐ₃₀₀ | L_{b268} |
| 117 | Lₐ₃₁₂ | L_{b268} | 118 | Lₐ₃₂₄ | L_{b268} |
| 119 | Lₐ₄₄₈ | L_{b268} | 120 | Lₐ₄₉₅ | L_{b268} |

wherein Compound 121 to Compound 160 have a structure of Ir(Lₐ)₂(L_{b}), wherein the two Lₐ are different, and Lₐ and L_{b} correspond to structures in the following table, respectively;

| Compound | | | | Compound | | | |
|---|---|---|---|---|---|---|---|
| No. | Lₐ | Lₐ | L_{b} | No. | Lₐ | Lₐ | L_{b} |
| 121 | Lₐ₄ | Lₐ₂ | L_{b1} | 122 | Lₐ₅₀ | Lₐ₅₁ | L_{b1} |
| 123 | Lₐ₅₇ | Lₐ₅₈ | L_{b1} | 124 | Lₐ₁₁₉ | Lₐ₁₂₄ | L_{b1} |
| 125 | Lₐ₂₅₂ | Lₐ₂₅₃ | L_{b1} | 126 | Lₐ₃₀₀ | Lₐ₃₀₁ | L_{b1} |
| 127 | Lₐ₃₁₂ | Lₐ₃₁₃ | L_{b1} | 128 | Lₐ₃₂₄ | Lₐ₃₂₅ | L_{b1} |
| 129 | Lₐ₄ | Lₐ₂ | L_{b31} | 130 | Lₐ₅₀ | Lₐ₅₁ | L_{b31} |
| 131 | Lₐ₅₇ | Lₐ₅₈ | L_{b31} | 132 | Lₐ₁₁₉ | Lₐ₁₂₄ | L_{b31} |
| 133 | Lₐ₂₅₂ | Lₐ₂₅₃ | L_{b31} | 134 | Lₐ₃₀₀ | Lₐ₃₀₁ | L_{b31} |
| 135 | Lₐ₃₁₂ | Lₐ₃₁₃ | L_{b31} | 136 | Lₐ₃₂₄ | Lₐ₃₂₅ | L_{b31} |
| 137 | Lₐ₄ | Lₐ₂ | L_{b88} | 138 | Lₐ₅₀ | Lₐ₅₃ | L_{b88} |
| 139 | Lₐ₅₇ | Lₐ₅₈ | L_{b88} | 140 | Lₐ₁₁₉ | Lₐ₁₂₄ | L_{b88} |
| 141 | Lₐ₂₅₂ | Lₐ₂₅₃ | L_{b88} | 142 | Lₐ₃₀₀ | Lₐ₃₀₁ | L_{b88} |
| 143 | Lₐ₃₁₂ | Lₐ₃₁₃ | L_{b88} | 144 | Lₐ₃₂₄ | Lₐ₃₂₅ | L_{b88} |
| 145 | Lₐ₄ | Lₐ₂ | L_{b122} | 146 | Lₐ₅₀ | Lₐ₅₁ | L_{b122} |
| 147 | Lₐ₅₇ | Lₐ₅₈ | L_{b122} | 148 | Lₐ₁₁₉ | Lₐ₁₂₄ | L_{b122} |
| 149 | Lₐ₂₅₂ | Lₐ₂₅₃ | L_{b122} | 150 | Lₐ₃₀₀ | Lₐ₃₀₁ | L_{b122} |
| 151 | Lₐ₃₁₂ | Lₐ₃₁₃ | L_{b122} | 152 | Lₐ₃₂₄ | Lₐ₃₂₅ | L_{b122} |
| 153 | Lₐ₄ | Lₐ₂ | L_{b126} | 154 | Lₐ₅₀ | Lₐ₅₁ | L_{b126} |
| 155 | Lₐ₅₇ | Lₐ₅₈ | L_{b126} | 156 | Lₐ₁₁₉ | Lₐ₁₂₄ | L_{b126} |
| 157 | Lₐ₂₅₂ | Lₐ₂₅₃ | L_{b126} | 158 | Lₐ₃₀₀ | Lₐ₃₀₁ | L_{b126} |
| 159 | Lₐ₃₁₂ | Lₐ₃₁₃ | L_{b126} | 160 | Lₐ₃₂₄ | Lₐ₃₂₅ | L_{b126} |

18. An electroluminescent device, comprising:
an anode,
a cathode, and
an organic layer disposed between the anode and the cathode, wherein the organic layer comprises the metal complex according to claim 1.

19. The device according to claim 18, wherein the device emits red light or white light.

20. The device according to claim 18, wherein the organic layer is an emissive layer, and the metal complex is an emissive material: preferably, the emissive layer further comprises at least one host material; more preferably, the at least one host material comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

21. A compound composition, comprising the metal complex according to claim 1.
